(19) United States
(12) Patent Application Publication
(10) Pub. No.: US 2011/0042646 A1
(43) Pub. Date: Feb. 24, 2011

(54) Nitride semiconductor wafer, nitride semiconductor chip, method of manufacture thereof, and semiconductor device

(75) Inventors: Masataka Ohta, Osaka (JP); Takeshi Kamikawa, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/805,848

(22) Filed: Aug. 20, 2010

(30) Foreign Application Priority Data
Aug. 21, 2009 (JP) 2009-192047
Sep. 30, 2009 (JP) 2009-228384

(51) Int. Cl. H01L 29/12; H01L 29/20; H01L 21/20

(52) U.S. Cl. 257/14; 257/615; 438/478; 257/618; 257/E21.09; 257/E29.069; 257/E29.089

(57) ABSTRACT

A nitride semiconductor chip allows enhancement of luminous efficacy. The nitride semiconductor laser chip (nitride semiconductor chip) has a GaN substrate, which has a principal growth plane, and an active layer, which is formed on the principal growth plane of the GaN substrate and which has a quantum well structure including a well layer and a barrier layer. The principal growth plane is a plane having an off angle in the a-axis direction relative to the m plane. The barrier layer is formed of AlGaN, which is a nitride semiconductor containing Al.

This nonprovisional application claims priority under 35 U.S.C. §119(a) on Patent Application No. 2009-192047 filed in Japan on Aug. 21, 2009 and Patent Application No. 2009-228384 filed in Japan on Sep. 30, 2009, the entire contents of which are hereby incorporated by reference.

### BACKGROUND OF THE INVENTION

1. Field of the Invention

The present invention relates to a nitride semiconductor wafer, a nitride semiconductor chip, a method of manufacture thereof, and a semiconductor device. More particularly, the invention relates to a nitride semiconductor wafer provided with a nitride semiconductor substrate, a nitride semiconductor chip, a method of manufacture thereof, and a semiconductor device.

2. Description of Related Art

Nitride semiconductors as exemplified by GaN, AlN, InN, and their mixed crystals are characterized by having wider band gaps Eg than AlGaInAs- and AlGaInP-based semiconductors and in addition being direct band gap materials. For these reasons, nitride semiconductors have been receiving attention as materials for building semiconductor light-emitting chips such as semiconductor laser chips emitting light in wavelength regions from ultraviolet to green and light-emitting diode chips covering wide emission wavelength ranges from ultraviolet to red, and are expected to find wide application in projectors and full-color displays, and further in environmental, medical, and other fields.

On the other hand, in recent years, many research institutions have been making vigorous attempts to realize semiconductor light-emitting chips emitting light in a green region (green semiconductor lasers) by making longer the emission wavelengths of semiconductor light-emitting chips using nitride semiconductors.

Generally, in a semiconductor light-emitting chip using a nitride semiconductor, a substrate (nitride semiconductor substrate) of GaN, which has a hexagonal crystal system, is used, and its c plane (the (0001) plane) is used as the principal growth plane. By stacking nitride semiconductor layers including an active layer on the c plane, a nitride semiconductor light-emitting chip is formed. Generally, in a case where a nitride semiconductor light-emitting chip is formed by use of a nitride semiconductor substrate, an active layer containing In is used, and by increasing the In composition ratio, a longer emission wavelength is sought.

Inconveniently, however, the c plane of a GaN substrate is a polar plane having polarity in the c-axis direction, and therefore stacking nitride semiconductor layers including an active layer on the c plane causes spontaneous polarization in the active layer. Also inconveniently, when nitride semiconductor layers including an active layer are stacked on the c plane, as the In composition ratio increases, lattice strain increases, inducing in the active layer a strong internal electric field due to piezoelectric polarization. The internal electric field reduces the overlap between the wave functions of electrons and holes, and thus diminishes the rate of radiative recombination. Accordingly, increasing the In composition ratio in an attempt to realize light emission in a green region suffers from the problem that, as the emission wavelength is lengthened, luminous efficacy significantly lowers.

To avoid the effects of spontaneous polarization and piezoelectric polarization, therefore, there are nowadays proposed nitride semiconductor light-emitting chips having nitride semiconductor layers stacked not on the c plane as commonly practiced but on the m plane (the {1-100} plane), which is a non-polar plane. Such nitride semiconductor light-emitting chips are disclosed, for example, in JP-A-2008-226865.

JP-A-2008-226865 mentioned above discloses a Fabry-Pérot semiconductor laser diode with reduced threshold current. This semiconductor laser diode (nitride semiconductor light-emitting chip) is provided with a GaN substrate of which the m plane, which is a non-polar plane, is used as the principal growth plane, and on this principal growth plane (the m plane), individual nitride semiconductor layers including an active layer are stacked. Here, the active layer has a multiple quantum well structure, and includes a barrier layer formed of GaN.

The m plane of a GaN substrate is a crystal plane perpendicular to the c plane, and therefore stacking individual nitride semiconductor layers including an active layer on the m plane causes the c axis, which is an axis of polarization, to lie on the plane of the active layer. This helps avoid the effects of spontaneous polarization and piezoelectric polarization and suppress a lowering in luminous efficacy.

As described above, by use of a nitride semiconductor substrate having the m plane as the principal growth plane, it is possible to obtain a nitride semiconductor light-emitting chip in which a lowering in luminous efficacy resulting from spontaneous polarization and piezoelectric polarization is suppressed.

Even by use of the conventional active layer structure disclosed in JP-A-2008-226865, however, the luminous efficacy obtained cannot be said to be satisfactorily high. Thus, there still remains room for improvement in luminous efficacy.

### SUMMARY OF THE INVENTION

The present invention has been devised to overcome the problems mentioned above, and it is an object of the present invention to provide a nitride semiconductor chip with enhanced luminous efficacy, a nitride semiconductor wafer, a method of manufacture of a nitride semiconductor chip, and a semiconductor device provided with such a nitride semiconductor chip.

Another object of the invention is to provide a nitride semiconductor chip that offers enhanced device characteristics and increased yields, a nitride semiconductor wafer, a method of manufacture of a nitride semiconductor chip, and a semiconductor device provided with such a nitride semiconductor chip.

Yet another object of the invention is to provide a nitride semiconductor chip with superb device characteristics and high reliability, and a method of manufacture thereof.

Through various experiments conducted and intensive studies made with attention paid to the problems mentioned above, the inventors of the present invention have ascertained that, when a GaN layer or an InGaN layer is used as a barrier layer in an active layer, dark lines may appear in the light emission pattern. It has been found out that, to suppress appearance of such dark lines, it is very effective to form a barrier layer out of a nitride semiconductor containing Al.

Moreover, the inventors have also found out that forming a light-emitting diode chip by stacking nitride semiconductor layers on a nitride semiconductor substrate having no off angle and having the m plane as the principal growth plane, and injecting current into the light-emitting diode chip to make it produce EL emission, results in a bright-spotted emission pattern. Then, through intensive studies, the inventors have found out that, by using as the principal growth plane of a nitride semiconductor substrate a plane having an off angle in the a-axis direction relative to the m plane, it is possible to suppress bright-spotted EL emission pattern.

According to a first aspect of the invention, a nitride semiconductor chip is provided with: a nitride semiconductor substrate having a principal growth plane; and an active layer formed to the principal growth plane side of the nitride semiconductor substrate and having a quantum well structure including a well layer and a barrier layer. Here, the principal growth plane is a plane having an off angle in an a-axis direction relative to an m plane, and the barrier layer is formed of a nitride semiconductor containing Al.

In this nitride semiconductor chip according to the first aspect, by using a nitride semiconductor layer containing Al as the barrier layer as described above, it is possible to almost completely suppress appearance of a dark line. This makes it possible to suppress a lowering in luminous efficacy resulting from appearance of a dark line.

Moreover, according to the first aspect, by forming the barrier layer out of a nitride semiconductor containing Al, it is possible to enhance the flatness of the barrier layer. Thus, by forming the well layer on the barrier layer with high flatness, it is possible to suppress a non-uniform distribution of In composition across the plane in the well layer. In addition, it is also possible to enhance the crystallinity of the active layer (well layer). This makes it possible to further enhance luminous efficacy.

Moreover, in the nitride semiconductor chip according to the first aspect, by using as the principal growth plane of the nitride semiconductor substrate a plane having an off angle in the a-axis direction relative to the m plane as described above, it is possible to suppress a bright-spotted EL emission pattern. That is, with that configuration, it is possible to improve the EL emission pattern of the nitride semiconductor chip (suppress bright-spotted emission, variations in wavelength across the plane, etc.). This makes it possible to enhance the luminous efficacy of the nitride semiconductor chip. Moreover, by enhancing luminous efficacy, it is possible to obtain a high-luminance nitride semiconductor chip. One reason that an effect of suppressing bright-spotted emission as described above is obtained is considered to be as follows: as a result of the principal growth plane of the nitride semiconductor substrate having an off-angle in the a-axis direction relative to the m plane, when the nitride semiconductor layer including the active layer is grown on the principal growth plane, the direction of migration of atoms changes.

Furthermore, according to the first aspect, by suppressing a bright-spotted EL emission pattern, it is possible to make the EL emission pattern uniform, and thus it is possible to reduce the driving voltage. By suppressing bright-spotted emission, it is possible to obtain a uniform EL emission pattern, and thus it is possible to increase gain in the formation of a nitride semiconductor laser chip.

As described above, according to the first aspect, with the configuration described above, it is possible to greatly enhance luminous efficacy. Moreover, by enhancing the luminous efficacy, it is possible to enhance device characteristics and reliability, and thus it is possible to obtain a nitride semiconductor chip with superb device characteristics and high reliability.

In the nitride semiconductor chip according to the first aspect described above, preferably, the barrier layer is formed of a nitride semiconductor containing Al, Ga, and N. With this configuration, it is possible to easily enhance the flatness of the barrier layer, and in addition it is possible to easily suppress appearance of a dark line.

In the nitride semiconductor chip according to the first aspect described above, it is preferable that the barrier layer be formed of AlInGaN.

In the nitride semiconductor chip according to the first aspect described above, the barrier layer may be formed of AlGaN. Also in a case where the barrier layer is formed of AlGaN in this way, it is possible to obtain effects similar to those obtained in a case where the barrier layer is formed of AlInGaN.

In the nitride semiconductor chip according to the first aspect described above, the active layer may be so formed as to include a plurality of barrier layers as the barrier layer. In this case, at least part of the plurality of barrier layers may be formed of AlInGaN.

In the nitride semiconductor chip according to the first aspect described above, preferably, the absolute value of the off angle in the a-axis direction is greater than 0.1 degrees. With this configuration, it is possible to easily suppress a bright-spotted EL emission pattern and variations in wavelength across the plane while suppressing appearance of a dark line.

In the nitride semiconductor chip according to the first aspect described above, it is preferable that the well layer be formed of a nitride semiconductor containing In and have an In composition ratio of 0.15 or more but 0.45 or less. In the nitride semiconductor chip according to the first aspect described above, even in a case where the In composition ratio in the well layer is 0.15 or more, that is, even under conditions where a bright-spotted EL emission pattern is prominent, it is possible to effectively suppress a bright-spotted EL emission pattern, and thus it is possible to obtain a prominent effect of suppressing bright-spotted emission. On the other hand, by making the In composition ratio in the well layer equal to or less than 0.45, it is possible to effectively suppress the inconvenience of a large number of dislocations developing in the active layer as a result of strain such as lattice mismatch due to the In composition ratio in the well layer being more than 0.45.

In the nitride semiconductor chip according to the first aspect described above, in a case where the barrier layer is formed of a nitride semiconductor containing Al, it is preferable that the well layer be formed of InGaN.

In the nitride semiconductor chip according to the first aspect described above, it is preferable that the active layer be given a two-layer quantum well structure. With this configuration, it is possible to obtain an effect of suppressing bright-spotted emission and an effect of suppressing a dark line, and in addition it is possible to easily reduce the driving voltage. Thus, this too makes it possible to enhance device characteristics and reliability.

In the nitride semiconductor chip according to the first aspect described above, the active layer may be given a single-layer quantum well structure. Also with this configuration, it is possible to obtain an effect of suppressing bright-spotted emission and an effect of suppressing a dark line, and in addition it is possible to easily reduce the driving voltage.

In the nitride semiconductor chip according to the first aspect described above, it is preferable that the nitride semiconductor substrate be formed of GaN.

In the nitride semiconductor chip according to the first aspect described above, preferably, on the principal growth plane of the nitride semiconductor substrate, a nitride semiconductor layer containing Al is formed in contact with the principal growth plane. With this configuration, it is possible to obtain good surface morphology; thus, it is possible to give the nitride semiconductor layer a uniform thickness distribution across the plane, and in addition it is possible to give the semiconductor layer stacked on that nitride semiconductor layer a uniform thickness distribution across the plane. Moreover, by enhancing surface morphology, it is possible to reduce variations in device characteristics, and thus it is possible to increase manufacturing yields. This makes it possible to easily obtain chips having characteristics within the rated ranges. Moreover, by enhancing surface morphology, it is possible to further enhance device characteristics and reliability.

In the nitride semiconductor chip according to the first aspect described above, preferably, to the principal growth plane side of the nitride semiconductor substrate, a pair of guide layers are formed between which the active layer is formed, and the guide layers are formed of a nitride semiconductor containing In. With this configuration, it is possible to effectively achieve light confinement, and thus it is possible to further enhance luminous efficacy. Moreover, with that configuration, it is possible to further enhance luminous efficacy, and thus it is possible to further increase gain in the formation of a nitride semiconductor laser chip.

In the nitride semiconductor chip according to the first aspect described above, the principal growth plane of the nitride semiconductor substrate may have an off angle, in addition to in the a-axis direction, also in a c-axis direction. In this case, it is preferable that the off angle in the a-axis direction be larger than the off angle in the c-axis direction. With this configuration, it is possible to effectively suppress a bright-spotted EL emission pattern, variations in wavelength across the plane, and appearance of a dark line.

According to a second aspect of the invention, a nitride semiconductor chip is provided with: a nitride semiconductor substrate having an m plane as a principal growth plane; and a nitride semiconductor layer formed on the principal growth plane of the nitride semiconductor substrate and including an active layer. Here, the nitride semiconductor substrate includes a carved region, which is a region carved in the thickness direction from the principal growth plane, and an uncarved region, which is a region not carved. Moreover, the active layer has a barrier layer formed of a nitride semiconductor containing Al and In. In the present invention, nitride semiconductor substrates include substrates whose principal growth plane is formed of a nitride semiconductor.

In this nitride semiconductor chip according to the second aspect, by forming the barrier layer in the active layer out of a nitride semiconductor containing Al and In as described above, it is possible to almost completely suppress appearance of a dark line. This makes it possible to suppress a lowering in luminous efficacy resulting from appearance of a dark line. Consequently, it is possible to enhance device characteristics and reliability. By suppressing appearance of a dark line, it is possible to obtain an emission pattern of uniform light emission, and thus it is possible to increase gain in the formation of a nitride semiconductor laser chip.

Here, in a nitride semiconductor light-emitting chip (nitride semiconductor chip) such as a nitride semiconductor laser chip, when a nitride semiconductor layer is grown on an m plane of a nitride semiconductor substrate, strain may develop in the nitride semiconductor layer due to a difference in lattice constant, thermal expansion coefficient, etc. between the nitride semiconductor substrate and the nitride semiconductor layer, and the strain may produce a crack in the nitride semiconductor layer. Development of a crack in the nitride semiconductor layer reduces the number of acceptable chips obtained from a single wafer, resulting in the problem of low yields. Development of a crack also degrades device characteristics such as reliability and light emission lifetime. Suppressing development of a crack is therefore crucial in the manufacturing of chips.

In particular, in the fabrication of a semiconductor light-emitting chip emitting light in an ultraviolet region or a semiconductor light-emitting chip emitting light in a green region (for example, a green semiconductor laser), for effective light confinement, a semiconductor layer with a large difference in lattice constant from a substrate may be formed on the substrate. In such a case, a crack is very likely to develop, resulting in the problem of great difficulty in enhancing device characteristics and yields.

Out of these considerations, according to the second aspect, to suppress the above problems, a carved region is formed in the nitride semiconductor substrate. That is, by forming a carved region in the nitride semiconductor substrate, it is possible to form a concavity in the surface of the nitride semiconductor layer over the carved region. Thus, even in a case where a difference in lattice constant, thermal expansion coefficient, etc. between the nitride semiconductor substrate and the nitride semiconductor layer is so large that strain develops in the nitride semiconductor layer, the strain in the nitride semiconductor layer (the nitride semiconductor layer formed over the carved region) can be alleviated with the just-mentioned concavity portion formed in the surface of the nitride semiconductor layer over the carved region. Thus, it is possible to obtain a very powerful effect of suppressing a crack, and it is thus possible to effectively suppress development of a crack in the nitride semiconductor layer. Thus, with the configuration described above, it is possible to form, with almost no crack developing, a nitride semiconductor layer having a composition more different from that of the nitride semiconductor substrate. Thus, even in the fabrication of a semiconductor light-emitting chip emitting light in an ultraviolet region or a semiconductor light-emitting chip emitting light in a green region (for example, a green semiconductor laser), it is possible to suppress development of a crack. This makes it possible to fabricate semiconductor light-emitting chips and the like emitting light in ultraviolet and green regions with high yields while enhancing device characteristics.

Moreover, according to the second aspect, by suppressing appearance of a dark line as described above, it is possible to reduce variations in device characteristics, and thus it is possible to increase the number of chips having characteristics within the rated ranges. Thus, this too makes it possible to increase yields.

Furthermore, according to the second aspect, by forming the carved region in the nitride semiconductor substrate, it is possible to effectively alleviate strain in the active layer, and thus it is possible to more effectively suppress appearance of a dark line. Moreover, with the configuration described above, it is possible to effectively suppress appearance of a dark line after the growth of the nitride semiconductor layer and also even after an energizing test conducted after completion as a semiconductor. This makes it possible to obtain a nitride semiconductor chip with high luminance and high reliability.

As described above, according to the second aspect, with the configuration described above, it is possible to greatly enhance luminous efficacy. Moreover, by enhancing luminous efficacy, it is possible to enhance device characteristics and reliability, and thus it is possible to obtain a nitride semiconductor chip with superb device characteristics and high reliability. Furthermore, according to the second aspect, it is possible to effectively suppress development of a crack, and thus it is possible to increase the number of acceptable chips obtained from a single wafer. This makes it possible to increase yields. Moreover, by suppressing development of a crack, it is possible to enhance chip reliability, and in addition to enhance device characteristics.

In the nitride semiconductor chip according to the second aspect described above, preferably, the barrier layer is formed of AlInGaN. With this configuration, it is possible to more effectively suppress appearance of a dark line. Moreover, by forming the barrier layer out of AlInGaN, it is possible to increase the amount of In absorbed into the well layer formed on the barrier layer. Thus, by forming the barrier layer out of AlInGaN, it is possible to widen the ranges of growth conditions. Moreover, AlInGaN, which has In added to AlGaN, allows easy formation of a film with good crystallinity even at lower growth temperature; thus, by forming the barrier layer, which is typically formed at a comparatively low growth temperature of about 600° C. to 800° C., out of AlInGaN, even in a case where the barrier layer is formed at a comparatively low temperature as just mentioned, it is possible to obtain a barrier layer with good crystallinity. Furthermore, by forming the barrier layer out of AlInGaN, it is possible to reduce strain that the barrier layer produces in the well layer. The lower the strain produced in the well layer, the more preferable, because that reduces the rate at which the light-emitting chip deteriorates while operating.

According to a third aspect of the invention, a nitride semiconductor chip is provided with: a nitride semiconductor substrate having as a principal growth plane a plane having an off angle in an a-axis direction relative to an m plane; and a nitride semiconductor layer formed on the principal growth plane of the nitride semiconductor substrate and including an active layer. Here, the nitride semiconductor substrate includes a carved region, which is a region carved in a thickness direction from the principal growth plane, and an uncarved region, which is a region not carved. Moreover, the active layer has a barrier layer formed of a nitride semiconductor containing Al and In.

In this nitride semiconductor chip according to the third aspect, as in that according to the second aspect described previously, by forming the barrier layer out of a nitride semiconductor containing Al and In, it is possible to almost completely suppress appearance of a dark line. This makes it possible to enhance luminous efficacy.

Moreover, in the nitride semiconductor chip according to the third aspect, by use of a nitride semiconductor substrate having an off angle in the a-axis direction, it is possible to suppress appearance of a dark line, and in addition it is possible to suppress a bright-spotted EL emission pattern. That is, with that configuration, it is possible to further improve the EL emission pattern of the nitride semiconductor chip (suppress bright-spotted emission, variations in wavelength across the plane, etc.). Thus, this too makes it possible to enhance the luminous efficacy of the nitride semiconductor chip. Moreover, by enhancing luminous efficacy, it is possible to obtain a high-luminance nitride semiconductor chip.

Moreover, according to the third aspect, by forming the carved region in the nitride semiconductor substrate, it is possible to form, with almost no crack developing, a nitride semiconductor layer having a composition more different from that of the nitride semiconductor substrate. Furthermore, owing to the carved region being formed, it is possible to effectively alleviate strain in the active layer containing Al, and thus it is possible to more effectively suppress appearance of a dark line.

Moreover, according to the third aspect, by use of a nitride semiconductor substrate provided with an off angle in the a-axis direction relative to the m plane, it is possible to make it difficult to fill the inside of the carved region with the nitride semiconductor layer. This makes it possible to easily form a concavity in the surface of the nitride semiconductor layer over the carved region. Consequently, it is possible to easily suppress development of a crack.

Moreover, according to the third aspect, by using as the principal growth plane of the nitride semiconductor substrate a plane having an off angle in the a-axis direction relative to the m plane, it is possible to give the nitride semiconductor layer formed on that principal growth plane good crystallinity. Thus, it is possible to make a crack less likely to develop in the nitride semiconductor layer. Moreover, with the configuration described above, it is possible to give the nitride semiconductor layer good surface morphology, and thus it is possible to obtain a nitride semiconductor layer with a uniform thickness. Thus, it is possible to suppress the inconvenience of a locally thicker region being formed in the nitride semiconductor layer due to the nitride semiconductor layer being not uniformly thick. Since a crack is likely to develop in such a thicker region, by suppressing formation of a locally thicker region in the nitride semiconductor layer, it is possible to make a crack still less likely to develop. Moreover, with the configuration described above, it is possible to give the nitride semiconductor layer very good surface morphology, and it is thus possible to reduce variations in device characteristics. Thus, it is possible to increase the number of chips having characteristics within the rated ranges, and this too makes it possible to increase yields. Moreover, by enhancing surface morphology, it is also possible to enhance device characteristics and reliability.

Moreover, according to the third aspect, by using as the principal growth plane a plane having an off angle in the a-axis direction relative to the m plane, it is possible to enhance the flatness of the barrier layer formed of a nitride semiconductor containing Al and In. Thus, by forming the well layer on the barrier layer with high flatness, it is possible to suppress the well layer having a non-uniform distribution of In composition across the plane. It is also possible to enhance the crystallinity of the active layer (well layer). This makes it possible to further enhance luminous efficacy.

Furthermore, according to the third aspect, as described above, by suppressing appearance of a dark line, it is possible to reduce variations in device characteristics, and thus it is possible to increase the number of chips having characteristics within the rated ranges. Thus, this too makes it possible to increase yields.

As described above, according to the third aspect, with the configuration described above, it is possible to greatly enhance luminous efficacy. Moreover, by enhancing luminous efficacy, it is possible to enhance device characteristics and reliability, and thus it is possible to obtain a nitride semiconductor chip with superb device characteristics and high reliability. Furthermore, according to the third aspect, it is possible to effectively suppress development of a crack, and thus it is possible to increase the number of acceptable chips obtained from a single wafer. This makes it possible to increase yields. Moreover, by suppressing development of a crack, it is possible to enhance the reliability of the chip, and in addition to enhance device characteristics.

According to the third aspect, with the configuration described above, it is possible to obtain a very powerful effect of suppressing a crack, and thus it is possible to form, with almost no crack developing, a nitride semiconductor layer having a composition more different from that of the nitride semiconductor substrate. Thus, even in the fabrication of a semiconductor light-emitting chip emitting light in an ultraviolet region or a semiconductor light-emitting chip emitting light in a green region (for example, a green semiconductor laser), it is possible to suppress development of a crack. This makes it possible to fabricate semiconductor light-emitting chips and the like emitting light in ultraviolet and green regions with high yields while enhancing device characteristics.

In the nitride semiconductor chip according to the third aspect described above, preferably, the absolute value of the off angle in the a-axis direction is greater than 0.1 degrees. With this configuration, it is possible to easily suppress a bright-spotted EL emission pattern and variations in wavelength across the plane while suppressing appearance of a dark line.

In the nitride semiconductor chip according to the third aspect described above, the principal growth plane of the nitride semiconductor substrate may have an off angle, in addition to in the a-axis direction, also in a c-axis direction. In this case, it is preferable that the off angle in the a-axis direction be larger than the off angle in the c-axis direction. With this configuration, it is possible to effectively suppress a bright-spotted EL emission pattern, variations in wavelength across the plane, and appearance of a dark line.

In the nitride semiconductor chips according to the second and third aspects described above, preferably, the nitride semiconductor layer includes a gradient thickness region which is formed over the uncarved region and whose thickness decreases in gradient fashion toward the carved region. By forming such a gradient thickness region in the nitride semiconductor layer, it is possible to alleviate strain developing in the nitride semiconductor layer also with the gradient thickness region, and thus it is possible to obtain a more powerful effect of suppressing a crack. In addition, it is possible to more effectively suppress strain in the active layer. Thus, it is possible to easily form, with almost no crack developing, a nitride semiconductor layer having a composition more different from that of the nitride semiconductor substrate. For example, in a case where a GaN substrate is used as the nitride semiconductor substrate, it is possible to form an AlGaN layer with a higher Al composition thicker than ever. This makes it possible to fabricate chips that require a nitride semiconductor film with a high Al composition (for example, semiconductor light-emitting chips and the like emitting in ultraviolet and green regions) and that thus have conventionally been difficult to fabricate. Moreover, with that configuration, it is possible to effectively alleviate strain in the active layer, and thus it is possible to more effectively suppress appearance of a dark line. Moreover, through control of the off angle in the a-axis direction in the nitride semiconductor substrate, the gradient thickness region can be formed in the vicinity of the carved region (next to the carved region). The reason that a powerful effect of suppressing a crack as described above is obtained is considered to be as follows: because the gradient thickness region is thin in the first place, it contains little strain itself; in addition, since its thickness varies gradually (in a gradient fashion), the strain is alleviated progressively, resulting in a more powerful effect of alleviating strain.

In the nitride semiconductor chips according to the second and third aspects described above, it is preferable that the carved region be formed to extend in a c-axis direction as seen in a plan view. With this configuration, it is possible to easily suppress development of a crack in the nitride semiconductor layer, and in addition to alleviate strain in the active layer. Moreover, in a case where use is made of a nitride semiconductor substrate having as the principal growth plane a plane having an off angle in the a-axis direction relative to the m plane, it is possible to easily form, in a part of the nitride semiconductor layer in the vicinity of the carved region (neat to the carved region), a gradient thickness region whose thickness decreases in a gradient fashion (gradually) toward the carved region. The carved region may be formed to extend in a direction crossing the c-axis direction at an angle of ±15 degrees or less. Also with this configuration, it is possible to easily form the gradient thickness region, and thus it is possible to easily suppress development of a crack in the nitride semiconductor layer. Moreover, in the above configuration, a carved region extending in a direction perpendicular to the c-axis direction may additionally be formed in the substrate. With this configuration, it is possible to more effectively alleviate strain.

In the nitride semiconductor chips according to the second and third aspects described above, preferably, the nitride semiconductor layer includes an optical waveguide region, and the optical waveguide region is located over the uncarved region. With this configuration, it is possible to easily obtain a nitride semiconductor chip with high luminous efficacy, high gain, and suppressed crack development.

According to a fourth aspect of the invention, a nitride semiconductor wafer is provided with: a nitride semiconductor substrate having an m plane as a principal growth plane; and a nitride semiconductor layer formed on the principal growth plane of the nitride semiconductor substrate and including an active layer. Here, the nitride semiconductor substrate includes a carved region, which is a region carved in a thickness direction from the principal growth plane, and an uncarved region, which is a region not carved. Moreover, the active layer has a barrier layer formed of a nitride semiconductor containing Al and In.

In this nitride semiconductor wafer according to the fourth aspect, by forming the barrier layer in the active layer out of a nitride semiconductor containing Al and In as described above, it is possible to almost completely suppress appearance of a dark line. This makes it possible to enhance the luminous efficacy of the nitride semiconductor chip obtained by splitting the nitride semiconductor wafer.

Moreover, according to the fourth aspect, by forming the carved region in the nitride semiconductor substrate, it is possible to effectively suppress development of a crack in the nitride semiconductor layer. This makes it possible to increase the number of acceptable chips obtained from a single wafer. Consequently, it is possible to increase yields. Moreover, by suppressing development of a crack, it is possible to enhance chip reliability, and in addition to enhance device characteristics. Moreover, by forming the carved region in the nitride semiconductor substrate, it is possible to effectively alleviate strain in the active layer. This makes it possible to more effectively suppress appearance of a dark line. Moreover, by alleviating strain in the active layer, it is possible to suppress appearance and expansion of a dark line.

According to a fifth aspect of the invention, a nitride semiconductor wafer is provided with: a nitride semiconductor substrate having as a principal growth plane a plane having an off angle in an a-axis direction relative to an m plane; and a nitride semiconductor layer formed on the principal growth plane of the nitride semiconductor substrate and including an active layer. Here, the nitride semiconductor substrate includes a carved region, which is a region carved in a thickness direction from the principal growth plane, and an uncarved region, which is a region not carved. Moreover, the active layer has a barrier layer formed of a nitride semiconductor containing Al and In.

In this nitride semiconductor wafer according to the fifth aspect, by use of a nitride semiconductor substrate having as the principal growth plane a plane having an off angle in the a-axis direction relative to the m plane as described above, it is possible to suppress a bright-spotted EL emission pattern. Moreover, by forming the barrier layer in the active layer out of a nitride semiconductor containing Al and In, it is possible to suppress development of a dark line. Thus, by use of the nitride semiconductor wafer configured as described, it is possible to obtain a nitride semiconductor chip with greatly enhanced luminous efficacy.

Moreover, according to the fifth aspect, by forming the carved region in the nitride semiconductor substrate, it is possible to effectively suppress development of a crack in the nitride semiconductor layer. This makes it possible to enhance device characteristics, reliability, and yields.

In the nitride semiconductor wafers according to the fourth and fifth aspects described above, the principal growth plane of the nitride semiconductor substrate may have an off angle, in addition to in the a-axis direction, also in a c-axis direction. In this case, it is preferable that the off angle in the a-axis direction be larger than the off angle in the c-axis direction.

In the nitride semiconductor wafers according to the fourth and fifth aspects described above, it is preferable that the nitride semiconductor layer include a gradient thickness region which is formed over the uncarved region and whose thickness decreases in gradient fashion toward the carved region.

In the nitride semiconductor wafers according to the fourth and fifth aspects described above, it is preferable that the carved region be formed to extend in a c-axis direction as seen in a plan view. The carved region may be formed to extend in a direction crossing the c-axis direction at an angle of ±15 degrees or less. Moreover, in the above configuration, a carved region extending in a direction perpendicular to the c-axis direction may additionally be formed in the substrate.

According to a sixth aspect of the invention, a nitride semiconductor chip is formed by use of the nitride semiconductor wafer according to the fourth or fifth aspect described above. With this configuration, it is possible to obtain, with high yields, a nitride semiconductor chip with greatly enhanced luminous efficacy, superb device characteristics, and high reliability. In the nitride semiconductor chip according to the sixth aspect just described, it is preferable that the nitride semiconductor substrate include at least part of the carved region.

According to a seventh aspect of the invention, a method of manufacturing a nitride semiconductor chip includes: a step of preparing a nitride semiconductor substrate including as a principal growth plane a plane having an off angle in an a-axis direction relative to an m plane; and a step of forming, to the principal growth plane side of the nitride semiconductor substrate, by an epitaxial growth process, an active layer having a quantum well structure including a well layer and a barrier layer. Here, the step of forming the active layer includes a step of forming the barrier layer out of a nitride semiconductor containing Al.

In this nitride semiconductor chip manufacturing method according to the seventh aspect, by use of a nitride semiconductor substrate having as the principal growth plane a plane having an off angle in the a-axis direction relative to the m plane as described above, it is possible to obtain a nitride semiconductor chip with a suppressed bright-spotted EL emission pattern. That is, with that configuration, it is possible to obtain a nitride semiconductor chip with an improved EL emission pattern (with suppressed bright-spotted emission, suppressed variations in wavelength across the plane, etc.). This makes it possible to obtain a nitride semiconductor chip with enhanced luminous efficacy and high luminance.

Moreover, according to the seventh aspect, by suppressing a bright-spotted EL emission pattern, it is possible to make the EL emission pattern uniform, and thus it is also possible to reduce the driving voltage of the nitride semiconductor chip. By suppressing bright-spotted emission, it is possible to obtain an EL emission pattern of uniform light emission, and thus it is possible to increase gain in the formation of a nitride semiconductor laser chip. Moreover, with the configuration described above, it is possible to suppress a bright-spotted EL emission pattern, and in addition to form individual nitride semiconductor layers with high flatness; thus, it is possible to enhance luminous efficacy, and this makes it possible to enhance device characteristics and reliability. That is, it is possible to obtain, with high yields, a nitride semiconductor chip with superb device characteristics and high reliability.

Moreover, according to the seventh aspect, by forming the barrier layer out of a nitride semiconductor layer containing Al as described above, it is possible to almost completely suppress appearance of a dark line, and thus it is possible to suppress a lowering in luminous efficacy resulting from appearance of a dark line.

Furthermore, according to the seventh aspect, by forming the barrier layer out of a nitride semiconductor containing Al, it is possible to enhance the flatness of the barrier layer; thus, by forming the well layer on the barrier layer with high flatness, it is possible to suppress the well layer having a non-uniform distribution of In composition across the plane. It is also possible to enhance the crystallinity of the active layer (well layer). This makes it possible to further enhance luminous efficacy.

According to an eighth aspect of the invention, a method of manufacturing a nitride semiconductor chip includes: a step of preparing a nitride semiconductor substrate having an m plane as a principal growth plane; a step of forming a carved region, which is a region carved in a depressed shape, in the principal growth plane of the nitride semiconductor substrate; and a step of forming a nitride semiconductor layer on the principal growth plane of the nitride semiconductor substrate. Here, the step of forming the nitride semiconductor layer includes a step of forming a quantum well structure including a well layer and a barrier layer. Moreover, the step of forming the active layer includes a step of forming the barrier layer out of a nitride semiconductor containing Al and In.

According to a ninth aspect of the invention, a method of manufacturing a nitride semiconductor chip includes: a step of preparing a nitride semiconductor substrate having as a principal growth plane a plane having an off angle in an a-axis direction relative to an m plane; a step of forming a carved region, which is a region carved in a depressed shape, in the principal growth plane of the nitride semiconductor substrate; and a step of forming a nitride semiconductor layer on the principal growth plane of the nitride semiconductor substrate. Here, the step of forming the nitride semiconductor layer includes a step of forming a quantum well structure including a well layer and a barrier layer. Moreover, the step of forming the active layer includes a step of forming the barrier layer out of a nitride semiconductor containing Al and In.

In the nitride semiconductor chip manufacturing methods according to the eighth and ninth aspects described above, preferably, the principal growth plane of the nitride semiconductor substrate may have an off angle, in addition to in the a-axis direction, also in a c-axis direction. In this case, it is preferable that the off angle in the a-axis direction be larger than the off angle in the c-axis direction.

In the nitride semiconductor chip manufacturing methods according to the eighth and ninth aspects described above, preferably, the step of forming the carved region includes a step of forming, in a region of the principal growth plane other than the carved region, an uncarved region, which is a region not carved; moreover, the step of forming the nitride semiconductor layer includes a step of forming, in a region over the uncarved region, a gradient thickness region whose thickness decreases in a gradient fashion toward the carved region.

In the nitride semiconductor chip manufacturing methods according to the seventh to ninth aspects described above, it is preferable that the methods further include a step of stacking an n-type semiconductor layer, an active layer, and a p-type semiconductor layer sequentially on the principal growth plane of the nitride semiconductor substrate. In this case, it is preferable that the p-type semiconductor layer be formed at a growth temperature of 700° or higher but lower than 1100° C. Even in a case where the p-type semiconductor layer is formed at a high temperature of 1000° C. or higher, by forming the barrier layer in the active layer out of a nitride semiconductor containing Al, it is possible to suppress blackening of the active layer (well layer). This permits formation of the p-type semiconductor layer at a high temperature of 1000° C. or higher, and thus, by forming the p-type semiconductor layer at high temperature, it is possible to effectively obtain an effect of reducing the driving voltage. On the other hand, by forming the p-type semiconductor layer at a growth temperature of 700° C. or higher, it is possible to suppress the inconvenience of the p-type semiconductor layer having a high resistance due to its being formed at a growth temperature lower than 700° C. Thus, this too makes it possible to enhance device characteristics and reliability. By use of a nitride semiconductor substrate having a principal growth plane provided with an off angle relative to the m plane, even in a case where the p-type semiconductor layer is formed at a growth temperature lower than 900° C., it is possible to obtain p-type conductivity.

Moreover, in that case, it is preferable that the n-type semiconductor layer be formed at a growth temperature of 900° C. or higher but lower than 1300° C. By forming the n-type semiconductor layer at a high temperature of 900° C. or higher in this way, it is possible to give the n-type semiconductor layer a flat surface. Thus, by forming the active layer and the p-type semiconductor layer on the n-type semiconductor layer with a flat surface, it is possible to suppress degradation of crystallinity in the active layer and the p-type semiconductor layer. This makes it possible to form a high-quality crystal. On the other hand, by forming the n-type semiconductor layer at a growth temperature lower than 1300° C., it is possible to suppress the inconvenience of the surface of the nitride semiconductor substrate re-evaporating and becoming rough during the raising of temperature due to the n-type semiconductor layer being formed at a growth temperature of 1300° C. or higher. Thus, with this configuration, it is possible to obtain, easily and with high yields, a nitride semiconductor chip with superb device characteristics and high reliability.

Furthermore, in that case, it is preferable that the active layer be formed at a growth temperature of 600° C. or higher but 800° C. or lower. By forming the active layer at a growth temperature of 800° C. or lower, it is possible to suppress the inconvenience of the active layer being blackened by thermal damage due to its being formed at a growth temperature higher than 800° C. (for example, 830° C. or higher). On the other hand, by forming the active layer at a growth temperature of 600° C. or higher, it is possible to suppress the inconvenience of a shorter atom diffusion length and hence degraded crystallinity due to the active layer being formed at a growth temperature lower than 600° C. Thus, with this configuration, it is possible to obtain, more easily and with higher yields, a nitride semiconductor chip with superb device characteristics and high reliability.

According to a tenth aspect of the invention, a semiconductor device is provided with a nitride semiconductor chip according to any of the first to third aspects described above.

As described above, according to the invention, it is possible to easily obtain a nitride semiconductor chip with enhanced luminous efficacy, a nitride semiconductor wafer, a method of manufacture of a nitride semiconductor chip, and a semiconductor device provided with such a nitride semiconductor chip.

According to the invention, it is also possible to easily obtain a nitride semiconductor chip that offers enhanced device characteristics and increased yields, a nitride semiconductor wafer, a method of manufacture of a nitride semiconductor chip, and a semiconductor device provided with such a nitride semiconductor chip.

According to the invention, it is further possible to easily obtain a nitride semiconductor chip with superb device characteristics and high reliability, and a method of manufacture thereof.

### BRIEF DESCRIPTION OF THE DRAWINGS

FIG. 1 is a schematic diagram illustrating a crystal structure of a nitride semiconductor (a diagram showing a unit cell);

FIG. 2 is a sectional view showing the structure of a nitride semiconductor laser chip according to Embodiment 1 of the invention (a diagram corresponding to the section along line A-A in FIG. 6);

FIG. 3 is an overall perspective view of a nitride semiconductor laser chip according to Embodiment 1 of the invention;

FIG. 4 is a schematic diagram illustrating an off angle of a substrate;

FIG. 5 is a sectional view showing the structure of an active layer in a nitride semiconductor laser chip according to Embodiment 1 of the invention;

FIG. 6 is a plan view of a nitride semiconductor laser chip according to Embodiment 1 of the invention (a diagram of the nitride semiconductor laser chip as seen from above);

FIG. 7 is a perspective view illustrating a method of manufacturing a nitride semiconductor laser chip according to Embodiment 1 of the invention (a diagram illustrating a method of manufacturing a substrate);

FIG. 8 is a perspective view illustrating a method of manufacturing a nitride semiconductor laser chip according to Embodiment 1 of the invention (a diagram illustrating a method of manufacturing a substrate);

FIG. 9 is a perspective view illustrating a method of manufacturing a nitride semiconductor laser chip according to Embodiment 1 of the invention (a diagram illustrating a method of manufacturing a substrate);

FIG. 10 is a plan view illustrating a method of manufacturing a nitride semiconductor laser chip according to Embodiment 1 of the invention (a diagram illustrating a method of manufacturing a substrate);

FIG. 11 is a sectional view illustrating a method of manufacturing a nitride semiconductor laser chip according to Embodiment 1 of the invention (a diagram illustrating a method of manufacturing a substrate);

FIG. 12 is a sectional view illustrating a method of manufacturing a nitride semiconductor laser chip according to Embodiment 1 of the invention;

FIG. 13 is a sectional view illustrating a method of manufacturing a nitride semiconductor laser chip according to Embodiment 1 of the invention;

FIG. 14 is a sectional view illustrating a method of manufacturing a nitride semiconductor laser chip according to Embodiment 1 of the invention;

FIG. 15 is a sectional view illustrating a method of manufacturing a nitride semiconductor laser chip according to Embodiment 1 of the invention;

FIG. 16 is a sectional view illustrating a method of manufacturing a nitride semiconductor laser chip according to Embodiment 1 of the invention;

FIG. 17 is a sectional view illustrating a method of manufacturing a nitride semiconductor laser chip according to Embodiment 1 of the invention;

FIG. 18 is a sectional view illustrating a method of manufacturing a nitride semiconductor laser chip according to Embodiment 1 of the invention;

FIG. 19 is a sectional view illustrating a method of manufacturing a nitride semiconductor laser chip according to Embodiment 1 of the invention;

FIG. 20 is a perspective view of a semiconductor laser device provided with a nitride semiconductor laser chip according to Embodiment 1 of the invention;

FIG. 21 is a perspective view of a light-emitting diode chip fabricated to verify the effects of a nitride semiconductor laser chip according to Embodiment 1 of the invention;

FIG. 22 is a microscope photograph of an EL emission pattern observed with a light-emitting diode chip fabricated to verify the effects of a nitride semiconductor laser chip according to Embodiment 1 of the invention (a microscope photograph of an EL emission pattern observed with a test chip);

FIG. 23 is a sectional view showing the structure of a nitride semiconductor laser chip according to Embodiment 2 of the invention;

FIG. 24 is a plan view illustrating the structure of a nitride semiconductor laser chip according to Embodiment 2 of the invention;

FIG. 25 is a sectional view illustrating the structure of a nitride semiconductor laser chip according to Embodiment 2 of the invention;

FIG. 26 is a sectional view of a light-emitting diode chip according to Embodiment 5 of the invention;

FIG. 27 is a sectional view schematically showing part of a nitride semiconductor wafer according to Embodiment 6 of the invention;

FIG. 28 is a plan view of a substrate used in a nitride semiconductor wafer according to Embodiment 6 of the invention;

FIG. 29 is an enlarged sectional view of part of a substrate used in a nitride semiconductor wafer according to Embodiment 6 of the invention;

FIG. 30 is a sectional view illustrating the structure of semiconductor layers in a nitride semiconductor wafer according to Embodiment 6 of the invention;

FIG. 31 is a sectional view illustrating the structure of a nitride semiconductor wafer according to Embodiment 6 of the invention;

FIG. 32 is a microscope photograph of a section of a nitride semiconductor wafer according to Embodiment 6 of the invention, as observed on an electronic microscope;

FIG. 33 is a plan view illustrating the structure of a nitride semiconductor wafer according to Embodiment 6 of the invention;

FIG. 34 is a plan view schematically showing part of a nitride semiconductor wafer according to Embodiment 6 of the invention;

FIG. 35 is a plan view of a nitride semiconductor laser chip according to Embodiment 6 of the invention;

FIG. 36 is a sectional view schematically showing a nitride semiconductor laser chip according to Embodiment 6 of the invention;

FIG. 37 is a sectional view showing part of a nitride semiconductor laser chip according to Embodiment 6 of the invention;

FIG. 38 is a sectional view illustrating the structure of an active layer in a nitride semiconductor laser chip according to Embodiment 6 of the invention;

FIG. 39 is a sectional view illustrating a method of manufacturing a nitride semiconductor laser chip according to Embodiment 6 of the invention;

FIG. 40 is a sectional view illustrating a method of manufacturing a nitride semiconductor laser chip according to Embodiment 6 of the invention;

FIG. 41 is a sectional view illustrating a method of manufacturing a nitride semiconductor laser chip according to Embodiment 6 of the invention;

FIG. 42 is a sectional view illustrating a method of manufacturing a nitride semiconductor laser chip according to Embodiment 6 of the invention;

FIG. 43 is a sectional view illustrating a method of manufacturing a nitride semiconductor laser chip according to Embodiment 6 of the invention;

FIG. 44 is a sectional view illustrating a method of manufacturing a nitride semiconductor laser chip according to Embodiment 6 of the invention;

FIG. 45 is a sectional view illustrating a method of manufacturing a nitride semiconductor laser chip according to Embodiment 6 of the invention;

FIG. 46 is a sectional view illustrating a method of manufacturing a nitride semiconductor laser chip according to Embodiment 6 of the invention;

FIG. 47 is a sectional view illustrating a method of manufacturing a nitride semiconductor laser chip according to Embodiment 6 of the invention;

FIG. 48 is a sectional view illustrating a method of manufacturing a nitride semiconductor laser chip according to Embodiment 6 of the invention;

FIG. 49 is a sectional view illustrating a method of manufacturing a nitride semiconductor laser chip according to Embodiment 6 of the invention;

FIG. 50 is a plan view illustrating a method of manufacturing a nitride semiconductor laser chip according to Embodiment 6 of the invention;

FIG. 51 is a plan view illustrating a method of manufacturing a nitride semiconductor laser chip according to Embodiment 6 of the invention;

FIG. 52 is a perspective view of a nitride semiconductor laser device incorporating a nitride semiconductor laser chip according to Embodiment 6 of the invention;

FIG. 53 is a microscope photograph of a nitride semiconductor layer surface on an n-type GaN substrate as formed by a manufacturing method according to Embodiment 6 (a microscope photograph of a nitride semiconductor layer surface observed with Test Sample 2);

FIG. 54 is a microscope photograph of a nitride semiconductor layer surface observed with Comparative Sample 2;

FIG. 55 is a perspective view of a light-emitting diode chip fabricated to verify the effects of a nitride semiconductor laser chip according to Embodiment 6 of the invention;

FIG. 56 is a microscope photograph of a bright-spotted EL emission pattern (a microscope photograph of an EL emission pattern observed with the comparison chip in connection with Embodiment 6;

FIG. 57 is a sectional view illustrating a nitride semiconductor wafer and a nitride semiconductor laser chip according to Embodiment 8 of the invention (a diagram showing a section of part of a substrate used in a nitride semiconductor wafer and a nitride semiconductor laser chip according to Embodiment 8);

FIG. 58 is a sectional view illustrating a method of manufacturing a nitride semiconductor laser chip according to Embodiment 8 of the invention;

FIG. 59 is a sectional view illustrating a method of manufacturing a nitride semiconductor laser chip according to Embodiment 8 of the invention;

FIG. 60 is a sectional view illustrating a nitride semiconductor wafer and a nitride semiconductor laser chip according to a first modified example of Embodiment 8 of the invention;

FIG. 61 is a sectional view illustrating a nitride semiconductor wafer and a nitride semiconductor laser chip according to a second modified example of Embodiment 8 of the invention;

FIG. 62 is a sectional view illustrating a method of manufacturing a nitride semiconductor laser chip according to Embodiment 9 of the invention;

FIG. 63 is a sectional view illustrating a method of manufacturing a nitride semiconductor laser chip according to Embodiment 9 of the invention;

FIG. 64 is a sectional view illustrating a method of manufacturing a nitride semiconductor laser chip according to Embodiment 9 of the invention;

FIG. 65 is a sectional view illustrating a nitride semiconductor wafer and a nitride semiconductor laser chip according to Embodiment 10 of the invention;

FIG. 66 is a sectional view of a light-emitting diode chip according to Embodiment 11 of the invention;

FIG. 67 is a sectional view schematically showing a light-emitting diode chip according to Embodiment 12 of the invention;

FIG. 68 is a sectional view illustrating another example of the structure of an active layer in Embodiments 1 to 5 (a sectional view showing an example of an active layer having an SQW structure);

FIG. 69 is a sectional view illustrating another example of the structure of an active layer in Embodiments 6 to 12 (a sectional view showing an example of an active layer having an SQW structure);

FIG. 70 is a sectional view illustrating other examples of the shape of a depressed portion (carved region) in Embodiments 3 and 6 to 12;

FIG. 71 is a sectional view illustrating other examples of the shape of a depressed portion (carved region) in Embodiments 3 and 6 to 12;

FIG. 72 is a sectional view illustrating other examples of the shape of a depressed portion (carved region) in Embodiments 3 and 6 to 12;

FIG. 73 is a microscope photograph of dark lines observed in a PL emission pattern (a microscope photograph of dark lines observed in a PL emission pattern of Comparative Sample 1 having a barrier layer formed of InGaN);

FIG. 74 is a microscope photograph of dark lines observed in an EL emission pattern;

FIG. 75 is a microscope photograph of a PL emission pattern of a light-emitting diode chip having a barrier layer formed of AlGaN;

FIG. 76 is a microscope photograph of a PL emission pattern of a light-emitting diode chip having a barrier layer formed of AlInGaN (a microscope photograph of a PL emission pattern of Test Sample 1 according to Embodiment 6);

FIG. 77 is a microscope photograph obtained when, by use of a GaN substrate having as a principal growth plane a plane having an off angle in an a-axis direction relative to an m plane, a GaN layer with a thickness of about 1 μm was formed on the principal growth plane and surface morphology was inspected under an optical microscope;

FIG. 78 is a microscope photograph obtained when, by use of a GaN substrate having as a principal growth plane a plane having an off angle in an a-axis direction relative to an m plane, a GaN layer with a thickness of about 0.1 μm was formed on the principal growth plane, then an AlGaN layer with a thickness of about 0.9 μm was formed on the GaN layer, and then surface morphology was inspected under an optical microscope;

FIG. 80 is a microscope photograph obtained when, by use of a GaN substrate having as a principal growth plane a plane having an off angle in an a-axis direction relative to an m plane, an AlGaN layer with an Al composition ratio of 5% and with a thickness of about 2 μm was formed on the principal growth plane and surface morphology was inspected under an optical microscope;

FIG. 81 is a microscope photograph obtained when, by use of a GaN substrate having as a principal growth plane a plane having an off angle of +0.5 degrees in a c-axis direction relative to an m plane, an AlGaN layer with a thickness of about 1 μm was formed on the principal growth plane and surface morphology was inspected under an optical microscope;

FIG. 82 is a microscope photograph obtained when, by use of a GaN substrate having as a principal growth plane a plane having an off angle of +0.5 degrees in a c-axis direction relative to an m plane, a GaN layer with a thickness of about 1 μm was formed on the principal growth plane and surface morphology was inspected under an optical microscope; and

FIG. 83 is a microscope photograph showing a bright-spotted EL emission pattern (a microscope photograph of an EL emission pattern observed with the comparison chip in connection with Embodiment 1).

### DETAILED DESCRIPTION OF PREFERRED EMBODIMENTS

Prior to the description of specific embodiments of the present invention, what the inventors have found out through various studies will be explained.

In a case where a light-emitting chip is formed by use of a nitride semiconductor substrate having the m plane as the principal growth plane, typically, the active layer is composed of a multiple-layer film including a well layer and a barrier layer. In this case, with a view to achieving effective light confinement and alleviating strain developing in the active layer, it is common to use a well layer of InₐGa₁₋ₐN (0<a≦1) and a barrier layer of In_{b}Ga_{1-b}N (0≦b<1, a>b).

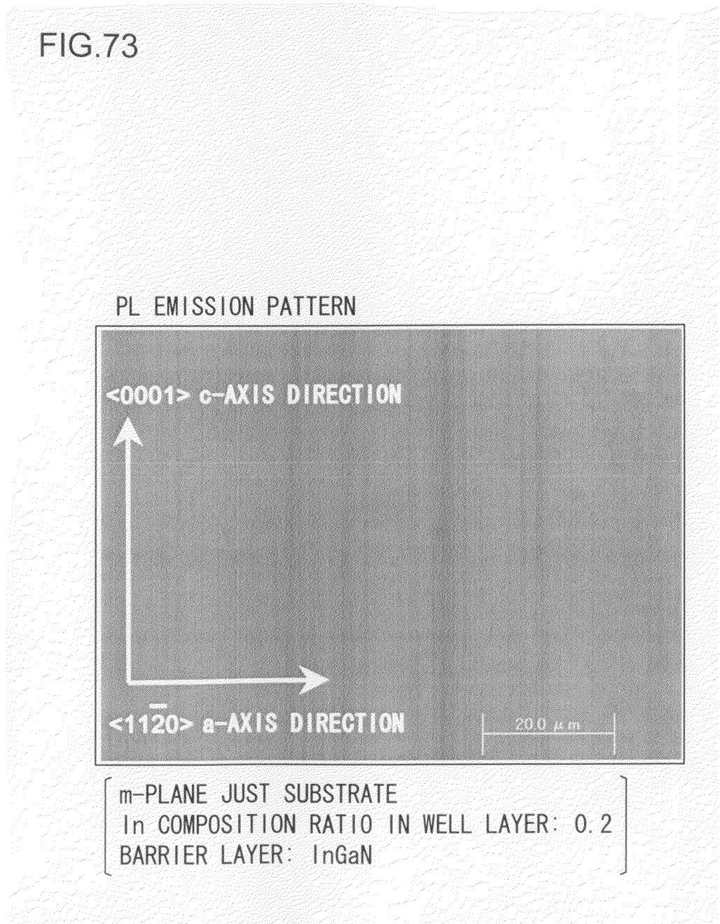

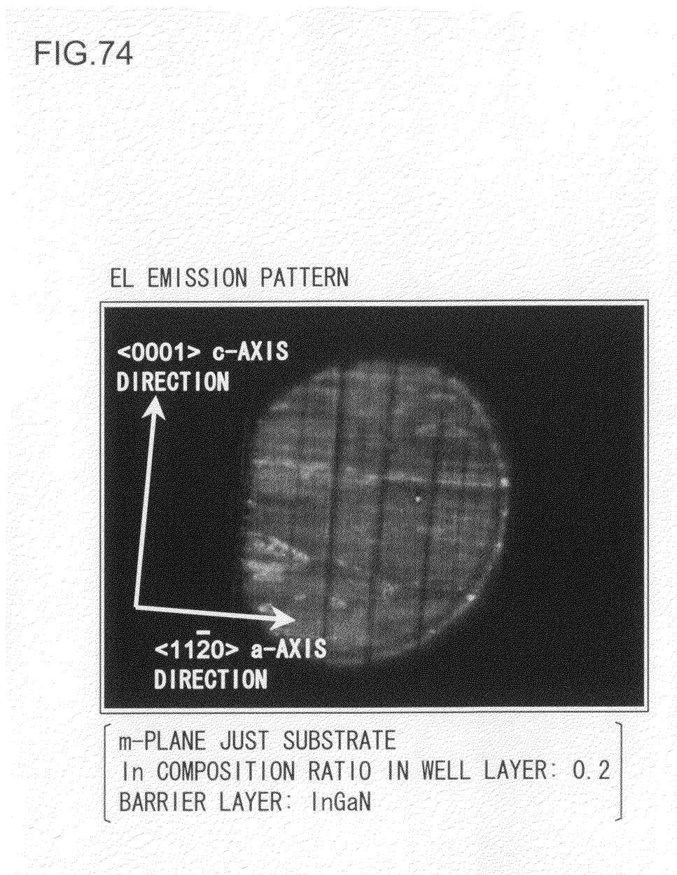

With nitride semiconductor light-emitting chips using an active layer structure as described above, however, through inspection of their PL emission pattern (the light distribution across the plane as observed when light is emitted by photoexcitation), the inventors have ascertained that, as the In composition ratio in the active layer increases, dark lines as shown in FIG. 73 may appear in the PL emission pattern of nitride semiconductor light-emitting chips. Those dark lines may be observed not only in a PL emission pattern but also, as shown in FIG. 74, in an EL emission pattern (the light distribution across the plane as observed when light is emitted by current injection).

Appearance of such dark lines is undesirable because it causes a lowering in luminous intensity (luminous efficacy) when a light-emitting chip is operated, and causes an increase in the driving current when a laser chip is operated by APC (automatic power control). Moreover, the dark lines appearing with an increased In composition in the active layer appear parallel to the c-axis direction (the <0001> direction) of the m plane. With a higher In concentration or the like, dark lines may appear in the a-axis direction (the <11-20> direction) as well, resulting in meshed dark lines. It is supposed that dark lines occur due to defects such as misfit dislocations which result from differences in lattice constant and thermal expansion coefficient between GaN in the substrate or elsewhere and an InGaN layer in the active layer. With the c plane (0001), which has conventionally been used widely, even increased In does not produce such dark lines. Thus, it is considered that appearance of such dark lines is a phenomenon peculiar to nitride semiconductor light-emitting chips using a nitride semiconductor substrate having as the principal growth plane a non-polar plane, in particular the m plane.

Moreover, through studies by the inventors, it has been found out that using InGaN in a barrier layer results in prominent appearance of dark lines. It has also been found out that, in that case, as the In composition ratio in the barrier layer increases, appearance of dark lines becomes more prominent. Furthermore, it has been found out that, even in a case where a GaN layer is used as a barrier layer, if the In composition ratio “a” in a well layer is so high that the In concentration is such that the emission wavelength is over about 490 nm, dark lines appear.

As discussed above, it has been found out that, in a nitride semiconductor light-emitting chip using a nitride semiconductor substrate having the m plane as the principal growth plane, unlike a nitride semiconductor light-emitting chip using the c plane, while a lowering in luminous efficacy resulting from spontaneous polarization and piezoelectric polarization is suppressed, a lowering in luminous efficacy results from appearance of dark lines. Appearance of such dark lines poses, in a nitride semiconductor light-emitting chip using the m plane, a great problem because it hampers the lengthening of the emission wavelength. In particular, in semiconductor laser chips, low luminous efficacy is a serious problem because it leads to low gain.

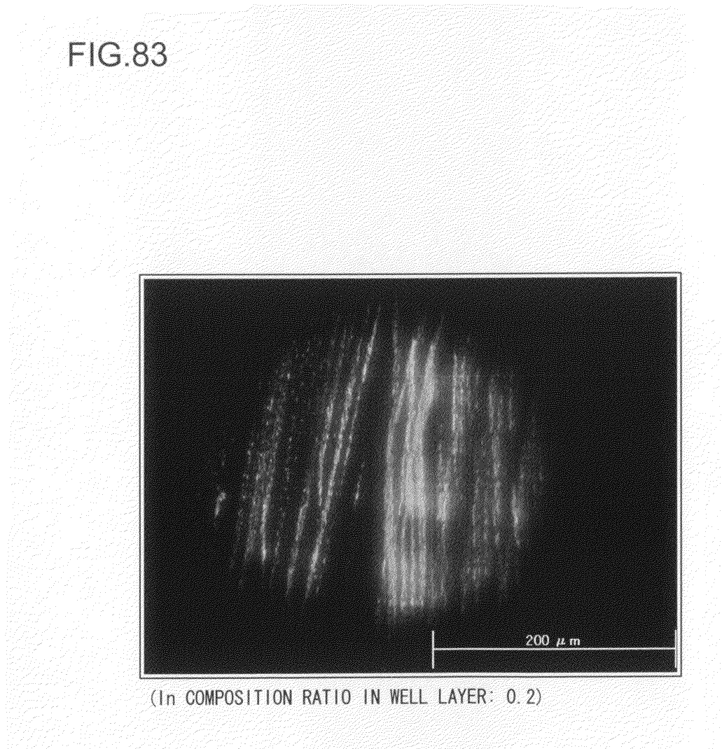

Through measurement of luminous efficacy (in light emission resulting from current injection, that is, electroluminescence, abbreviated to EL) with regard to nitride semiconductor light-emitting chips using a nitride semiconductor substrate having the m plane as the principal growth plane, the inventors have confirmed that, as the In composition ratio in the active layer increases, luminous efficacy sharply lowers. Through intensive studies in search of the cause of the phenomenon, the inventors have found out that the lowering of luminous efficacy is caused by the EL emission pattern (the light distribution across the plane as observed when light is emitted by current injection) becoming bright-spotted. That is, the inventors have found out that, as the In composition ratio in the active layer increases, as shown in FIG. 83, the EL emission pattern becomes bright-spotted. Such a bright-spotted EL emission pattern becomes more prominent as the In composition ratio in the active layer increases, and a tendency has been observed that a bright-spotted EL emission pattern is especially prominent starting around a green region (with the In composition ratio in the active layer (well layer) equal to or more than 0.15). Variations in wavelength across the plane are also observed that are considered to result from variations in current injection density. As the In composition ratio is increased further, the number of light-emitting bright spots (the area of light emission) decreases. Thus, a strong correlation is observed between the bright-spotted EL emission pattern and the In composition ratio, and it has therefore been found out that the phenomenon of the EL emission pattern becoming bright-spotted causes the lowering of luminous efficacy that occurs with increased In composition ratios in the active layer. The bright-spotted EL emission pattern described above is a phenomenon prominent in nitride semiconductor light-emitting chips using a nitride semiconductor substrate having a non-polar plane, in particular the m plane, as the principal growth plane.

As discussed above, it has been found out that, in nitride semiconductor light-emitting chips using a nitride semiconductor substrate having the m plane as the principal growth plane, there is the problem of lower luminous efficacy due to a bright-spotted EL emission pattern. In nitride semiconductor light-emitting chips using the m plane, such a bright-spotted EL emission pattern poses a great problem because it hampers the lengthening of the emission wavelength. In particular, in semiconductor laser chips, low luminous efficacy is a serious problem because it leads to low gain.

Through further intensive studies, the inventors have found out that, by using as the principal growth plane of a nitride semiconductor substrate a plane having an off angle relative to the m plane, it is possible to suppress a bright-spotted EL emission pattern.

Bright-spotted emission can be observed in an EL emission pattern, but cannot be observed distinctly in a PL emission pattern. Thus, bright-spotted emission is considered to be caused by a phenomenon arising from non-uniform current injection. It is observed particularly distinctly when the amount of injected current is small, for example, as current is gradually increased, when the current injection density is in the range between a level at which light emission starts and, in a case where the p-side electrode has a diameter of about 220 μm, about 50 mA. Even in a large-current region, bright-spotted emission is undesirable because it suppresses luminous efficacy. Bright-spotted emission therefore poses a problem in the fabrication of light-emitting diode chips (LEDs), which are typically operated at low current density; it also poses a problem in the fabrication of semiconductor laser chips (LDs), which are operated at high current density.

In contrast, dark lines are observed distinctly both in a PL emission pattern and in an EL emission pattern. Thus, it has been found out that bright-spotted emission and dark lines have different causes, and occur by different mechanisms.

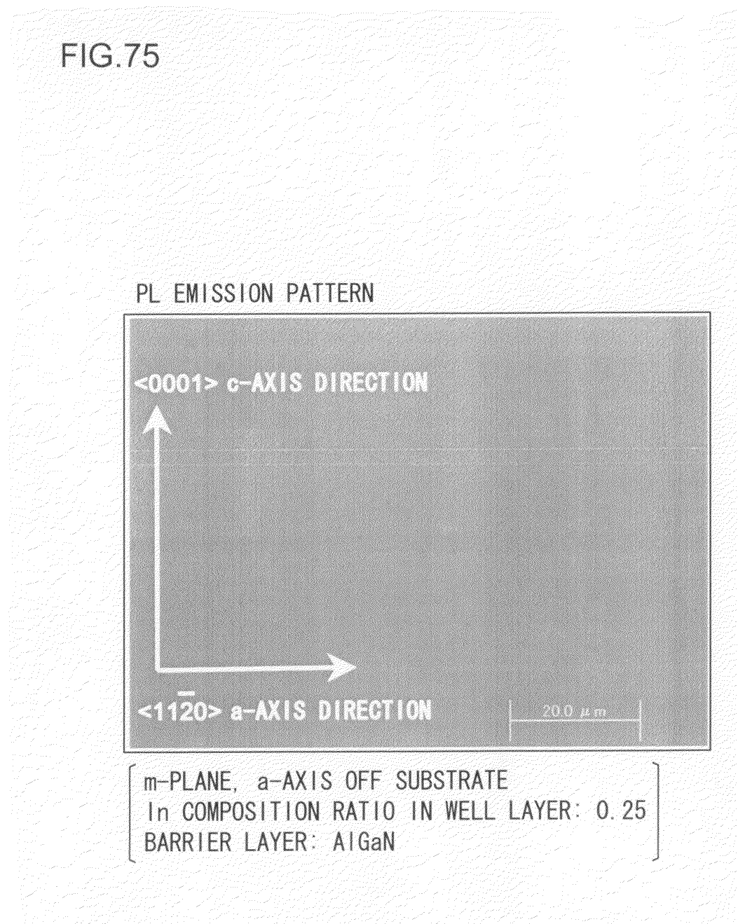

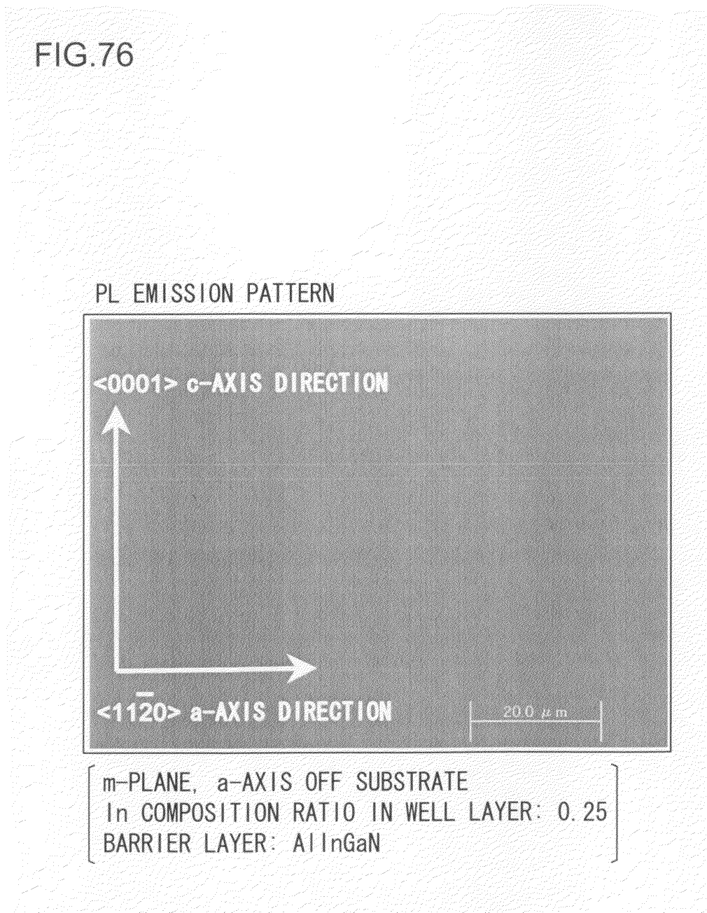

Thus, based on the above findings, through intensive studies, the inventors have found out for the first time that, by forming a barrier layer in the active layer out of a nitride semiconductor containing Al (for example, AlGaN, AlInGaN, AlInN, etc.), it is possible to suppress appearance of dark lines. Specifically, it has been found out that by forming a barrier layer out of a nitride semiconductor containing Al, it is possible to almost completely suppress appearance of dark lines as shown in FIGS. 75 and 76. As a nitride semiconductor layer for the barrier layer, the best choices are layers of AlGaN and AlInGaN, the second best being AlInN. The above effect can be obtained, however, with any nitride semiconductor layer containing Al (for example, an AlGaN, AlInGaN, AlInN, or like layer). In a case where a nitride semiconductor layer containing Al (for example, an AlGaN, AlInGaN, AlInN, or like layer) is used as the barrier layer in the active layer, it is preferable that the well layer in the active layer be formed of InGaN. In a case where a nitride semiconductor layer containing Al is used as a barrier layer, using any non-polar layer such as the m plane offers an effect of suppressing appearance of dark lines.

It has been found out that, in a case where the barrier layer is formed of AlInGaN, compared with in a case where it is formed of AlGaN, the amount of In absorbed into the well layer formed on the barrier layer is larger. Thus, forming the barrier layer out of AlInGaN is preferable, because it is then possible to widen the ranges of growth conditions. Moreover, AlInGaN, which has In added to AlGaN, allows easy formation of a film with good crystallinity even when grown at lower temperature. Thus, forming the barrier layer, which is typically formed at a comparatively low growth temperature of about 600° C. to 800° C., out of AlInGaN is preferable, because by doing so, even in a case where the barrier layer is formed at comparatively low temperature as mentioned above, it is possible to obtain a barrier layer with good crystallinity. Moreover, forming the barrier layer out of AlInGaN is preferable, because doing so helps reduce the strain that the barrier layer produces in the well layer. The smaller the strain that develops in the well layer, the better, because that slows down the deterioration of the light-emitting chip during operation.

FIG. 73 referred to above is a microscope photograph of dark lines observed in a PL emission pattern, and the PL emission pattern in FIG. 73 is that of a light-emitting diode chip fabricated by use of a GaN substrate having the m plane as the principal growth plane (an m-plane just substrate). This light-emitting diode chip has a well layer formed of In_{0.2}Ga_{0.8}N and a barrier layer formed of In_{0.02}Ga_{0.98}N.

FIG. 74 referred to above is a microscope photograph of dark lines observed in an EL emission pattern, and the EL emission pattern in FIG. 74 is that of a light-emitting diode chip fabricated by use of a GaN substrate having the m plane as the principal growth plane (an m-plane just substrate). This light-emitting diode chip has a well layer formed of In_{0.2}Ga_{0.8}N and a barrier layer formed of In_{0.02}Ga_{0.98}N.

FIG. 75 referred to above is a microscope photograph of a PL emission pattern of a light-emitting diode chip having a barrier layer formed of AlGaN. This light-emitting diode chip has a well layer formed of In_{0.25}Ga_{0.75}N and has a barrier layer formed of Al_{0.01}Ga_{0.99}N. Used as a nitride semiconductor substrate here is an m-plane, a-axis off substrate (with an off angle of 1.7 degrees in the a-axis direction, and with an off angle of +0.1 degrees in the c-axis direction).

FIG. 76 referred to above is a microscope photograph of a PL emission pattern of a light-emitting diode chip having a barrier layer formed of AlInGaN. This light-emitting diode chip has a well layer formed of In_{0.25}Ga_{0.75}N and has a barrier layer formed of Al_{0.01}In_{0.03}Ga_{0.96}N. Used as a nitride semiconductor substrate here is an m-plane, a-axis off substrate (with an off angle of 1.7 degrees in the a-axis direction, and with an off angle of +0.1 degrees in the c-axis direction).

On the other hand, when, by use of a nitride semiconductor substrate having as the principal growth plane a plane having an off angle in the a-axis direction relative to the m plane, the inventors formed a GaN layer (a non-doped GaN layer, that is, one that has not been subjected to any intentional doping; or an n-type GaN layer, that is, one that has been intentionally doped with an n-type impurity) with a thickness of about 1 μm on that principal growth plane, it was found out that the thickness distribution across the plane was very poor. The thickness distribution then was very poor even in comparison with that obtained when a GaN layer with a thickness of about 1 μm was formed on an m-plane GaN substrate having no off angle in the a-axis direction. This phenomenon of a large thickness distribution across the plane occurring when a GaN layer having the same composition as a substrate is formed on the substrate by an epitaxial growth process such as a MOCVD (metal organic chemical vapor deposition) process is considered to be a very peculiar one.

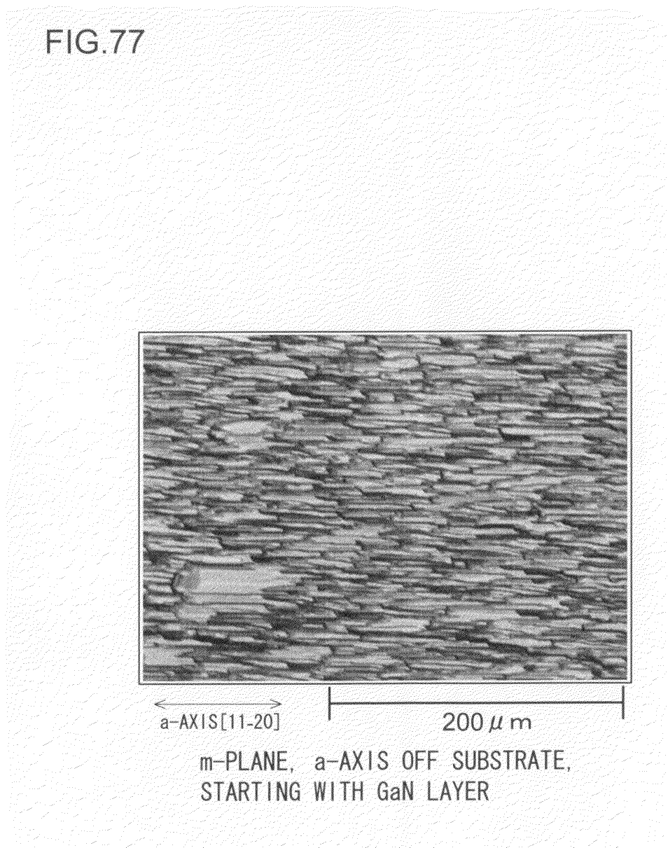

FIG. 77 is a microscope photograph obtained when, by use of a GaN substrate having as the principal growth plane a plane having an off angle in the a-axis direction relative to the m plane, a GaN layer with a thickness of about 1 μm was formed on that principal growth plane and the surface morphology was inspected under an optical microscope. FIG. 77 shows the surface morphology as observed with individual nitride semiconductor layers stacked on the principal growth plane starting with the GaN layer. As shown in FIG. 77, on the surface of the semiconductor layers, very distinct wave-form surface irregularities are observed in the direction parallel to the a-axis direction. Moreover, the nitride semiconductor layers shown in FIG. 77 have a thickness distribution of about 200 to 400 nm, and with nitride semiconductor layers with such a poorly uniform thickness distribution, it is extremely difficult to form a chip.

Conventionally, it is common practice to form, first, a semiconductor layer of the same composition as a substrate in contact with the surface (principal growth plane) of the substrate with a view to enhancing the flatness at the layer surface and the crystallinity of the semiconductor layer, and then form a chip on top. For example, with a GaN substrate, first, a GaN layer is formed on the substrate. This makes the composition of the substrate the same as that of the semiconductor layer (GaN layer) formed on the substrate surface (principal growth plane), eliminating differences in lattice constant, thermal expansion coefficient, etc., and thus suppressing development of strain. It is known that, by doing so, it is possible to form a semiconductor layer with high flatness and good crystallinity. In fact, it is common to do so in cases where, by use of a nitride semiconductor substrate having the c plane as the principal growth plane (for example, a c-plane GaN substrate), crystal growth is performed on that principal growth plane. In such cases (where a GaN layer is formed on a c-plane GaN substrate), very good surface morphology is obtained, and this is considered to be the normal phenomenon.

It was, however, recently found out for the first time that, with a nitride semiconductor substrate having as the principal growth plane a plane having an off angle in the a-axis direction relative to the m plane, applying the above-described configuration rather degrades surface morphology.

Through intensive studies, the inventors have found out that the degradation of surface morphology is associated with the thickness of the GaN layer. Specifically, through the studies, it has been found out that, with a nitride semiconductor substrate having as the principal growth plane a plane having an off angle in the a-axis direction relative to the m plane, forming a thick film of GaN with a thickness of about 1 μm greatly degrades surface morphology, resulting in peculiar surface morphology as shown in FIG. 77.

The inventors have also found out that, the greater the total thickness of the GaN layer formed on the principal growth plane, the poorer the surface morphology. The total thickness here denotes, in a case where a single GaN layer is formed, the thickness of this GaN layer and, in a case where a plurality of GaN layers are formed, (the sum of) their thicknesses added up. Accordingly, forming a thick GaN layer before forming an active layer degrades surface morphology, and forming the active layer on the surface of the layer with such degraded surface morphology causes the active layer, under the influence of the degraded surface morphology, to divide into high-In-composition and low-In-composition regions across the plane. This, it has been found out, results in an across-the-plane distribution of composition. It has also been found out that, maybe not only because of the across-the-plane distribution of the active layer's composition but also because of degradation, in the active layer's crystallinity, luminous intensity also lowers.

Through further studies based on the above findings, the inventors have found out that, by giving the GaN layer formed between the substrate and the active layer a total thickness of 0.7 μm or less, it is possible to improve surface morphology. It is preferable that the total thickness of the GaN layer formed between the substrate and the active layer be 0.5 μm or less, and more preferably 0.3 μm or less.

It has further been revealed that, in a case where a nitride semiconductor chip is formed by use of a nitride semiconductor substrate having as the principal growth plane a plane having an off angle in the a-axis direction relative to the m plane, it is preferable to form no GaN layer at all or, if any, as little of a GaN layer as possible before forming an active layer.

As described above, by forming nitride semiconductor layers in such a way as to satisfy the above-mentioned condition that the total thickness of the GaN layer be 0.7 μm or less, it is possible to improve surface morphology and make the layer surface flat. Then, by forming an active layer (a well layer which is a nitride semiconductor layer containing In) on that flat layer surface, it is possible to suppress an across-the-plane distribution of In composition, and thereby to improve luminous efficacy.

From the viewpoint of improving luminous efficacy, it is preferable to give the GaN layer formed between the substrate and the well layer, which is a nitride semiconductor layer containing In, a total thickness of 0.7 μm or less. In a case where a plurality of well layers are formed, the GaN layer formed between the most substrate-side well layer and the nitride semiconductor substrate may be given a total thickness of 0.7 μm or less, or the GaN layer formed between any other well layer and the nitride semiconductor substrate may be given a total thickness of 0.7 μm or less.

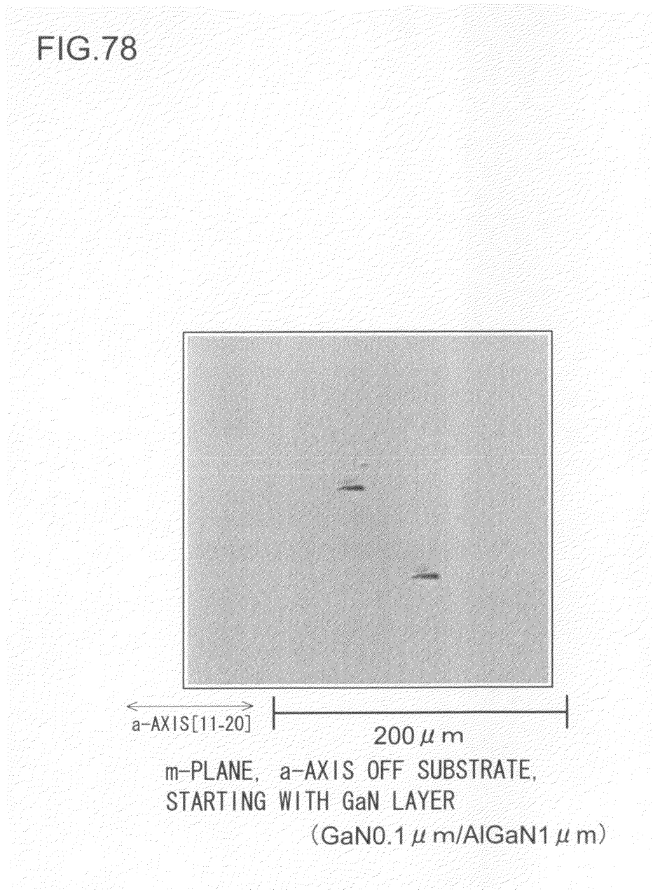

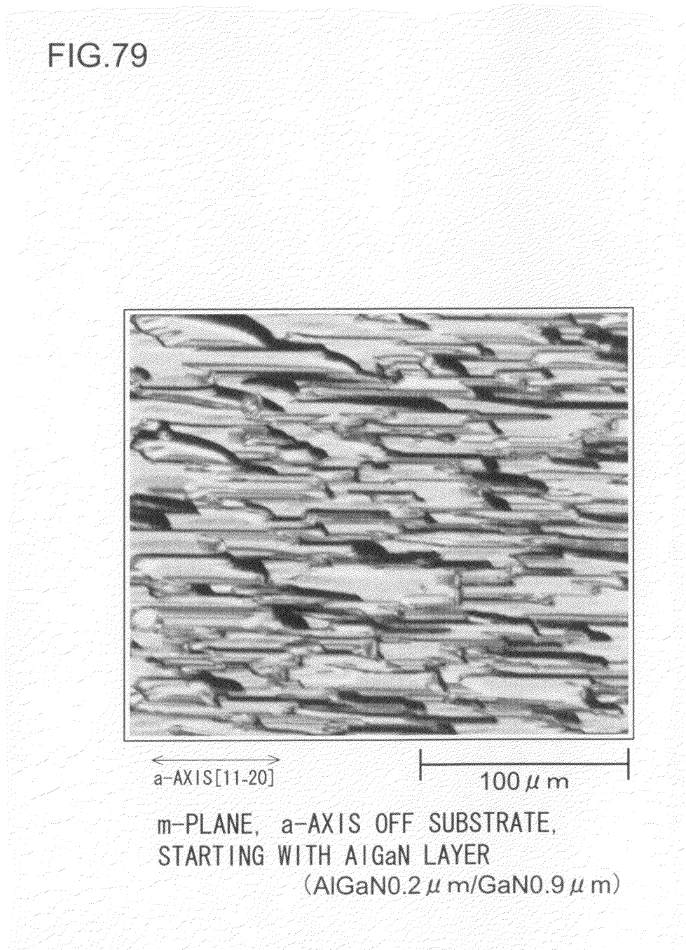

FIG. 78 is a microscope photograph obtained when, by use of a GaN substrate having as the principal growth plane a plane having an off angle in the a-axis direction relative to the m plane, a GaN layer with a thickness of about 0.1 μm was formed on that principal growth plane, then an AlGaN layer with a thickness of about 0.9 μm was formed on this GaN layer, and then the surface morphology was inspected under an optical microscope. FIG. 78 shows the surface morphology as observed with individual nitride semiconductor layers stacked on the principal growth plane starting with the GaN layer. The AlGaN layer had the composition Al_{0.05}Ga_{0.95}N. Moreover, in FIG. 78, the GaN and AlGaN layers were given a total thickness of about 1 μm so that the total thickness of the GaN and AlGaN layers was equal to the thickness of the GaN layer in FIG. 77. Specifically, in FIG. 78, instead of a GaN layer with a thickness of about 1 μm, there were formed a GaN layer with a thickness of about 0.1 μm and an AlGaN layer with a thickness of about 0.9 μm.

As shown in FIG. 78, forming a GaN layer with a thickness of about 0.1 μm gives very good surface morphology, and it is seen that the resulting flatness on the layer surface is greatly enhanced compared with that in the case shown in FIG. 77 where a GaN substrate with a thickness of about 1 μm is formed. In this way, the thicker the GaN layer, the poorer the surface morphology. By contrast, a thin GaN layer suppresses degradation of surface morphology. It has also been found out that, once a thick film of GaN is formed and surface morphology degrades, forming an AlGaN layer thereafter does not help much improve the degraded surface morphology, with surface morphology becoming poorer as the number of semiconductor layers stacked increases.

Through the studies this time, it has also been found out that, in a case where use is made of a nitride semiconductor substrate having as the principal growth plane a plane having an off angle in the a-axis direction relative to the m plane, it is preferable that the semiconductor layer in contact with the principal growth plane be formed of In_{y}Ga_{1-y}N (0<y ≦1), AlₓGa₁₋ₓN (0<x≦1), or AlₐIn_{b}Ga_{c}N (a+b+c=1).

With In_{y}Ga_{1-y}N (0<y≦1), as conditions for keeping better surface morphology, it is more preferable that 0<y≦0.1, and it is preferable that the layer in contact with the principal growth plane of the nitride semiconductor substrate have a thickness of 0.7 μm or less. In a case where the semiconductor in contact with the principal growth plane is InGaN, film formation is performed at a low temperature of about 700° C. to 900° C. In a case where use is made of a nitride semiconductor substrate having as the principal growth plane a plane having an off angle in the a-axis direction relative to the m plane, if, during heating of the substrate prior to film formation, the temperature is raised to above about 1100° C., depending on the atmosphere inside the furnace (the conditions such as gas flow rate, pressure, etc.), N (nitrogen) or Ga (gallium) may evaporate from the substrate surface before growth, causing surface roughness on the substrate. It has been found out that this surface roughness does not occur at a substrate temperature of 900° C. or less. For this reason, it is preferable to use InGaN, which allows film formation at low temperature (about 700° C. to 900° C.) and thus helps effectively suppress surface roughness on the substrate.

Likewise, AlₐIn_{b}Ga_{c}N (a+b+c=1, 0<a≦1, 0<b≦1, 0≦c<1), when it contains In, allows low-temperature film formation, and thus offers similar effects as InGaN. Also in this case, it is preferable that the layer in contact with the principal growth plane of the substrate have a thickness of 0.7 μm or less, and from the viewpoint of surface morphology, it is more preferable that the Al composition ratio “a” be 0<a≦0.1 and in addition the In composition ratio “b” be 0<b≦0.1. That is, it is preferable to use a nitride semiconductor layer containing Al and In as the semiconductor layer in contact with the principal growth plane, because doing so makes it easy to form a film with high flatness by growth at low temperature.

Also in this case, it is preferable to give the GaN layer formed between the substrate and the active layer (well layer) a total thickness of 0.7 μm or less.

FIG. 79 is a microscope photograph obtained when, by use of a GaN substrate having as the principal growth plane a plane having an off angle in the a-axis direction relative to the m plane, an AlGaN layer with a thickness of about 0.2 μm was formed on that principal growth plane, then a GaN layer with a thickness of about 0.9 μm was formed on this AlGaN layer, and then the surface morphology was inspected under an optical microscope. FIG. 79 shows the surface morphology as observed with individual nitride semiconductor layers stacked on the principal growth plane starting with the AlGaN layer. The AlGaN layer had the composition Al_{0.05}Ga_{0.95}N.

Using an AlGaN layer as the semiconductor layer in contact with the principal growth plane gives the AlGaN layer good surface morphology. However, forming a GaN layer with a thickness of over 0.7 μm, for example about 0.9 μm, degrades surface morphology as shown in FIG. 79. That is, it has been found out that, even when an AlGaN layer (Al_{0.05}Ga_{0.95}N layer) is formed between the substrate and the GaN layer, if the GaN layer is thick, surface morphology degrades.

It has also been found out that, in a case where an AlGaN layer or the like is formed between a plurality of GaN layers (for example, in a four-layer structure of GaN/AlGaN/GaN/AlGaN layers), giving the GaN layer a total thickness more than 0.7 μm degrades surface morphology. For example, when a GaN layer with a thickness of about 1 μm was formed on the principal growth plane of a substrate and then an AlGaN layer (for example, Al_{0.95}Ga_{0.95}N layer) with a thickness of about 1 μm was formed, the surface morphology degraded as a result of the GaN layer being formed did not recover, resulting in surface morphology similar to that shown in FIG. 77.

Thus, through the studies, it has been found out that the total thickness of the GaN layer formed on the substrate (between the substrate and the active layer (well layer)) ultimately determines surface morphology, and thus that it is necessary to suppress the GaN layer having too great a total thickness before the formation of the active layer (well layer which is a nitride semiconductor layer containing In).

In a case where use is made of a nitride semiconductor substrate having as the principal growth plane a plane having an off angle in the a-axis direction relative to the m plane, it is preferable to adopt a configuration in which the layered structure stacked on the substrate (the layered structure of the light-emitting chip) contains no GaN layer at all or, if any, as little of a GaN layer as possible; it is, however, also possible to use a GaN layer as an optical guide layer for light confinement or the like. It is also possible to form a very thin GaN layer into a super-lattice with AlGaN, AlInGaN, or InGaN (AlGaN/GaN/AlGaN/GaN . . . , AlInGaN/GaN/AlInGaN/GaN . . . , InGaN/GaN/InGaN/GaN . . . , etc.), thereby to increase the total GaN layer thickness while suppressing degradation of surface morphology. This super-lattice structure can then be used as an optical guide layer or an optical clad layer. Using the above structure makes it possible to form a comparatively good layer by use of a thin-film GaN layer. When a thin-film GaN layer is used in a super-lattice structure in such a case, it is particularly preferable that its thickness be 1 nm or more but 50 nm or less. Even in that case, it is necessary to suppress the total thickness of the GaN layer formed between the substrate and the active layer (well layer) to 0.7 μm or less.

To obtain a light-emitting chip or electronic device with superior characteristics, it is preferable, as described above, that the layered structure stacked on the substrate include no or as little as possible of a GaN layer and that the layered structure be composed of semiconductor layers of compositions different from GaN, such as InGaN, AlGaN, InAlGaN, InAlN, etc.

Through the studies this time, it has also been found out that when a nitride semiconductor layer containing Al or In (for example, an AlGaN, InGaN, AlInGaN, AlInN, or like layer) is formed even with a thickness over 1 μm, unlike a GaN layer, deterioration of surface morphology is suppressed. Accordingly, in a case where a LD structure is fabricated by use of a nitride semiconductor substrate having as the principal growth plane a plane having an off angle in the a-axis direction relative to the m plane, it is preferable to use as an optical clad layer a nitride semiconductor layer containing Al, such as an AlGaN, AlInGaN, AlInN, or like layer). Alternatively, it is preferable to use a nitride semiconductor layer containing Al and In. Moreover, it is preferable to use as an optical guide layer a nitride semiconductor layer containing In, such as an InGaN, AlInGaN, AlInN, or like layer.

In a case where a nitride semiconductor substrate with a non-polar plane is used, or in a case where a nitride semiconductor layer containing Al or a nitride semiconductor layer containing Al and In is used as a barrier layer in an active layer, it is preferable, for the purposes of, among others, alleviating strain in the active layer and suppressing appearance of dark lines, to use as an optical clad layer a nitride semiconductor layer containing Al and In, such as an AlInGaN, AlInN, or like layer. Moreover, it is preferable to use as an optical guide layer a nitride semiconductor layer containing In, such as an InGaN, AlInGaN, AlInN, or like layer, or a nitride semiconductor layer containing Al and In. Needless to say, similar considerations apply in a case where use is made of a nitride semiconductor substrate having as the principal growth plane a plane having an off angle in the a-axis direction relative to the m plane.

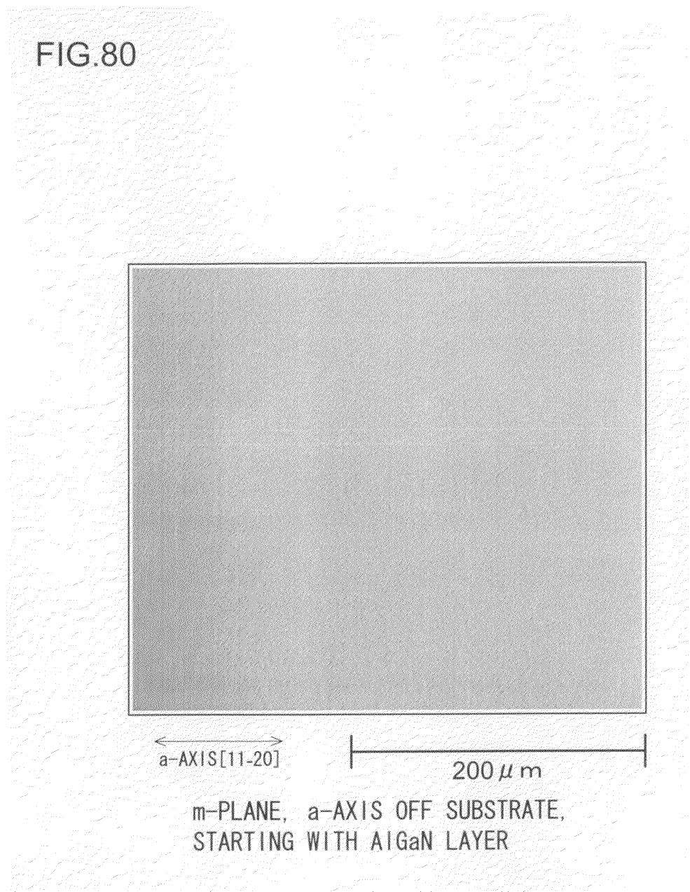

FIG. 80 is a microscope photograph obtained when, by use of a GaN substrate having as the principal growth plane a plane having an off angle in the a-axis direction relative to the m plane, an AlGaN layer with an Al composition ratio of 5% and with a thickness of about 2 μm was formed on that principal growth plane and the surface morphology was inspected under an optical microscope. FIG. 80 shows the surface morphology as observed with individual nitride semiconductor layers stacked on the principal growth plane starting with the AlGaN layer. As shown in FIG. 80, the surface morphology obtained when a nitride semiconductor layer containing Al is formed as a thick film is very good. It has thus been found out that, even when a nitride semiconductor layer containing Al or In is formed as a thick film, degradation of surface morphology is suppressed. It is considered that using a nitride semiconductor layer containing Al or In as the semiconductor layer in contact with the substrate surface (principal growth plane) changes the growth mode in such a way as to enhance flatness and crystallinity.

Using as the semiconductor layer in contact with the substrate surface (principal growth plane) a nitride semiconductor layer containing Al or In (for example, an AlGaN, InGaN, AlInGaN, AlInN, or like layer) as described above brings about a marked enhancement in surface morphology. This phenomenon is peculiar to cases where use is made of a nitride semiconductor substrate having as the principal growth plane a plane having an off angle in the a-axis direction relative to the m plane; no report whatsoever has to this date been made of the phenomenon, which thus came to light for the first time through the inventors' studies this time.

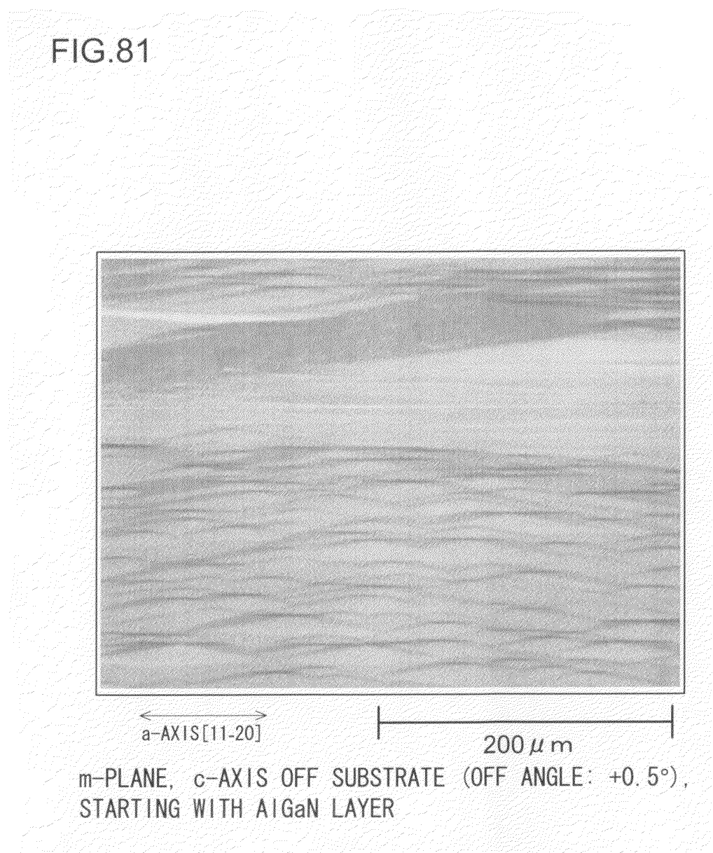

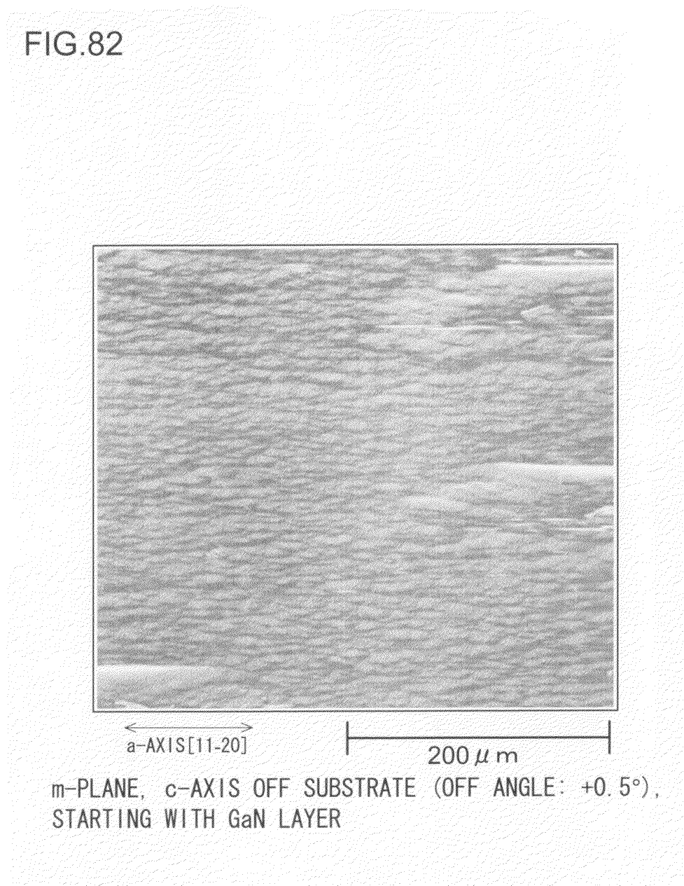

For comparison, FIG. 81 is a microscope photograph obtained when, by use of a GaN substrate having as the principal growth plane a plane having an off angle of +0.5 degrees in the c-axis direction relative to the m plane, an AlGaN layer with a thickness of about 1 μm was formed on that principal growth plane and the surface morphology was inspected under an optical microscope; FIG. 82 is a microscope photograph obtained when, by use of a GaN substrate having as the principal growth plane a plane having an off angle of +0.5 degrees in the c-axis direction relative to the m plane, a GaN layer with a thickness of about 1 μm was formed on that principal growth plane and the surface morphology was inspected under an optical microscope. FIG. 81 shows the surface morphology as observed with individual nitride semiconductor layers stacked on the principal growth plane starting with the AlGaN layer, and FIG. 82 shows the surface morphology as observed with individual nitride semiconductor layers stacked on the principal growth plane starting with the GaN layer.

As shown in FIGS. 81 and 82, surface morphology was poor in both cases, with no notable difference observed between them. In this way, there usually arises no notable difference in surface morphology between when a GaN layer is formed (semiconductor layers are stacked starting with a GaN layer) and when an AlGaN layer is formed (semiconductor layers are stacked starting with an AlGaN layer). Thus, it has been found out that the above-mentioned phenomenon is peculiar to a nitride semiconductor substrate having as the principal growth plane a plane having an off angle in the a-axis direction relative to the m plane.

Based on the foregoing, in a case where a GaN layer is formed on a nitride semiconductor substrate having as the principal growth plane a plane having an off angle in the a-axis direction relative to the m plane, it is preferable that the total thickness of the GaN layer formed between the substrate surface (principal growth plane) and the active layer (the well layer which is a nitride semiconductor layer containing In) be 0.7 μm or less, and more preferably 0.5 μm or less; it is still more preferable that the total GaN layer thickness be 0.3 μm or less. With a total GaN layer thickness of 0.5 μm or less, no significant degradation of surface morphology occurs. Thus, it is possible, as by thereafter forming an AlGaN layer, to form a plurality of GaN layers on the substrate. Even then, however, it is still necessary to fulfill the condition that the total thickness of the GaN layer formed between the substrate surface (principal growth plane) and the active layer (well layer) be 0.7 μm or less.

Studies by the inventors have also revealed that a nitride semiconductor substrate having an off angle in the a-axis direction relative to the m plane is a non-polar substrate very suitable to form a nitride semiconductor layer containing Al (for example, an AlGaN, AlInGaN, AlInN, or like layer) with satisfactory flatness and crystallinity. It has also been found out that, by use of a substrate with such characteristics as just mentioned, and by forming a barrier layer in the active layer out of a nitride semiconductor layer containing Al (for example, an AlGaN, AlInGaN, AlInN, or like layer), it is possible to obtain, in addition to an effect of suppressing appearance of dark lines as mentioned above, also an effect of enhancing the flatness and crystallinity of the barrier layer, and it is thus possible to greatly enhance luminous efficacy.

Of m-plane nitride semiconductor substrates, those having an off angle in the a-axis direction suffer from, as described above, poor surface morphology when an n-type GaN layer or a non-doped GaN layer is formed with a thickness over 1 μm. However, with a p-type GaN layer, that is, one intentionally doped with an impurity that produces p-type conductivity, even when it was formed with a thickness of about 0.5 μm, no degradation of surface morphology was observed (that is, so long as the total thickness of an n-type GaN layer and a non-doped GaN layer was 0.7 μm or less, even when a p-type GaN layer was additionally formed with a thickness of about 0.5 μm, no degradation of surface morphology was observed). Thus, it is practicable to use a p-type GaN layer as a contact layer. Here, however, it should be noted that, in a case where a nitride semiconductor layer containing Al (for example, an AlGaN, AlInGaN, AlInN, or like layer) is formed, since doing so gives better surface morphology, it is preferable to form a contact layer by use of a nitride semiconductor containing Al. This enhances surface morphology, further improves the thickness distribution across the plane, and thus enhances the uniformity of current injection. This is preferable, because it is thereby possible to obtain, as a result of the improved emission pattern, effects such as enhanced luminous efficacy and a reduced driving voltage.

Hereinafter, specific embodiments of the present invention will be described in detail with reference to the accompanying drawings. In the embodiments presented below, a “nitride semiconductor” denotes a semiconductor of the composition AlₓGa_{y}In_{z}N (where 0≦x≦1, 0≦y≦1, 0≦z≦1, and x+y+z=1).

### Embodiment 1

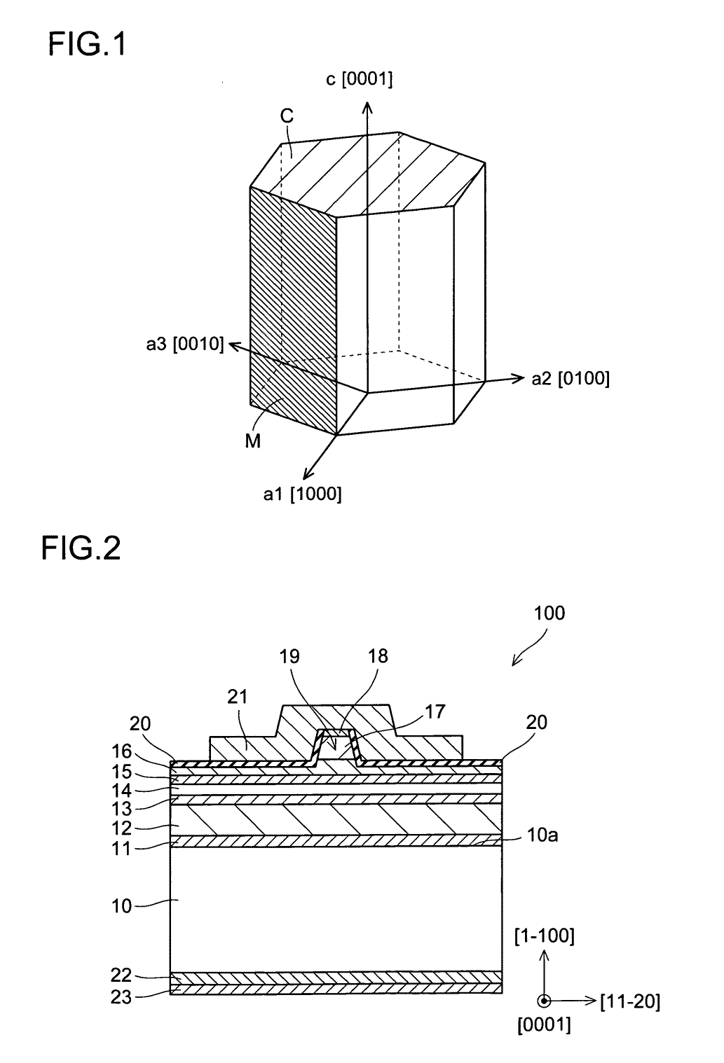

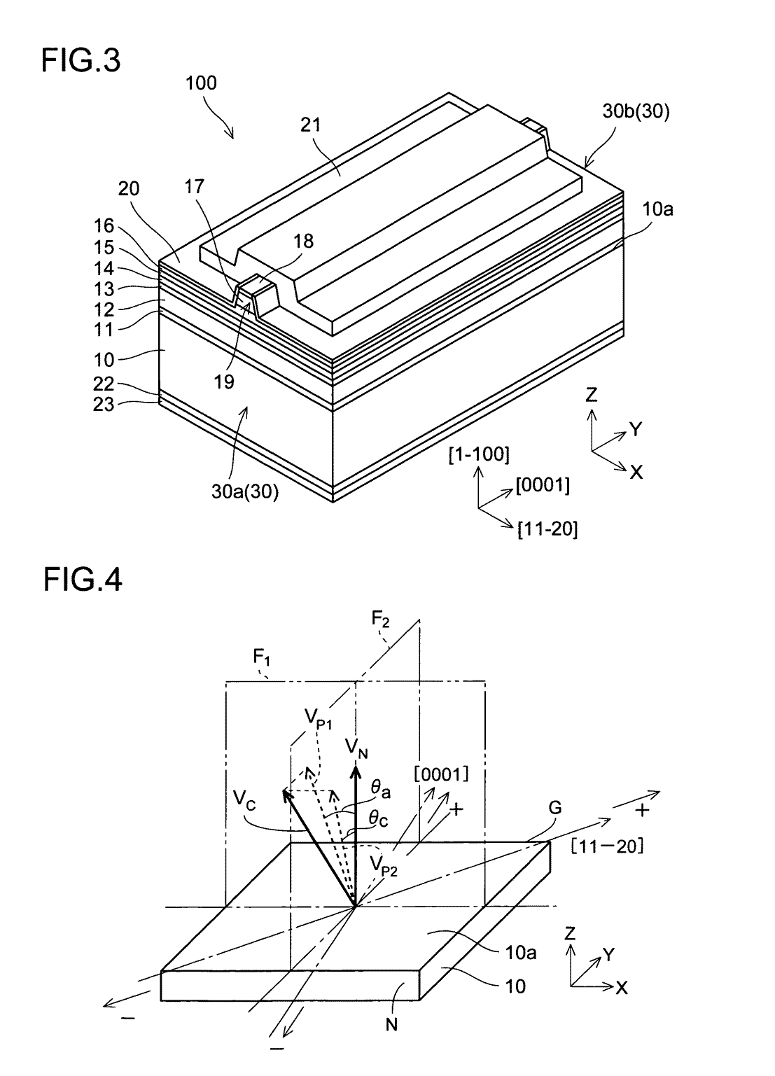

FIG. 1 is a schematic diagram illustrating a crystal structure of a nitride semiconductor. FIG. 2 is a sectional view showing the structure of a nitride semiconductor laser chip according to a first embodiment (Embodiment 1) of the invention. FIG. 3 is an overall perspective view of a nitride semiconductor laser chip according to Embodiment 1 of the invention. FIGS. 4 to 6 are diagrams illustrating the structure of a nitride semiconductor laser chip according to Embodiment 1 of the invention. First, with reference to FIGS. 1 to 6, the structure of a nitride semiconductor laser chip 100 according to Embodiment 1 of the invention will be described.

The nitride semiconductor laser chip 100 according to Embodiment 1 is formed of a nitride semiconductor having a crystal structure of a hexagonal crystal system as shown in FIG. 1. In this crystal structure, when the hexagonal crystal system is considered to be a hexagonal column about a c axis [0001], the plane (the top face of the hexagonal column) to which the c axis is normal is called the c plane (0001), and any of the side wall faces of the hexagonal column is called the m plane {1-100}. In a nitride semiconductor, no plane of symmetry exists in the c-axis direction, and therefore a direction of polarization runs along the c-axis direction. Thus, the c plane exhibits different properties between the +c axis side and the −c axis side. Specifically, the +c plane (the (0001) plane, a Ga polar plane G) and the −c plane (the (000-1) plane, a N polar plane N) are not equivalent planes, and have different chemical properties. On the other hand, the m plane is a crystal plane perpendicular to the c plane, and therefore a normal to the m plane is perpendicular to the direction of polarization. Thus, the m plane is a non-polar plane, that is, a plane having no polarity. Since, as described above, the side wall faces of the hexagonal column are each the m plane, the m plane can be represented by six plane orientations, namely (1-100), (10-10), (01-10), (−1100), (−1010), and (0-110); these plane orientations are equivalent in terms of crystal geometry, and are therefore collectively represented by {1-100}.

As shown in FIGS. 2 and 3, the nitride semiconductor laser chip 100 according to Embodiment 1 is provided with a GaN substrate 10 as a nitride semiconductor substrate. The principal growth plane 10a of the GaN substrate 10 is a plane having an off-angle relative to the m plane. Specifically, the GaN substrate 10 of the nitride semiconductor laser chip 100 has an off-angle in the a-axis direction (the [11-20] direction) relative to the m plane. The GaN substrate 10 may have, in addition to the off-angle in the a-axis direction, an off-angle in the c-axis direction (the [0001] direction) as well.

Now, with reference to FIG. 4, the off-angle of the GaN substrate 10 will be described in more detail. First, with respect to the m plane, two crystal axis directions are defined, namely the a-axis [11-20] direction and the c-axis [0001] direction. These axes, namely the a and c axes, are perpendicular to each other, and in addition are both perpendicular to the m axis. Moreover, the directions that are parallel to the a-, c-, and m-axis directions when the crystal axis vector (the m axis [1-100]) V_{C} of the GaN substrate 10 coincides with the normal vector V_{N} of the substrate surface (principal growth plane) (that is, when the off-angle is 0 in all directions) are taken as the X, Y, and Z directions respectively. Next, a first plane F₁ a normal to which runs in the Y direction and a second plane F₂ a normal to which runs in the X direction are considered. Then, the crystal axis vectors V_{C} that appear when the crystal axis vector V_{C} is projected on the first and second planes F₁ and F₂ are taken as a first and a second projected vector V_{P1} and V_{P2} respectively. Here, the angle θa between the first projected vector V_{P1} and the normal vector V_{N} is the off-angle in the a-axis direction, and the angle θc between the second projected vector V_{P2} and the normal vector V_{N} is the off-angle in the c-axis direction. An off-angle in the a-axis direction, irrespective of whether it is in the + or − direction, indicates the same surface status from a crystallographic point of view, and thus behaves in the same manner in the + and − directions; this permits an off-angle in the a-axis direction to be stated in terms of an absolute value. On the other hand, an off-angle in the c-axis direction makes either the Ga polar plane G or the N polar plane N stronger depending on whether it is in the + or − direction, and thus behaves differently depending on the direction; therefore, an off-angle in the c-axis direction is stated with a distinction made between the + and − directions.

As described above, the GaN substrate 10 according to Embodiment 1 has, as the principal growth plane 10a, a plane inclined in the a-axis direction relative to the m plane {1-100}.

In the above-described GaN substrate 10, the absolute value of the off-angle in the a-axis direction relative to the m plane is adjusted to be more than 0.1 degrees. As the off angle in the a-axis direction increases, however, the amount of In absorbed in the active layer (an InGaN layer such as a well layer) tends to decrease, and accordingly, from the perspective of source material efficiency and the like, it is preferable that the absolute value of the off angle in the a-axis direction be 10 degrees or smaller. Even with an off angle of 10 degrees or larger in the a-axis direction, film formation is possible. In a case where an off angle is provided also in the c-axis direction, it is preferable that the off angle in the c-axis direction be adjusted to be larger than ±0.1 degrees. It is preferable that the off angle in the c-axis direction be adjusted to be smaller than the off angle in the a-axis direction.

In the case described above, it is preferable that the off-angle in the a-axis direction be adjusted to be larger than 1 degree but 10 degrees or smaller. Adjusting the off-angle in the a-axis direction in that range is more preferable, because it is then possible to obtain a marked effect of reducing the driving voltage and in addition an effect of improving surface morphology.

The nitride semiconductor laser chip 100 according to Embodiment 1 is formed by stacking a plurality of nitride semiconductor layers on the principal growth plane 10a of the above-described GaN substrate 10.

Specifically, in the nitride semiconductor laser chip 100 according to Embodiment 1, as shown in FIGS. 2 and 3, on the principal growth plane 10a of the GaN substrate 10, an n-type GaN layer 11 with a thickness of about 0.1 μm is formed. On the n-type GaN layer 11, a lower clad layer 12 of n-type Al_{0.06}Ga_{0.94}N with a thickness of about 2.2 μm is formed. On the lower clad layer 12, a lower guide layer 13 of n-type GaN with a thickness of about 0.1 gm is formed. On the lower guide layer 13, an active layer 14 is formed. The GaN substrate 10 is formed to have n-type conductivity. The lower guide layer 13 may be non-doped.

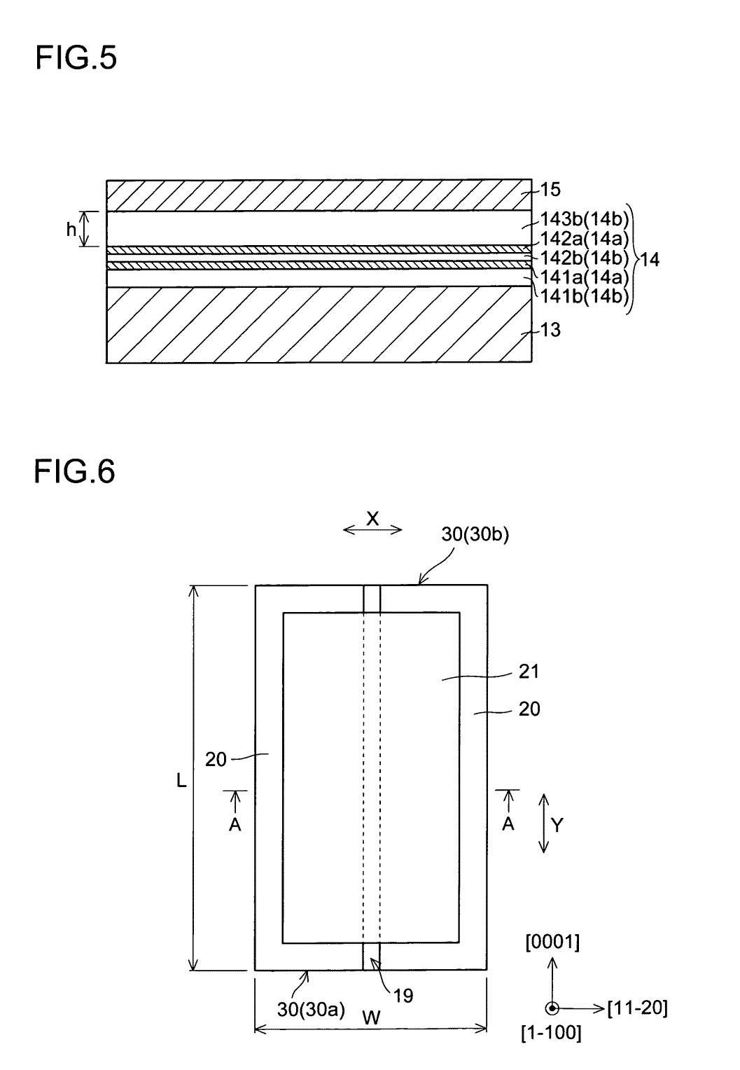

As shown in FIG. 5, the active layer 14 has a quantum well structure having well layers 14a and barrier layers 14b stacked alternately.

Here, in Embodiment 1, the barrier layers 14b in the active layer 14 are formed of AlGaN, which is a nitride semiconductor containing Al. Specifically, the active layer 14 has a quantum well (DQW, double quantum well) structure having two well layers 14a of Inₓ₁Ga₁₋ₓ₁N and three barrier layers 14b of Alₓ₂Ga₁₋ₓ₂N stacked alternately. More specifically, the active layer 14 is formed by successively stacking, from the lower guide layer 13 side, a first barrier layer 141b, a first well layer 141a, a second barrier layer 142b, a second well layer 142a, and a third barrier layer 143b. The two well layers 14a (first and second well layers 141a and 142a) are each formed to have a thickness of about 1.5 nm to 4 nm. The first barrier layer 141b is formed to have a thickness of about 30 nm, the second barrier layer 142b is formed to have a thickness of about 16 nm, and the third barrier layer 143b is formed to have a thickness of about 60 nm. Thus, the three barrier layers 14b are each formed to have a different thickness. With this configuration, it is possible to effectively suppress appearance of dark lines.

It is preferable that the first barrier layer 141b be formed to have a thickness of 8 nm or more but 50 nm or less, and more preferably 10 nm or more but 40 nm or less. Forming the first barrier layer 141b with a thickness of at least 8 nm or more in this way makes it possible to easily enhance the flatness of the first barrier layer 141b, which is formed after the growth of the lower guide layer 13. On the other hand, forming the first barrier layer 141b with a thickness of 50 nm or less makes it possible to inject carriers efficiently. It is preferable that the second barrier layer 142b be formed to have a thickness of 8 nm or more but 30 nm or less, and more preferably 10 nm or more but 20 nm or less. Forming the second barrier layer 142b with a thickness of at least 8 nm or more in this way makes it possible to easily enhance the flatness of the second barrier layer 142b, which is formed after the growth of the first well layer 141a. On the other hand, forming the second barrier layers 142b with a thickness of 30 nm or less makes it possible to inject carriers efficiently. It is preferable that the third barrier layer 143b be formed to have a thickness of 8 nm or more but 100 nm or less, and more preferably 10 nm or more but 80 nm or less. Forming the third barrier layer 143b with a thickness of at least 8 nm or more makes it possible to easily enhance the flatness of the third barrier layer 143b, which is formed after the growth of the second well layer 142a with a high In composition and before the growth of a carrier block layer 15, which will be described later. On the other hand, forming the third barrier layer 143b with a thickness of 100 nm or less makes it possible to inject carriers efficiently.

While two well layers are provided in Embodiment 1, in a case where more than two well layers are provided (for example, where three or four well layers are provided), the first barrier layer is defined to denote the first barrier layer formed under (on the substrate side of) the well layer nearest to the substrate. The second barrier layer is defined to be any barrier layer interposed between well layers. The third barrier layer is defined to be a barrier layer formed on the well layer (last well layer) farthest from the substrate. These definitions of the first, second, and third barrier layers make it possible to apply the above noted preferred thickness conditions even in cases where two or more well layers are formed. Fulfilling those conditions is preferable, because it is then possible to obtain the effects mentioned above.

The barrier layers may be formed of AlInGaN instead of AlGaN. A barrier layer containing Al and In offers the advantage of easy formation of a film with high flatness at low temperature. Moreover, in a case where two or more well layers are provided, when a GaN layer is not used as a barrier layer interposed between well layers (in Embodiment 1, the second barrier layer), the barrier layer may be given a two-layer structure such as AlGaN/AlInGaN, AlInGaN/AlGaN, or the like, or a multiple-layer structure such as AlInGaN/AlGaN/AlInGaN, AlInGaN/InGaN/AlInGaN, AlGaN/InGaN/AlGaN, or the like. In a case where one well layer is provided, it is preferable that the layer in contact with it from above (on the opposite side of it from the substrate, specifically the second barrier layer) be an AlInGaN layer. By forming the barrier layer in that way, it is possible to effectively suppress appearance of dark lines.

In Embodiment 1, the well layers 14a in the active layer 14 are so formed as to have an In composition ratio x1 of 0.15 or more but 0.45 or less (for example, 0.2 to 0.25). The barrier layers 14b in the active layer 14 are formed of AlGaN (Alₓ₂Ga₁₋ₓ₂N), and are formed to have an Al composition ratio x2 of, for example, 0<x2≦0.08. Giving the barrier layers 14b formed of AlGaN (Alₓ₂Ga₁₋ₓ₂N) an Al composition ratio x2 of 0.08 or less in this way makes it possible to achieve efficient light confinement. Moreover, forming the barrier layers 14b out of AlGaN, compared with forming them out of GaN or InGaN as conventionally practiced, makes it possible to enhance luminous efficacy. In particular, under the condition that the well layers 14a have an In composition ratio x1 of 0.15 or more but 0.45 or less, luminous efficacy tends to show a marked improvement.

The reason is considered to be as follows: when the well layers have a high In composition ratio, using a nitride semiconductor layer containing Al (for example, an AlGaN, AlInGaN, or like layer) in the barrier layers makes it possible to suppress the dark lines peculiarly observed with light-emitting chips using a nitride semiconductor substrate having the m plane as the principal growth plane, resulting in improved luminous efficacy.

Generally, a well layer is given, in its region with a high In composition ratio (x1≧0.15), a thickness of about 3 nm. In a case where a nitride semiconductor layer containing Al (for example, an AlGaN layer etc.) is formed as a barrier layer on a GaN substrate having an off angle in the a-axis direction relative to the m plane, however, the well layer may be given a thickness of 4.0 nm or more. The reason is considered to be that it is possible to obtain effects such as an effect of suppressing appearance of dark lines and an effect of protecting the active layer. Furthermore, the use of the above-described GaN substrate 10 enhances the flatness on the layer surface, and makes the In composition across the plane extremely uniform. Thus, even when the well layers are thick, they are less likely to suffer from formation of a local region with a high In composition. This too is considered to make it possible to form the well layers thick.

On the other hand, giving the well layers a thickness over 8 nm may cause a large number of misfit dislocations. Accordingly, it is preferable that the well layers be given a thickness of 8 nm or less. It is further preferable that their thickness be in a range of about 2.5 nm to 4.0 nm.

For similar reasons, in a case where the well layers are given a thickness in a range of about 1.5 nm to 4.0 nm, by forming the barrier layers out of a nitride semiconductor containing Al (for example, AlGaN etc.), it is possible to increase the number of well layers. For example, in a nitride semiconductor laser chip, in a case where a conventional active layer structure is adopted, forming three or more well layers greatly degrades luminous efficacy. On the other hand, when the barrier layers are formed of a nitride semiconductor containing Al, even in a case where five well layers are formed, degradation of luminous efficacy is suppressed. In a light-emitting diode chip (LED), when the barrier layers are formed of a nitride semiconductor containing Al, even in a case where eight well layers are formed, degradation of luminous efficacy is suppressed. Compared with semiconductor laser chips, light-emitting diode chips have thinner p-type semiconductor layers and incur less thermal damage to the active layer during formation of p-type semiconductor layers; for these reasons, it is easier to form the active layer (well layers) in multiple layers with light-emitting diode chips than with semiconductor laser chips.

A well layer in an active layer is formed to serve as a quantum well, and accordingly it may eventually have a varying thickness within a range of several nanometers or less or be localized into dots.

The reason that forming the barrier layers 14b out of a nitride semiconductor containing Al such as AlGaN, AlInGaN, etc. enhances luminous efficacy is considered to be as follows. With a nitride semiconductor substrate having as the principal growth plane a plane having an off angle in the a-axis direction relative to the m plane, as described above, forming on that principal growth plane a GaN layer with a thickness over 1 μm tends to degrade surface morphology. By contrast, forming a nitride semiconductor layer containing Al (for example, an AlGaN, AlInGaN, AlInN, or like layer) instead enhances surface morphology. Thus, a nitride semiconductor substrate having an off angle in the a-axis direction relative to the m plane may be said to be a non-polar substrate very suitable to form a nitride semiconductor layer containing Al (for example, an AlGaN, AlInGaN, AlInN, or like layer) with satisfactory flatness and crystallinity. Thus, forming the barrier layers in the active layer out of a nitride semiconductor containing Al (for example, an AlGaN, AlInGaN, AlInN, or like layer) enhances the flatness of the barrier layers, and then forming the well layers on the barrier layers with high flatness enhances the crystallinity of the well layers. This is considered to be the probable reason. By forming the barrier layers in that way, it is also possible to effectively suppress appearance of dark lines.

In a case where the barrier layers in the active layer are formed of a nitride semiconductor containing Al (for example, an AlGaN, AlInGaN, AlInN, or like layer), as described above, it is preferable that the well layers be formed of InGaN.

In Embodiment 1, as described above, the GaN layer formed between the principal growth plane 10a of the GaN substrate 10 and the active layer 14 (well layers 14a) is given a total thickness of 0.7 μm or less. Specifically, between the principal growth plane 10a of the GaN substrate 10 and the active layer 14 (well layers 14a), as described above, two GaN layers (the n-type GaN layer 11 and the lower guide layer 13) are formed, and their total thickness is about 0.2 μm (=about 0.1 μm+about 0.1 μm). It is more preferable that the total thickness of the GaN layer be 0.5 μm or less, and further preferably 0.3 μm or less. It is further preferable that the total thickness of the GaN layer formed between the substrate surface and a well layer, which is a nitride semiconductor layer containing In (in a case where a plurality of well layers are provided, preferably, the most substrate-side well layer) be 0.7 μm or less, more preferably 0.5 μm or less, and further preferably 0.3 μm or less.

In Embodiment 1, the semiconductor layer in contact with the principal growth plane 10a of the GaN substrate 10 is a GaN layer.

As shown in FIGS. 2 and 3, on the active layer 14, a carrier block layer 15 of p-type Al_{y}Ga_{1-y}N (0<y<1) with a thickness of 40 nm or less (for example, about 12 nm) is formed. The carrier block layer 15 is formed to have an Al composition ratio y of 0.08 or more but 0.35 or less (for example, about 0.15). On the carrier block layer 15, an upper guide layer 16 of p-type Al_{0.01}Ga_{0.99}N is formed which has an elevated portion and, elsewhere than there, a flat portion. The upper guide layer 16 is formed to have a lower Al composition ratio than a clad layer. On the elevated portion of the upper guide layer 16, an upper clad layer 17 of p-type Al_{0.06}Ga_{0.94}N with a thickness of about 0.5 μm is formed. On the upper clad layer 17, a contact layer 18 of p-type Al_{0.01}Ga_{0.99}N with a thickness of about 0.1 μm is formed. Together the contact layer 18, the upper clad layer 17, and the elevated portion of the upper guide layer 16 constitute a stripe-shaped (elongate) ridge portion 19 with a width of about 1 μm to 10 μm (for example, about 1.5 μm). As shown in FIG. 6, the ridge portion 19 is formed so as to extend in the Y direction (approximately the c-axis [0001] direction). The p-type semiconductor layers (the carrier block layer 15, the upper guide layer 16, the upper clad layer 17, and the contact layer 18) are doped with Mg as a p-type impurity.

Here, it is practicable to form the contact layer out of GaN, but forming it out of a nitride semiconductor layer containing Al (for example, AlGaN, AlInGaN, or AlInN) enhances surface morphology and improves the thickness distribution across the plane. It is therefore preferable that the contact layer be formed of a nitride semiconductor layer containing Al.

As shown in FIG. 5, the distance h between the carrier block layer 15 and the well layers 14a (the most carrier block layer 15 side one of the well layers 14a (142a)) is set to be about 60 nm. In Embodiment 1, the distance h is equal to the thickness of the third barrier layer 143b.

Setting the distance h between the carrier block layer 15 and the well layers 14a at 200 nm or more permits current to spread when carriers diffuse from the carrier block layer 15 to the active layer 14, and thus helps slightly suppress bright-spotted emission. On the other hand, by use of the above-described GaN substrate 10 having a principal growth plane 10a provided with an off-angle in the a-axis direction relative to the m plane, even when the distance h between the carrier block layer 15 and the well layers 14a is not set at 200 nm or more, it is possible to suppress bright-spotted emission effectively. For example, even when the distance h between the carrier block layer 15 and the well layers 14a is set at less than 120 nm, it is possible to suppress bright-spotted emission effectively. The smaller the distance h between the carrier block layer 15 and the well layers 14a, the more preferable, because that enhances the efficiency of carrier injection into the well layers 14a. Accordingly, by making the distance h between the carrier block layer 15 and the well layers 14a smaller than 120 nm, it is possible to enhance the efficiency of carrier injection into the well layers 14a.

Moreover, in the nitride semiconductor laser chip 100 according to Embodiment 1, as shown in FIGS. 2 and 3, on each side of the ridge portion 19, an insulating layer 20 for current constriction is formed. Specifically, on top of the upper guide layer 16, on the side faces of the upper clad layer 17, and on the side faces of the contact layer 18, an insulating layer 20 of SiO₂ with a thickness of about 0.1 μm to 0.3 μm (for example, about 0.15 μm) is formed.

On the top faces of the insulating layer 20 and of the contact layer 18, a p-side electrode 21 is formed so as to cover part of the contact layer 18. The p-side electrode 21, in its part covering the contact layer 18, makes direct contact with the contact layer 18. The p-side electrode 21 has a multiple-layer structure having the following layers stacked successively in order from the insulating layer 20 (the contact layer 18) side: a Pd layer (not shown) with a thickness of about 15 nm; a Pt layer (not shown) with a thickness of about 15 nm; and a Au layer (not shown) with a thickness of about 200 nm.

On the back face of the GaN substrate 10, an n-side electrode 22 is formed, which has a multiple-layer structure having the following layers stacked successively in order from the GaN substrate 10's back face side: a Hf layer (not shown) with a thickness of about 5 nm; and an Al layer (not shown) with a thickness of about 150 nm. On the n-side electrode 22, a metallized layer 23 is formed, which has a multiple-layer structure having the following layers stacked successively in order from the n-side electrode 22 side: a Mo layer (not shown) with a thickness of about 36 nm; a Pt layer (not shown) with a thickness of about 18 nm; and a Au layer (not shown) with a thickness of about 200 nm.

Furthermore, as shown in FIGS. 3 and 6, the nitride semiconductor laser chip 100 according to Embodiment 1 has a pair of resonator (cavity) faces 30, which include a light emission face 30a through which laser light is emitted and a light reflection face 30b opposite from the light emission face 30a. On the light emission face 30a, an emission-side coating (not shown) with a reflectance of, for example, 5% to 80% is formed. On the other hand, on the light reflection face 30b, a reflection-side coating (not shown) with a reflectance of, for example, 95% is formed. The reflectance of the emission-side coating is adjusted to be a desired value according to the laser output. The emission-side coating is composed of, in order from the semiconductor's emission facet side, for example, a film of aluminum oxynitride (oxide-nitride) or aluminum nitride AlOₓN₁₋ₓ (where 0≦x≦1) with a thickness of 30 nm, and a film of Al₂O₃ with a thickness of 215 nm. The reflection-side coating is composed of multiple-layered films of, for example, SiO₂, TiO₂, etc. Other than the materials just mentioned, films of dielectric materials such as SiN, ZrO₂, Ta₂O₅, MgF₂, etc. may be used. The coating on the light emission face side may instead be composed of a film of AlOₓN₁₋ₓ (where 0≦x≦1) with a thickness of 12 nm, and a film of silicon nitride SiN with a thickness of 100 nm.

By forming a film of aluminum oxynitride or aluminum nitride AlOₓN₁₋ₓ (where 0≦x≦1) on a cleaved facet (in Embodiment 1, the c plane), or an etched facet etched by vapor-phase etching or liquid-phase etching, of an m-plane nitride semiconductor substrate as described above, it is possible to greatly reduce the rate of non-radiative recombination at the interface between the semiconductor and the emission-side coating, and thereby to greatly improve the COD (catastrophic optical damage) level. More preferably, the film of aluminum oxynitride or aluminum nitride AlOₓN₁, (where 0≦x≦1) has a crystal of the same hexagonal crystal system as the nitride semiconductor; further preferably, it is crystallized with its crystal axes aligned with those of the nitride semiconductor, because that further reduces the rate of non-radiative recombination and further improves the COD level. To increase the reflectance on the light emission face side, there may be formed, on the above-mentioned coating, stacked films having films of silicon oxide, aluminum oxide, titanium oxide, tantalum oxide, zirconium oxide, silicon oxide, etc. stacked together.

As shown in FIG. 6, the nitride semiconductor laser chip 100 according to Embodiment 1 has a length L (chip length L (resonator length L)) of about 300 μm to 1800 μm (for example, about 600 μm) in the direction (the Y direction (approximately the c-axis direction)) perpendicular to the resonator faces 30, and has a width W (chip width W) of about 150 μm to 600 μm (for example, about 400 μm) in the direction (the X direction (approximately the a-axis [11-20] direction)) along the resonator faces 30.

In Embodiment 1, as described above, a plane having an off-angle in the a-axis direction relative to the m plane is taken as the principal growth plane 10a of the GaN substrate 10, and this makes it possible to suppress a bright-spotted EL emission pattern and variations in wavelength across the plane. That is, with that configuration, it is possible to improve the EL emission pattern. This makes it possible to enhance the luminous efficacy of the nitride semiconductor laser chip. By enhancing luminous efficacy, it is possible to obtain a high-luminance nitride semiconductor laser chip. One reason that an effect of suppressing bright-spotted emission as described above is obtained is considered to be as follows: as a result of the principal growth plane 10a of the GaN substrate 10 having an off-angle in the a-axis direction relative to the m plane, when the active layer 14 (the well layers 14a) is grown on the principal growth plane 10a, the direction of migration of In atoms changes so that, even under conditions with a high In composition ratio (with a large supply of In), agglomeration of In is suppressed. Another reason is considered to be that the growth mode of the p-type semiconductor layers formed on the active layer 14 also changes so as to enhance the activation rate of Mg as a p-type impurity and reduce the resistance of the p-type semiconductor layers. Reducing the resistance of the p-type semiconductor layers makes uniform injection of current easier, and thus makes the EL emission pattern uniform.

In Embodiment 1, by suppressing a bright-spotted EL emission pattern, it is possible to make the EL emission pattern uniform, and thus it is possible to reduce the driving voltage. By suppressing bright-spotted emission, it is possible to obtain an EL emission pattern of uniform light emission, and thus it is possible to increase gain in the formation of the nitride semiconductor laser chip.

In Embodiment 1, by using a nitride semiconductor layer containing Al as the barrier layers 14b, it is possible to almost completely suppress appearance of dark lines. This makes it possible to suppress a lowering in luminous efficacy.

In Embodiment 1, by forming the barrier layers 14b out of a nitride semiconductor containing Al, it is possible to enhance the flatness of the barrier layers 14b. Thus, by forming the well layers 14a on the barrier layers 14b with high flatness, it is possible to suppress a non-uniform distribution of In composition across the plane in the well layers 14a. In addition, it is also possible to enhance the crystallinity of the active layer 14. This makes it possible to further enhance luminous efficacy.

By forming the barrier layer 14b formed under (on the GaN substrate 10 side of) the well layer 14a out of a nitride semiconductor layer containing Al (for example, Alₓ₂Ga₁₋ₓ₂N), and giving it an Al composition ratio x2 of 0<x2≦0.08, it is possible to obtain, in addition to an effect of suppressing appearance of dark lines and an effect of protecting the active layer 14, an effect of enhancing the flatness of the barrier layers 14b. This makes it possible to enhance the luminous efficacy of the well layers 14a, and thus it is possible to obtain a semiconductor laser chip with superb device characteristics and high reliability.

As described above, in Embodiment 1, with the configuration described above, it is possible to greatly enhance luminous efficacy. Moreover, by enhancing the luminous efficacy, it is possible to enhance device characteristics and reliability, and thus it is possible to obtain a nitride semiconductor laser chip 100 with superb device characteristics and high reliability.

In Embodiment 1, on the GaN substrate 10 having as the principal growth plane 10a a plane having an off angle in the a-axis direction relative to the m plane, the GaN layer formed between the principal growth plane 10a and the active layer 14 (well layers 14a) is formed to have a total thickness of 0.7 μm or less (0.2 μm), and this makes it possible to greatly improve surface morphology and obtain good surface morphology. This makes it possible to give the GaN layer (the n-type GaN layer 11 and the lower guide layer 13) a uniform thickness distribution across the plane, and also to give the semiconductor layer formed further on the GaN layer a uniform thickness distribution across the plane. That is, it is possible to give the individual nitride semiconductor layers formed on the GaN substrate 10 a uniform thickness distribution across the plane. Moreover, by improving surface morphology, it is possible to reduce variations in device characteristics (for example, I-L response, I-V response, far-field pattern, wavelength, etc.), and thus to increase manufacturing yields. This makes it possible to easily obtain chips having characteristics within the rated ranges. Moreover, by enhancing surface morphology, it is possible to further enhance device characteristics and reliability.

In Embodiment 1, by making the absolute value of the off angle in the a-axis direction larger than 0.1 degrees, it is possible to suppress a bright-spotted EL emission pattern easily.

In a case where the principal growth plane 10a of the GaN substrate 10 has an off-angle also in the c-axis direction relative to the m plane, by making the off-angle in the a-axis direction larger than the off-angle in the c-axis direction, it is possible to effectively suppress a bright-spotted EL emission pattern. That is, with that configuration, it is possible to suppress the inconvenience of the effect of suppressing bright-spotted emission being diminished due to too large an off-angle in the c-axis direction. This makes it possible to enhance luminous efficacy easily.

In Embodiment 1, giving the active layer 14 of the nitride semiconductor laser chip 100a DQW structure makes it possible to reduce the driving voltage easily. This too helps enhance device characteristics and reliability. Also when the active layer 14 is given a DQW structure, it is possible to suppress a bright-spotted EL emission pattern.

In Embodiment 1, by giving the carrier block layer 15 formed of p-type Al_{y}Ga_{1-y}N an Al composition ratio y of 0.08 or more but 0.35 or less, it is possible to form an energy barrier sufficiently high with respect to carriers (electrons), and thus it is possible to more effectively prevent the carriers injected into the active layer 14 from flowing into the p-type semiconductor layers. This makes it possible to suppress a bright-spotted EL emission pattern effectively. By giving the carrier block layer 15 an Al composition ratio y of 0.35 or less, it is possible to suppress an increase in the resistance of the carrier block layer 15 due to the Al composition ratio y being too high. In a region with a high In composition ratio x1 (x1≧0.15) in the well layers 14a, an Al composition ratio y of 0.08 or more in the carrier block layer 15 formed on the active layer 14 makes it extremely difficult to grow the carrier block layer 15 satisfactorily. This is because, as the In concentration in the well layers 14a increases, the flatness of the surface of the active layer 14 deteriorates, and this makes it difficult to form a film with a high Al composition ratio y with good crystallinity. However, by use of the GaN substrate 10 having as the principal growth plane 10a a plane having an off-angle in the a-axis direction relative to the m plane, even in a case where the In composition ratio x1 in the active layer 14 (the well layers 14a) is 0.15 or more but 0.45 or less, it is possible to form on that active layer 14a carrier block layer 15 with an Al composition ratio y of 0.08 or more but 0.35 or less with good crystallinity. This makes it possible to suppress a bright-spotted EL emission pattern effectively and make the EL emission pattern even.

It is more preferable that the barrier layer (for example, in Embodiment 1, the third barrier layer) between the carrier block layer 15 and the well layers 14a be a nitride semiconductor layer containing Al and In. The carrier block layer is formed with a higher Al composition ratio than the barrier layer, and thus stress from the carrier block layer acts on the well layer. Thus, by forming the barrier layer between the carrier block layer 15 and the well layers 14a to contain In, it is possible to alleviate stress. Moreover, the barrier layer between the carrier block layer 15 and the well layers 14a may be so formed as to partly contain AlInGaN. Furthermore, the barrier layer between the carrier block layer 15 and the well layers 14a may be given a two-layer structure such as AlGaN/AlInGaN, AlInGaN/AlGaN, or AlInGaN/InGaN, or a multiple-layer structure such as AlInGaN/AlGaN/AlInGaN, AlInGaN/InGaN/AlInGaN, AlGaN/InGaN/AlGaN, or the like. From the viewpoint of the above-mentioned alleviation of stress, the barrier layer between the carrier block layer 15 and the well layers 14a may be InGaN. Forming the barrier layer in that way helps effectively suppress appearance of dark lines.

By use of the above-described GaN substrate 10 having a principal growth plane 10a provided with an off-angle in the a-axis direction relative to the m plane, even in a case where the In composition ratio x1 in the well layers 14a is 0.15 or more, that is, even under conditions where a bright-spotted EL emission pattern is prominent, it is possible to effectively suppress a bright-spotted EL emission pattern. Thus, by giving the well layers 14a in the active layer 14 an In composition ratio x1 of 0.15 or more, it is possible to obtain a prominent effect of suppressing bright-spotted emission. On the other hand, by giving the well layers 14a an In composition ratio x1 of 0.45 or less, it is possible to suppress the inconvenience of a large number of dislocations developing in the active layer 14 as a result of strain such as lattice mismatch due to the In composition ratio x1 in the well layers 14a being more than 0.45.

By using AlInGaN in the barrier layers 14b, as by using AlGaN in the barrier layers 14b, it is possible to enhance luminous efficacy. In addition, from the viewpoint of semiconductor laser chips, it is possible to obtain the advantage of enhanced light confinement. Moreover, by forming the well layers 14a on the barrier layers 14b formed of AlInGaN, it is possible to greatly enhance the efficiency with which In is absorbed into the well layers 14a. Thus, even with a low gas flow rate of In, it is possible to maintain a high In composition ratio. This makes it possible to enhance In absorption efficiency. Consequently, it is possible to achieve lengthening of the emission wavelength more effectively. It is also possible to reduce the consumption of source material gas (for example TMI), which is advantageous in terms of cost.

In a case where AlInGaN (AlₛInₜGaᵤN (s+t+u=1)) is used for the barrier layers 14b, it is preferable that the Al composition ratio s be set within a range of 0<s≦0.08. In that case, it is preferable that the In composition ratio t be set within a range of 0<t≦0.10, and more preferably 0<t≦0.03. By setting those composition ratios in those ranges, it is possible to form the AlInGaN barrier layers flatter. By forming the well layers 14a on these flat barrier layers, even when the well layers 14a are formed of Inₓ₁Ga₁₋ₓ₁N with a high In composition ratio x1 (for example, with x1 being 0.15 or more but 0.45 or less), it is possible to suppress, more effectively, appearance of dark lines as shown in FIGS. 73 and 74. The preferred thickness of the barrier layers 14b when formed of AlInGaN is similar to their preferred thickness when they are formed of AlGaN.

Here, the effect of suppressing appearance of dark lines, which is obtained by forming a barrier layer out of a nitride semiconductor layer containing Al, is an utterly different one from the effect of suppressing bright-spotted emission, which is obtained by use of a nitride semiconductor substrate having as the principal growth plane a plane having an off angle in the a-axis direction relative to the m plane. Specifically, using a nitride semiconductor layer containing Al as a barrier layer is effective with a non-polar plane such as the m plane; on the other hand, even in a case where a barrier layer of InGaN is used, by providing an off angle in the a-axis direction, it is possible to suppress a bright-spotted EL emission pattern.

However, forming a nitride semiconductor layer containing Al on a nitride semiconductor substrate having an off angle in the a-axis direction offers an effect of enhancing crystallinity etc., and thus using a nitride semiconductor substrate having an off angle in the a-axis direction and in addition using a nitride semiconductor layer containing Al as a barrier layer enhances the crystallinity of the barrier layer. Combining the two designs in this way is thus more preferable, because doing so brings about an effect of synergy. Needless to say, using a nitride semiconductor substrate having an off angle in the a-axis direction and in addition using a nitride semiconductor layer containing Al as a barrier layer makes it possible to suppress appearance of dark lines and in addition to suppress bright-spotted emission.

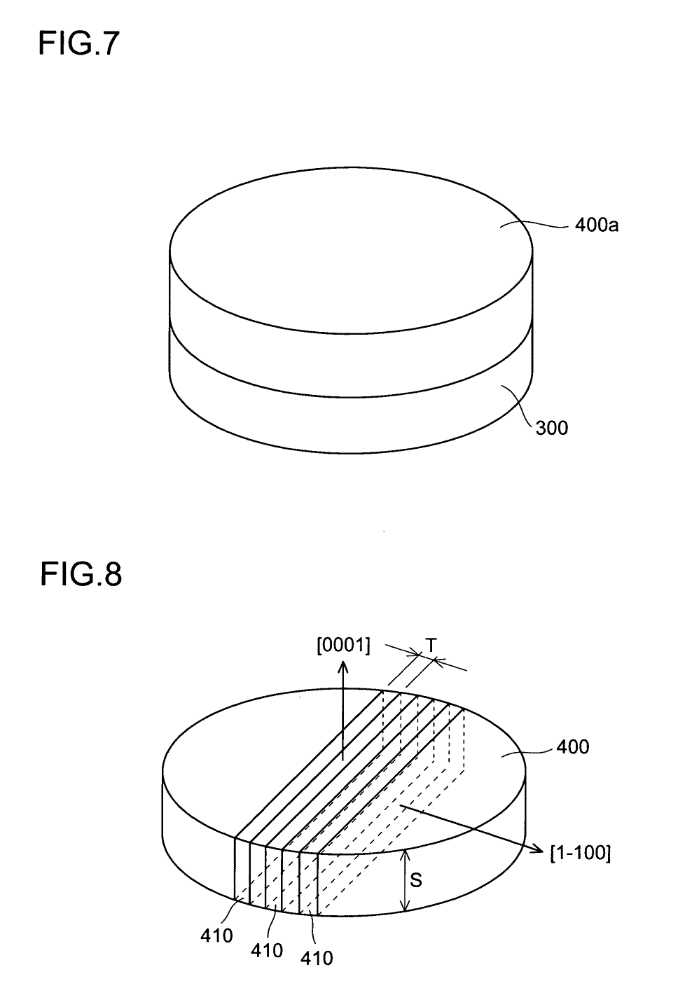

FIGS. 7 to 19 are diagrams illustrating a method of manufacture of a nitride semiconductor laser chip according to Embodiment 1 of the invention. Next, with reference to FIGS. 2, 3, and 5 to 19, a method of manufacture of the nitride semiconductor laser chip 100 according to Embodiment 1 of the invention will be described.

First, a GaN substrate 10 having as a principal growth plane 10a a plane having an off-angle relative to the m plane is prepared. This GaN substrate 10 is fabricated by, for example, using as a seed substrate a substrate cut out of a GaN bulk crystal having the c plane (0001) as a principal plane and growing a GaN crystal on that seed substrate. Specifically, as shown in FIG. 7, a protective film (not shown) of SiO₂ is formed on part of a base substrate 300, and then on the base substrate 300, over the protective film, a GaN bulk crystal is grown by an epitaxial growth process such as an MOCVD (metal organic chemical vapor deposition) process. This causes growth to start in the part where the protective film is not formed, and over the protective film, the GaN crystal grows laterally. The parts of the GaN crystal grown laterally meet over the protective film and continue to grow, and thus a GaN crystal layer 400a is formed on the base substrate 300. The GaN crystal layer 400a is formed sufficiently thick so that it may be handled independently even after removal of the base substrate 300. Next, from the GaN crystal layer 400a thus formed, the base substrate 300 is removed, for example, by etching. This leaves, as shown in FIG. 8, a GaN bulk crystal 400 having the c plane (0001) as a principal plane. As the base substrate 300, it is possible to use, for example, a GaAs substrate, a sapphire substrate, a ZnO substrate, a SiC substrate, a GaN substrate, etc. The GaN bulk crystal 400 is given a thickness S of, for example, about 3 mm.

Next, both principal planes, that is, the (0001) and (000-1) planes, of the GaN bulk crystal 400 thus obtained are ground and polished so as to each have an average roughness Ra of 5 nm. The average roughness Ra here conforms to the arithmetic average roughness Ra defined in JIS B 0601, and can be measured on an AFM (atomic force microscope).

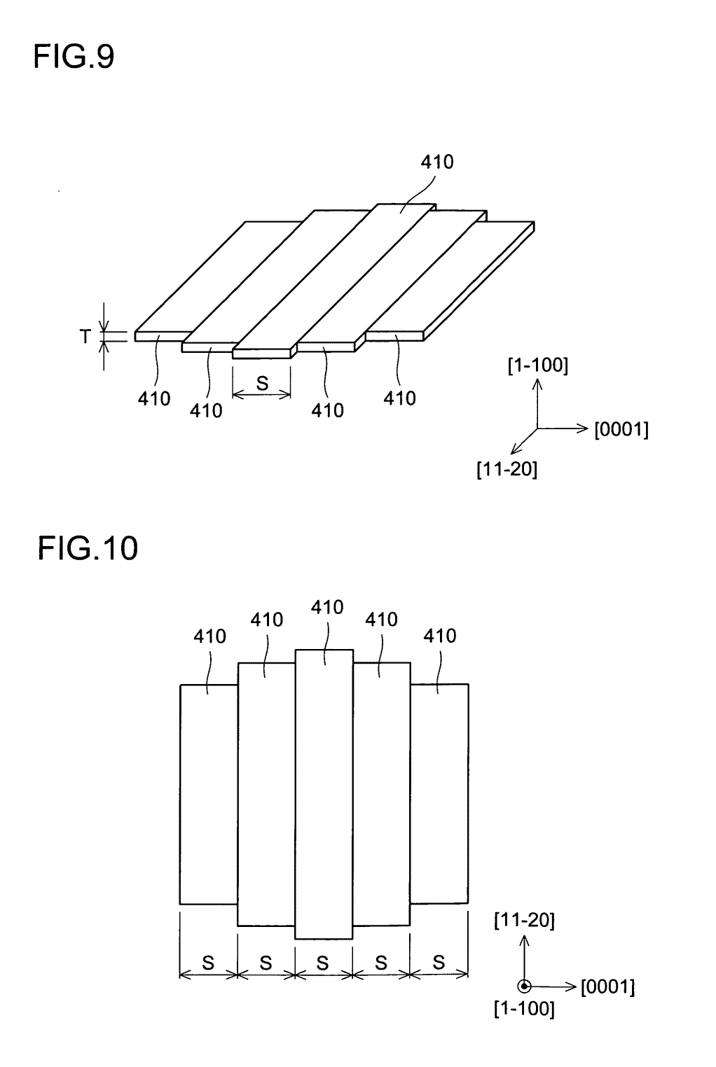

Next, the GaN bulk crystal 400 is sliced at a plurality of planes perpendicular to the [1-100] direction so that a plurality of GaN crystal substrates 410 having the m plane {1-100} as a principal plane are cut out each with a thickness T (for example, 1 mm) (and with a width S of 3 mm). Then, with each of the GaN crystal substrates 410 thus cut out, the four faces that have not yet been ground or polished are ground and polished so as to have an average roughness Ra of 5 nm. Thereafter, as shown in FIGS. 9 and 10, the plurality of GaN crystal substrates 410 are arranged side by side in such a way that their respective principal planes are parallel to one another and that their respective [0001] directions are aligned with one another.

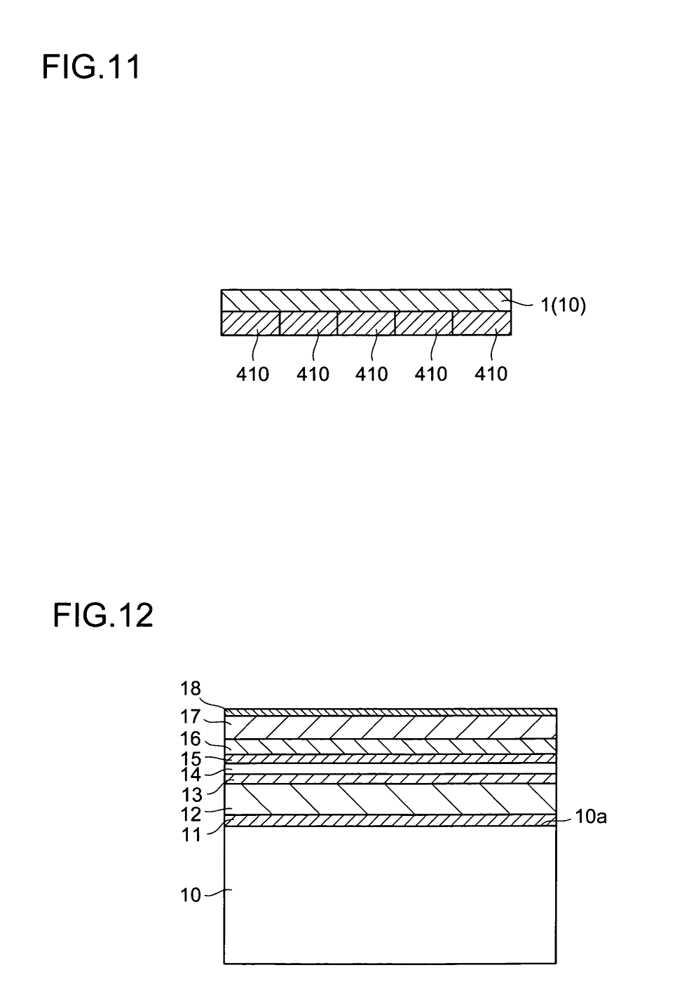

Subsequently, as shown in FIG. 11, the plurality of GaN crystal substrates 410 thus arranged side by side are taken as a seed substrate, and on the m plane {1-100} of those GaN crystal substrates 410, a GaN crystal is grown by an epitaxial growth process such as an HVPE (hydride vapor phase epitaxy) process. In this way, a GaN substrate 1 having the m plane as a principal growth plane is obtained. Next, the principal plane of the GaN substrate 1 thus obtained is polished by chemical and mechanical polishing so as to control the off-angles in the a- and c-axis directions independently, thereby to set the off-angles in the a- and c-axis directions relative to the m plane at desired off-angles. These off-angles can be measured by an X-ray diffraction method. In this way, a GaN substrate 10 having as the principal growth plane a plane having off-angles in both the a- and c-axis directions relative to the m plane is obtained.

In the above-described fabrication of the GaN substrate 10, in a case where a substrate with a large off-angle is fabricated, when a plurality of GaN crystal substrates 410 are cut out of the GaN bulk crystal 400, they may be cut out at a predetermined cut-out angle relative to the [1-100] direction so that the principal plane of the GaN crystal substrates 410 has a desired off-angle relative to the m plane {1-100}. Doing so permits the principal plane of the GaN crystal substrates 410 to have a desired off-angle relative to the m plane {1-100}, and accordingly the principal plane (principal growth plane) of the GaN substrate 1 (10) formed on that principal plane comes to have the desired off-angle relative to the m plane {1-100}.

Polishing the principal plane of the GaN crystal substrates 410 cut out of the GaN bulk crystal 400 (see FIG. 8) by chemical and mechanical polishing makes it possible to use the GaN crystal substrates 410 as the GaN substrate 10. In that case, the GaN crystal substrates 410 may be given a width S of 3 mm or more.

Here, in Embodiment 1, the off-angle in the a-axis direction in the above-described GaN substrate 10 is adjusted to be larger than 0.1 degrees. In a case where an off-angle is provided also in the c-axis direction, it is preferable that the off-angle in the c-axis direction be adjusted to be larger than ±0.1 degrees. Moreover, it is preferable that the off-angle in the c-axis direction be adjusted to be smaller than the off-angle in the a-axis direction.

Subsequently, as shown in FIG. 12, on the principal growth plane 10a of the GaN substrate 10 obtained, individual nitride semiconductor layers are grown by an MOCVD process. At this time, the individual nitride semiconductor layers are grown in such a way that the total thickness of the GaN layer formed between the GaN substrate 10 and the active layer 14 (well layers 14a) is 0.7 μm or less.

Specifically, on the principal growth plane 10a of the GaN substrate 10, the following layers are grown successively: an n-type GaN layer 11 with a thickness of about 0.1 μm; a lower clad layer 12 of n-type Al_{0.06}Ga_{0.94}N with a thickness of about 2.2 μm; a lower guide layer 13 of n-type GaN with a thickness of about 0.1 μm; and an active layer 14. When the active layer 14 is grown, as shown in FIG. 5, two well layers 14a of Inₓ₁Ga₁₋ₓ₁N and three barrier layers 14b of Alₓ₂Ga₁₋ₓ₂N are alternately grown. Specifically, on the lower guide layer 13, the following layers are grown successively from bottom up: a first barrier layer 141b with a thickness of about 30 μm; a first well layer 141a with a thickness of about 1.5 nm to 4 nm; a second barrier layer 142b with a thickness of about 16 nm; a second well layer 142a with a thickness of about 1.5 nm to 4 nm; and a third barrier layer 143b with a thickness of about 60 nm. In this way, on the lower guide layer 13, an active layer 14 having a DQW structure composed of two well layers 14a and three barrier layers 14b is formed. At this time, the well layers 14a are so formed that the In composition ratio x1 there is 0.15 or more but 0.45 or less (for example, 0.2 to 0.25). On the other hand, the barrier layers 14b are so formed that the Al composition ratio x2 there is, for example, in a range of 0<x2≦0.08.

Next, as shown in FIG. 12, on the active layer 14, the following layers are grown successively: a carrier block layer 15 of p-type Al_{y}Ga_{1-y}N; an upper guide layer 16 of p-type Al_{0.01}Ga_{0.99}N with a thickness of about 0.05 μm; an upper clad layer 17 of p-type Al_{0.06}Ga_{0.94}N with a thickness of about 0.5 μm; and a contact layer 18 of p-type Al_{0.01}Ga_{0.99}N with a thickness of about 0.1 μm. At this time, it is preferable that the carrier block layer 15 be formed so as to have a thickness of 40 nm or less (for example, about 12 nm). Moreover, the carrier block layer 15 is so formed that the Al composition ratio y there is 0.08 or more but 0.35 or less (for example, about 0.15). The n-type semiconductor layers (the n-type GaN layer 11, the lower clad layer 12, and the lower guide layer 13) are doped with, for example, Si as an n-type impurity, and the p-type semiconductor layers (the carrier block layer 15, the upper guide layer 16, the upper clad layer 17, and the contact layer 18) are doped with, for example, Mg as a p-type impurity.

In Embodiment 1, the n-type semiconductor layers are formed at a growth temperature of 900° C. or higher but lower than 1300° C. (for example, 1075° C.). The well layers 14a in the active layer 14 are formed at a growth temperature of 600° C. or higher but 800° C. or lower (for example, 700° C.). The barrier layers 14b, which are contiguous with the well layers 14a, are formed at the same growth temperature (for example, 700° C.) as the well layers 14a. The p-type semiconductor layers are formed at a growth temperature of 700° C. or higher but lower than 900° C. (for example, 880° C.). The growth temperature of the n-type semiconductor layers is preferably 900° C. or higher but lower than 1300° C., and more preferably 1000° C. or higher but lower than 1300° C. The growth temperature of the well layers 14a in the active layer 14 is preferably 600° C. or higher but 830° C. or lower, and in a case where the In composition ratio x1 in the well layers 14a is 0.15 or more, preferably 600° C. or higher but 770° C. or lower; more preferably, 630° C. or higher but 740° C. or lower. The growth temperature of the barrier layers 14b in the active layer 14 is preferably the same as or higher than that of the well layers 14a. The growth temperature of the p-type semiconductor layers is preferably 700° C. or higher but lower than 900° C., and more preferably 700° C. or higher but 880° C. or lower. Needless to say, since even forming the p-type semiconductor layers at a temperature of 900° C. or higher gives p-type conductivity, the p-type semiconductor layers may be formed at a temperature of 900° C. or higher.

In a case where the well layers have a high In composition ratio, if a semiconductor layer is formed at higher temperature than the growth temperature of the well layers after their growth, the well layers suffer thermal damage, producing non-radiative black spots. These black spots are considered to result from agglomeration of In atoms. Accordingly, suppressing agglomeration of In atoms leads to protection of the active layer from thermal damage. In a light-emitting chip (for example, a semiconductor laser chip) in which p-type semiconductor layers need to be stacked at a growth temperature higher than that for the well layers after the growth of these, the active layer needs to be heat-resistant. According to the studies thus far conducted by the inventors, when an m-plane substrate is used, p-type semiconductor layers exhibiting p-type conductivity (for example, p-type AlGaN, p-type GaN, and like layers) can be formed at lower temperature than when a c-plane substrate is used as conventionally practiced. In the light of these findings, while it is possible to use GaN or InGaN in barrier layers, by using a nitride semiconductor layer containing Al (for example, an AlGaN, AlInGaN, or like layer) in barrier layers, it is possible to more effectively suppress the influence of heat, and also to suppress appearance of dark lines. Thus, by forming the barrier layers out of a nitride semiconductor layer containing Al as described above, it is possible to further enhance luminous efficacy. Also, a nitride semiconductor substrate having an off angle in the a-axis direction relative to the m plane offers an effect of enhancing flatness, which effect is peculiar to an a-axis off substrate. Consequently, using such a nitride semiconductor substrate (an m-plane a-axis off substrate) and forming on its principal growth plane a barrier layer formed of a nitride semiconductor containing Al further enhances luminous efficacy.

As source materials for the growth of these nitride semiconductors, the following materials can be used. Group-III source material gasses that can be used include, for example, trimethylgallium ((CH₃)₃Ga; TMG), trimethylaluminium ((CH₃)₃Al; TMA), and trimethylindium ((CH₃)₃In; TMI). Group-V source material gasses that can be used include, for example, ammonia gas (NH₃). As for dopants, as an n-type dopant (n-type impurity), for example, monosilane (SiH₄) can be used; as a p-type dopant (p-type impurity), for example, cyclopentadienylmagnesium (CP₂Mg) can be used.

In a case where the well layers are grown at a low growth temperature of 600° C. or higher but 770° C. or lower (in particular where they are grown at a low growth temperature of 650° C. or higher but 740° C. or lower), it is preferable that the growth rate of the well layers be 0.05 Å/s (angstrom per second) or higher but 0.7 Å/s or lower, and more preferably 0.05 Å/s or higher but 0.2 Å/s or lower. Setting the growth rate of the well layers low in this way suppresses migration of atoms; on the other hand, reducing the growth rate in that way alleviates suppression of migration, and secures adequate movement of atoms. This improves crystallinity and enhances luminous efficacy. With the growth rate of the well layers lower than 0.05 Å/s, however, the number of atoms leaving the crystal surface is greater than the number of atoms supplied to the crystal surface. As a result, due to an etching effect, the crystal surface tends to become rough, likely resulting in poor flatness. For this reason, it is preferable that the growth rate of the well layers be 0.05 Å/s or higher as mentioned above. Needless to say, the well layers may be grown by any method (under any conditions) other than specifically described above; however, forming them as described above helps further enhance luminous efficacy.

In a case where the growth temperature of the well layers is 600° C. or higher but 720° C. or lower, hydrogen (H₂) may be introduced as a carrier gas during their growth.

In a case where hydrogen is introduced as a carrier gas, it is preferable that its gas flow rate be 0.005 L/min (liters per minute) or higher but 0.100 L/min or lower, and more preferably 0.010 L/min or higher but 0.050 L/min or lower. A gas flow rate lower than 0.005 L/min makes it difficult to obtain the effect of introducing hydrogen during growth of the well layers. On the other hand, introducing hydrogen as a carrier gas at a gas flow rate higher than 0.100 L/min tends to reduce absorption of In atoms even when the growth temperature of the well layers is 600° C. or higher but 720° C. or lower, and makes it difficult to achieve a lengthening in emission wavelength.

Introducing hydrogen during growth of the well layers as described above makes clear the satellite peak in an X-ray diffraction image; it also brings about improvements as by enhancing the emission pattern at the time of current injection, and may thus help enhance luminous efficacy. Si or Mg may be added to any or all of the well layers. The well layers may be formed, instead of InGaN, AlInGaN. In that case, the well layers are formed by a similar method as when formed of InGaN.

The well layers and the barrier layers may be formed continuously without any intermission in growth, or may be formed with an intermission interspersed in growth.

When the barrier layers are formed, the carrier gas may be nitrogen alone, but it is preferable that hydrogen be mixed. In a case where hydrogen is used as a carrier gas, it is preferable that the flow rate of hydrogen be lower than 1.0 L/min, and more preferably 0.500 L/min or lower. While the fact that the flow rate of hydrogen is 0 L/min means that the carrier gas is nitrogen alone, introducing hydrogen at a flow rate as just mentioned improves interface steepness. This makes the satellite peak in an X-ray diffraction image clear. It should be noted that, with the flow rate of hydrogen being 1.0 L/min or higher, due to an etching effect, the crystal surface tends to become rough, likely resulting in poor flatness; also, absorption of In atoms is diminished in a case where the barrier layers are formed of a nitride semiconductor containing In.

It is preferable that the barrier layers be formed at a growth rate of 0.05 Å/s or higher but 1.2 Å/s or lower, and more preferably 0.05 Å/s or higher but 0.8 Å/s or lower. With the growth rate of the barrier layers lower than 0.05 Å/s, the number of atoms leaving the crystal surface is greater than the number of atoms supplied to the crystal surface. As a result, due to an etching effect, the crystal surface tends to become rough, possibly resulting in poor flatness. On the other hand, with a growth rate higher than 1.2 Å/s, crystallinity and flatness may degrade. For these reasons, it is preferable that the growth rate of the barrier layers be in the range just mentioned. Needless to say, the barrier layers may be grown by any method (under any conditions) other than specifically described above; however, forming them as described above helps further enhance luminous efficacy.

While the tendencies mentioned above apply equally in cases where the barrier layers are formed of GaN, InGaN, or AlGaN, their effects are more notable in cases where the barrier layers are formed of a nitride semiconductor containing Al, the most preferable being cases where the barrier layers are formed of an AlGaN or AlInGaN layer.

In a case where the barrier layers are formed of AlInGaN, one method of forming it involves supplying, as a group-III source material gas, TMG, TMI, and TMA all at the same time and, as a group-V source material gas, ammonia gas also at the same time.

According to another method, when the barrier layers are formed, as a group-III source material gas, TMG and TMA are supplied at the same time, with no supply of TMI (that is, first, an AlGaN layer is formed as a barrier layer) and then, by use of TMI gas remnant from growth of a well layer and by exploiting diffusion and segregation of In, In is absorbed automatically to form an AlInGaN barrier layer. Specifically, the growth temperature of the well layers is set at 700° C., and TMG, TMI, and ammonia gas are supplied in such a vapor-phase ratio as to achieve the desired wavelength. Thereafter, the supply of TMG and TMI is stopped, followed by an intermission in growth for several seconds, and then, with the growth temperature kept at 700° C., TMG, TMA and ammonia gas are supplied to form a barrier layer. In an analysis in which barrier layers formed by this method were subjected to measurement of their composition rate by AES (Auger electron spectroscopy, or Auger analysis), the Al composition ratio was detected to be 1.0%, and the In composition ratio 2.0%. That is, with the method just described, In was absorbed automatically. Thus, by a method like this, a barrier layer formed of AlInGaN may be formed. A similar effect can be obtained by simply switching the source materials without providing an intermission in growth. In a case where this method is used, to control absorption of In atoms, the barrier layers are formed at a growth temperature 30° C. or more higher than the growth temperature of the well layers (for example, when the growth temperature of the well layers is 700° C., the growth temperature of the barrier layers is 730° C.); this permits In to evaporate, and makes it possible to form an AlGaN film. Also, increasing the flow rate of the hydrogen carrier gas introduced during formation of the barrier layers helps suppress absorption of In, and makes it possible to form an AlGaN film. In either case, no In atoms were detected from the barrier layers by AES measurement.

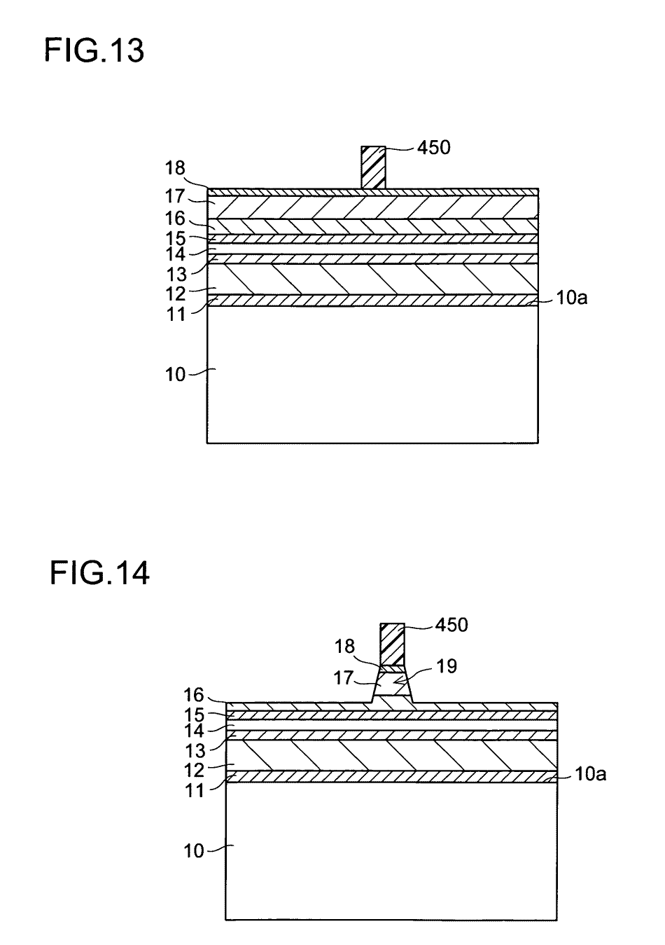

Subsequently, as shown in FIG. 13, by use of a photolithography technology, on the contact layer 18, a stripe-shaped (elongate) resist layer 450 is formed that has a width of about 1 μm to 10 μm (for example, about 1.5 μm) and that extends parallel to the Y direction (approximately the c-axis [0001] direction). Then, as shown in FIG. 14, by a RIE (reactive ion etching) process using chlorine-based gas such as SiCl₄ or Cl₂ or Ar gas, and with the resist layer 450 used as a mask, etching is performed halfway into the depth of (meaning, so as to leave a small part of, and thus not to completely penetrate) the upper guide layer 16. In this way, a stripe-shaped (elongate) ridge portion 19 (see FIGS. 3 and 6) is formed which is constituted by an elevated portion of the upper guide layer 16, the upper clad layer 17, and the contact layer 18 and which extends parallel to the Y direction (approximately the c-axis direction), with each ridge portion 19 parallel to another.

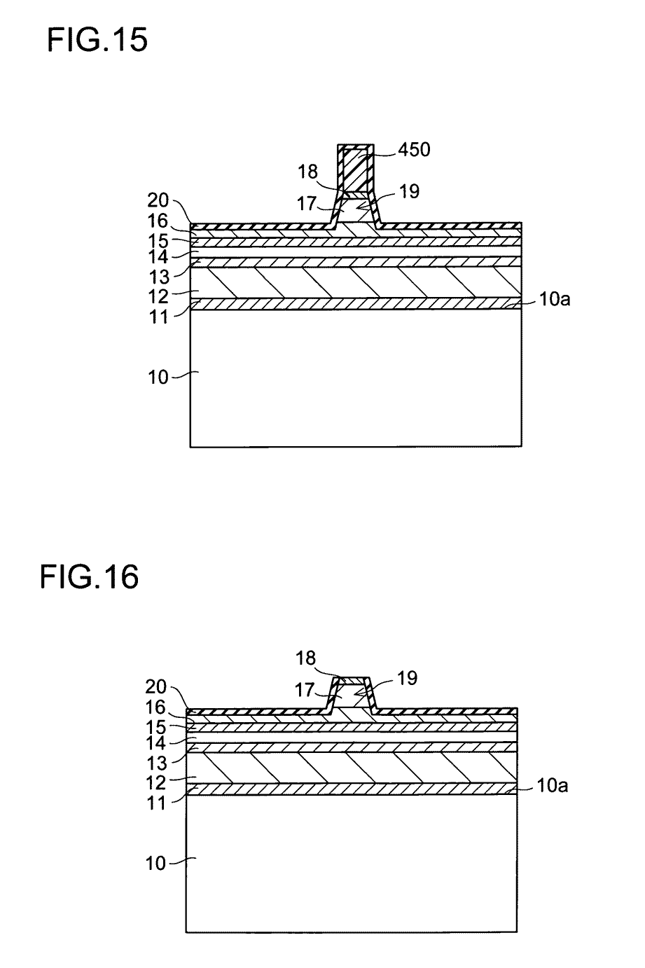

Next, as shown in FIG. 15, with the resist layer 450 left on the ridge portion 19, by a sputtering process or the like, an insulating layer 20 of SiO₂ with a thickness of about 0.1 μm to 0.3 μm (for example, about 0.15 μm) is formed to bury the ridge portion 19. Then, the resist layer 450 is removed by lift-off so that the contact layer 18 at the top of the ridge portion 19 is exposed. In this way, on each side of the ridge portion 19, an insulating layer 20 as shown in FIG. 16 is formed.

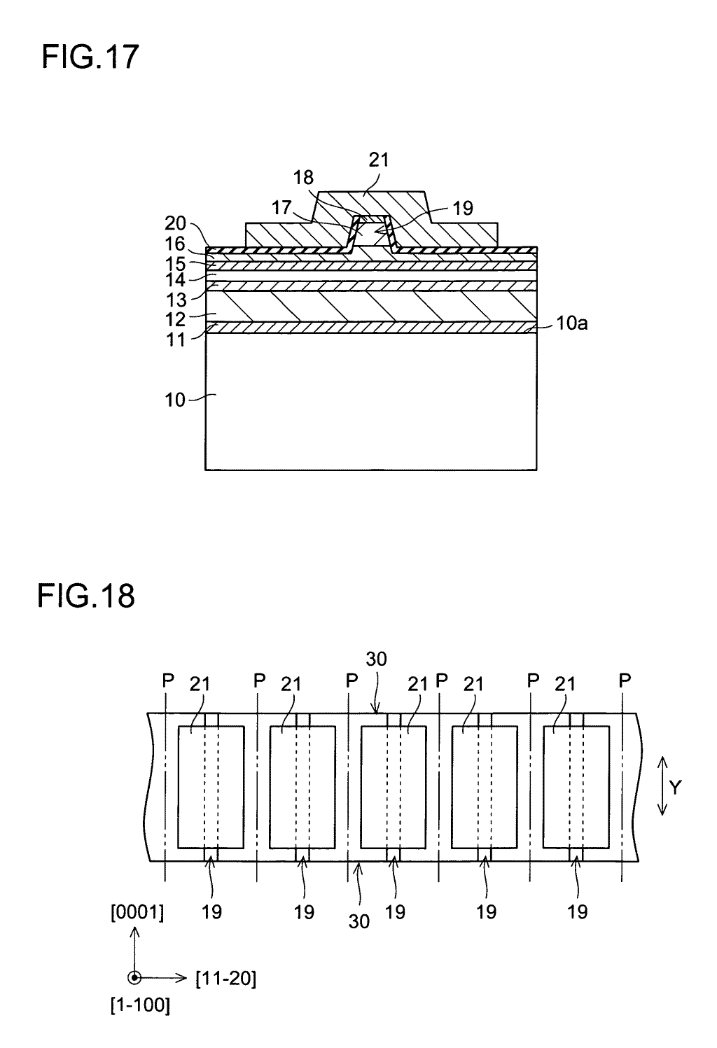

Next, as shown in FIG. 17, by a vacuum deposition process or the like, the following layers are formed successively from the substrate side (the insulating layer 20 side): a Pd layer (not shown) with a thickness of about 15 μm; and a Au layer (not shown) with a thickness of about 200 nm. Thus, on the insulating layer 20 (the contact layer 18), a p-side electrode 21 having a multiple-layer structure is formed.

Thereafter, to make the substrate easy to split, the back face of the GaN substrate 10 is ground or polished until the thickness of the GaN substrate 10 is reduced to about 100 μm. Thereafter, as shown in FIG. 2, on the back face of the GaN substrate 10, by a vacuum deposition process or the like, the following layers are formed successively from the GaN substrate 10's back face side: a Hf layer (not shown) with a thickness of about 5 nm; and an Al layer (not shown) with a thickness of about 150 nm. Thus, an n-side electrode 22 having a multiple-layer structure is formed. Then, on the n-side electrode 22, the following layers are formed successively from the n-side electrode 22 side: a Mo layer (not shown) with a thickness of about 36 nm; a Pt layer (not shown) with a thickness of about 18 nm; and a Au layer (not shown) with a thickness of about 200 nm. Thus, a metallized layer 23 having a multiple-layer structure is formed. Before the n-side electrode 22 is formed, dry etching or wet etching may be performed for the purpose of, for example, adjusting the n-side electrical characteristics.

Subsequently, as shown in FIG. 18, by a technique such as a scribing-breaking process or laser scribing, the wafer is split into bars. This produces a bar-shaped array of chips having resonator faces 30 at the split facets. Next, by a technique such as a vacuum deposition process or a sputtering process, a coating is applied to the facets (resonator faces 30) of the bar-shaped array of chips. Specifically, on one of the facets which will serve as a light emission face, an emission-side coating (not shown) of, for example, a film of aluminum oxynitride or the like is formed. On the facet opposite from it, which will serve as a light reflection face, a reflection-side coating (not shown) of, for example, multiple-layered films of SiO₂, TiO₂, etc. is formed.

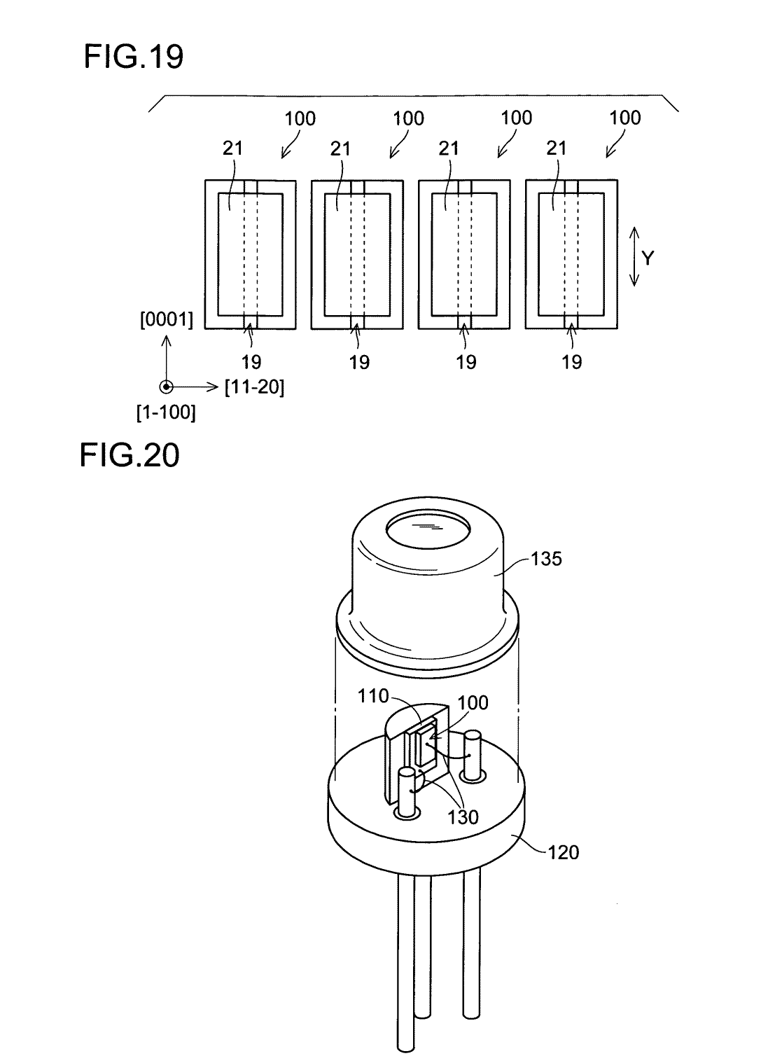

Lastly, the bar-shaped array of chips is split along planned splitting lines P along the Y direction (approximately the c-axis [0001] direction) into separate pieces of individual nitride semiconductor laser chips as shown in FIG. 19. In this way, the nitride semiconductor laser chip 100 according to Embodiment 1 of the invention is manufactured.

The nitride semiconductor laser chip 100 according to Embodiment 1 manufactured as described above is, as shown in FIG. 20, mounted on a stem 120 with a sub-mount 110 interposed in between and is electrically connected to lead pins by wires 130. Then, a cap 135 is welded on the stem 120 to complete assemblage into a can-packaged semiconductor laser device (semiconductor device).

In the manufacturing method of the nitride semiconductor laser chip 100 according to Embodiment 1, as described above, the GaN layer (the n-type GaN layer 11 and the lower guide layer 13) formed between the GaN substrate 10 and the active layer 14 (well layers 14a) is so formed as to have a total thickness of 0.7 μm or less (about 0.2 μm), and this makes it possible to obtain good surface morphology. This makes it possible to give the individual nitride semiconductor layers a uniform thickness distribution across the plane, and thus to enhance the flatness of the individual nitride semiconductor layers. Moreover, by enhancing surface morphology, it is possible to reduce variations in device characteristics, and thus to increase the number of chips having characteristics within the rated ranges. This makes it possible to increase manufacturing yields. By enhancing surface morphology, it is also possible to further enhance device characteristics and reliability.

In Embodiment 1, by forming the n-type semiconductor layers at a high temperature of 900° C. or higher, it is possible to give the n-type semiconductor layers a flat surface. Thus, by forming the active layer 14 and the p-type semiconductor layers on the n-type semiconductor layers with a flat surface, it is possible to suppress degradation of crystallinity in the active layer 14 and the p-type semiconductor layers. This too makes it possible to form a high-quality crystal. On the other hand, by forming the n-type semiconductor layers at a growth temperature lower than 1300° C., it is possible to suppress the inconvenience of the surface of the GaN substrate 10 re-evaporating and becoming rough during the raising of temperature due to the n-type semiconductor layers being formed at a growth temperature of 1300° C. or higher. Thus, with this configuration, it is possible to easily manufacture a nitride semiconductor laser chip 100 with superb device characteristics and high reliability.

In Embodiment 1, by forming the well layers 14a in the active layer 14 at a growth temperature of 600° C. or higher, it is also possible to suppress the inconvenience of a shorter atom diffusion length and hence degraded crystallinity due to the well layers 14a being formed at a growth temperature lower than 600° C. On the other hand, by forming the well layers 14a in the active layer 14 at a growth temperature of 800° C. or lower, it is possible to suppress the inconvenience of the active layer 14 being blackened by thermal damage due to the well layers 14a in the active layer 14 being formed at a growth temperature higher than 800° C. (for example, 830° C. or higher). The growth temperature of the barrier layers 14b, which are contiguous with the well layers 14a, is preferably the same as or higher than that of the well layers 14a.

In Embodiment 1, by forming the p-type semiconductor layers at a growth temperature of 700° C. or higher, it is possible to suppress the inconvenience of the p-type semiconductor layers having a high resistance due to their growth temperature being too low. On the other hand, by forming the p-type semiconductor layers at a growth temperature lower than 1100° C., it is possible to reduce thermal damage to the active layer 14. Forming the barrier layers out of a nitride semiconductor layer containing Al such as AlGaN or AlInGaN makes the active layer more resistant to thermal damage occurring during formation of the p-type semiconductor layers. That is, even when the p-type semiconductor layers are formed at a growth temperature of 1000° C. or higher, it is possible to suppress the active layer being blackened by thermal damage.

Here, in a case where a GaN substrate having the c plane as a principal growth plane is used, forming the p-type semiconductor layers at a growth temperature lower than 900° C. causes the p-type semiconductor layers to have an extremely high resistance and thus makes the resulting device (for example, a semiconductor light-emitting chip) difficult to use as such. By contrast, using the above-described GaN substrate 10 having as the principal growth plane 10a a plane having an off-angle in the a-axis direction relative to the m plane makes it possible, even at a growth temperature lower than 900° C., to obtain p-type conductivity by doping with Mg as a p-type impurity. In particular, in a case where the In composition ratio x1 in the well layers 14a in the active layer 14 is 0.15 or more but 0.45 or less, the In composition tends to vary across the plane due to segregation of In and the like. Thus, the lower the growth temperature of the p-type semiconductor layers, the more preferable. The difference between the growth temperature of the well layers 14a in the active layer 14 and the growth temperature of the p-type semiconductor layers is preferably less than 200° C. from the viewpoint of avoiding thermal damage to the active layer 14, and more preferably 150° C. or less.

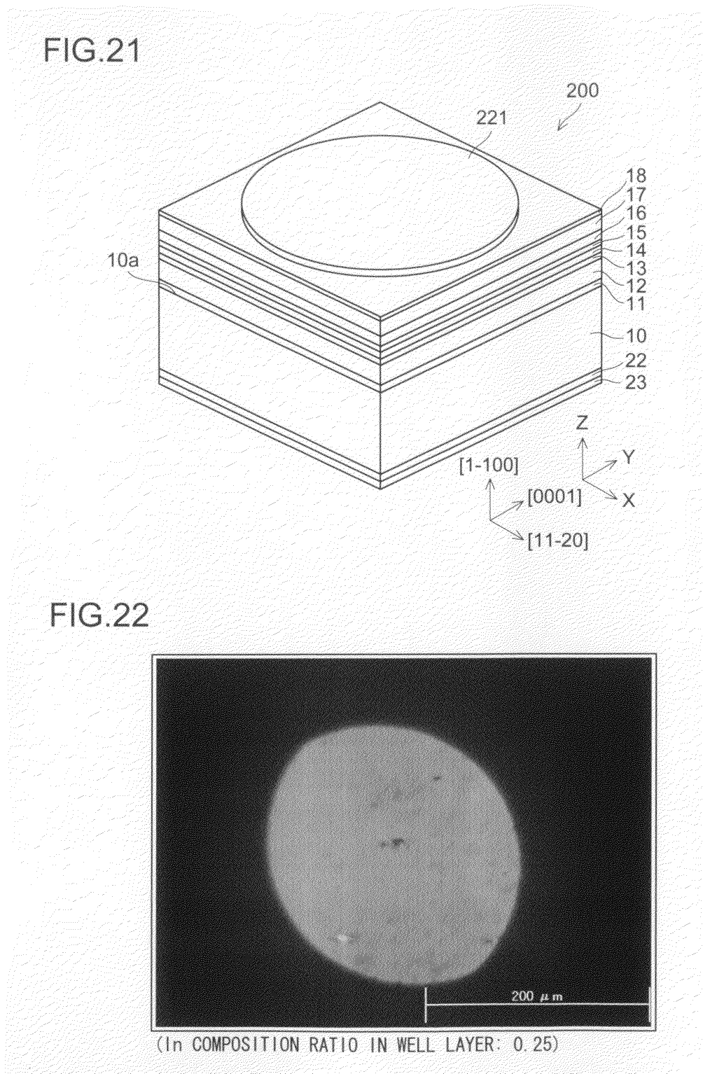

Next, a description will be given of experiments conducted to verify the effects of the nitride semiconductor laser chip 100 according to Embodiment 1 described above. In these experiments, first, a light-emitting diode chip 200 as shown in FIG. 21 was fabricated as a test chip, and the EL emission pattern was inspected. The reason that a light-emitting diode chip was used for the inspection of the EL emission pattern is that, with a nitride semiconductor laser chip, which has a constricted current injection region as a result of a ridge portion being formed, it is difficult to inspect the EL emission pattern.

The test chip (light-emitting diode chip 200) was fabricated by forming nitride semiconductor layers similar to those in Embodiment 1 described above on a GaN substrate 10 similar to that in Embodiment 1 described above. The formation of the nitride semiconductor layers was conducted in a similar manner as in Embodiment 1 described above. Specifically, as shown in FIG. 21, by use of a GaN substrate 10 having as a principal growth plane 10a a plane having an off-angle relative to the m plane, on its principal growth plane 10a, the following layers were formed successively: an n-type GaN layer 11; a lower clad layer 12; a lower guide layer 13; an active layer 14; a carrier block layer 15; an upper guide layer 16; an upper clad layer 17; and a contact layer 18. Next, on the contact layer 18, a p-side electrode 221 was formed. The p-side electrode 221 was formed transparent to allow inspection of the EL emission pattern. On the back face of the GaN substrate 10, an n-side electrode 22 and a metallized layer 23 were formed. In the test chip, the GaN substrate 10 had an off-angle of 1.7 degrees in the a-axis direction and an off-angle of +0.1 degrees in the c-axis direction. In the test chip, the In composition ratio in the well layers was 0.25, and the Al composition ratio in the barrier layers was 2%. In the test chip, the barrier layers were formed of AlGaN. Current was injected into the thus fabricated test chip (light-emitting diode chip 200) to make it emit light, and the light distribution across the plane was inspected. FIG. 22 is a microscope photograph of the EL emission pattern observed in the test chip.

On the other hand, as a comparison chip, a light-emitting diode chip employing a GaN substrate having the m plane as a principal growth plane (substantially an m-plane just substrate, with an off angle of 0 degrees in the a-axis direction and an off angle of +0.05 degrees in the c-axis direction) was fabricated. This comparison chip was fabricated in the same manner as the test chip described above. The gas flow rate of In was the same as for the test chip, but in the comparison chip, the In composition ratio in the well layers was 0.2. In the comparison chip, the barrier layers were formed of In_{0.02}Ga_{0.98}N. As with the test chip, the light distribution across the plane was inspected. Except employing an m-plane just substrate as the GaN substrate, having an In composition ratio of 0.2 in the well layers, and having the barrier layers formed of InGaN, the comparison chip had a configuration similar to that of the test chip (light-emitting diode chip 200). The EL emission pattern shown in FIG. 83 is (a microscope photograph of) the EL emission pattern observed in the comparison chip.

Whereas as shown in FIG. 83 the comparison chip exhibited a bright-spotted EL emission pattern, as shown in FIG. 22 the test chip, despite having a higher In composition ratio in the well layers, exhibited an EL emission pattern of uniform light emission as a result of a bright-spotted EL emission pattern being suppressed. It was thus confirmed that using a GaN substrate 10 having as a principal growth plane 10a a plane having an off-angle in the a-axis direction relative to the m plane helped suppress a bright-spotted EL emission pattern.

In the comparison chip, in which the barrier layers were formed of InGaN, as in FIG. 73 referred to earlier, dark lines appeared in the PL emission pattern. Also in a chip in which the barrier layers were formed of GaN, as in the comparison chip, appearance of dark lines was confirmed. By contrast, in the test chip, in which the barrier layers were formed of a nitride semiconductor layer containing Al (an AlGaN layer), as in FIG. 75 referred to earlier, no dark lines were observed.

On the other hand, through measurement of luminous efficacy with the test chip and the comparison chip, it was confirmed that the luminous efficacy of the test chip was increased to about twice that of the comparison chip. This is considered to have resulted from effects such as an effect of suppressing appearance of dark lines, an effect of protecting the active layer, and an effect of improving flatness. The emission wavelength of the test chip was 530 nm, and the emission wavelength of the comparison chip was 490 nm. It was thus confirmed that the test chip, in which the off-angle was controlled, was more efficient also in terms of In absorption than the comparison chip, which used an m-plane just substrate. The foregoing confirms that providing an off-angle in the a-axis direction relative to the m plane offers an effect of suppressing bright-spotted emission and hence increasing luminous efficacy in a wavelength region of green.

It is also confirmed that, by forming the barrier layers in the active layer out of a nitride semiconductor layer containing Al, it is possible to obtain a chip offering uniform, high luminous intensity even in a very long emission wavelength region of 530 nm. Also confirmed is that the increase in luminous intensity in a long wavelength region, which is the effect obtained by forming the barrier layers in the active layer out of a nitride semiconductor layer containing Al, is achieved in a preferable way when use is made of a non-polar substrate having the m plane, the a plane, or the like as the principal growth plane. This, it has been found out, is more preferable because, then, using a substrate having an off angle in the a-axis direction relative to the m plane, which permits formation of a nitride semiconductor layer containing Al with good flatness and good crystallinity, it is possible even to make the EL emission pattern extremely uniform.

With the configuration of the test chip described above, largely the same effects were obtained when the barrier layers formed of Alₓ₂Ga₁₋ₓ₂N had an Al composition ratio x2 in a range of 0<x2≦0.08.

Subsequently, by use of a plurality of GaN substrates with different off-angles in the a- and c-axis directions, a plurality of chips like the light-emitting diode chip 200 shown in FIG. 21 were fabricated, and were subjected to experiments including inspection of the EL emission pattern.

The results reveal that providing an off-angle in the a-axis direction relative to the m plane gives an effect of suppressing a bright-spotted EL emission pattern. It is also found out that, whereas the effect of suppressing bright-spotted emission is weak with the off-angle in the a-axis direction in a range of 0.1 degrees or smaller, the effect of suppressing a bright-spotted EL emission pattern is prominent with the off-angle in the a-axis direction equal to 0.1 degrees or larger. Thus, it is confirmed that by using as the principal growth plane of a GaN substrate a plane having an off-angle in the a-axis direction relative to the m plane, it is possible to suppress a bright-spotted EL emission pattern. It is also confirmed that making the off angle in the a-axis direction larger than the off angle in the c-axis direction helps suppress a bright-spotted EL emission pattern more effectively.

### Practical Example 1

As a nitride semiconductor laser chip according to Practical Example 1, a nitride semiconductor laser chip similar to the one according to Embodiment 1 described above was fabricated by use of a GaN substrate having an off-angle of 1.7 degrees in the a-axis direction and an off-angle of +0.1 degrees in the c-axis direction relative to the m plane {1-100}. The In composition ratio in the well layers was 0.25, and the Al composition ratio in the barrier layers was 2%. In other respects, the configuration of Practical Example 1 was similar to that of Embodiment 1 described above. Another nitride semiconductor laser chip fabricated in a similar manner as the one according to Embodiment 1 described above but by using a GaN substrate having no off-angle (an m-plane just substrate) was taken as Comparative Example 1. In other respects, the configuration of the nitride semiconductor laser chip of Comparison Example 1 was similar to that of Practical Example 1.

With respect to Practical Example 1 and Comparison Example 1, the threshold current was measured. Whereas with the nitride semiconductor laser chip of Comparison Example 1 the value of the threshold current was about 120 mA, with the nitride semiconductor laser chip of Practical Example 1 the value of the threshold current was 55 mA; thus, it was confirmed that the threshold current was far lower with the nitride semiconductor laser chip of Practical Example 1 than with that of Comparison Example 1. The reason is considered to be that suppressed bright-spotted emission led to uniform light emission across the plane and hence a higher gain. Also with regard to the driving voltage, it was confirmed that the driving voltage as observed when a current of 50 mA was injected was about 0.4 V lower with the nitride semiconductor laser chip of Practical Example 1 than with that of Comparison Example 1. One reason for these results is considered to be that using as the principal growth plane of a GaN substrate a plane having an off-angle in the a-axis direction relative to the m plane changed how Mg was absorbed into the p-type semiconductor layers in such a way as to enhance the activation rate. The emission wavelength of the nitride semiconductor laser chip according to Practical Example 1 was 505 nm. The reason that lasing was possible with a comparatively low threshold current density even in lasing at a long wavelength of 500 nm or more is considered to be that forming a GaN layer with a total thickness of 0.7 μm or less between a nitride semiconductor substrate having an off angle in the a-axis direction and an active layer (well layers) improved surface morphology and improved film flatness. It is also considered that using a nitride semiconductor layer containing Al as a barrier layer had effects such as an effect of suppressing appearance of dark lines.

### Practical Example 2

As a nitride semiconductor laser chip according to Practical Example 2, by use of a GaN substrate having an off angle of 4 degrees in the a-axis direction and an off angle of +1 degree in the c-axis direction relative to the m plane {1-100}, a nitride semiconductor laser chip was fabricated in which the barrier layers were formed of AlₛInₜGaᵤN (s+t+u=1). In Practical Example 2, the barrier layers were formed of AlₛInₜGaᵤN (s=0.02, t=0.01, u=0.97). That is, in Practical Example 2, the barrier layers were formed of AlInGaN. In other respects than the barrier layers, the configuration of Practical Example 2 was similar to that of Embodiment 1 (Practical Example 1) described above. Practical Example 2 offered similar effects as Practical Example 1 described above.

With the configuration of Practical Example 2 described above, largely the same effects were obtained when the barrier layers formed of AlₛInₜGaᵤN (s+t+u=1) had an Al composition ratio s in a range of 0<s≦0.08 and an In composition ratio t in a range of 0<t≦0.10.

In a case where the barrier layers are formed of AlₛInₜGaᵤN (s+t+u=1), it is preferable that the Al composition be lower than the In composition. To achieve light emission at wavelengths in a long wavelength region, the active layer needs to be formed at a low temperature of 900° C. or lower, typically about 700° C. to 800° C.; this might be, it is considered, the reason that the In content enhances crystallinity in low-temperature growth. Moreover, using an AlInGaN layer containing In as a barrier layer gives a higher index of refraction than using an AlGaN layer, and thus helps achieve efficient light confinement.

### Practical Example 3

As a nitride semiconductor laser chip according to Practical Example 3, by use of a GaN substrate having an off angle of 6 degrees in the a-axis direction and an off angle of −1.1 degrees in the c-axis direction relative to the m plane {1-100}, a nitride semiconductor laser chip was fabricated in which the barrier layers were formed of AlₛInₜGaᵤN (s+t+u=1). In Practical Example 3, the first barrier layer was formed of AlₛInₜGaᵤN (s=0.02, t=0, u=0.98), and the second and third barrier layers were formed of AlₛInₜGaᵤN (s=0.02, t=0.01, u=0.97). That is, in Practical Example 3, the first barrier layer was formed of AlGaN, and unlike the first barrier layer, the second and third barrier layers were each formed of AlInGaN. In other respects than the barrier layers, the configuration of Practical Example 3 was similar to that of Embodiment 1 (Practical Example 1) described above. Practical Example 3 offered similar effects as Practical Example 1 described above. The first barrier layer may have a different composition from the second and third barrier layers as in Practical Example 3, or each barrier layer may have a different Al composition.

With the configuration of Practical Example 3 described above, largely the same effects were obtained when the barrier layers formed of AlₛInₜGaᵤN (s+t+u=1) had an Al composition ratio s in a range of 0<s≦0.08 and an In composition ratio t in a range of 0<t≦0.10.

### Practical Example 4

As a nitride semiconductor laser chip according to Practical Example 4, by use of a GaN substrate having an off angle of 6 degrees in the a-axis direction and an off angle of +2 degrees in the c-axis direction relative to the m plane {1-100}, a nitride semiconductor laser chip was fabricated which was largely similar to that of Practical Example 1. Specifically, in Practical Example 4, the barrier layers were formed of AlGaN. A difference was that, whereas in Practical Example 1 the three barrier layers (first, second, and third barrier layers) had the same Al composition ratio, in Practical Example 4, they had different Al composition ratios. Specifically, the first barrier layer had an Al composition ratio of 2%, and the second and third barrier layers had an Al composition ratio of 0.08%. Practical Example 4 offered similar effects as Practical Example 1 described above. A design in which the first barrier layer had a higher Al composition ratio than the other barrier layers as in Practical Example 4 offered similar effects.

### Embodiment 2

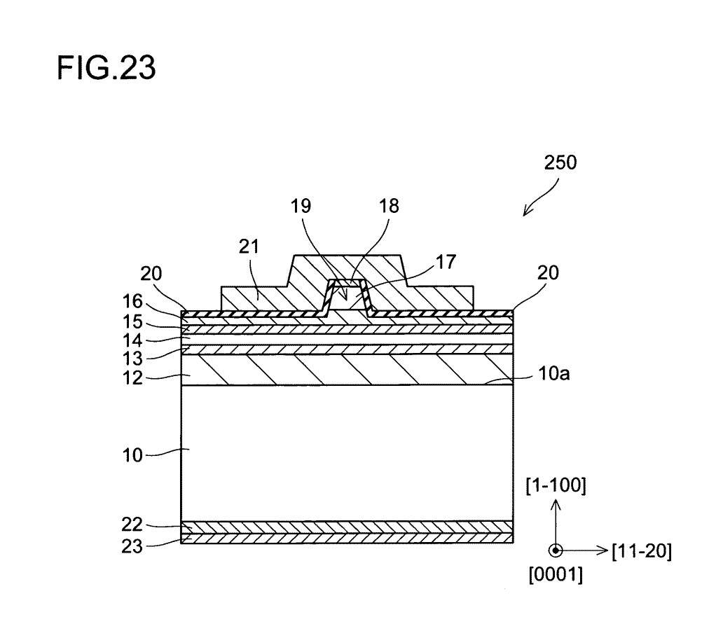

FIG. 23 is a sectional view showing the structure of a nitride semiconductor laser chip according to a second embodiment (Embodiment 2) of the invention. Next, with reference to FIGS. 2 and 23, a nitride semiconductor laser chip 250 according to Embodiment 2 of the invention will be described. It should be noted that, among different drawings, corresponding elements are identified by common reference signs and no overlapping description of them will be repeated.

In the nitride semiconductor laser chip 250 according to Embodiment 2, as shown in FIG. 23, the semiconductor layer in contact with the principal growth plane 10a of the GaN substrate 10 is a nitride semiconductor layer containing Al. Moreover, the lower guide layer 13 formed on the lower clad layer 12 is formed of AlGaN. Specifically, in the nitride semiconductor laser chip 250 according to Embodiment 2, on the principal growth plane 10a of the GaN substrate 10, a lower clad layer 12 of n-type Al_{0.06}Ga_{0.94}N with a thickness of about 2.2 μm is formed in contact with the principal growth plane 10a. On the lower clad layer 12, a lower guide layer 13 of n-type Al_{0.05}Ga_{0.95}N with a thickness of about 0.1 μm is formed. That is, in Embodiment 2, no n-type GaN layer 11 (see FIG. 2) is formed. Moreover, in Embodiment 2, the lower guide layer 13 formed on the lower clad layer 12 is, instead of a GaN layer, an AlGaN layer. Thus, in Embodiment 2, the individual nitride semiconductor layers stacked on the GaN substrate 10 do not include a GaN layer.

In a case where the lower guide layer 13 is formed of AlGaN, it is preferable to give it an Al composition ratio in a range of higher than 0 but 0.03 or lower. Giving it an Al composition ratio of 0, that is, forming it as a GaN layer, may degrade flatness. On the other hand, an Al composition ratio over 0.03 causes insufficient light confinement.

It is preferable that the lower guide layer 13 formed of AlGaN be formed to have a thickness of 0.05 μm or more but 0.4 μm or less, and more preferably 0.08 μm or more but 0.25 μm or less. Giving the lower guide layer 13a thickness less than 0.05 μm tends to result in an insufficient effect of enhancing flatness. On the other hand, giving the lower guide layer 13a thickness over 0.4 μm causes the distribution of optical electric field intensity to widen across the layer, and thus diminishes the light confinement coefficient.

In a case where the guide layer is formed of AlGaN as described above, by increasing the Al composition ratio in the clad layer, it is possible to further enhance light confinement.

In other respects, the configuration of Embodiment 2 is similar to that of Embodiment 1 described previously.

In Embodiment 2, as described above, on the principal growth plane 10a having an off angle in the a-axis direction relative to the m plane, the lower clad layer 12 formed of AlGaN is formed in contact with the principal growth plane 10a, and this makes it possible to greatly improve surface morphology, and to enhance the flatness on the layer surface. This makes it possible to give the individual nitride semiconductor layers formed on the GaN substrate 10a uniform thickness distribution across the plane. Moreover, by improving surface morphology, it is possible to reduce variations in device characteristics (for example, I-L response, I-V response, far-field pattern, wavelength, etc.), and thus it is possible to increase manufacturing yields. This makes it possible to easily obtain chips having characteristics within the rated ranges. Moreover, by enhancing surface morphology, it is possible to further enhance device characteristics and reliability.

In Embodiment 2, on the lower clad layer 12, the lower guide layer 13 formed of AlGaN is formed, and this too makes it possible to enhance the flatness on the layer surface.

In other respects, the effects of Embodiment 2 are similar to those of Embodiment 1 described previously.

In Embodiment 2 described above, the lower guide layer 13 may be formed of, instead of AlGaN, AlInGaN or InGaN; it may even be given a super-lattice structure involving any combination of AlGaN, AlInGaN, and InGaN. From the viewpoint of light confinement, it is more preferable that the lower guide layer 13 be formed of a nitride semiconductor containing In. In a case where InGaN, AlGaN, or AlInGaN is used for the lower guide layer 13, it may be non-doped, without being intentionally doped with any impurity, or may be doped with, for example, Si as an n-type impurity.

In a case where an InGaN layer is used as the lower guide layer 13, the In composition ratio there is set in a range lower than the In composition ratio in the well layers. Preferably, the In composition ratio in the lower guide layer 13 is set in a range of higher than 0 but 0.05 or lower. Giving it an In composition ratio of 0, that is, forming it as a GaN layer, may degrade flatness. On the other hand, an In composition ratio higher than 0.05 produces great strain, and may lead to degraded crystal quality. It is preferable that the lower guide layer 13 formed of InGaN be formed to have a thickness of 0.05 μm or more but 0.5 μm or less, and more preferably 0.08 μm or more but 0.3 μm or less. Giving the lower guide layer 13a thickness less than 0.05 μm tends to cause insufficient light confinement. On the other hand, giving the lower guide layer 13a thickness more than 0.4 μm causes the distribution of optical electric field intensity to widen across the layer, and thus diminishes the light confinement coefficient.

In a case where an AlInGaN layer is used as the lower guide layer 13, it is preferable that the In composition ratio there be higher than 0 but 0.10 or lower, and that the Al composition ratio there be higher than 0 but 0.08 or lower. It is preferable that the lower guide layer 13 formed of AlInGaN be formed to have a thickness of 0.05 μm or more but 0.5 μm or less, and more preferably 0.07 μm or more but 0.3 μm or less. In a case where the lower guide layer 13 is formed of AlInGaN, a value outside the just mentioned ranges (over the upper limit of at least one of the ranges for composition and thickness) may result in degraded crystal quality. On the other hand, at least a value equal to or under the just mentioned ranges for composition or a value under the lower limit of the just mentioned range for thickness results in an insufficient effect of light confinement or of flatness enhancement.

As a modified example of Embodiment 2, in the configuration of Embodiment 2 described above, a nitride semiconductor layer containing In (for example, an InGaN, AlInGaN, AlInN, or like layer) may be formed between the GaN substrate 10 and the lower clad layer 12 so as to be in contact with the principal growth plane 10a of the GaN substrate 10. In that case, setting the lattice constant of the nitride semiconductor layer containing In greater than that of GaN offers an effect of suppressing development of cracks. Preferred examples of nitride semiconductor layers containing In include InGaN and AlInGaN layers.

### Practical Example 5

As a nitride semiconductor laser chip according to Practical Example 5, by use of a GaN substrate having an off angle of 8 degrees in the a-axis direction and an off angle of +4 degrees in the c-axis direction relative to the m plane {1-100}, a nitride semiconductor laser chip was fabricated which was largely similar to that of Practical Example 1. A difference was that, in Practical Example 5, the semiconductor layer in contact with the principal growth plane of the substrate was not an n-type GaN layer but a lower clad layer. That is, in Practical Example 5, no n-type GaN layer was formed, and, on the principal growth plane of the substrate, nitride semiconductor layers were stacked starting with a lower clad layer of n-type Al_{0.06}G_{0.94}N with a thickness of about 2.2 μm. This too offered similar effects. Moreover, improved surface morphology was obtained, and a reduction of about 0.2 V in the driving voltage was observed.

In the configuration of Practical Example 5 described above, similar effects were obtained also when the lower clad layer was formed of AlₛInₜGaᵤN (s+t+u=1). Here, largely the same effects were obtained when the Al composition ratio s was in a range of 0<s≦0.15 and the In composition ratio t was in a range of 0<the ≦0.10.

### Practical Example 6

As a nitride semiconductor laser chip according to Practical Example 6, by use of a GaN substrate having an off angle of 3 degrees in the a-axis direction and an off angle of +1 degree in the c-axis direction relative to the m plane {1-100}, a nitride semiconductor laser chip was fabricated which was largely similar to that of Practical Example 1. A difference was that, here, the semiconductor layer in contact with the principal growth plane of the substrate was, in place of the n-type GaN layer, an InGaN layer of In_{0.02}Ga_{0.98}N with a thickness of about 0.1 μm. That is, in Practical Example 6, individual nitride semiconductor layers were formed starting with an InGaN layer. This too offered similar effects.

### Practical Example 7

As a nitride semiconductor laser chip according to Practical Example 7, by use of a GaN substrate having an off angle of 4 degrees in the a-axis direction and an off angle of +1 degree in the c-axis direction relative to the m plane {1-100}, a nitride semiconductor laser chip was fabricated which was largely similar to that of Practical Example 1. A difference was that, in Practical Example 7, the semiconductor layer in contact with the principal growth plane of the substrate was not an n-type GaN layer but a layer of n-type In_{0.02}Ga_{0.98}N with a thickness of about 0.1 μm. That is, in Practical Example 7, no n-type GaN layer was formed, and, on the principal growth plane of the substrate, a nitride semiconductor layer of n-type In_{0.02}Ga_{0.98}N with a thickness of about 0.1 μm was stacked. On top of this, a lower clad layer was formed which had a thickness of about 1.5 μm and had a super-lattice structure of 250 cycles of n-type Al_{0.12}Ga_{0.88}N (with a thickness of 4 nm) and GaN (with a thickness of 2 nm). This too offered similar effects.

### Practical Example 8

As a nitride semiconductor laser chip according to Practical Example 8, by use of a GaN substrate having an off angle of 3 degrees in the a-axis direction and an off angle of −0.5 degrees in the c-axis direction relative to the m plane {1-100}, a nitride semiconductor laser chip was fabricated which was largely similar to that of Practical Example 1. A difference was that, in Practical Example 8, the lower guide layer was formed, instead of GaN in Practical Example 1, AlₛInₜGaᵤN (s=0.02, t=0.01, u=0.97). Also as Practical Example 8, another chip in which the lower guide layer was formed of InGaN (with an In composition ratio of 1.5%) was fabricated. These configurations offered similar effects.

A comparison among a chip in which the lower guide layer was formed of GaN and chips in which it was formed of In_{0.015}Ga_{0.985}N and Al_{0.02}In_{0.01}Ga_{0.97}N, respectively, showed that the chips having the lower guide layer formed of InGaN or AlInGaN, respectively, offered an about 1.5 times increase in luminous efficacy compared with the one having it formed of GaN. As semiconductor laser chips, those exhibited an increased effect of light confinement and a reduction of about 20 mA in threshold current. With respect to these effects, with chips having the lower guide layer formed of InGaN, largely similar effects were obtained when the In composition ratio y2 in In_{y2}Ga_{1-y2}N was in a range of 0<y2≦0.05; with chips having the lower guide layer formed of AlₛInₜGaᵤN, largely similar effects were obtained when the Al composition ratio s was in a range of 0<s≦0.08 and the In composition ratio t was in a range of 0<t≦0.10.

In a case where the lower guide layer was formed of InGaN, a similar tendency was observed when the In composition ratio was higher than 0.0% but 5.0% or lower. Chips with an In composition ratio y higher than 5.0% tend to exhibit non-radiative black spots and hence lower luminous efficacy. On the other hand, in a case where the lower guide layer was formed of AlInGaN, similar effects were observed when the Al composition ratio was higher than 0.0% but 8.0% or lower. Owing to the added Al, AlInGaN suppressed black spots up to an In composition ratio of 10%.

### Embodiment 3

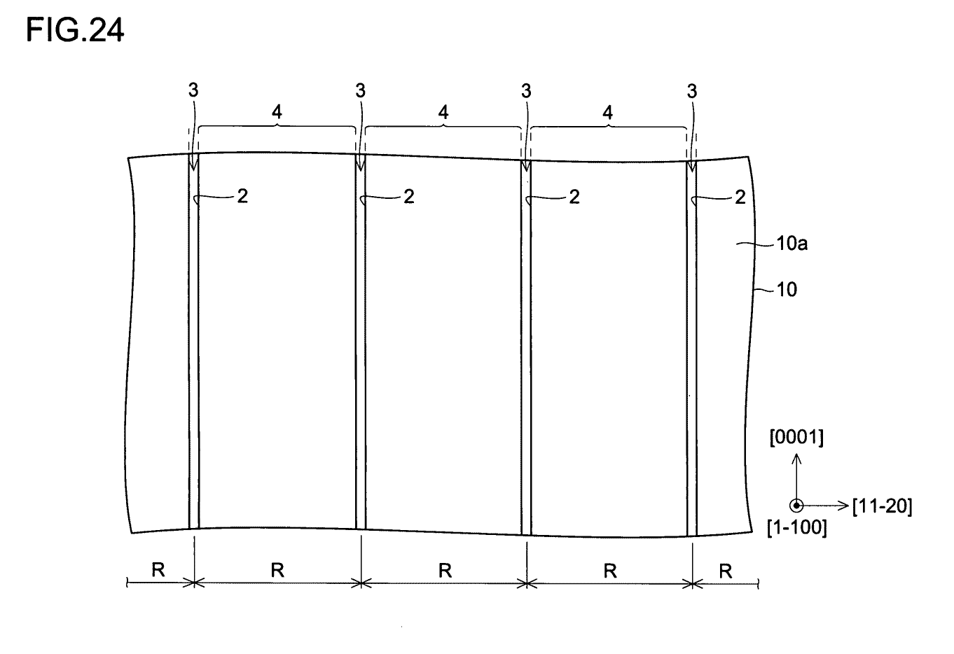

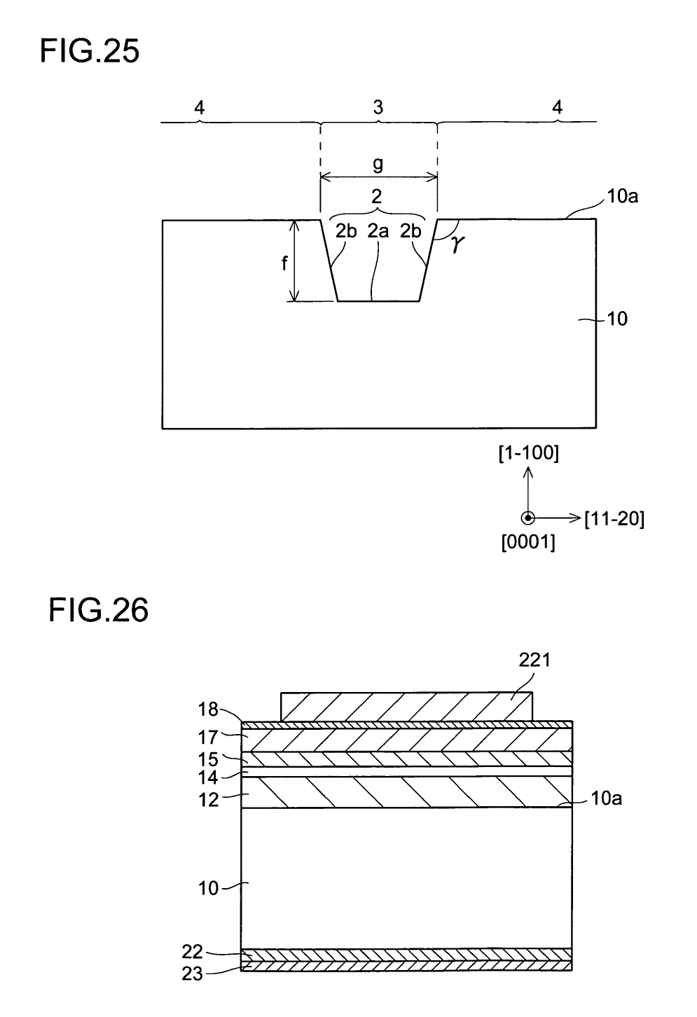

FIGS. 24 and 25 are diagrams illustrating the structure of a nitride semiconductor laser chip according to a third embodiment (Embodiment 3) of the invention. FIG. 24 is a plan view of a nitride semiconductor substrate (semiconductor wafer) used for the manufacturing of a nitride semiconductor laser chip according to Embodiment 3, and FIG. 25 is an enlarged sectional view of part of the nitride semiconductor substrate (semiconductor wafer). Next, with reference to FIGS. 24 and 25, a nitride semiconductor laser chip according to Embodiment 3 of the invention will be described.

In the nitride semiconductor laser chip according to Embodiment 3, compared with the configurations of Embodiments 1 and 2 described previously, a carved region is formed in the principal growth plane 10a of the GaN substrate 10. Specifically, as shown in FIG. 24, the GaN substrate 10 has a plurality of depressed portions 2 formed by being carved in its thickness direction from the principal growth plane 10a. As seen in a plan view, these depressed portions 2 are formed to extend in a direction parallel to the c-axis [0001] direction. Moreover, the depressed portions 2 are arranged at equal intervals, with a period R of about 150 μm to 600 μm (for example, about 400 μm), in the a-axis [11-20] direction, which is perpendicular to the c-axis [0001] direction. That is, the plurality of depressed portions 2 are formed in the shape of stripes on the principal growth plane 10a of the GaN substrate 10. In the GaN substrate 10, the regions where the depressed portions 2 are formed (that is, the regions that are carved) constitute carved regions 3. On the other hand, the regions of the principal growth plane 10a where the depressed portions 2 are not formed (that is, the regions that are not carved) constitute uncarved regions 4.

Moreover, as shown in FIG. 25, the plurality of depressed portions 2 each include a floor surface portion 2a and a pair of side surface portions 2b. The side surface portions 2b are inclined at a predetermined inclination angle γ larger than 90 degrees. Thus, the side surface portions 2b of the depressed portion 2 are inclined surfaces. Accordingly, the depressed portion 2 is formed such that its opening width is increasingly large upward. The depressed portion 2 has an opening width g (width at the open end) of about 5 μm in the [11-20] direction, and has a depth f of about 5 μm in the thickness direction of the n-type GaN substrate 10.

As a result of use of the GaN substrate 10 having an off angle in the a-axis direction, in the nitride semiconductor layer over the uncarved region 4, a gradient thickness region (not shown) is formed whose thickness decreases in a gradient fashion (gradually) toward the depressed portion 2 (carved region 3). This gradient thickness region is formed in a region closely on one (for example, right) side of the depressed portion 2 (carved region 3), substantially in the shape of a band extending in a direction parallel to the depressed portion 2 (carved region 3). The gradient thickness region too serves to alleviate strain in the nitride semiconductor layer such as results from lattice mismatch with the GaN substrate 10.

In the nitride semiconductor layer over the uncarved region 4, an emission portion formation region (not shown) is formed where there is far less variation in thickness than in the gradient thickness region and which is thus suitable for formation of the ridge portion. In this emission portion formation region, the ridge portion is formed.

In other respects than the GaN substrate 10, the configuration of Embodiment 3 is similar to those of Embodiments 1 and 2 described previously. With the nitride semiconductor laser chip according to Embodiment 3, splitting into individual chips may be done such that each chip includes at least part of the depressed portion 2, or such that each chip includes no part of the depressed portion 2.

The depressed portions 2 can be formed by a photolithography technology and an etching technology, etc.

In Embodiment 3, as described above, by forming the depressed portion 2 (carved region 3) on the principal growth plane 10a side of the GaN substrate 10, it is possible to form a concavity in the surface of the nitride semiconductor layer over the depressed portion 2 (the part of the nitride semiconductor layer located over the depressed portion 2). As a result, even in a case where there is a large difference in lattice constant, thermal expansion coefficient, etc. between the GaN substrate 10 and the nitride semiconductor layer formed on its principal growth plane 10a, and as a result the nitride semiconductor layer is strained, the strain in the nitride semiconductor layer formed over the uncarved region 4 can be alleviated with the concavity formed in the surface of the nitride semiconductor layer over the depressed portion 2 (carved region 3). This makes it possible to effectively suppress development of cracks in the nitride semiconductor layer.

As described above, in Embodiment 3, by forming the depressed portion 2 in the GaN substrate 10, it is possible to obtain very strong effects of alleviating strain and of suppressing cracks, and thus, even in a case where the barrier layers are formed of a nitride semiconductor containing Al, it is possible to alleviate strain in the barrier layers and suppress development of cracks. Also in a case where the clad layer is given an increased Al composition ratio for better light confinement, it is possible to suppress development of cracks.

In other respects, the effects of Embodiment 3 are similar to those of Embodiments 1 and 2 described previously.

### Practical Example 9

As a nitride semiconductor laser chip according to Practical Example 9, by use of a substrate (an m-plane a-axis off substrate) having a carved region formed in it, a nitride semiconductor laser chip was fabricated which was largely similar to that of Practical Example 1. In Practical Example 9, however, unlike in Embodiment 1, the clad layers (upper and lower clad layers) were given an Al composition ratio of 8.0%. This too offered effects similar to those of Practical Example 1.

Here, in a case where the barrier layers are formed of a nitride semiconductor containing Al, GaN suffers great stretching strain, possibly developing a crack. Moreover, forming the barrier layers out of a nitride semiconductor containing Al tends to increase the strain acting on the active layer, and therefore it is preferable to alleviate strain (stress) as much as possible. The clad layer may also be given an increased Al composition ratio for better light confinement, and this too makes development of a crack likely.

Even in such a case, by forming the carved region (depressed portion), it was possible to prevent development of cracks.

Another nitride semiconductor laser chip fabricated in a similar manner as that of Practical Example 9 described above but by using a substrate (an m-plane a-axis off substrate) having no carved region (depressed portion) formed in it was taken as Comparative Example 2.

In Practical Example 9, although the clad layer had an Al composition ratio as high as 8.0% (0.08), no development of cracks was recognized. On the other hand, in Comparative Example 2, many cracks developed. Thus, in Practical Example 9, a very strong effect of suppressing cracks was confirmed, and an effect of increasing yields was obtained. Thus, it was possible to enhance device characteristics and reliability.

### Embodiment 4

In a fourth embodiment (Embodiment 4) of the invention, a nitride semiconductor laser chip is formed by use of a GaN substrate having as the principal growth plane a plane having an off angle (for example, −0.5 degrees) in the c-axis direction relative to the m plane. The barrier layers in the active layer are formed of AlInGaN. In other respects, the configuration of Embodiment 4 is similar to that of Embodiment 1 described previously.

In Embodiment 4, forming the barrier layers out of AlInGaN as described above makes it possible to suppress appearance of dark lines; doing so, as compared with forming the barrier layers out of GaN or InGaN, also helps enhance interface steepness, and thus helps make clear the satellite peak observed by X-ray diffraction measurement. This is considered to result from the Al and In contents in the barrier layers suppressing agglomeration and diffusion of In and suppressing thermal damage to the active layer.

In a case where use is made of a GaN substrate having an off angle in the c-axis direction relative to the m plane, compared with in a case where use is made of a GaN substrate having an off angle in the a-axis direction relative to the m plane, although the flatness on the layer surface is poorer, practicably high luminous efficacy can be obtained. Moreover, using AlInGaN for the barrier layers helps achieve extremely high efficiency in absorption of In into the well layers. As a result, even with a reduced gas flow rate of In, a high In composition ratio can be maintained. This makes it possible to enhance absorption efficiency, and thus to achieve a lengthening in emission wavelength effectively.

### Embodiment 5

FIG. 26 is a sectional view of a light-emitting diode chip according to a fifth embodiment (Embodiment 5) of the invention. Next, with reference to FIGS. 2, 23, and 26, a description will be given of an example in which a nitride semiconductor chip according to the invention is applied to a light-emitting diode chip (LED, or light-emitting diode).

The light-emitting diode chip according to Embodiment 5 is formed by forming individual nitride semiconductor layers similar to those in Embodiments 1 and 2 described previously on a GaN substrate 10 similar to that in Embodiments 1 and 2 described previously. In Embodiment 5, however, unlike in Embodiments 1 and 2 described previously, neither the lower guide layer 13 (see FIGS. 2 and 23) nor the upper guide layer 16 (see FIGS. 2 and 23) is formed.

Specifically, as shown in FIG. 26, on the principal growth plane 10a of the GaN substrate 10, the following layers are formed successively: a lower clad layer 12; an active layer 14; a carrier block layer 15; an upper clad layer 17; and a contact layer 18. On the contact layer 18, a p-side electrode 221 is formed which is formed of an oxide-based transparent electrically conductive film such as ITO (indium tin oxide). On the back face of the GaN substrate 10, an n-side electrode 22 and a metallized layer 23 are formed.

In Embodiment 5, as in Embodiments 1 to 4 described previously, the barrier layers in the active layer 14 are formed of a nitride semiconductor containing Al (for example, AlGaN, AlInGaN, AlInN, etc.).

In Embodiment 5, by forming the barrier layers out of a nitride semiconductor containing Al as described above, it is possible to suppress appearance of dark lines. This makes it possible to enhance luminous efficacy.

In Embodiment 5, with the configuration described above, it is possible to enhance flatness on the layer surface and crystallinity, and this too makes it possible to enhance luminous efficacy.

In Embodiment 5, by forming the barrier layers out of a nitride semiconductor containing Al, even in a case where an increased number of well layers are provided, it is possible to suppress a lowering in luminous efficacy. Thus, by increasing the number of well layers, it is possible to enhance luminous efficacy easily.

Moreover, as described previously, forming the barrier layers out of AlInGaN helps achieve extremely high efficiency in absorption of In into the well layers. As a result, even with a reduced gas flow rate of In, it is possible to maintain a high In composition ratio, and thus to enhance absorption efficiency. This makes it possible to achieve a lengthening in emission wavelength more effectively. In that case, compared with in a case where the barrier layers are formed of AlGaN, it is possible to form the well layers in multiple layers more easily.

Furthermore, forming the barrier layers out of AlInGaN, compared with forming them out of AlGaN, helps reduce crystal strain. That is, by stacking well layers of InGaN and barrier layers of AlInGaN alternately, compared with stacking well layers of InGaN and barrier layers of AlGaN alternately, it is possible to reduce the crystal strain resulting from a difference in lattice constant. Generally, light-emitting diode chips are often given a quantum well structure including two or more, comparatively many, well layers. Thus, from the viewpoint of crystal strain, forming the barrier layers out of AlInGaN is more advantageous than forming them out of AlGaN.

In other respects, the effects of Embodiment 5 are similar to those obtained when the configurations of Embodiments 1 and 2 described previously are applied to light-emitting diode chips.

### Practical Example 10

In Practical Example 10, an LED was fabricated by use of a GaN substrate having an off angle of 3 degrees in the a-axis direction and an off angle of +0.5 degrees in the c-axis direction relative to the m plane {1-100}. In Practical Example 10, first, on the principal growth plane of the substrate, an n-type Al_{0.01}Ga_{0.99}N layer with a thickness of about 1 μm was formed, and then a 4QW active layer of Al_{0.01}Ga_{0.99}N (with a thickness of about 15 nm) and In_{0.25}Ga_{0.75}N (with a thickness of about 3 nm) was formed. Next, on the 4QW active layer, a p-type Al_{0.2}Ga_{0.8}N carrier block layer with a thickness of about 20 nm was formed. Then, on the p-type Al_{0.2}Ga_{0.8}N carrier block layer, a p-type GaN contact layer with a thickness of about 0.2 μm was formed. Thereafter, on the p-type GaN contact layer, an oxide-based transparent electrically conductive film of ITO with a thickness of about 50 nm was formed on an EB (electron beam) vapor deposition machine to form a p-side electrode formed of ITO. With this configuration, Embodiment 10 too offered an effect of suppressing appearance of dark lines, an effect of improving luminous efficacy, and an effect of suppressing bright-spotted emission.

As the above-mentioned oxide-based transparent electrically conductive film, instead of an ITO transparent electrically conductive film, which is indium oxide-based, it is possible to use an In₂O₃—ZnO-based transparent electrically conductive film, a ZnO-based transparent electrically conductive film, of which the main component is zinc oxide, a SnO₂-based transparent electrically conductive film, which is tin oxide-based, or the like. By use of such a transparent electrically conductive film, it is possible to greatly enhance light extraction efficiency. Moreover, by use of a substrate having an off angle in the a-axis direction relative to the m plane, it is possible to form the electrode on a p-type layer whose surface morphology has been improved, and thus it is possible to obtain a low contact resistance; furthermore, it is possible to suppress bright-spotted emission to achieve uniform light emission and uniform injection and thereby enhance luminous efficacy; thus, using a transparent electrically conductive film as the contact electrode for the nitride semiconductor layers formed on the above-described substrate gives a great advantage, and is therefore preferable. Particularly preferable is an ITO electrode, because it allows annealing at low temperature and is thus less likely to inflict thermal damage to the active layer. In Practical Example 10, annealing was performed at 600° C.

Preferably, the oxide-based transparent electrically conductive film is formed, first, in an amorphous state on the contact layer 18 on an EB vapor deposition machine, a sputtering machine, or the like, and is thereafter crystallized by thermal annealing at a temperature of about 400° C. to 700° C., because this lowers the resistance of the film and helps reduce the driving voltage. Here, more preferably, use is made of a nitride semiconductor substrate having an off angle in the a-axis direction, because this makes it possible to form a contact layer with very high flatness, and thus helps reduce the contact resistance between the oxide-based transparent electrically conductive film and the contact layer 18.

### Practical Example 11

In Practical Example 11, by use of a substrate similar to that in Practical Example 10, an LED having largely the same structure as in Practical Example 10 was fabricated. A difference was that, in Practical Example 11, the barrier layers were formed of AlₛInₜGaᵤN (s=0.01, t=0.03, u=0.96). This too offered effects similar to those described above. The Al content and the additional In content in the barrier layers are preferable, because together they make growth at low temperature possible,

### Practical Example 12

In Practical Example 12, by use of a substrate similar to that in Practical Example 10, an LED similar to that of Embodiment 5 described previously was fabricated. A difference was that, in Practical Example 12, two types of chips were fabricated, specifically one in which the barrier layers were formed of AlGaN (with an Al composition ratio of 1.5%) and another in which the barrier layers were formed of AlₛInₜGaᵤN (s=0.02, t=0.01, u=0.97). Both LEDs of Practical Example 12 emitted light at an emission wavelength of 520 nm, and no dark lines were observed in the emission pattern of either.

In chips in which the barrier layers were formed of Alₓ₂Ga₁₋ₓ₂N, largely similar effects were obtained when the Al composition ratio x2 was in a range of 0<x2≦0.08. In chips in which the barrier layers were formed of AlₛInₜGaᵤN, largely similar effects were obtained when the Al composition ratio s was in a range of 0<s≦0.08 and the In composition ratio t was in a range of 0<t≦0.10.

Furthermore, a plurality of chips with different numbers, increasing from two to eight in increments of one, of well layers were fabricated, and their luminous efficacy was measured. With chips having the barrier layers formed of GaN or InGaN, as the number of well layers increased, luminous efficacy greatly lowered. By contrast, with chips having the barrier layers formed of a nitride semiconductor containing Al (for example, AlGaN), no lowering in luminous efficacy was observed. With three or more well layers, forming the barrier layers out of AlInGaN, as compared with forming them out of AlGaN, resulted in about 1.2 time enhanced luminous efficacy.

### Embodiment 6

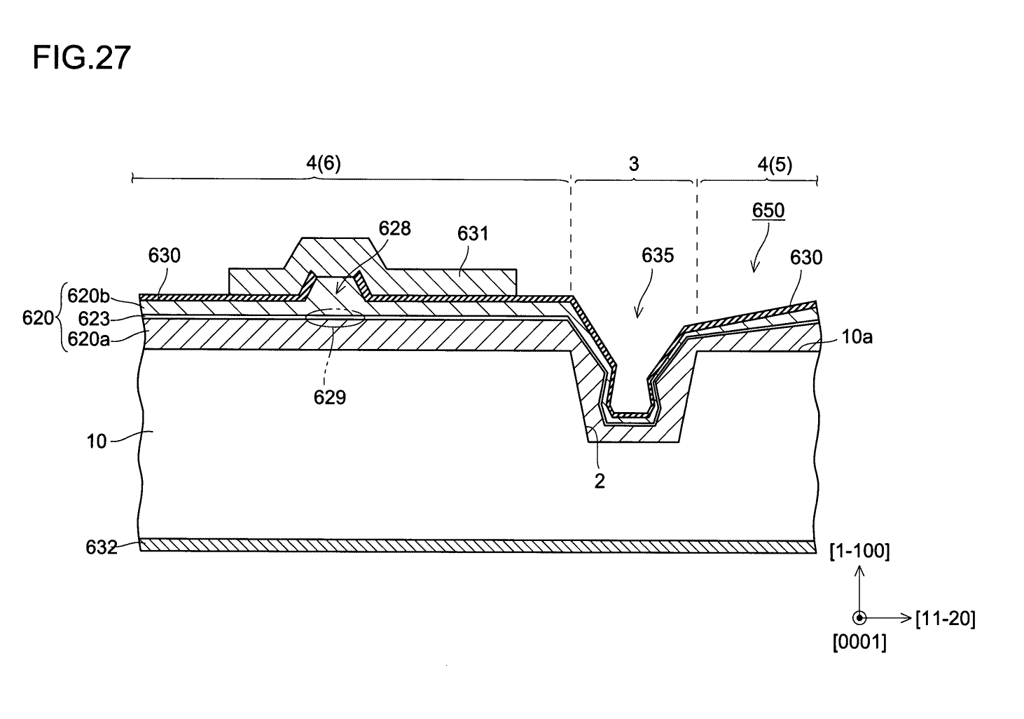

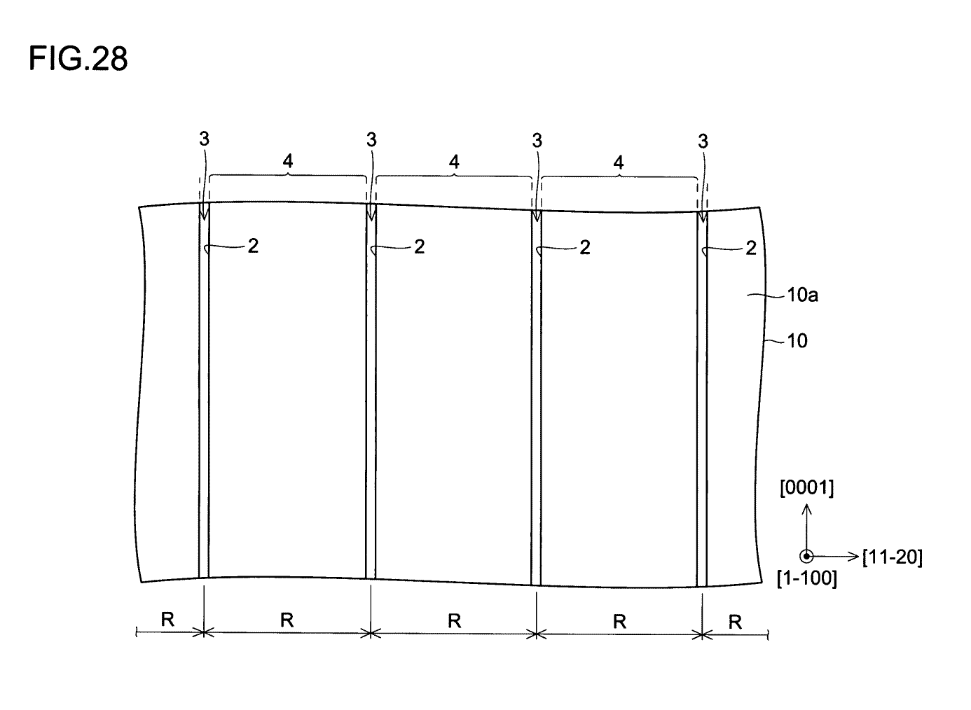

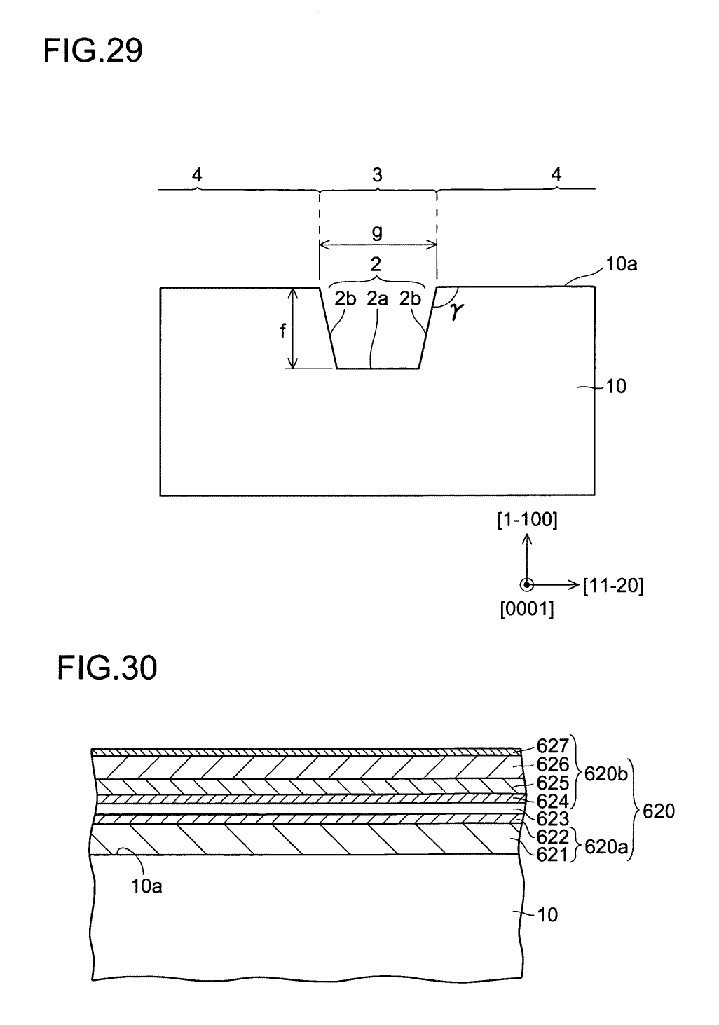

FIG. 27 is a sectional view schematically showing part of a nitride semiconductor wafer according to a sixth embodiment (Embodiment 6) of the invention. FIG. 28 is a plan view of a substrate used in a nitride semiconductor wafer according to Embodiment 6 of the invention. FIG. 29 is an enlarged sectional view showing part of a substrate used in a nitride semiconductor wafer according to Embodiment 6 of the invention. FIGS. 30 to 34 are diagrams illustrating a nitride semiconductor wafer according to Embodiment 6 of the invention. Next, with reference to FIGS. 27 to 34, a nitride semiconductor wafer 650, including a nitride semiconductor laser chip (nitride semiconductor chip), according to Embodiment 6 of the invention will be described.

As shown in FIG. 27, the nitride semiconductor wafer 650 according to Embodiment 6 is provided with an n-type GaN substrate 10 (nitride semiconductor substrate) similar to that in Embodiment 1 described previously. The n-type GaN substrate 10 has, as a principal growth plane 10a, a plane having an off angle relative to the m plane. Specifically, the n-type GaN substrate 10 of the nitride semiconductor wafer 650 has an off angle in the a-axis direction ([11-20] direction). The n-type GaN substrate 10 may have, in addition to the off angle in the a-axis direction, an off angle in the c-axis direction ([0001] direction) as well.

Thus, the n-type GaN substrate 10 in Embodiment 6 has, as the principal growth plane 10a, a plane inclined relative to the m plane {1-100}.

In the above-described n-type GaN substrate 10, the absolute value of the off-angle in the a-axis direction relative to the m plane is adjusted to be more than 0.1 degrees. As the off angle in the a-axis direction increases, however, the amount of In absorbed in the active layer (an InGaN layer such as a well layer) tends to decrease, and accordingly, from the perspective of source material efficiency and the like, it is preferable that the absolute value of the off angle in the a-axis direction be 10 degrees or smaller. Even with an off angle of 10 degrees or larger in the a-axis direction, film formation is possible. In a case where an off angle is provided also in the c-axis direction, it is preferable that the off angle in the c-axis direction be adjusted to be larger than ±0.1 degrees. It is preferable that the off angle in the c-axis direction be adjusted to be smaller than the off angle in the a-axis direction.

In the case described above, it is preferable that the off-angle in the a-axis direction be adjusted to be larger than 1 degree but 10 degrees or smaller. Adjusting the off-angle in the a-axis direction in that range is more preferable, because it is then possible to obtain a marked effect of reducing the driving voltage and in addition an effect of improving surface morphology.

In Embodiment 6, as shown in FIGS. 27 and 28, the above-described n-type GaN substrate 10 has a plurality of depressed portions 2 formed by being carved in its thickness direction from the principal growth plane 10a. As seen in a plan view, these depressed portions 2 are formed to extend in a direction crossing the a-axis [11-20] direction. Specifically, in Embodiment 6, the plurality of depressed portions 2 are formed to extend in a direction parallel to the c-axis [0001] direction, and are arranged at equal intervals, with a period R (see FIG. 28) of about 150 μm to 1200 μm (for example, about 400 μm), in the a-axis [11-20] direction, which is perpendicular to the c-axis [0001] direction. That is, the plurality of depressed portions 2 are formed in the shape of stripes on the principal growth plane 10a of the n-type GaN substrate 10. In the n-type GaN substrate 10, the regions where the depressed portions 2 are formed (that is, the regions that are carved) constitute carved regions 3. On the other hand, the regions of the principal growth plane 10a where the depressed portions 2 are not formed (that is, the regions that are not carved) constitute uncarved regions 4.

Moreover, as shown in FIG. 29, the plurality of depressed portions 2 each include a floor surface portion 2a and a pair of side surface portions 2b. The side surface portions 2b are inclined at a predetermined inclination angle γ (see FIG. 29) larger than 90 degrees. Thus, the side surface portions 2b of the depressed portion 2 are inclined surfaces. Accordingly, the depressed portion 2 is formed such that its opening width is increasingly large upward. The depressed portion 2 has an opening width g (width at the open end) of about 5 μm in the [11-20] direction, and has a depth f of about 5 μm in the thickness direction of the n-type GaN substrate 10.

As shown in FIG. 27, the nitride semiconductor wafer 650 according to Embodiment 6 has a structure in which, on the principal growth plane 10a of the above-described n-type GaN substrate 10, a nitride semiconductor layer 620 is formed, which includes an n-type nitride semiconductor layer 620a, an active layer 623, and a p-type nitride semiconductor layer 620b. The n-type nitride semiconductor layer 620a includes an n-type clad layer and an n-type guide layer, and the p-type nitride semiconductor layer 620b includes a carrier block layer, a p-type clad layer, a p-type guide layer, and a p-type contact layer. By an epitaxial growth process such as an MOCVD process, on the principal growth plane 10a of the n-type GaN substrate 10, individual nitride semiconductor layers are formed in the order the n-type nitride semiconductor layer 620a, the active layer 623, and the p-type nitride semiconductor layer 620b. Specifically, as shown in FIG. 30, on the principal growth plane 10a of the n-type GaN substrate 10, the following layers are formed successively: an n-type clad layer 621 of n-type Al_{0.06}Ga_{0.94}N (with a thickness of about 2.2 μm); an n-type guide layer 622 of n-type In_{0.02}Ga_{0.98}N (with a thickness of about 0.2 μm); an active layer 623; a carrier block layer 624 of Al_{0.15}Ga_{0.85}N (with a thickness of about 20 nm); a p-type guide layer 625 of In_{0.02}Ga_{0.98}N (with a thickness of about 0.1 μm); a p-type clad layer 626 of Al_{0.05}Ga_{0.95}N (with a thickness of about 0.5 μm); and a p-type contact layer 627 of p-type GaN (with a thickness of about 0.1 μm). The n-type GaN substrate 10 and the n-type nitride semiconductor layer 620a are doped with, for example, Si as an n-type impurity, and the p-type nitride semiconductor layer 620b is doped with, for example, Mg as a p-type impurity.

Here, a high Al content in a layer containing Al, Ga, and N included in the nitride semiconductor layer 620 produces a larger difference in lattice constant from the n-type GaN substrate 10 or the like, and thereby makes development of a crack more likely. In particular, the n-type clad layer 621 has a high Al composition ratio for satisfactory light confinement; it accordingly has a large difference in lattice constant from the n-type GaN substrate 10 and also has a thickness as large as about 2.2 μm. Thus, in the n-type clad layer 621, cracks are very likely to develop.

On the other hand, in the nitride semiconductor wafer 650 according to Embodiment 6, as a result of the depressed portion 2 (carved region 3) being formed in the principal growth plane 10a of the n-type GaN substrate 10, a concavity 635 is formed in the surface of the nitride semiconductor layer 620 (the surface of the individual layers constituting the nitride semiconductor layer 620) over the depressed portion 2 (carved region 3). This concavity 635 alleviates strain in the nitride semiconductor layer 620 such as results from lattice mismatch with the n-type GaN substrate 10. In Embodiment 6, as a result of the n-type GaN substrate 10 having as the principal growth plane 10a a plane having an off angle in the a-axis direction relative to the m plane, it is more difficult to fill the inside of the depressed portion 2 with the nitride semiconductor layer 620.

In Embodiment 6, the depressed portion 2 (carved region 3) also alleviates strain developing in the active layer 623.

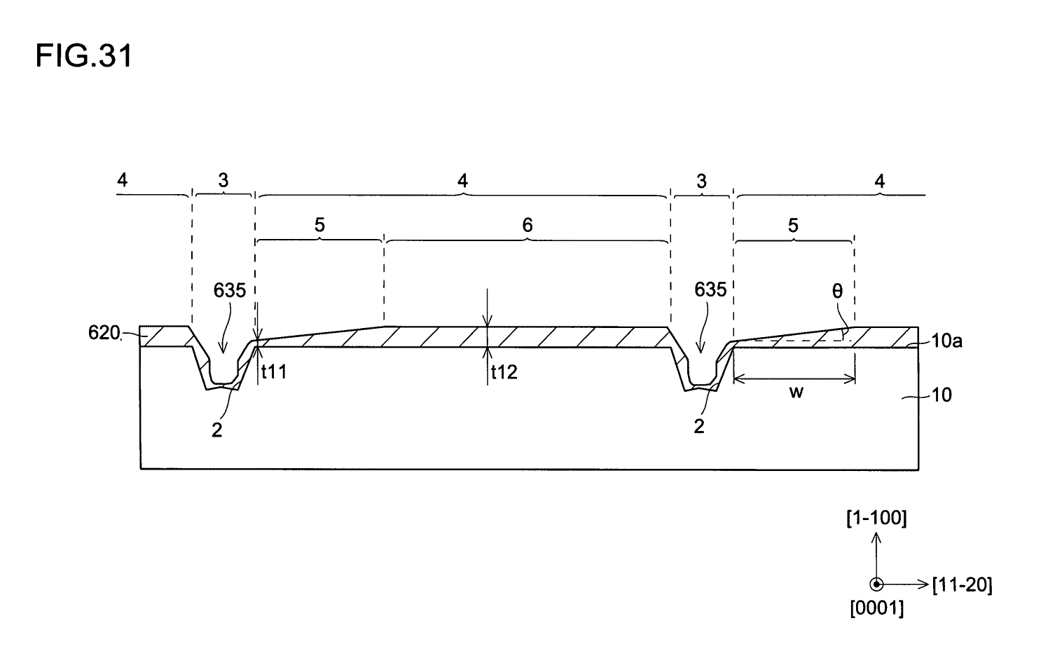

Furthermore, in Embodiment 6, as shown in FIGS. 27 and 31, as a result of the nitride semiconductor layer 620 being formed on the principal growth plane 10a of the n-type GaN substrate 10, in the nitride semiconductor layer 620 over the uncarved region 4, a gradient thickness region 5 is formed whose thickness decreases in a gradient fashion (gradually) toward the depressed portion 2 (carved region 3). As shown in FIGS. 31 to 34, the gradient thickness region 5 is formed in a region closely on one (for example, right) side of the depressed portion 2 (carved region 3), substantially in the shape of a band extending in the direction parallel to the depressed portion 2 (carved region 3). The gradient thickness region 5 too serves to alleviate strain in the nitride semiconductor layer 620 such as results from lattice mismatch with the n-type GaN substrate 10.

Thus, owing to the double strain alleviating effect by the concavity 635 formed in the surface of the nitride semiconductor layer 620 and by the gradient thickness region 5 formed in the nitride semiconductor layer 620 over the uncarved region 4, the nitride semiconductor wafer 650 according to Embodiment 6 offers a very powerful effect of suppressing cracks. In addition, the use of the n-type GaN substrate 10 having as the principal growth plane 10a a plane having an off-angle in the a-axis direction relative to the m plane gives the nitride semiconductor layer 620 formed on the principal growth plane 10a good crystallinity. This makes a crack unlikely to develop in the nitride semiconductor layer 620. Thus, development of cracks is suppressed even in the n-type clad layer 621, where a crack is extremely likely to develop. Needless to say, development of cracks is suppressed in the other individual nitride semiconductor layers than the n-type clad layer 621 as well.

In a case where the n-type GaN substrate 10 is used that has as the principal growth plane 10a a plane having an off-angle in the a-axis direction relative to the m plane and that has the depressed portion 2 (carved region 3) formed in it, the gradient thickness region 5 is formed in a region on one (for example, right) side of the depressed portion 2 (carved region 3) (in a region close to the depressed portion 2). The reason is considered to be as follows: due to the principal growth plane 10a of the n-type GaN substrate 10 having an off-angle in the a-axis direction relative to the m plane, the direction of the flow of source material atoms changes so as to be aligned with the a axis, and moreover the flow of source material atoms is split by the depressed portion 2 (carved region 3), with the result that the supply of source material atoms is reduced in a region in the uncarved regions 4 closely on one side of the depressed portion 2 (carved region 3). Whether the gradient thickness region 5 is formed on one (for example, right) side of the depressed portion 2 (carved region 3) or on the other (for example, left) side of the depressed portion 2 (carved region 3) depends on whether the off-angle in the a-axis direction is positive (+) or negative (−). This is considered to be because the direction of the flow of source material atoms changes according to whether the off-angle in the a-axis direction is positive (+) or negative (−). Whether the off-angle in the a-axis direction is positive (+) or negative (−) makes no difference from a crystallographic point of view, and this permits the off-angle in the a-axis direction to be discussed in terms of its absolute value. In a case where a GaN substrate having the c plane as the principal growth plane is used, even when a depressed portion (carved region) like that described above is formed, no gradient thickness region as described above is formed. Also, even with a GaN substrate having the m plane as the principal growth plane, if it has no off-angle in the a-axis direction, even when a depressed portion (carved region) like that described above is formed, no gradient thickness region as described above is formed. As will be described later, however, by forming a growth suppression film in the depressed portion 2 (carved region 3), it is possible to form a gradient thickness region.

As shown in FIG. 31, the gradient thickness region 5 in the nitride semiconductor layer 620 is thinnest at its part closest to the depressed portion 2 (carved region 3) and its thickness increases gradually (in a gradient fashion) away from the depressed portion 2 (carved region 3). In a part of the gradient thickness region 5 close to the depressed portion 2 (carved region 3), each layer involved, whether it is the n-type nitride semiconductor layer 620a (see FIG. 1) or the p-type nitride semiconductor layer 620b (see FIG. 1), is formed thinner. The thinnest part of the gradient thickness region 5 has a thickness t11 about one-half to two-thirds of the thickness t12 of the region (the emission portion formation region 6 described later) of the nitride semiconductor layer 620 over the uncarved region 4 other than the gradient thickness region 5. Depending on the growth conditions of the nitride semiconductor layer 620, however, the thickness may deviate from what has just been stated, which is intended simply as a rough criterion.

The width w of the gradient thickness region 5 (its width in the [11-20] direction) and the thickness gradient angle θ of the gradient thickness region 5 (the angle of the surface of the gradient thickness region 5 to the principal growth plane 10a of the n-type GaN substrate 10) are controlled by the off-angle in the a-axis direction. Specifically, the larger the off-angle in the a-axis direction, the smaller the width w of the gradient thickness region 5, and the larger the thickness gradient angle θ. Accordingly, in Embodiment 6, through adjustment of the off-angle in the a-axis direction, the width w of the gradient thickness region 5 is set at a predetermined width, and the thickness gradient angle θ is set at a predetermined angle. Too small an off-angle in the a-axis direction results in too large a width w of the gradient thickness region 5. On the other hand, the larger the thickness gradient angle θ, the more the thickness of the gradient thickness region 5 varies. Thus, for alleviation of stress in the nitride semiconductor layer 620, the larger the thickness gradient angle θ, the more preferable. Accordingly, with consideration given to the conditions for forming the gradient thickness region 5, it is preferable that the absolute value of the off-angle in the a-axis direction be 0.5 degrees or larger. In a case where the period R (see FIG. 28) of the depressed portions 2 is, for example, 400 μm, it is more preferable that, through adjustment of the off-angle in the a-axis direction, the width w of the gradient thickness region 5 be set to be 1 μm or more but 150 μm or less. Setting the width w of the gradient thickness region 5 to be 1 μm or more makes it possible to suppress the inconvenience of the effect of suppressing cracks being diminished due to the width w of the gradient thickness region 5 being less than 1 μm.

Since the gradient thickness region 5 is a region whose thickness varies, forming an emission portion (the ridge portion described later) there will make it difficult to suppress variations in characteristics. For this reason, the gradient thickness region 5 may be said to be a region unsuitable for formation of an emission portion (ridge portion).

On the other hand, the nitride semiconductor layer 620 over the uncarved region 4 has an emission portion formation region 6 where there is far less variation in thickness than in the gradient thickness region 5 and which is thus suitable for formation of an emission portion (ridge portion). That is, the nitride semiconductor layer 620 formed on the principal growth plane 10a of the n-type GaN substrate 10 includes, over the uncarved region 4, the gradient thickness region 5, which is unsuitable for formation of an emission portion (ridge portion), and the emission portion formation region 6, which is very uniformly thick and is suitable for formation of an emission portion (ridge portion). The effect of suppressing bright-spotted emission is weaker in the gradient thickness region 5 than in the emission portion formation region 6.

In Embodiment 6, the emission portion formation region 6 in the nitride semiconductor layer 620 has very good surface morphology. In the emission portion formation region 6, although there is very little variation in thickness overall, when a comparison is made between the variation in thickness in the c-axis [0001] direction and the variation in thickness in the a-axis [11-20] direction, the former is smaller than the latter.

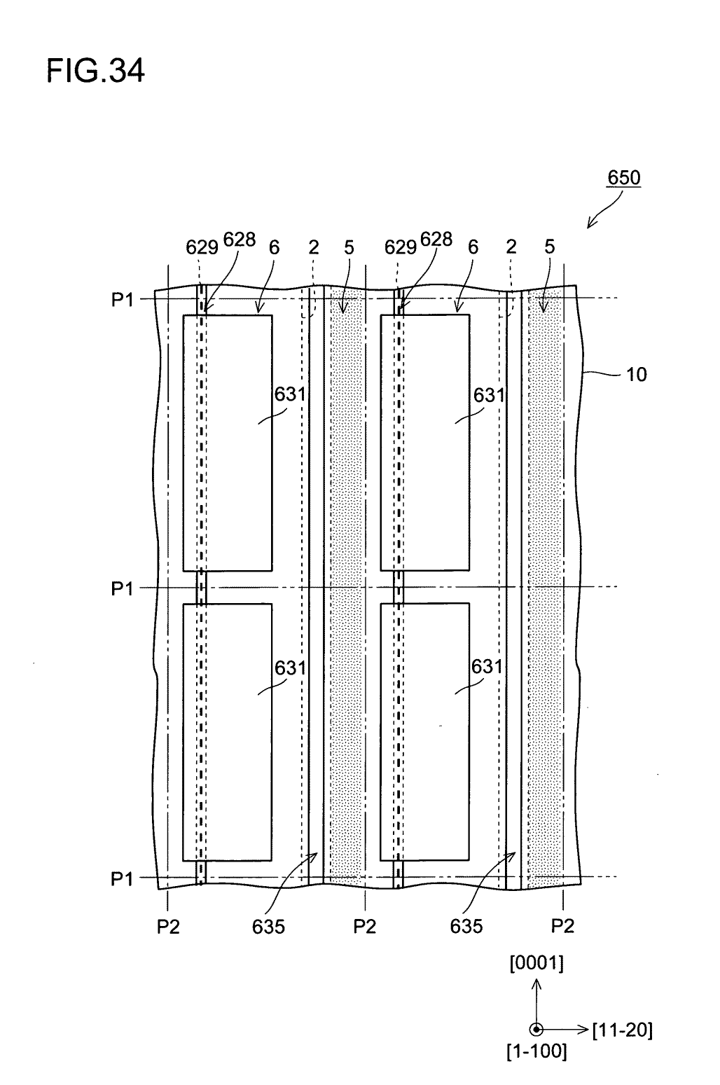

As shown in FIG. 27, in a predetermined region in the emission portion formation region 6 in the nitride semiconductor layer 620, a ridge portion 628 is formed that is an elevated portion serving as a current passage portion. As shown in FIG. 34, as seen in a plan view, such ridge portions 628 are formed to extend in the c-axis [0001] direction, in which there is less variation in thickness, and are arranged with a period of about 150 μm to 1200 μm (for example, about 400 μm) in the a-axis [11-20] direction. Thus, a plurality of ridge portions 628 are formed in the shape of stripes. With the ridge portions 628 so formed, in the nitride semiconductor layer 620, optical waveguide regions 629 (see FIGS. 27 and 34) serving as emission portions are formed in the shape of stripes. As shown in FIG. 27, the ridge portion 628 is formed in the emission portion formation region 6, away from the depressed portion 2 by a predetermined distance or more (for example, 5 μm or more). On the top face of the nitride semiconductor layer 620, and on both side faces of the ridge portion 628, an insulating layer 630 for current constriction is formed.

On the nitride semiconductor layer 620, a p-side electrode 631 for supplying electric current to the optical waveguide region 629 is formed. On the other hand, on the back face of the n-type GaN substrate 10, an n-side electrode 632 is formed.

As shown in FIG. 34, on the nitride semiconductor wafer 650, planned splitting lines P1 and P2 along which to split it into individual pieces of nitride semiconductor laser chips are set. As seen on a plan view, the planned splitting lines P1 are set to extend in the a-axis [11-20] direction; as seen on a plan view, the planned splitting lines P2 are set to extend in the c-axis [0001] direction. The planned splitting lines P2 are so set that each nitride semiconductor laser chip after the splitting includes one depressed portion 2 and at least part of a gradient thickness region 5.

The nitride semiconductor wafer 650 according to Embodiment 6 configured as described above is split along the planned splitting lines P1 and P2 into individual pieces of nitride semiconductor laser chips.

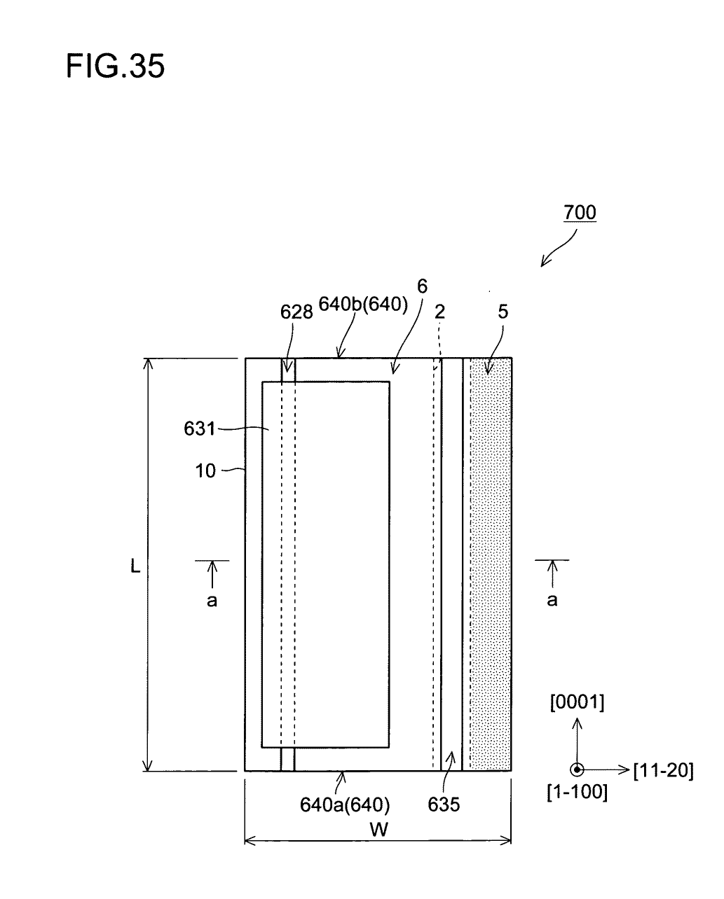

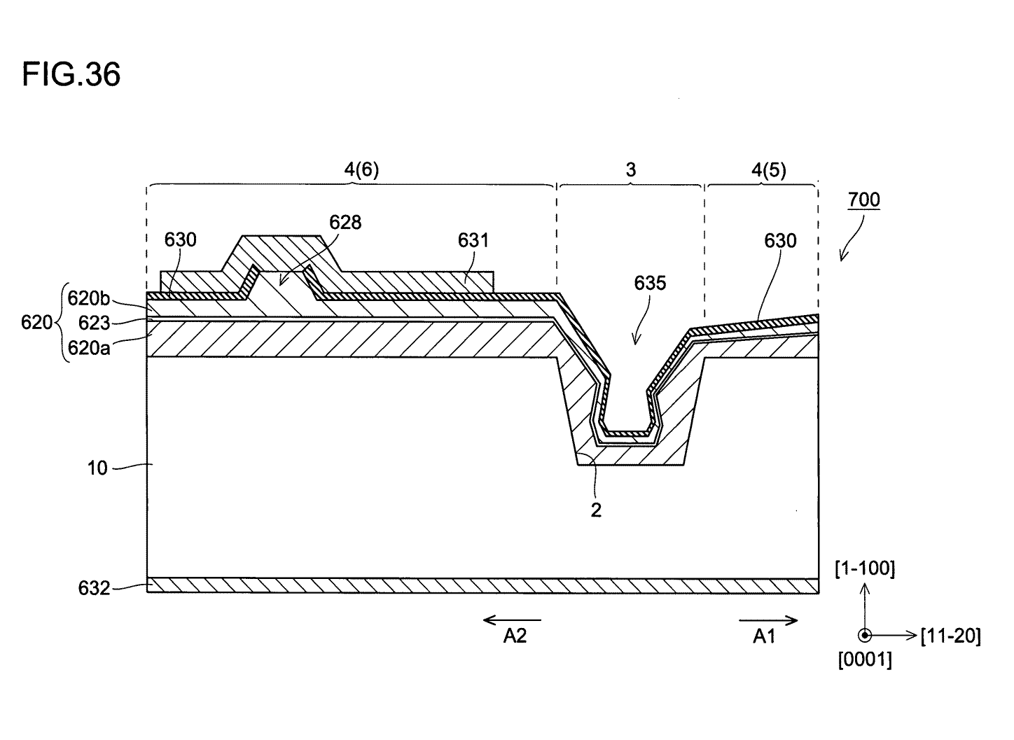

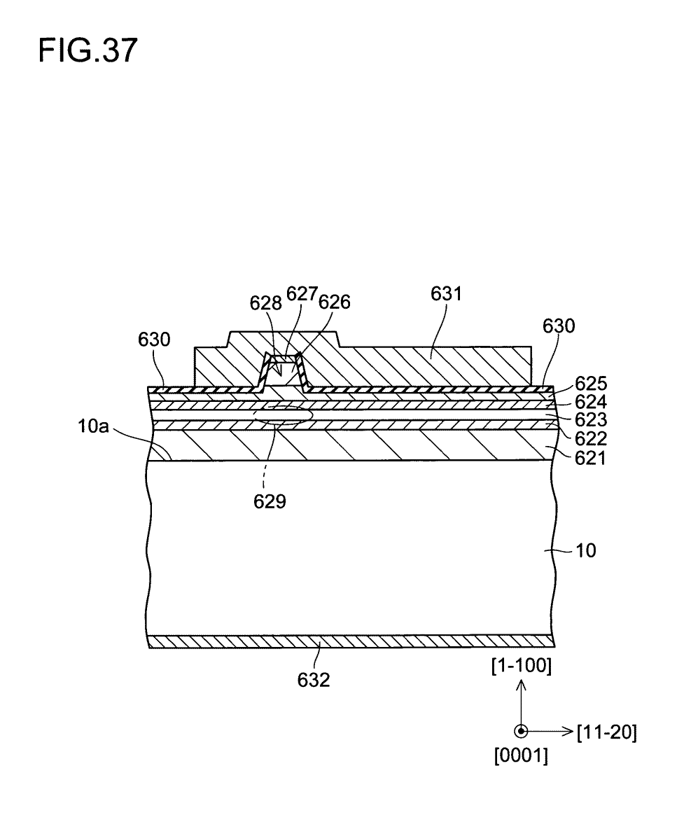

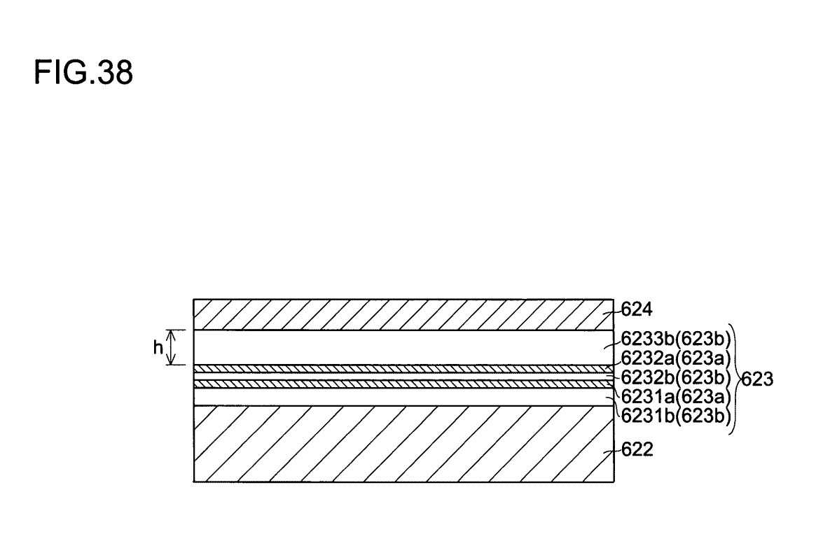

FIG. 35 is a plan view of a nitride semiconductor laser chip according to Embodiment 6 of the invention, and FIG. 36 is a sectional view schematically showing a nitride semiconductor laser chip according to Embodiment 6 of the invention. FIG. 37 is a sectional view showing part of a nitride semiconductor laser chip according to Embodiment 6 of the invention, and FIG. 38 is a sectional view illustrating the structure of an active layer in a nitride semiconductor laser chip according to Embodiment 6 of the invention. Next, with reference to FIGS. 35 to 38, a description will be given of a nitride semiconductor laser chip 700 according to Embodiment 6 of the invention. A nitride semiconductor laser chip 700 according to Embodiment 6 can be obtained from the nitride semiconductor wafer 650 according to Embodiment 6 described above; therefore, the following description deals with, as an example, a nitride semiconductor laser chip 700 obtained from the nitride semiconductor wafer 650 described above.

As shown in FIG. 35, the nitride semiconductor laser chip 700 according to Embodiment 6 has a pair of resonator (cavity) faces 640, which include a light emission face 640a through which laser light is emitted and a light reflection face 640b opposite from the light emission face 640a. The nitride semiconductor laser chip 700 has a length L (chip length L (resonator length L)) of about 300 μm to 1800 μm (for example, about 600 μm) in the direction (the c-axis [0001] direction) perpendicular to the resonator faces 640, and has a width W (chip width W) of about 150 μm to 1200 μm (for example, about 400 μm) in the direction (the a-axis [11-20] direction) along the resonator faces 640.

As shown in FIG. 36, the nitride semiconductor laser chip 700 according to Embodiment 6 is provided with an n-type GaN substrate 10 having as the principal growth plane 10a a plane having an off-angle in the a-axis direction relative to the m plane, and is formed by stacking, on the principal growth plane 10a of this n-type GaN substrate 10, a nitride semiconductor layer 620 including an n-type nitride semiconductor layer 620a, an active layer 623, and a p-type nitride semiconductor layer 620b.

Here, in Embodiment 6, the semiconductor layer in contact with the principal growth plane 10a of the n-type GaN substrate 10 is formed of a nitride semiconductor containing Al. Specifically, in the nitride semiconductor laser chip 700, as shown in FIG. 37, on the principal growth plane 10a of the n-type GaN substrate 10, an n-type clad layer 621 of Al_{0.06}Ga_{0.94}N with a thickness of about 2.2 μm is formed in contact with the principal growth plane 10a. The semiconductor layer in contact with the principal growth plane 10a of the n-type GaN substrate 10 may be, instead of an AlGaN layer, for example, an AlInGaN, AlInN, or like layer; it may even be other than a nitride semiconductor layer containing Al such as an AlGaN, AlInGaN, or like layer, for example an InGaN or InN layer.

On the n-type clad layer 621, an n-type guide layer 622 of In_{0.02}Ga_{0.98}N with a thickness of about 0.2 μm is formed. On the n-type guide layer 622, an active layer 623 is formed. Instead of the n-type guide layer 622, a non-doped guide layer may be formed.

As show in FIG. 38, the active layer 623 has a quantum well structure in which well layers 623a and barrier layers 623b are stacked alternately. In Embodiment 6, the active layer 623 has the barrier layers 623b formed of AlInGaN, which is a nitride semiconductor containing Al and In. Specifically, the active layer 623 has a quantum well (DQW, or double quantum well) structure in which two well layers 623a of InGaN (Inₓ₁Ga₁₋ₓ₁N) and three barrier layers 623b of AlInGaN are stacked alternately. More specifically, the active layer 623 is formed by successively stacking, in order from the n-type guide layer 622 side, a first barrier layer 6231b, a first well layer 6231a, a second barrier layer 6232b, a second well layer 6232a, and a third barrier layer 6233b. The two well layers 623a (the first and second well layers 6231a and 6232a) are each formed to have a thickness of about 3 nm to 4 nm. The first barrier layer 6231b is formed to have a thickness of about 30 nm, the second barrier layer 6232b is formed to have a thickness of about 16 nm, and the third barrier layer 6233b is formed to have a thickness of about 60 nm. Thus, the three barrier layers 623b are each formed to have a different thickness.

It is preferable that the first barrier layer 6231b be formed to have a thickness of 8 nm or more but 50 nm or less, and more preferably 10 nm or more but 40 nm or less. Forming the first barrier layer 6231b with a thickness of at least 8 nm or more in this way makes it possible to easily enhance the flatness of the first barrier layer 6231b, which is formed after the growth of the n-type guide layer 622. On the other hand, forming the first barrier layer 6231b with a thickness of 50 nm or less makes it possible to inject carriers efficiently. It is preferable that the second barrier layer 6232b be formed to have a thickness of 8 nm or more but 30 nm or less, and more preferably 10 nm or more but 20 nm or less. Forming the second barrier layer 6232b with a thickness of at least 8 nm or less in this way makes it possible to easily enhance the flatness of the second barrier layer 6232b, which is formed after the growth of the first well layer 6231a. On the other hand, forming the barrier layers 6232b with a thickness of 30 nm or less makes it possible to inject carriers efficiently. It is preferable that the third barrier layer 6233b be formed to have a thickness of 8 nm or more but 100 nm or less, and more preferably 10 nm or more but 80 nm or less. Forming the third barrier layer 6233b with a thickness of at least 8 nm or more makes it possible to easily enhance the flatness of the third barrier layer 6233b, which is formed after the growth of the second well layer 6232a and before the growth of the carrier block layer 624. On the other hand, forming the third barrier layer 6233b with a thickness of 100 nm or less makes it possible to inject carriers efficiently.

While two well layers are provided in Embodiment 6, in a case where more than two well layers are provided (for example, where three or four well layers are provided), the first barrier layer is defined to denote the first barrier layer formed under (on the substrate side of) the well layer nearest to the substrate. The second barrier layer is defined to be any barrier layer interposed between well layers. The third barrier layer is defined to be a barrier layer formed on the well layer (last well layer) farthest from the substrate. These definitions of the first, second, and third barrier layers make it possible to apply the above noted preferred thickness conditions even in cases where two or more well layers are formed. Fulfilling those conditions is preferable, because it is then possible to obtain the effects mentioned above.

In Embodiment 6, the well layers 623a (active layer 623) are so formed as to have an In composition ratio x1 of 0.15 or more but 0.45 or less (for example, 0.2 to 0.25). The barrier layers 623b are formed of AlₛInₜGaᵤN (s+t+u=1). The barrier layers 623b are so formed to have an Al composition ratio s of, for example, 0<s≦0.08 and an In composition ratio t of, for example, 0<t≦0.10. Giving the barrier layers 623b an Al composition ratio s of 0.08 or less is more preferable, because that makes it possible to achieve efficient light confinement. Forming the barrier layers 623b out of AlInGaN makes it possible to effectively suppress appearance of dark lines, which is peculiar to the m plane. Moreover, forming the barrier layers 623b out of AlInGaN, compared with forming them out of GaN or InGaN, makes it possible to enhance luminous efficacy. In particular, under the condition that the well layers 623a have an In composition ratio x1 of 0.15 or more but 0.45 or less, luminous efficacy tends to show a marked improvement.

Here, generally, a well layer is given, in its region with a high In composition ratio (x1≧0.15), a thickness of about 3 nm. The aim is to suppress development of misfit dislocations or the like as results from lattice mismatch with an increased In composition ratio. In a case where a nitride semiconductor layer containing Al (for example, an AlInGaN layer etc.) is formed as a barrier layer on a GaN substrate having an off angle in the a-axis direction relative to the m plane, however, the well layer may be given a thickness of 4.0 nm or more. The reason is considered to be that it is possible to obtain effects such as an effect of suppressing appearance of dark lines and an effect of protecting the active layer. Furthermore, the use of the above-described GaN substrate 10 enhances the flatness on the layer surface, and makes the In composition across the plane extremely uniform. Thus, even when the well layers are thick, they are less likely to suffer from formation of a local region with a high In composition. This too is considered to make it possible to form the well layers thick.

On the other hand, giving the well layers a thickness over 8 nm may cause a large number of misfit dislocations. Accordingly, it is preferable that the well layers be given a thickness of 8 nm or less. It is further preferable that their thickness be in a range of about 2.5 nm to 4.0 nm.

For similar reasons, in a case where the well layers are given a thickness in a range of about 1.5 nm to 4.0 nm, by forming the barrier layers out of a nitride semiconductor containing Al (for example, AlInGaN etc.), it is possible to increase the number of well layers For example, in a nitride semiconductor laser chip, in a case where a conventional active layer structure is adopted, forming three or more well layers greatly degrades luminous efficacy. On the other hand, when the barrier layers are formed of a nitride semiconductor containing Al, even in a case where five well layers are formed, degradation of luminous efficacy is suppressed. In a light-emitting diode chip (LED), when the barrier layers are formed of a nitride semiconductor containing Al, even in a case where eight well layers are formed, degradation of luminous efficacy is suppressed. Compared with semiconductor laser chips, light-emitting diode chips have thinner p-type semiconductor layers and incur less thermal damage to the active layer during formation of p-type semiconductor layers; for these reasons, it is easier to form the active layer (well layers) in multiple layers with light-emitting diode chips than with semiconductor laser chips.

A well layer in an active layer is formed to serve as a quantum well, and accordingly it may eventually have a varying thickness within a range of several nanometers or less or be localized into dots.

In a case where the barrier layers in the active layer are formed of a nitride semiconductor containing Al (for example, an AlInGaN, AlGaN, AlInN, or like layer), as described above, it is preferable that the well layers be formed of InGaN.

As shown in FIG. 37, on the active layer 623, a carrier block layer 624 is formed as a p-type semiconductor layer containing Al. The carrier block layer 624 is formed of p-type Al_{y}Ga_{1-y}N, and is given a thickness of 40 nm or less (for example, about 12 nm). The carrier block layer 624 is formed to have an Al composition ratio y of 0.08 or more but 0.35 or less (for example, about 0.15). On the carrier block layer 624, a p-type guide layer 625 of p-type In_{0.02}Ga_{0.98}N is formed which has an elevated portion and, elsewhere than there, a flat portion. On the elevated portion of the p-type guide layer 625, a p-type clad layer 626 of p-type Al_{0.05}Ga_{0.95}N with a thickness of about 0.5 μm is formed. On the p-type clad layer 626, a p-type contact layer 627 of p-type GaN with a thickness of about 0.1 μm is formed. Together the p-type contact layer 627, the p-type clad layer 626, and the elevated portion of the p-type guide layer 625 constitute a stripe-shaped (elongate) ridge portion 628 with a width of about 1 μm to 10 μm (for example, about 1.5 μm). As shown in FIG. 35, the ridge portion 628 is formed so as to extend in the c-axis [0001] direction.

As shown in FIG. 38, the distance h between the carrier block layer 624 and the well layers 623a (the most carrier block layer 624 side one of the well layers 623a (6232a)) is set to be about 60 nm for enhanced carrier injection efficiency. It is preferable that the distance h between the carrier block layer 624 and the well layers 623a be set at 80 nm or less, and more preferably 30 nm or less. In Embodiment 6, the distance h is equal to the thickness of the third barrier layer 6233b.

Setting the distance h between the carrier block layer 624 and the well layers 623a at 200 nm or more permits current to spread when carriers diffuse from the carrier block layer 624 to the active layer 623, and thus helps slightly suppress bright-spotted emission. On the other hand, by use of the above-described GaN substrate 10 having a principal growth plane 10a provided with an off-angle in the a-axis direction relative to the m plane, even when the distance h between the carrier block layer 624 and the well layers 623a is not set at 200 nm or more, it is possible to suppress bright-spotted emission effectively. For example, even when the distance h between the carrier block layer 624 and the well layers 623a is set at less than 120 nm, it is possible to suppress bright-spotted emission effectively. The smaller the distance h between the carrier block layer 624 and the well layers 623a, the more preferable, because that enhances the efficiency of carrier injection into the well layers 623a. Accordingly, by making the distance h between the carrier block layer 624 and the well layers 623a smaller than 120 nm, it is possible to enhance the efficiency of carrier injection into the well layers 623a.

Here, in the nitride semiconductor laser chip 700 according to Embodiment 6, as shown in FIG. 36, the depressed portion 2 (carved region 3) is formed in a predetermined region on the n-type GaN substrate 10. As seen in a plan view, the depressed portion 2 is formed to extend in a direction (the c-axis [0001] direction) parallel to the ridge portion 628 (optical waveguide region 629 (see FIG. 37)). Moreover, the depressed portion 2 is arranged on one side-surface side of the nitride semiconductor laser chip 700. In a region over the uncarved region 4 away from the depressed portion 2 by a predetermined distance or more (for example, 5 μm or more), the ridge portion 628 is formed.

In Embodiment 6, as described above, as a result of the depressed portion 2 (carved region 3) being formed in the principal growth plane 10a of the n-type GaN substrate 10, a concavity 635 is formed in the surface of the nitride semiconductor layer 620 (the surface of the individual layers constituting the nitride semiconductor layer 620) over the depressed portion 2 (carved region 3). This concavity 635 alleviates strain in the nitride semiconductor layer 620 such as results from lattice mismatch with the n-type GaN substrate 10.

Moreover, in Embodiment 6, as a result of the nitride semiconductor layer 620 being formed on the principal growth plane 10a of the n-type GaN substrate 10, in the nitride semiconductor layer 620 over the uncarved region 4, a gradient thickness region 5 and an emission portion formation region 6 are formed. The gradient thickness region 5 is formed on one side (A1 side) of the depressed portion 2 (carved region 3), and the emission portion formation region 6 is formed on the other side (A2 side) of the depressed portion 2 (carved region 3), that is, on the side thereof opposite from the gradient thickness region 5. The gradient thickness region 5 too serves to alleviate strain in the nitride semiconductor layer 620 such as results from lattice mismatch with the n-type GaN substrate 10.

Thus, owing to the double strain alleviating effect by the concavity 635 formed in the surface of the nitride semiconductor layer 620 and by the gradient thickness region 5 formed in the nitride semiconductor layer 620 over the uncarved region 4, the nitride semiconductor laser chip 700 according to Embodiment 6 offers a very powerful effect of suppressing cracks.

In addition, in Embodiment 6, the use of the n-type GaN substrate 10 having as the principal growth plane 10a a plane having an off-angle in the a-axis direction relative to the m plane gives the nitride semiconductor layer 620 formed on the principal growth plane 10a good crystallinity. Moreover, the use of the above-described n-type GaN substrate 10 gives the emission portion formation region 6 in the nitride semiconductor layer 620 very good surface morphology. This makes a crack unlikely to develop in the nitride semiconductor layer 620.

Accordingly, even when an AlGaN layer with a high Al composition, which greatly differs in lattice constant etc. from the n-type GaN substrate 10, is formed on the principal growth plane 10a, development of cracks is suppressed. Thus, development of cracks is suppressed in the nitride semiconductor layer 620 formed on the principal growth plane 10a of the n-type GaN substrate 10.

The ridge portion 628 is formed in a predetermined region in the emission portion formation region 6, which has good crystallinity and good surface morphology.

As shown in FIGS. 36 and 37, on each side of the ridge portion 628, an insulating layer 630 for current constriction is formed. Specifically, on top of the p-type guide layer 625, on the side faces of the p-type clad layer 626, and on the side faces of the p-type contact layer 627, an insulating layer 630 of SiO₂ with a thickness of about 0.1 μm to 0.3 μm (for example, about 0.15 μm) is formed.

On the top faces of the insulating layer 630 and of the p-type contact layer 627, a p-side electrode 631 is formed so as to cover part of the p-type contact layer 627. The p-side electrode 631, in its part covering the p-type contact layer 627, makes direct contact with the p-type contact layer 627. The p-side electrode 631 has a multiple-layer structure having the following layers stacked successively in order from the insulating layer 630 (p-type contact layer 627) side: a Pd layer (not shown) with a thickness of about 15 nm; a Pt layer (not shown) with a thickness of about 15 nm; and a Au layer (not shown) with a thickness of about 200 nm.

On the back face of the n-type GaN substrate 10, an n-side electrode 632 is formed, which has a multiple-layer structure having the following layers stacked successively in order from the n-type GaN substrate 10's back face side: a Hf layer (not shown) with a thickness of about 5 nm; an Al layer (not shown) with a thickness of about 150 nm; a Mo layer (not shown) with a thickness of about 36 nm; a Pt layer (not shown) with a thickness of about 18 nm; and a Au layer (not shown) with a thickness of about 200 nm.

In the nitride semiconductor laser chip 700, on the light emission face 640a (see FIG. 35), an emission-side coating (not shown) with a reflectance of, for example, 5% to 80% is formed. On the other hand, on the light reflection face 640b (see FIG. 35), a reflection-side coating (not shown) with a reflectance of, for example, 95% is formed. The reflectance of the emission-side coating is adjusted to be a desired value according to the laser output. The emission-side coating is composed of, in order from the semiconductor's emission facet side, for example, a film of aluminum oxynitride (oxide-nitride) or aluminum nitride AlOₓN₁₋ₓ (where 0≦x≦1) with a thickness of 30 nm, and a film of Al₂O₃ with a thickness of 215 nm. The reflection-side coating is composed of multiple-layered films of, for example, SiO₂, TiO₂, etc. Other than the materials just mentioned, films of dielectric materials such as SiN, ZrO₂, Ta₂O₅, MgF₂, etc. may be used.

The coating on the light emission face side may instead be composed of a film of AlOₓN₁₋ₓ (where 0≦x≦1) with a thickness of 12 nm, and a film of silicon nitride SiN with a thickness of 100 nm. By forming a film of aluminum oxynitride or aluminum nitride AlOₓN₁₋ₓ (where 0≦x≦1) on a cleaved facet (in Embodiment 6, the c plane), or an etched facet etched by vapor-phase etching or liquid-phase etching, of an m-plane nitride semiconductor substrate as described above, it is possible to greatly reduce the rate of non-radiative recombination at the interface between the semiconductor and the emission-side coating, and thereby to greatly improve the COD (catastrophic optical damage) level. More preferably, the film of aluminum oxynitride or aluminum nitride AlOₓN₁₋ₓ (where 0≦x≦1) has a crystal of the same hexagonal crystal system as the nitride semiconductor; further preferably, it is crystallized with its crystal axes aligned with those of the nitride semiconductor, because that further reduces the rate of non-radiative recombination and further improves the COD level. To increase the reflectance on the light emission face side, there may be formed, on the above-mentioned coating, stacked films having films of silicon oxide, aluminum oxide, titanium oxide, tantalum oxide, zirconium oxide, silicon oxide, etc. stacked together.

In Embodiment 6, by forming the barrier layers 623b out of AlInGaN, which is a nitride semiconductor containing Al and In, as described above, it is possible to almost completely suppress appearance of dark lines. This makes it possible to suppress a lowering in luminous efficacy resulting from appearance of dark lines. Moreover, by suppressing appearance of dark lines, it is possible to suppress degradation of luminous efficacy. This makes it possible to enhance device characteristics and reliability. It should be noted that, by suppressing appearance of dark lines, it is possible to obtain an emission pattern of uniform light emission, and thus to increase gain.

By using an AlInGaN layer in the barrier layers 623b, it is possible to obtain, in addition to an effect of suppressing appearance of dark lines, an effect of enhancing light confinement. Moreover, by forming the well layers 623a on the barrier layers 623b formed of AlInGaN, it is possible to greatly enhance the efficiency of In absorption into the well layers 623a. Thus, even with a low gas flow rate of In, it is possible to maintain a high In composition ratio. This makes it possible to enhance In absorption efficiency. Consequently, it is possible to achieve lengthening of the emission wavelength more effectively. It is also possible to reduce the consumption of source material gas (for example TMIn), which is advantageous in terms of cost.

In Embodiment 6, forming the well layers 623a out of AlInGaN, compared with forming them out of GaN or InGaN, helps enhance interface steepness, and thus helps make clear the satellite peak observed by X-ray diffraction measurement. This is considered to result from the Al and In contents in the barrier layers suppressing agglomeration and diffusion of In and suppressing thermal damage to the active layer 623.

In Embodiment 6, by forming the depressed portion 2 (carved region 3) in the n-type GaN substrate 10, it is possible to form a concavity in the surface of the nitride semiconductor layer 620 (the individual layers constituting the nitride semiconductor layer 620) over the depressed portion 2. As a result, even in a case where there is a large difference in lattice constant, thermal expansion coefficient, etc. between the n-type GaN substrate 10 and the nitride semiconductor layer 620, and as a result the nitride semiconductor layer 620 is strained, the strain in the nitride semiconductor layer 620 (the part of the nitride semiconductor layer 620 formed over the uncarved region 4) can be alleviated with the concavity formed in the surface of the nitride semiconductor layer 620 over the carved region 3. This makes it possible to effectively suppress development of cracks in the nitride semiconductor layer 620. Thus, with the above configuration, it is possible to obtain a nitride semiconductor laser chip 700 in which development of cracks is suppressed and which offers high reliability and superb device characteristics.

In Embodiment 6, by forming the depressed portion 2 (carved region 3) in the n-type GaN substrate 10, it is possible to effectively alleviate the strain in the active layer 623 resulting from the barrier layers 623b in the active layer 623 being formed of a nitride semiconductor containing Al (for example, AlInGaN). This makes it possible to suppress appearance of dark lines more effectively. Moreover, by forming the depressed portion 2 (carved region 3) in the n-type GaN substrate 10, it is possible to alleviate strain developing in the active layer 623. Thus, it is possible to suppress appearance and expansion of dark lines. This makes it possible to obtain a nitride semiconductor laser chip 700 with high luminance and high reliability.

In Embodiment 6, by taking as the principal growth plane 10a of the GaN substrate 10a plane having an off-angle in the a-axis direction relative to the m plane, it is possible to suppress a bright-spotted EL emission pattern and variations in wavelength across the plane. That is, with that configuration, it is possible to improve the EL emission pattern. This makes it possible to enhance the luminous efficacy of the nitride semiconductor laser chip. By enhancing luminous efficacy, it is possible to obtain a high-luminance nitride semiconductor laser chip 700. One reason that an effect of suppressing bright-spotted emission as described above is obtained is considered to be as follows: as a result of the principal growth plane 10a of the GaN substrate 10 having an off-angle in the a-axis direction relative to the m plane, when the active layer 623 (the well layers 623a) is grown on the principal growth plane 10a, the direction of migration of In atoms changes so that, even under conditions with a high In composition ratio (with a large supply of In), agglomeration of In is suppressed. Another reason is considered to be that the growth mode of the p-type semiconductor layers formed on the active layer 623 also changes so as to enhance the activation rate of Mg as a p-type impurity and reduce the resistance of the p-type semiconductor layers. Reducing the resistance of the p-type semiconductor layers makes uniform injection of current easier, and thus makes the EL emission pattern uniform.

In Embodiment 6, by suppressing a bright-spotted EL emission pattern, it is possible to make the EL emission pattern uniform, and thus it is possible to reduce the driving voltage. By suppressing a bright-spotted EL emission pattern, it is possible to enhance luminous efficacy, and this makes it possible to further enhance device characteristics and reliability. That is, with the above configuration, it is possible to easily obtain a nitride semiconductor laser chip 700 with superb device characteristics and high reliability.

In Embodiment 6, by taking as the principal growth plane 10a of the n-type GaN substrate 10a plane having an off-angle in the a-axis direction relative to the m plane, it is possible to give the nitride semiconductor layer 620 formed on the principal growth plane 10a good crystallinity. This makes a crack unlikely to develop in the nitride semiconductor layer 620. Moreover, with the above configuration, it is possible to give the nitride semiconductor layer 620 very good surface morphology, and thus it is possible to obtain a nitride semiconductor layer 620 with a uniform thickness. Thus, it is possible to suppress the inconvenience of the nitride semiconductor layer 620 having a locally thicker region due to the nitride semiconductor layer 620 being not uniformly thick. Since a crack is likely to develop in such a thicker region, by suppressing formation of a locally thicker region in the nitride semiconductor layer 620, it is possible to make a crack more unlikely to develop.

In Embodiment 6, by taking as the principal growth plane 10a a plane having an off-angle in the a-axis direction relative to the m plane, it is possible to enhance the flatness of the barrier layers 623b formed of a nitride semiconductor containing Al and In. Thus, by forming the well layers 623a on the barrier layers 623b with high flatness, it is possible to suppress a non-uniform distribution of In composition across the plane in the well layers 623a. In addition, it is also possible to enhance the crystallinity of the active layer 623 (well layers 623a). This makes it possible to further enhance luminous efficacy.

By forming the barrier layer 623 formed under (on the n-type GaN substrate 10 side of) the active layer 623a out of a nitride semiconductor containing Al (for example, AlₛInₜGaᵤN), and giving it an Al composition ratio s of 0<s≦0.08 and an In composition ratio t of 0<t≦0.10, it is possible to obtain, in addition to an effect of suppressing appearance of dark lines and an effect of protecting the active layer 623, an effect of enhancing the flatness of the barrier layers 623b. This makes it possible to enhance the luminous efficacy of the well layers 623a.

In Embodiment 6, by use of the n-type GaN substrate 10 provided with an off angle in the a-axis direction relative to the m plane, it is possible to make it more difficult to fill the inside of the depressed portion 2 with the nitride semiconductor layer 620. This makes it possible to easily form a concavity in the surface of the nitride semiconductor layer 620 over the depressed portion 2 (carved region 3). Consequently, it is possible to suppress development of cracks easily.

As described above, in Embodiment 6, it is possible to greatly enhance luminous efficacy, and thus it is possible to enhance device characteristics and reliability. This makes it possible to obtain a nitride semiconductor laser chip with superb device characteristics and high reliability. Moreover, it is possible to effectively suppress development of cracks, and thus it is possible to increase the number of acceptable chips obtained from a single wafer. This makes it possible to increase yields. Moreover, by suppressing development of cracks, it is possible to enhance chip reliability and chip characteristics. Furthermore, also by suppressing appearance of dark lines, it is possible to reduce variations in device characteristics, and thus it is possible to increase the number of chips having characteristics within the rated ranges. This too makes it possible to increase yields.

In Embodiment 6, in the nitride semiconductor layer 620 over the uncarved region 4, the gradient thickness region 5 is formed, whose thickness decreases in a gradient fashion (gradually) toward the depressed portion 2 (carved region 3), and this makes it possible to alleviate strain in the nitride semiconductor layer 620 also with the gradient thickness region 5. Thus, owing to the double strain alleviating effect by the concavity 635 formed in the surface of the nitride semiconductor layer 620 and by the gradient thickness region 5 formed in the nitride semiconductor layer 620 over the uncarved region 4, it is possible to obtain a very powerful effect of suppressing cracks. Thus, even in a case where, for satisfactory light confinement, an n-type clad layer 621 with a high Al composition ratio is formed, it can be formed easily with almost no crack developing. Moreover, it is possible, with the gradient thickness region 5, to effectively alleviate strain in the active layer 623, and thus it is possible to suppress appearance of dark lines more effectively. The reason that a powerful effect of suppressing cracks as described above is obtained is considered to be as follows: because the gradient thickness region is thin in the first place, it contains little strain itself; in addition, since its thickness varies gradually (in a gradient fashion), the strain is alleviated progressively, resulting in a more powerful effect of alleviating strain.

In Embodiment 6, with the configuration described above, it is possible to give the emission portion formation region 6 in the nitride semiconductor layer 620 very good surface morphology, and thus it is possible to reduce variations in chip characteristics. It is thus possible to increase the number of chips having characteristics within the rated ranges, and this too makes it possible to increase yields. Moreover, by enhancing surface morphology, it is also possible to enhance chip characteristics and reliability.

In Embodiment 6, by forming the depressed portion 2 (carved region 3) such that, as seen in a plan view, it extends in a direction parallel to the c-axis [0001] direction, it is possible to form the gradient thickness region 5 easily, and thus it is possible to obtain a powerful effect of alleviating strain easily.

In Embodiment 6, by making the absolute value of the off-angle in the a-axis direction in the n-type GaN substrate 10 larger than 0.1 degrees, it is possible to suppress a bright-spotted EL emission pattern and variations in wavelength easily while suppressing appearance of dark lines.

In a case where the principal growth plane 10a of the n-type GaN substrate 10 has an off angle also in the c-axis direction relative to the m plane, by making the off angle in the a-axis direction larger than the off angle in the c-axis direction, it is possible to suppress a bright-spotted EL emission pattern effectively. Specifically, with that configuration, it is possible to suppress the inconvenience of the effect of suppressing bright-spotted emission being diminished due to too large an off-angle in the c-axis direction. This makes it possible to enhance luminous efficacy easily. Moreover, in this case, by making the off angle in the c-axis direction larger than ±0.1 degrees, it is possible to suppress the inconvenience of the thickness of the nitride semiconductor layer 620 grown on the principal growth plane 10a varying due to the off-angle in the c-axis direction being smaller than ±0.1 degrees.

By making the absolute value of the off-angle in the a-axis direction in the n-type GaN substrate 10 equal to or larger than 0.5 degrees, it is possible to suppress the inconvenience of the gradient thickness region 5 being too large due to the absolute value of the off-angle in the a-axis direction being smaller than 0.5 degrees, and it is also possible to effectively suppress the inconvenience of a diminished effect of suppressing cracks (effect of alleviating strain) by the gradient thickness region 5.

In Embodiment 6, by giving the active layer 623 of the nitride semiconductor laser chip 700 a DQW structure, it is possible to reduce the driving voltage easily. This too makes it possible to enhance chip characteristics and reliability. Also when the active layer 623 is given a DQW structure, it is possible to suppress a bright-spotted EL emission pattern and to suppress appearance of dark lines.

In Embodiment 6, by giving the carrier block layer 624 formed of p-type Al_{y}Ga_{1-y}N an Al composition ratio y of 0.08 or more but 0.35 or less, it is possible to form an energy barrier sufficiently high with respect to carriers (electrons), and thus it is possible to more effectively prevent the carriers injected into the active layer 623 from flowing into the p-type semiconductor layers. This makes it possible to suppress a bright-spotted EL emission pattern effectively. By giving the carrier block layer 624 an Al composition ratio y of 0.35 or less, it is possible to suppress an increase in the resistance of the carrier block layer 624 due to the Al composition ratio y being too high. In a region with a high In composition ratio x1 (x1≧0.15) in the well layers 623a, an Al composition ratio y of 0.08 or more in the carrier block layer 624 formed on the active layer 623 makes it extremely difficult to grow the carrier block layer 624 satisfactorily. This is because, as the In concentration in the well layers 623a increases, the flatness of the surface of the active layer 623 deteriorates, and this makes it difficult to form a film with a high Al composition ratio y with good crystallinity. However, by use of the GaN substrate 10 having as the principal growth plane 10a a plane having an off-angle in the a-axis direction relative to the m plane, even in a case where the In composition ratio x1 in the active layer 623 (the well layers 623a) is 0.15 or more but 0.45 or less, it is possible to form on that active layer 623 a carrier block layer 624 with an Al composition ratio y of 0.08 or more but 0.35 or less with good crystallinity. This makes it possible to suppress a bright-spotted EL emission pattern effectively and make the EL emission pattern even.

It is more preferable that the barrier layer 623b (for example, in Embodiment 6, the third barrier layer 6233b) between the carrier block layer 624 and the well layers 623a be formed of a nitride semiconductor layer containing Al and In. The carrier block layer 624 is formed with a higher Al composition ratio than the barrier layer 623b, and thus stress from the carrier block layer 624 acts on the well layer 623a. Thus, by forming the barrier layer 623b between the carrier block layer 624 and the well layers 623a to contain In, it is possible to alleviate stress. Moreover, the barrier layer 623b between the carrier block layer 624 and the well layers 623a may be so formed as to partly contain AlInGaN. Furthermore, the barrier layer 623b between the carrier block layer 624 and the well layers 623a may be given a two-layer structure such as AlGaN/AlInGaN, AlInGaN/AlGaN, or AlInGaN/InGaN, or a multiple-layer structure such as AlInGaN/AlGaN/AlInGaN, AlInGaN/InGaN/AlInGaN, AlGaN/InGaN/AlGaN, or the like. From the viewpoint of the above-mentioned alleviation of stress, the barrier layer 623b between the carrier block layer 624 and the well layers 623a may be InGaN. By forming the barrier layer 623b in that way, it is possible to effectively suppress appearance of dark lines.

Here, the effect of suppressing appearance of dark lines, which is obtained by forming a barrier layer out of a nitride semiconductor layer containing Al and In, is an utterly different one from the effect of suppressing bright-spotted emission, which is obtained by use of a nitride semiconductor substrate having as the principal growth plane a plane having an off angle in the a-axis direction relative to the m plane. Specifically, using a nitride semiconductor layer containing Al and In as a barrier layer is effective with a non-polar plane such as the m plane; on the other hand, even in a case where a barrier layer of InGaN is used, by providing an off angle in the a-axis direction, it is possible to suppress a bright-spotted EL emission pattern.

However, forming a nitride semiconductor layer containing Al and In on a nitride semiconductor substrate having an off angle in the a-axis direction offers an effect of enhancing crystallinity etc., and thus using a nitride semiconductor substrate having an off angle in the a-axis direction and in addition using a nitride semiconductor layer containing Al and In as a barrier layer enhances the crystallinity of the barrier layer. Combining the two designs in this way is thus more preferable, because doing so brings about an effect of synergy. Needless to say, using a nitride semiconductor substrate having an off angle in the a-axis direction and in addition using a nitride semiconductor layer containing Al and In in a barrier layer makes it possible to suppress appearance of dark lines and in addition to suppress bright-spotted emission.

In a case where a nitride semiconductor layer containing Al and In is used as a barrier layer, by use of a non-polar substrate, such as an m-plane substrate, having a carved region formed in it, it is possible to effectively alleviate strain acting on the active layer. It is thus possible to suppress appearance and expansion of dark lines effectively.

By forming a carved region in an m-plane substrate having an off angle in the a-axis direction, it is possible to form a gradient thickness region. With this gradient thickness region, it is possible to suppress development of cracks more effectively. Needless to say, it is possible to obtain an effect of suppressing a bright-spotted EL emission pattern as well.

By forming a carved region in an m-plane substrate having an off angle in the a-axis direction and, during formation of a light-emitting chip by use of that substrate, forming a barrier layer in the active layer out of a nitride semiconductor containing Al and In, it is possible to obtain an effect of suppressing appearance of dark lines, an effect of suppressing bright-spotted emission, and an effect of suppressing development of cracks. This is thus more preferable, because it is then possible to suppress appearance and expansion of dark lines more effectively.

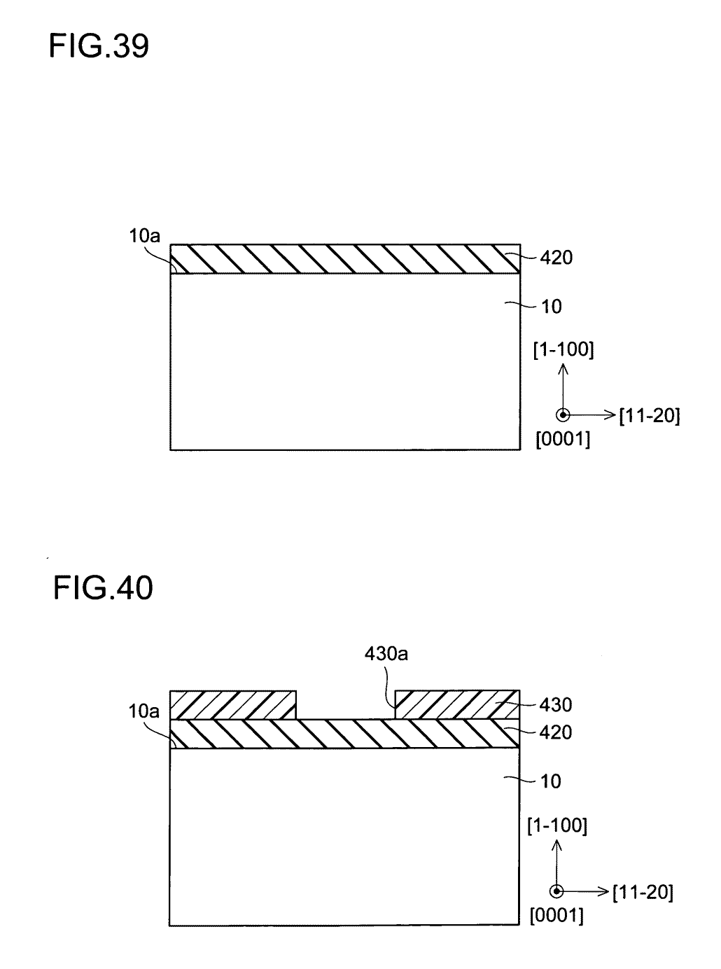

FIGS. 39 to 51 are diagrams illustrating a method of manufacture of a nitride semiconductor laser chip according to Embodiment 6 of the invention. Next, with reference to FIGS. 27, 31 to 34, and 38 to 51, a method of manufacture of the nitride semiconductor laser chip 700 according to Embodiment 6 of the invention will be described.

First, an n-type GaN substrate 10 having as a principal growth plane 10a a plane having an off-angle relative to the m plane is prepared. This n-type GaN substrate 10 can be fabricated by a method similar to that in Embodiment 1 described previously.

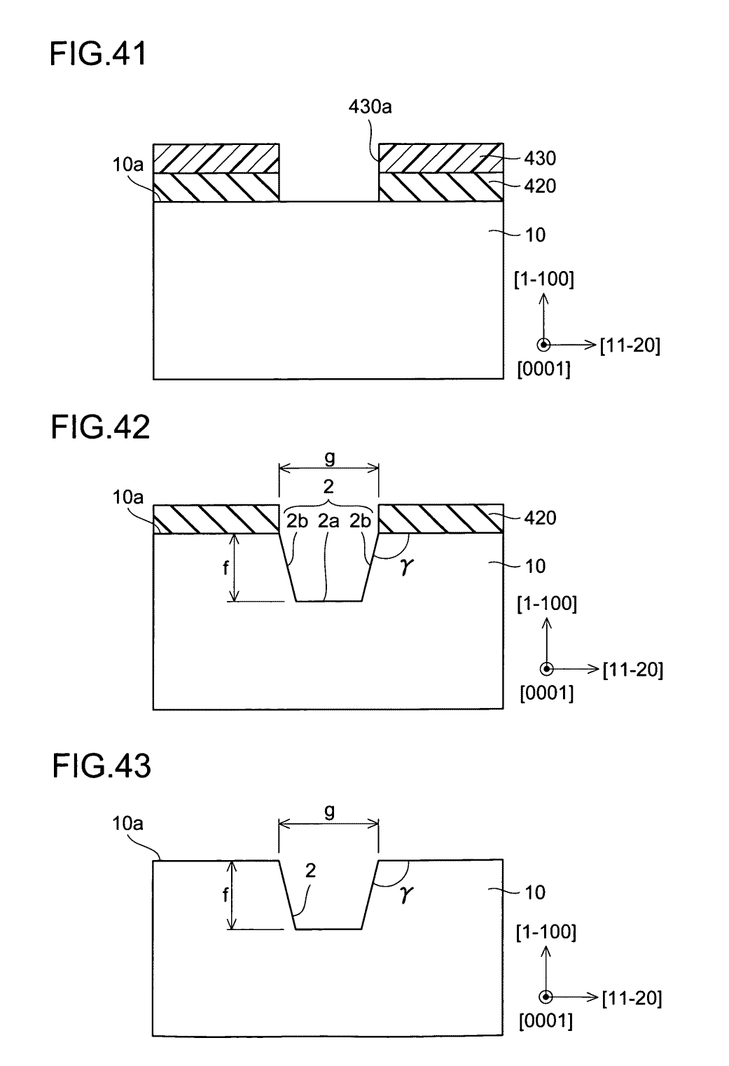

Next, as shown in FIG. 39, over the entire top face (principal growth plane 10a) of the n-type GaN substrate 10 obtained, by a sputtering process or the like, a SiO₂ layer 420 with a thickness of about 1 μm is formed. Next, as shown in FIG. 40, by use of a photolithography technology, on the SiO₂ layer 420, a resist layer 430 having an opening 430a as a resist pattern is formed. Then, as shown in FIG. 41, by use of a dry etching technology such as RIE (reactive ion etching), and with the resist layer 430 used as a mask, the SiO₂ layer 420 is etched so as to selectively remove a predetermined region of the SiO₂ layer 420. Thereafter, by use of a resist removal liquid or organic solvent (for example, acetone, ethanol, etc.), the resist layer 430 is removed. An advance to the next process may be made without removing the resist layer 430.

Subsequently, as shown in FIG. 42, by an ICP (inductively coupled plasma) process, or by a RIE process or the like, and with the SiO₂ layer 420 used as a mask, the n-type GaN substrate 10 is etched so as to selectively remove a predetermined region of the n-type GaN substrate 10. At this time, the etching conditions are so adjusted that the etched depth f of the n-type GaN substrate 10 is about 5 μm. In this way, in the n-type GaN substrate 10, the depressed portion 2 (carved region 3) described above is formed so as to extend in a direction parallel to the c-axis direction. By adjusting the etching conditions or the like, the side surface portions 2b of the depressed portion 2 are so formed that their inclination angle γ is equal to a predetermined angle larger than 90 degrees.

Thereafter, as shown in FIG. 43, by use of an etchant such as HF (hydrogen fluoride), the SiO₂ layer 420 (see FIG. 42) is removed.

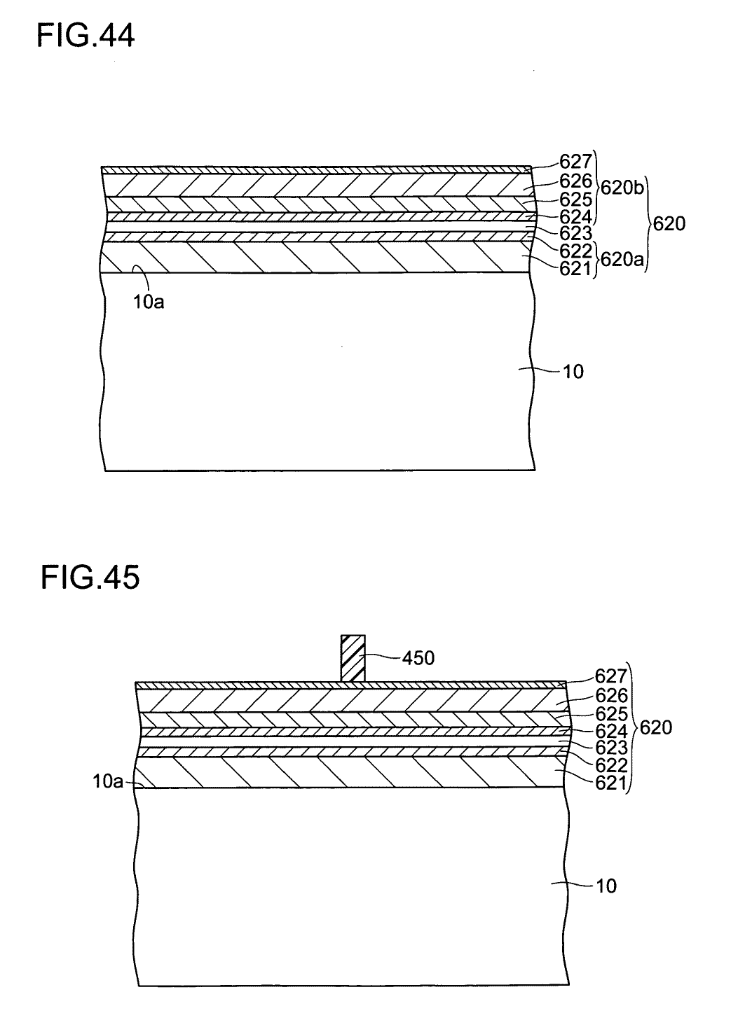

Next, as shown in FIG. 44, on the principal growth plane 10a of the n-type GaN substrate 10 (processed substrate) processed as described above, individual nitride semiconductor layers 621 to 627 are grown by an epitaxial growth process such as an MOCVD process. Specifically, on the principal growth plane 10a of the n-type GaN substrate 10, the following layers are grown successively: an n-type clad layer 621 of n-type Al_{0.06}Ga_{0.94}N with a thickness of about 2.2 μm; an n-type guide layer 622 of n-type In_{0.02}Ga_{0.98}N with a thickness of about 0.2 μm; and an active layer 623. When the active layer 623 is grown, as shown in FIG. 38, two well layers 623a of InGaN (Inₓ₁Ga₁₋ₓ₁N) and three barrier layers 623b of AlInGaN (AlₛInₜGaᵤN (s+t+u=1)) are alternately grown. Specifically, on the n-type guide layer 622, the following layers are grown successively from bottom up: a first barrier layer 6231b with a thickness of about 30 μm; a first well layer 6231a with a thickness of about 3 nm to 4 nm; a second barrier layer 6232b with a thickness of about 16 nm; a second well layer 6232a with a thickness of about 3 nm to 4 nm; and a third barrier layer 6233b with a thickness of about 60 nm. In this way, on the n-type guide layer 622, an active layer 623 having a DQW structure composed of two well layers 623a and three barrier layers 623b is formed. At this time, the well layers 623a are so formed that the In composition ratio X1 is 0.15 or more but 0.45 or less (for example, 0.2 to 0.25). On the other hand, the barrier layers 623b are so formed that the Al composition ratio s is, for example, 0<s≦0.08 and that the In composition ratio is, for example, 0<t≦0.10.

Next, as shown in FIG. 44, on the active layer 623, the following layers are grown successively: a carrier block layer 624 of p-type Al_{y}Ga_{1-y}N; a p-type guide layer 625 of p-type In_{0.02}Ga_{0.98}N with a thickness of about 0.05 μm; a p-type clad layer 626 of p-type Al_{0.06}Ga_{0.94}N with a thickness of about 0.5 μm; and a p-type contact layer 627 of p-type GaN with a thickness of about 0.1 μm. At this time, it is preferable that the carrier block layer 624 be formed so as to have a thickness of 40 nm or less (for example, about 12 nm). Moreover, the carrier block layer 624 is so formed that the Al composition ratio y there is 0.08 or more but 0.35 or less (for example, about 0.15). The n-type nitride semiconductor layer 620a (the n-type clad layer 621 and the n-type guide layer 622) are doped with, for example, Si as an n-type impurity, and the p-type nitride semiconductor layer 620b (the carrier block layer 624, the p-type guide layer 625, the p-type clad layer 626, and the p-type contact layer 627) are doped with, for example, Mg as a p-type impurity.

In Embodiment 6, the n-type nitride semiconductor layer 620a is formed at a growth temperature of 900° C. or higher but lower than 1300° C. (for example, 1075° C.). The well layers 623a in the active layer 623 are formed at a growth temperature of 600° C. or higher but 770° C. or lower (for example, 700° C.). The barrier layers 623b, which are contiguous with the well layers 623a, may be formed at the same growth temperature (for example, 700° C.) as the well layers 623a. The barrier layers 623b, which are nitride semiconductor layers containing Al, may be formed at a higher temperature than the well layers 623a. The growth temperature of the barrier layers 623b is preferably 600° C. or higher but 900° C. or lower. The p-type nitride semiconductor layer 620b is formed at a growth temperature of 700° C. or higher but lower than 900° C. (for example, 880° C.). The growth temperature of the n-type nitride semiconductor layer 620a is preferably 900° C. or higher but lower than 1300° C., and more preferably 1000° C. or higher but lower than 1300° C. The growth temperature of the well layers 623a in the active layer 623 is preferably 600° C. or higher but 830° C. or lower, and in a case where the In composition ratio x1 in the well layers 623a is 0.15 or more, preferably 600° C. or higher but 770° C. or lower; more preferably, 630° C. or higher but 740° C. or lower. The growth temperature of the barrier layers 623b in the active layer 623 is preferably the same as or higher than that for the well layers 623a. The growth temperature of the p-type nitride semiconductor layer 620b is preferably 700° C. or higher but lower than 900° C., and more preferably 700° C. or higher but 880° C. or lower. Needless to say, since even forming the p-type nitride semiconductor layer 620b at a temperature of 900° C. or higher gives p-type conductivity, the p-type nitride semiconductor layer 620b may be formed at a temperature of 900° C. or higher.

As source materials for the growth of these nitride semiconductors, for example, the following materials can be used: as a source material of Ga, trimethylgallium ((CH₃)₃Ga; TMGa); as a source material of Al, trimethylaluminium ((CH₃)₃Al; TMAl); as a source material of In, trimethylindium ((CH₃)₃In; TMIn); as a source material of N, NH₃. As a carrier gas, for example, H₂ can be used. As for dopants, as an n-type dopant (n-type impurity), for example, monosilane (SiH₄) can be used; as a p-type dopant (p-type impurity), for example, cyclopentadienylmagnesium (CP₂Mg) can be used.

Here, in Embodiment 6, as shown in FIG. 27, the principal growth plane 10a of the n-type GaN substrate 10 is a plane having an off-angle in the a-axis direction relative to the m plane, and this makes it difficult to fill the inside of the depressed portion 2 with the nitride semiconductor layer 620. As a result, when the nitride semiconductor layer 620 is formed on the n-type GaN substrate 10, a concavity 635 is easily formed in the surface of the nitride semiconductor layer 620 (on the surface of the individual layers constituting the nitride semiconductor layer 620) over the depressed portion 2 (carved region 3). This concavity 635 alleviates strain in the nitride semiconductor layer 620 such as results from lattice mismatch with the n-type GaN substrate 10.

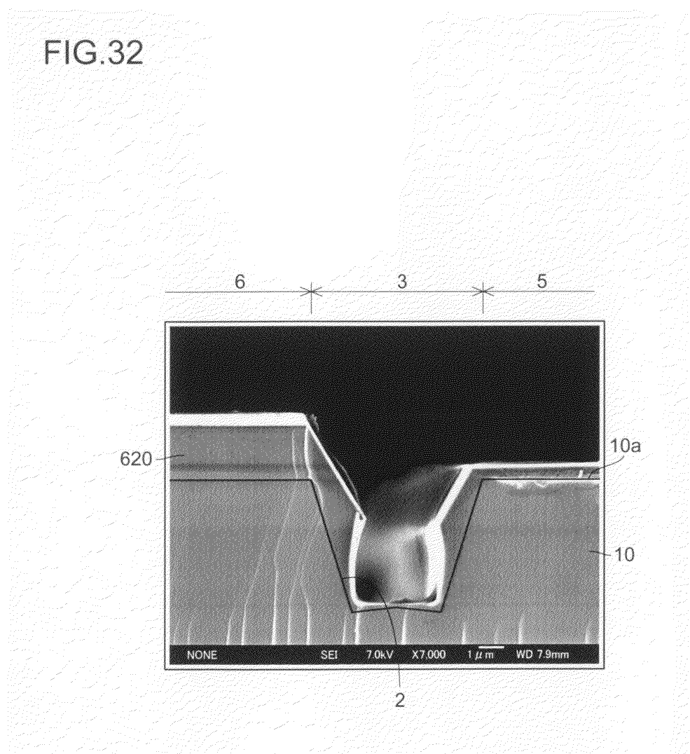

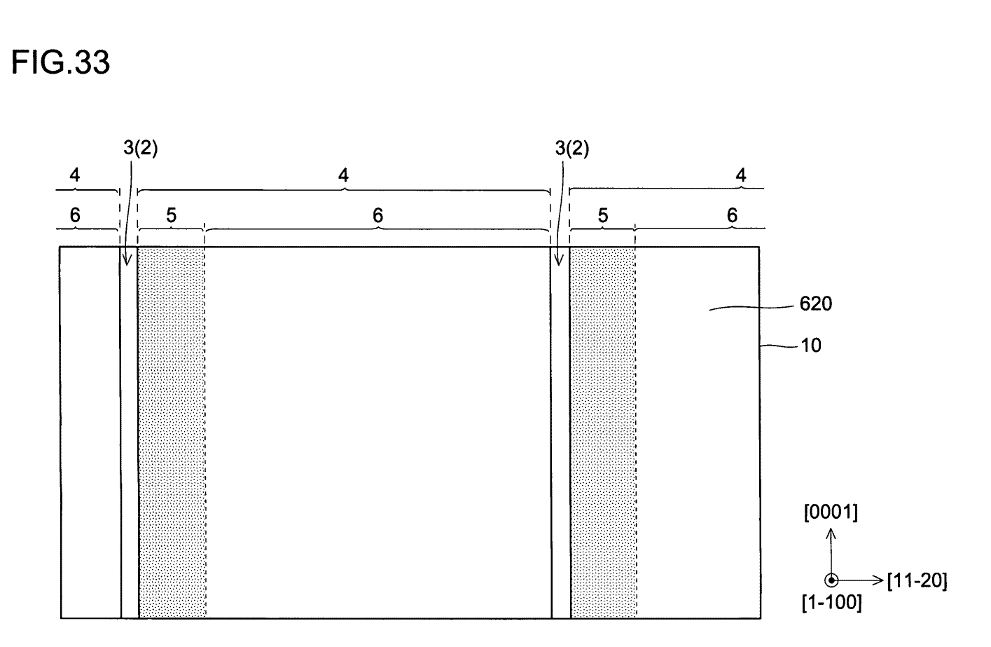

Moreover, in Embodiment 6, as shown in FIGS. 31 and 32, as a result of the nitride semiconductor layer 620 being formed on the principal growth plane 10a of the above-described n-type GaN substrate 10, in the nitride semiconductor layer 620 over the uncarved region 4, a gradient thickness region 5 is formed whose thickness decreases in a gradient fashion (gradually) toward the depressed portion 2 (carved region 3). As shown in FIG. 33, the gradient thickness region 5 is formed in a region closely on one (for example, right) side of the depressed portion 2 (carved region 3), substantially in the shape of a band extending in the direction parallel to the depressed portion 2 (carved region 3). This gradient thickness region 5 too serves to alleviate strain in the nitride semiconductor layer 620 such as results from lattice mismatch with the n-type GaN substrate 10.

Thus, with the method of manufacture of a nitride semiconductor laser chip according to Embodiment 6, owing to the double strain alleviating effect by the concavity 635 formed in the surface of the nitride semiconductor layer 620 and by the gradient thickness region 5 formed in the nitride semiconductor layer 620 over the uncarved region 4, it is possible to obtain a very powerful effect of suppressing cracks.

Furthermore, in Embodiment 6, using as the principal growth plane 10a of the n-type GaN substrate 10 a plane having an off-angle in the a-axis direction relative to the m plane gives the nitride semiconductor layer 620 formed on the principal growth plane 10a good crystallinity. Moreover, using the above-described n-type GaN substrate 10 gives the emission portion formation region 6 in the nitride semiconductor layer 620 very good surface morphology. This makes a crack unlikely to develop in the nitride semiconductor layer 620.

Accordingly, even when an AlGaN layer with a high Al composition, which greatly differs in lattice constant etc. from the n-type GaN substrate 10, is formed on the principal growth plane 10a, development of cracks is suppressed. Thus, a nitride semiconductor layer 620 in which development of cracks is suppressed is formed on the principal growth plane 10a of the n-type GaN substrate 10.

Moreover, in the nitride semiconductor layer 620 over the uncarved region 4, an emission portion formation region 6 is formed whose thickness varies far less than that of the gradient thickness region 5 and which is suitable for formation of an emission portion (ridge portion 628). The emission portion formation region 6 has very good surface morphology, and its thickness varies very little.

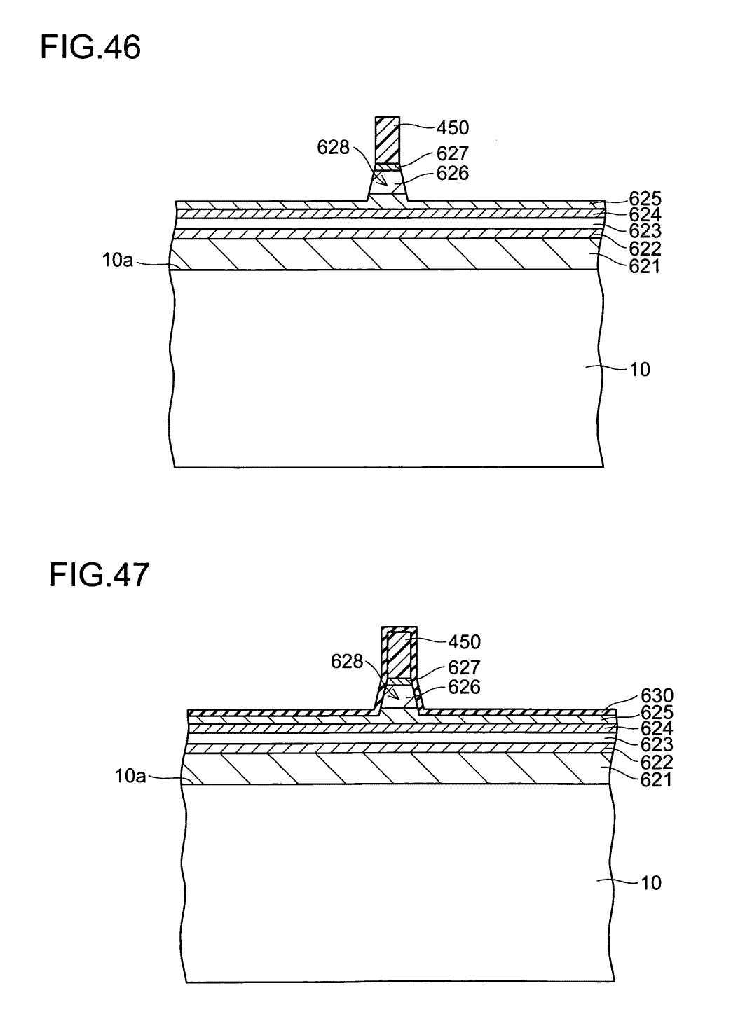

Subsequently, as shown in FIG. 45, by use of a photolithography technology, on the p-type contact layer 627 in the emission portion formation region 6 (see FIGS. 31 and 32), a stripe-shaped (elongate) resist layer 450 is formed that has a width of about 1 μm to 10 μm (for example, about 1.5 μm) and that extends in the c-axis [0001] direction. Then, as shown in FIG. 46, by a RIE process using chlorine-based gas such as SiCl₄ or Cl₂ or Ar gas, and with the resist layer 450 used as a mask, etching is performed halfway into the depth of (meaning, so as to leave a small part of, and thus not to completely penetrate) the p-type guide layer 625. In this way, a stripe-shaped (elongate) ridge portion 628 (see FIGS. 34 and 46) is formed which is constituted by an elevated portion of the p-type guide layer 625, the p-type clad layer 626, and the p-type contact layer 627 and which extends in the c-axis [0001] direction, with each ridge portion 628 parallel to another.

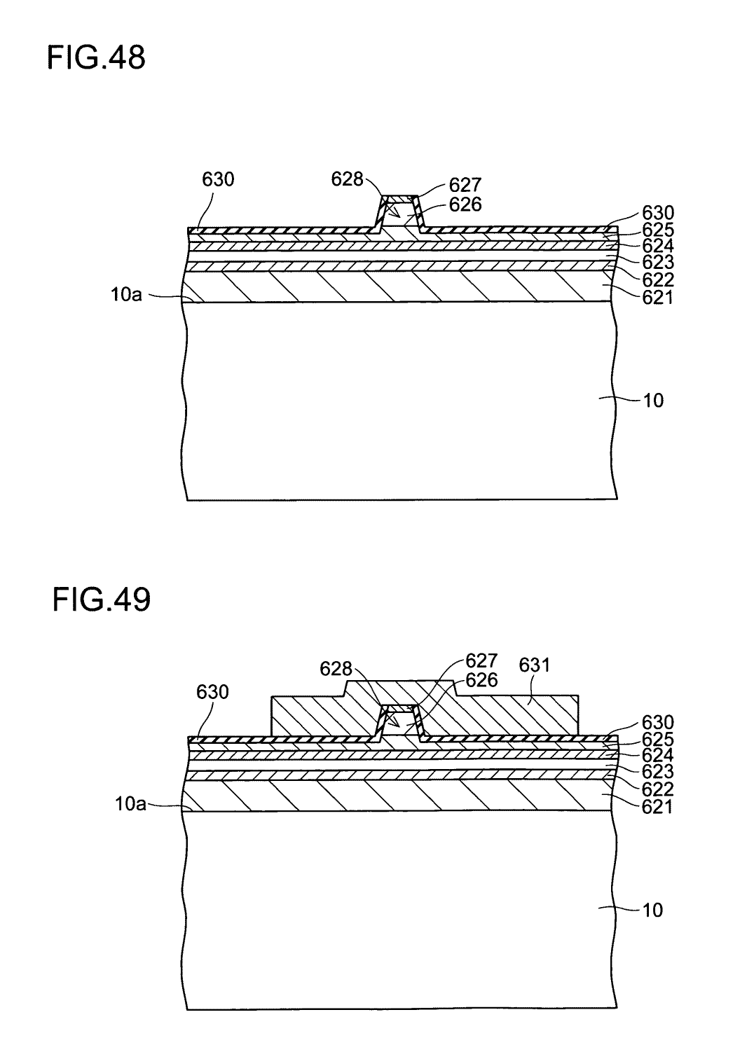

Next, as shown in FIG. 47, with the resist layer 450 left on the ridge portion 628, by a sputtering process or the like, an insulating layer 630 of SiO₂ with a thickness of about 0.1 μm to 0.3 μm (for example, about 0.15 μm) is formed to bury the ridge portion 628. Then, the resist layer 450 is removed by lift-off so that the p-type contact layer 627 at the top of the ridge portion 628 is exposed. In this way, on each side of the ridge portion 628, an insulating layer 630 as shown in FIG. 48 is formed.

Next, as shown in FIG. 49, by a vacuum deposition process or the like, the following layers are formed successively from the substrate side (the insulating layer 630 side): a Pd layer (not shown) with a thickness of about 15 μm; and a Au layer (not shown) with a thickness of about 200 nm. In this way, on the insulating layer 630 (the p-type contact layer 627), a p-side electrode 631 having a multiple-layer structure is formed.

Next, to make the substrate easy to split, the back face of the n-type GaN substrate 10 is ground or polished until the thickness of the n-type GaN substrate 10 is reduced to about 100 μm. Thereafter, as shown in FIG. 27, on the back face of the n-type GaN substrate 10, by a vacuum deposition process or the like, the following layers are formed successively from the n-type GaN substrate 10's back face side: a Hf layer (not shown) with a thickness of about 5 nm; an Al layer (not shown) with a thickness of about 150 nm; a Mo layer (not shown) with a thickness of about 36 nm; a Pt layer (not shown) with a thickness of about 18 nm; and a Au layer (not shown) with a thickness of about 200 nm. In this way, an n-side electrode 632 having a multiple-layer structure is formed. Before the n-side electrode 632 is formed, dry etching or wet etching may be performed for the purpose of, for example, adjusting the n-side electrical characteristics.

In this way, the nitride semiconductor wafer 650 according to Embodiment 6 described above is formed.

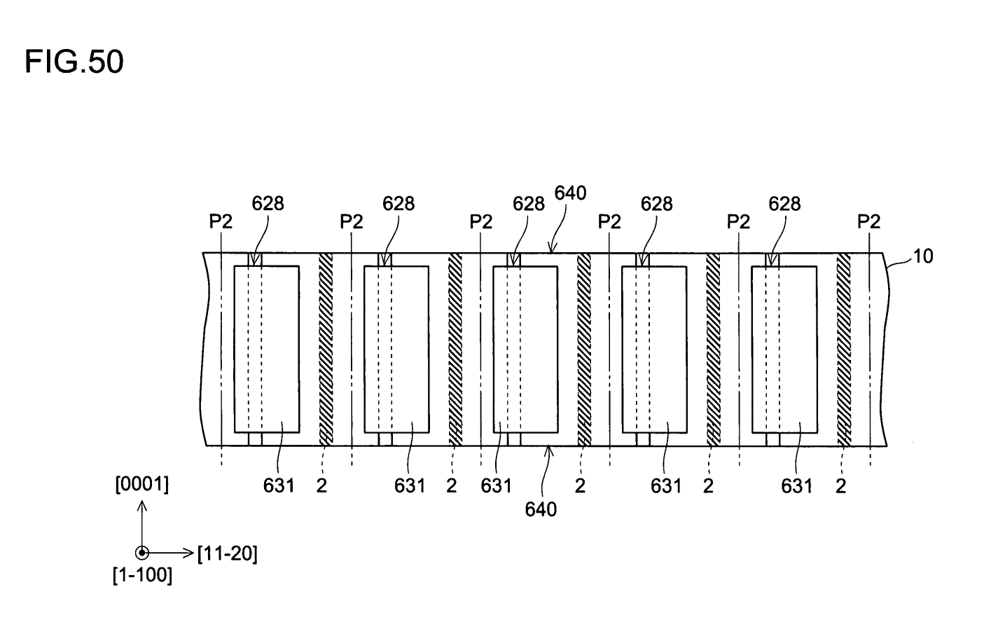

Thereafter, as shown in FIG. 50, by a technique such as a scribing-breaking process, laser scribing, or dry etching, the wafer is split into bars. This produces a bar-shaped array of chips having resonator faces 640 at the split facets. Next, by a technique such as a vacuum deposition process or a sputtering process, a coating is applied to the facets (resonator faces 640) of the bar-shaped array of chips. Specifically, on one of the facets which will serve as a light emission face, an emission-side coating (not shown) of, for example, a film of aluminum oxynitride or the like is formed. On the facet opposite from it, which will serve as a light reflection face, a reflection-side coating (not shown) of, for example, multiple-layered films of SiO₂, TiO₂, etc. is formed.

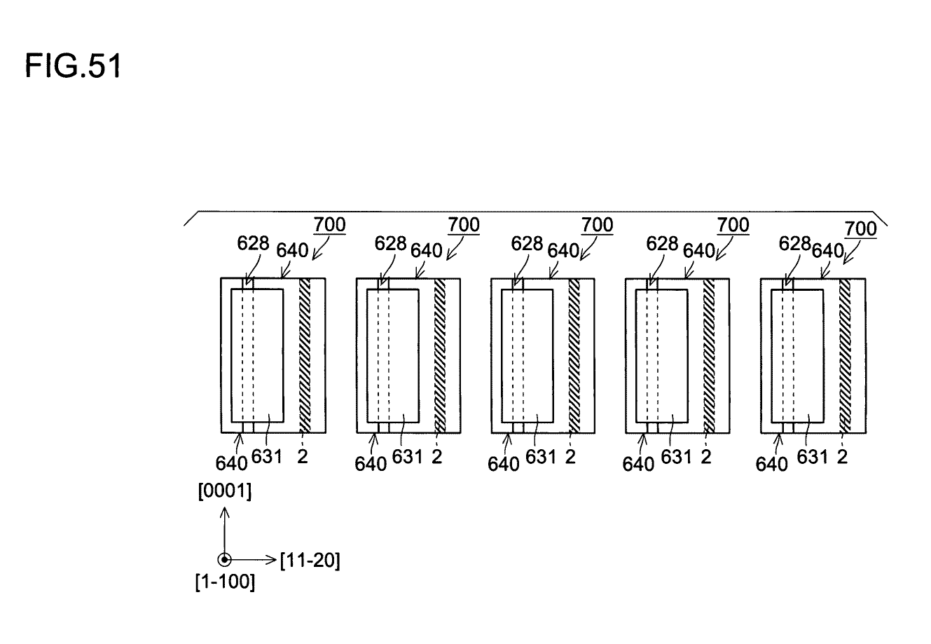

Lastly, the bar-shaped array of chips is split along planned splitting lines P2 along the c-axis [0001] direction into separate pieces of individual nitride semiconductor laser chips as shown in FIG. 51. In this way, the nitride semiconductor laser chip 700 according to Embodiment 6 of the invention is manufactured. The planned splitting lines P2 may be set on the gradient thickness region 5 side of the depressed portion 2, or may be set on the opposite side of the depressed portion 2 from the gradient thickness region 5.

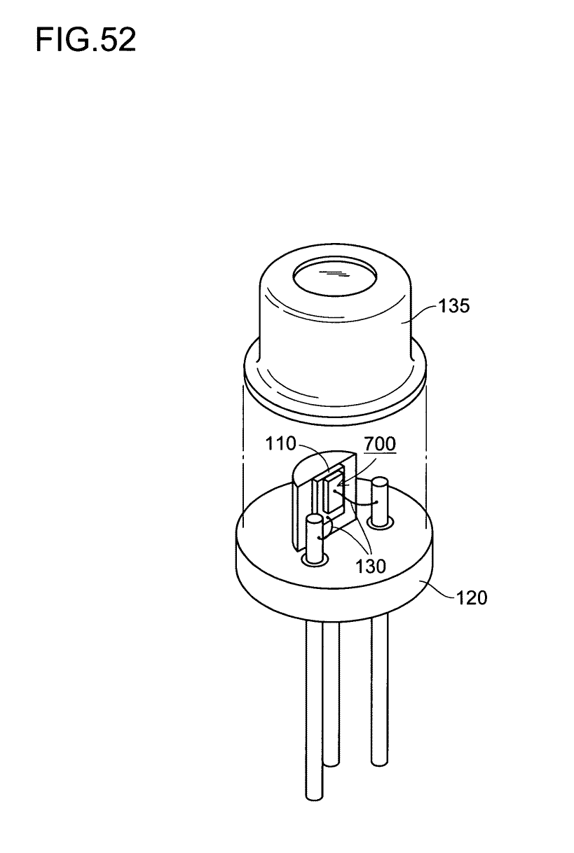

The nitride semiconductor laser chip 700 according to Embodiment 6 obtained by the method of manufacture described above is, as shown in FIG. 52, mounted on a stem 120 with a sub-mount 110 interposed in between and is electrically connected to lead pins by wires 130. Then, a cap 135 is welded on top of the stem 120 to complete assemblage into a can-packaged semiconductor laser device (semiconductor device).

With the method of manufacture of a nitride semiconductor laser chip according to Embodiment 6, as described above, by previously forming the depressed portion 2 (carved region 3) in the n-type GaN substrate 10, it is possible to alleviate strain in the nitride semiconductor layer 620 formed on the n-type GaN substrate 10. Thus, it is possible to effectively suppress development of cracks in the nitride semiconductor layer 620, and thus to increase the number of acceptable chips obtained from a single wafer. This makes it possible to increase yields.

With the method of manufacture according to Embodiment 6, when the nitride semiconductor layer 620 is formed on the n-type GaN substrate 10 having the depressed portion 2 (carved region 3) formed in it, by forming the barrier layers 623b out of AlInGaN, which is a nitride semiconductor containing Al and In, it is possible to suppress appearance of dark lines. This makes it possible to manufacture a high-luminance nitride semiconductor laser chip 700 with enhanced luminous efficacy.

With the method of manufacture according to Embodiment 6, by forming the depressed portion 2 (carved region 3) in the n-type GaN substrate 10, it is possible to effectively alleviate strain in the active layer 623 resulting from the barrier layers 623b being formed of a nitride semiconductor containing Al and In. This makes it possible to suppress appearance of dark lines more effectively.

When the nitride semiconductor wafer 650 is split, by splitting the nitride semiconductor wafer 650 in such a way that each chip include a whole concavity 635 formed over the depressed portion 2 (carved region 3), it is possible to further alleviate strain in the active layer 623 with the concavity portion included in the chip. This makes it possible to effectively suppress appearance and expansion of dark lines.

With the method of manufacture according to Embodiment 6, by use of the above-described n-type GaN substrate 10 having as the principal growth plane 10a a plane having an off angle in the a-axis direction relative to the m plane, it is also possible to obtain an effect of suppressing bright-spotted emission. In addition, it is possible to give the barrier layers 623b good crystallinity, and also to give it good surface morphology. This makes it possible to further enhance luminous efficacy.

With the method of manufacture according to Embodiment 6, by forming the carved region 2 (carved region 3) to extend in a direction parallel to the c-axis direction as seen in a plan view, it is possible to easily form, in a part of the nitride semiconductor layer 620 close to the carved region 2 (carved region 3) (next to the carved region 3), a gradient thickness region 5 whose thickness decreases in a gradient fashion (gradually) toward the carved region 2 (carved region 3). Also with this gradient thickness region 5, it is possible to alleviate strain in the nitride semiconductor layer 620, and thus it is possible to obtain a very powerful effect of suppressing cracks.

With the method of manufacture according to Embodiment 6, by forming the n-type semiconductor layer 620a at a high temperature of 900° C. or higher, it is possible to give the n-type semiconductor layer 620a a flat surface. Thus, by forming the active layer 623 and the p-type semiconductor layer 620b on the n-type semiconductor layer 620a with a flat surface, it is possible to suppress degradation of crystallinity in the active layer 623 and the p-type semiconductor layers 620a. This too makes it possible to form a high-quality crystal. On the other hand, by forming the n-type semiconductor layer 620a at a growth temperature lower than 1300° C., it is possible to suppress the inconvenience of the surface of the n-type GaN substrate 10 re-evaporating and becoming rough during the raising of temperature due to the n-type semiconductor layer 620a being formed at a growth temperature of 1300° C. or higher. Thus, with this configuration, it is possible to easily manufacture a nitride semiconductor laser chip 700 with superb device characteristics and high reliability.

With the method of manufacture according to Embodiment 6, by forming the well layers 623a in the active layer 623 at a growth temperature of 600° C. or higher, it is possible to suppress the inconvenience of a shorter atom diffusion length and hence degraded crystallinity due to the well layers 623a being formed at a growth temperature lower than 600° C. On the other hand, by forming the well layers 623a in the active layer 623 at a growth temperature of 770° C. or lower, it is possible to suppress the inconvenience of the active layer 623 being blackened by thermal damage due to the well layers 623a in the active layer 623 being formed at a growth temperature higher than 770° C. (for example, 830° C. or higher). The growth temperature of the barrier layers 623b, which are contiguous with the well layers 623a, is preferably the same as or higher than that of the well layers 623a.

With the method of manufacture according to Embodiment 6, by forming the p-type semiconductor layer 620b at a growth temperature of 700° C. or higher, it is possible to suppress the inconvenience of the p-type semiconductor layer 620b having a high resistance due to their growth temperature being too low. On the other hand, by forming the p-type semiconductor layer 620b at a growth temperature lower than 1100° C., it is possible to reduce thermal damage to the active layer 623.

In a case where an n-type GaN substrate having the c plane as a principal growth plane is used, forming the p-type semiconductor layer 620b at a growth temperature lower than 900° C. causes the p-type semiconductor layer 620b to have an extremely high resistance and thus makes the resulting device (nitride semiconductor chip) difficult to use as such. By contrast, using the above-described n-type GaN substrate 10 having as the principal growth plane 10a a plane having an off-angle in the a-axis direction relative to the m plane makes it possible, even at a growth temperature lower than 900° C., to obtain p-type conductivity by doping with Mg as a p-type impurity. In particular, in a case where the In composition ratio x1 in the well layers 623a in the active layer 623 is 0.15 or more but 0.45 or less, the In composition tends to vary across the plane due to segregation of In and the like. Thus, the lower the growth temperature of the p-type semiconductor layer 620b, the more preferable. The difference between the growth temperature of the well layers 623a in the active layer 623 and the growth temperature of the p-type semiconductor layer 620b is preferably less than 450° C. from the viewpoint of avoiding thermal damage to the active layer 623, and more preferably 300° C. or less. In a case where the In composition ratio X1 is less than 0.15, however, inconveniences such as segregation of In is less likely, and therefore growing the p-type nitride semiconductor layer 620b at a growth temperature of 900° C. or higher poses no problem.

Forming the barrier layers 623b in the active layer 623 out of a nitride semiconductor containing Al (for example, AlInGaN) makes the active layer 623 (well layers 623a) more resistant to thermal damage occurring during formation of the p-type nitride semiconductor layer 620b. This makes it possible to form the p-type nitride semiconductor layer 620b at a growth temperature as high as 1000° C. or higher. Thus, by forming the p-type nitride semiconductor layer 620b at high temperature, it is possible to suppress defects and the like developing in the p-type nitride semiconductor layer 620b, and thereby to enhance the crystallinity of the p-type nitride semiconductor layer 620b. Thus, it is possible to greatly enhance flexibility in the growth temperature of the p-type nitride semiconductor layer 620b. Consequently, it is possible to form semiconductor layers at optimal growth temperatures with consideration given to the specifications etc. required in the device.

Next, a description will be given of experiments conducted to verify the effect of Embodiment 6 described above.

In the experiments, first, as Test Sample 1, a sample chip was fabricated in which individual nitride semiconductor layers similar to those in Embodiment 6 described above were formed on an n-type GaN substrate similar to that in Embodiment 6 described above, and was tested for an effect of suppressing dark lines. The n-type GaN substrate used in Test Sample 1 had an off angle of 1.7 degrees in the a-axis direction and an off angle of +0.5 degrees in the c-axis direction.

In Test Sample 1, the barrier layers in the active layer were formed of Al_{0.01}In_{0.03}Ga_{0.96}N, with an Al composition of 1%. The Al composition in the barrier layers was measured by AES (Auger electron spectroscopy). As Comparative Sample 1, another sample chip was fabricated by using an m-plane GaN substrate and forming, on that substrate, individual nitride semiconductor layers similar to those in Embodiment 6. In Comparative Sample 1, however, used as the GaN substrate was an m-plane just substrate, and the barrier layers were formed of In_{0.02}Ga_{0.98}N. That is, Comparative Sample 1 differed from Test Sample 1 in that the barrier layers were formed of, instead of AlInGaN, in GaN, and that an m-plane just substrate was used as the n-type GaN substrate.

Then, with Test Sample 1 and Comparative Sample 1 thus fabricated, their respective PL (photoluminescence) emission pattern was inspected. Specifically, each sample was irradiated with light of a wavelength of 405 nm so that the active layer alone is selectively excited, and the emission pattern of the active layer was inspected.

FIG. 73 referred to earlier is a microscope photograph of dark lines observed in the PL emission pattern of Comparative Sample 1, in which the barrier layers were formed of InGaN; FIG. 76 referred to earlier is a microscope photograph of the PL emission pattern of Test Sample 1 according to Embodiment 6, in which the barrier layers were formed of AlInGaN.

As shown in FIG. 73, with Comparative Sample 1, in which the barrier layers were formed of InGaN, many dark lines were observed in the c-axis direction (the <0001> direction). By contrast, as FIG. 76 shows, with Test Sample 1, in which the barrier layers were formed of AlInGaN, no dark lines at all were observed. Dark lines can be observed to appear in an EL emission pattern resulting from current injection, and can also be observed clearly, as described above, in a PL emission pattern resulting from the active layer being selectively excited. The reason is considered to be that dark lines appear in the active layer.

Next, as Test Sample 2, a sample chip was fabricated in which individual nitride semiconductor layers similar to those in Embodiment 6 described above were formed on an n-type GaN substrate similar to that in Embodiment 6 described above, and was tested for an effect of suppressing cracks. The n-type GaN substrate used in Test Sample 2 had an off angle of +2.2 degrees in the a-axis direction and an off angle of −0.18 degrees in the c-axis direction. The period of the depressed portions (carved regions) was 400 μm.

As Comparative Sample 2, another sample chip was fabricated in which individual nitride semiconductor layers similar to those in Embodiment 6 were formed on an n-type GaN substrate having no off angle in the a-axis direction (a substantially m-plane just substrate), and was subjected to the same inspection as Test Sample 2. Specifically, the n-type GaN substrate used in Test Sample 2 had an off angle of 0 degrees in the a-axis direction and an off angle of +0.05 degrees in the c-axis direction. In other respects, Comparative Sample 2 had the same configuration as Test Sample 2. The formation of the individual nitride semiconductor layers in Test Sample 2 and Comparative Sample 2 was performed concurrently on an MOCVD machine.

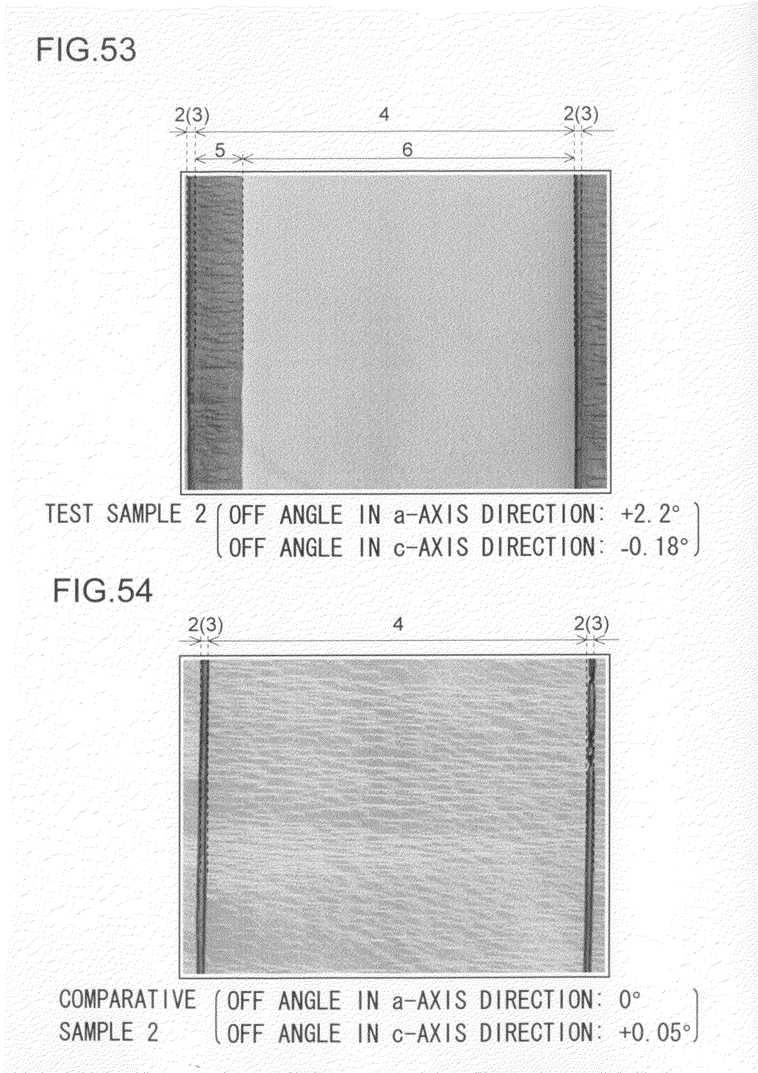

FIG. 53 is a microscope photograph of the nitride semiconductor layer surface observed with Test Sample 2, and FIG. 54 is a microscope photograph of the nitride semiconductor layer surface observed with Comparative Sample 2.

As shown in FIGS. 53 and 54, with Test Sample 2, which used an n-type GaN substrate having an off angle in the a-axis direction, formation of a gradient thickness region 5, whose thickness decreases in a gradient fashion (gradually) toward the carved region 2 (carved region 3), was observed. It was confirmed that the gradient thickness region 5 was formed in a region closely on one (for example, right) side of the depressed portion 2 (carved region 3), substantially in the shape of a band extending in a direction parallel to the depressed portion 2 (carved region 3). Moreover, with Test Sample 2, very good surface morphology was observed in the region of the nitride semiconductor layers over the uncarved region 4 other than the gradient thickness region 5 (that is, in the emission portion formation region 6). This confirms that, by use of a substrate having an off angle in the a-axis direction, it is possible to improve surface morphology.

Whereas with Comparative Sample 2, development of about 10 to 20 cracks per cm² (square centimeter) was observed after nitride semiconductor layer formation, with Test Sample 2, no development of cracks was observed after nitride semiconductor layer formation. For a further comparison, similar individual nitride semiconductor layers were formed by use of a GaN substrate having no carved regions formed in it, and development of about 70 to 90 cracks per cm² was observed. This confirms the following: by forming a carved region in a nitride semiconductor substrate, it is possible to obtain an effect of suppressing development of a crack; furthermore, forming a carved region in a nitride semiconductor substrate having an off angle in the a-axis direction causes a gradient thickness region to be formed in the nitride semiconductor layers, and this makes it possible to obtain a more powerful effect of suppressing development of a crack.

The foregoing confirms that, by forming a depressed portion (carved region) in an n-type GaN substrate having as a principal growth plane a plane having an off angle in the a-axis direction relative to the m plane, it is possible to obtain a very powerful effect of suppressing cracks.

When LED chips were fabricated by use of Test Sample 2 and Comparative Sample 2 described above and were each operated at a driving current of 100 mA, no appearance of dark lines was observed in either of the LED chips even after 200 hours operation. The reason is considered to be that formation of the carved region in the substrate effectively alleviated strain in the active layer.

With the LED chip fabricated by use of Test Sample 2, the value of the threshold current was very low, specifically 55 mA. This is considered to result from suppressed bright-spotted emission, suppressed appearance of dark lines, and an effect of alleviating strain in the active layer brought about by formation of a carved region in the substrate.

Even the LED chip fabricated by use of Comparative Sample 2 was preferable, because it clearly had more effect than a structure in which the barrier layers were formed of InGaN; the configuration of Test Sample 2 was more preferable.

Next, to test for the effect of the off-angle in the a-axis direction on the gradient thickness region, on each of four types of n-type GaN substrates having different off-angles in the a-axis direction, individual nitride semiconductor layers similar to those in Embodiment 6 described above were formed, and then the width of the gradient thickness region formed in the nitride semiconductor layers was inspected. The four types of n-type GaN substrates had off-angles of +0.5 degrees, +1.0 degree, +2.0 degrees, and +3.0 degrees, respectively, in the a-axis direction. The four types of n-type GaN substrates all had off-angles of about −0.2 degrees in the c-axis direction. The depressed portions (carved regions) were formed, as in Embodiment 6 described above, with a width of 5 μm and a depth of 5 μm. The period of the depressed portions (carved regions) was 400 μm. The individual nitride semiconductor layers formed on the substrate were similar to those in Embodiment 6 described above.

The results were as follows. It was observed that, as the off-angle in the a-axis direction increased, the width of the gradient thickness region tended to decrease. Specifically, with the off-angle in the a-axis direction equal to +0.5 degrees, the width of the gradient thickness region was 188.4 μm; with the off-angle in the a-axis direction equal to +1.0 degrees, the width of the gradient thickness region was 92.2 μm; with the off-angle in the a-axis direction equal to +2.0 degrees, the width of the gradient thickness region was 46.5 μm; and with the off-angle in the a-axis direction equal to +3.0 degrees, the width of the gradient thickness region was 32.7 μm.

It was also observed that, as the off-angle in the a-axis direction increased, the gradient of the gradient thickness region (thickness gradient angle) tended to become steeper.

With the off-angle in the a-axis direction equal to +0.5 degrees, about a half of the nitride semiconductor layer formed over the uncarved region was occupied by the gradient thickness region. Thus, with an off-angle in the a-axis direction smaller than 0.5 degrees, more than a half of the nitride semiconductor layer formed over the uncarved region will be occupied by the gradient thickness region. Here, it is preferable that the region where the device operation takes place (in a light-emitting device, the light-emitting region) be formed in the emission portion formation region, which has good surface morphology. Accordingly, from the viewpoint of securing a region (emission portion formation region) in which to fabricate a region for device operation (emission portion (ridge portion)), it is preferable that the off-angle in the a-axis direction be 0.5 degrees or larger.

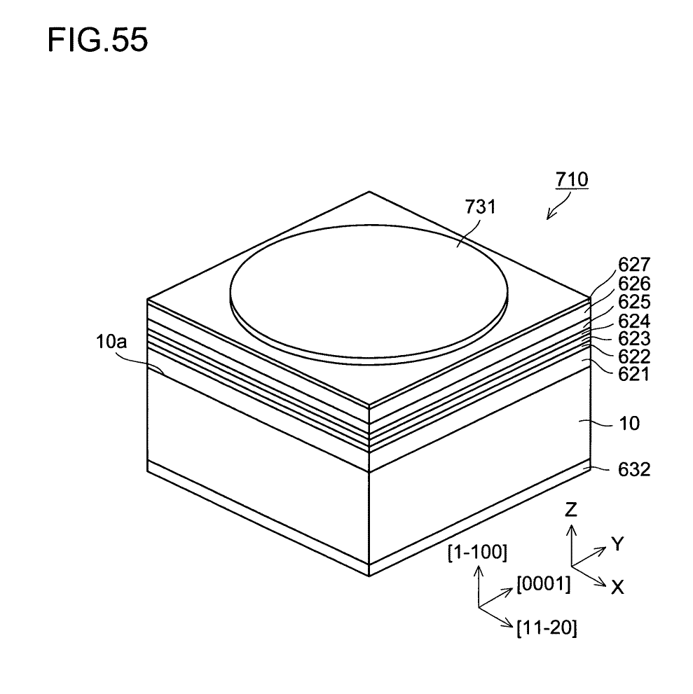

Next, as a test chip, a light-emitting diode chip 710 as shown in FIG. 55 was fabricated, and the EL emission pattern was inspected. The reason that a light-emitting diode chip was used for the inspection of the EL emission pattern is that, with a nitride semiconductor laser chip, which has a constricted current injection region as a result of a ridge portion being formed, it is difficult to inspect the EL emission pattern.

The test chip (light-emitting diode chip 710) was fabricated by forming a nitride semiconductor layer (individual semiconductor layers) similar to that in Embodiment 6 described above on top of an n-type GaN substrate 10 similar to that in Embodiment 6 described above. The formation of the nitride semiconductor layer was conducted in a similar manner as in Embodiment 6 described above. Specifically, as shown in FIG. 55, by use of an n-type GaN substrate 10 having as a principal growth plane 10a a plane having an off-angle relative to the m plane, on its principal growth plane 10a, the following layers were formed successively: an n-type clad layer 621; an n-type guide layer 622; an active layer 623; a carrier block layer 624; a p-type guide layer 625; a p-type clad layer 626; and a p-type contact layer 627. Next, on the p-type contact layer 627, a p-side electrode 731 was formed. The p-side electrode 731 was formed transparent to allow inspection of the EL emission pattern. On the back face of the n-type GaN substrate 10, an n-side electrode 632 was formed. In the test chip, the n-type GaN substrate 10 had an off-angle of +2.2 degrees in the a-axis direction and an off-angle of −0.18 degrees in the c-axis direction. In the test chip, the In composition ratio in the well layers was 0.29, and the Al composition ratio in the barrier layers was 2%. That is, in the test chip, the well layers were formed of In_{0.29}Ga_{0.71}N, and the barrier layers were formed of Al_{0.02}In_{0.03}Ga_{0.95}N. The test chip was so formed that the emission portion formation region acted as a light-emitting region. Current was injected into the thus fabricated test chip (the light-emitting diode chip 110) to make it emit light, and the light distribution across the plane was inspected. With the test chip according to Embodiment 6, an EL emission pattern similar to that in Embodiment 1 described previously (an emission pattern similar to the EL emission pattern shown in FIG. 22) was observed.

On the other hand, as a comparison chip, a light-emitting diode chip employing a GaN substrate having the m plane as a principal growth plane (a substantially m-plane just substrate, with an off angle of 0 degrees in the a-axis direction and an off angle of +0.05 degrees in the c-axis direction) was fabricated. This comparison chip was fabricated in the same manner as the test chip described above. The gas flow rate of In was the same as for the test chip, but in the comparison chip, the In composition ratio in the well layers was 0.2. In other respects, the comparison chip had a configuration similar to that of the test chip described above. Accordingly, in the comparison chip, the barrier layers were Al_{0.02}In_{0.03}Ga_{0.95}N layers as in the test chip. As with the test chip, the light distribution across the plane was inspected. Except employing an m-plane just substrate as the GaN substrate and having an In composition ratio of 0.2 in the well layers, the comparison chip had a configuration similar to that of the test chip (the light-emitting diode chip 710).

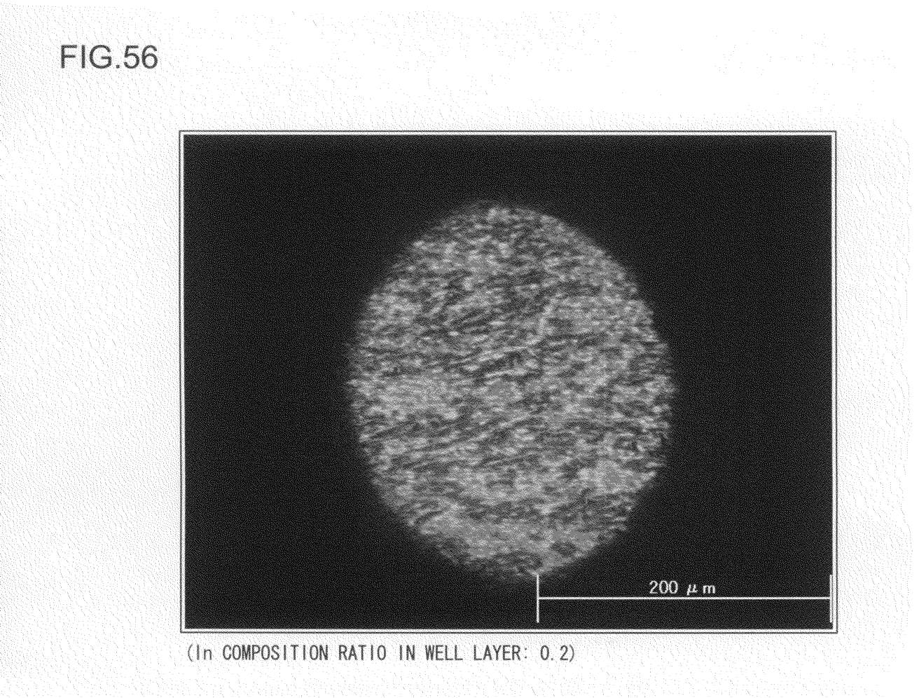

FIG. 56 is a microscope photograph of the EL emission pattern observed with comparison chip. As shown in FIGS. 41 and 56, whereas the comparison chip exhibits a bright-spotted EL emission pattern, the test chip exhibits an EL emission pattern of even light emission as a result of a bright-spotted EL emission pattern being suppressed. This confirms that using an n-type GaN substrate 10 having as a principal growth plane 10a a plane having an off-angle in the a-axis direction relative to the m plane helps suppress a bright-spotted EL emission pattern. On the other hand, through measurement of luminous efficacy with the test chip and the comparison chip, it was confirmed that the luminous efficacy of the test chip was increased to 1.5 times that of the comparison chip. The emission wavelength of the test chip was 530 nm, and the emission wavelength of the comparison chip was 490 nm. This confirms that the test chip, in which the off-angle was controlled, was more efficient also in terms of In absorption than the comparison chip, which used an m-plane just substrate. The foregoing confirms that providing an off-angle in the a-axis direction relative to the m plane helps suppress bright-spotted emission and increase luminous efficacy in a wavelength region of green.

The test chip and the comparison chip both used a nitride semiconductor layer containing Al and In in the barrier layers, and thus no appearance of dark lines was observed. In the test chip, use of the m-plane nitride semiconductor substrate having an off angle in the a-axis direction suppressed bright-spotted emission and resulted in a uniform emission pattern. Thus, with suppressed bright-spotted emission and a uniform emission pattern, the test chip was more preferable. With the test chip, owing also to formation of the gradient thickness region, no development of a crack was observed.

Subsequently, by use of a plurality of n-type GaN substrates with different off-angles in the a- and c-axis directions, a plurality of chips like the light-emitting diode chip 710 shown in FIG. 55 were fabricated, and were subjected to experiments including inspection of the EL emission pattern.

The results reveal that providing an off-angle in the a-axis direction relative to the m plane gives an effect of suppressing a bright-spotted EL emission pattern. It is also found out that, whereas the effect of suppressing bright-spotted emission is weak with the off-angle in the a-axis direction in a range of 0.1 degrees or smaller, the effect of suppressing a bright-spotted EL emission pattern is prominent with the off-angle in the a-axis direction larger than 0.1 degrees. Thus, it has been confirmed that by using as the principal growth plane of a GaN substrate a plane having an off-angle in the a-axis direction relative to the m plane, it is possible to suppress a bright-spotted EL emission pattern. It has also been confirmed that making the off angle in the a-axis direction larger than the off angle in the c-axis direction helps suppress a bright-spotted EL emission pattern more effectively.

### Practical Example 13

As a nitride semiconductor laser chip according to Practical Example 13, by use of an n-type GaN substrate having an off angle of +0.5 degrees in the a-axis direction and an off angle of −0.15 degrees in the c-axis direction relative to the m {1-100} plane, a nitride semiconductor laser chip was fabricated which was similar to that of Embodiment 6 described above. In Practical Example 13, the barrier layers were formed of Al_{0.02}In_{0.03}Ga_{0.95}N, and the well layers were formed of In_{0.25}Ga_{0.75}N. The substrate had carved regions formed in it in a direction parallel to the c-axis direction. In other respects, the configuration of Practical Example 13 was similar to that of Embodiment 6 described above. As Comparative Example 3, another nitride semiconductor laser chip was fabricated in which the barrier layers were formed of In_{0.02}Ga_{0.98}N. In the nitride semiconductor laser chip according to Comparative Example 3, no carved regions were formed; in other respects, the configuration here was similar to that of Practical Example 13.

In Comparative Example 3, many cracks developed in the nitride semiconductor layer, resulting in greatly diminished yields. With very few of them in which no cracks developed, the EL emission pattern was inspected. The results were that a large number of dark lines, as many as 100 of them per millimeter of width, developed. By contrast, in Practical Example 13, almost no development of dark lines was observed, with almost no lowering of yields. Inspection of the EL emission pattern of Practical Example 13 revealed no appearance of dark lines.

Moreover, with Practical Example 13 and Comparative Example 3, the threshold current was measured. Whereas with the nitride semiconductor laser chip according to Comparative Example 3, the value of the threshold current was about 130 mA, with the nitride semiconductor laser chip according to Practical Example 13, the value of the threshold current was 65 mA. Thus, it was confirmed that the threshold current was far lower in the nitride semiconductor laser chip according to Practical Example 13 than in Comparative Example 3. The reason is considered to be that suppressed appearance of dark lines permitted uniform light emission across the plane, resulting in increased gain.

Furthermore, by use of a substrate similar to that of Practical Example 13, a similar nitride semiconductor layer was formed, and an LED chip was fabricated without forming a current constriction structure. When the LED chip thus fabricated was operated at a driving current of 100 mA, no appearance of dark lines was observed in the EL emission pattern even after 200 hours operation. The reason is considered to be that formation of the carved region in the substrate effectively alleviated strain in the active layer.

In Comparative Example 3, about 70 to 90 cracks per cm² developed. By contrast, in Practical Example 13, no development of cracks was observed, and thus a great reduction in development of cracks was achieved.

### Practical Example 14

As a nitride semiconductor laser chip according to Practical Example 14, by use of an n-type GaN substrate having an off angle of 4 degrees in the a-axis direction and an off angle of +1 degree in the c-axis direction relative to the m plane {1-100}, a nitride semiconductor laser chip was fabricated in which the barrier layers were formed of AlₛInₜGaᵤN (s+t+u=1). In Practical Example 14, the barrier layers were formed of AlₛInₜGaᵤN (s=0.01, t=0.03, u=0.96). In respects other than the barrier layers, the configuration of Practical Example 14 was similar to that of Embodiment 6 (Practical Example 13) described above. Practical Example 14 offered similar effects as Practical Example 13 described above.

With the configuration of Practical Example 14 described above, largely the same effects were obtained when the barrier layers formed of AlₛInₜGaᵤN (s+t+u=1) had an Al composition ratio s in a range of 0<s≦0.08 and an In composition ratio t in a range of 0<t≦0.10.

In a case where the barrier layers are formed of AlₛInₜGaᵤN (s+t+u=1), it is preferable that the Al composition be lower than the In composition. To achieve light emission at wavelengths in a long wavelength region, the active layer needs to be formed at a low temperature of 900° C. or lower, typically about 700° C. to 800° C.; this might be, it is considered, the reason that the In content enhances crystallinity in low-temperature growth. Moreover, using an AlInGaN layer containing In as a barrier layer gives a higher index of refraction than using an AlGaN layer, and thus helps achieve efficient light confinement.

### Practical Example 15

As a nitride semiconductor laser chip according to Practical Example 15, by use of a GaN substrate having an off angle of 6 degrees in the a-axis direction and an off angle of −1.1 degrees in the c-axis direction relative to the m plane {1-100}, a nitride semiconductor laser chip was fabricated in which the barrier layers were formed of AlₛInₜGaᵤN (s+t+u=1). In Practical Example 15, the first barrier layer was formed of AlₛInₜGaᵤN (s=0.02, t=0, u=0.98), and the second and third barrier layers were formed of AlₛInₜGaᵤN (s=0.02, t=0.01, u=0.97). That is, in Practical Example 15, the first barrier layer was formed of AlGaN, and unlike the first barrier layer, the second and third barrier layers were each formed of AlInGaN. In other respects than the barrier layers, the configuration of Practical Example 15 was similar to that of Embodiment 6 (Practical Example 13) described above. Practical Example 15 offered similar effects as Practical Example 13 described above. The first barrier layer may have a different composition from the second and third barrier layers as in Practical Example 15, or each barrier layer may have a different Al composition.

With the configuration of Practical Example 15 described above, largely the same effects were obtained when the barrier layers formed of AlₛInₜGaᵤN (s+t+u=1) had an Al composition ratio s in a range of 0<s≦0.08 and an In composition ratio t in a range of 0<t≦0.10.

In a case where AlₛInₜGaᵤN (s+t+u=1) is used for the barrier layers, it is preferable that the Al composition be higher than the In composition. With that configuration, as a benefit resulting from the Al content, it is possible to enhance the effect of suppressing dark lines.

### Practical Example 16

As a nitride semiconductor laser chip according to Practical Example 16, by use of an n-type GaN substrate having an off angle of 6 degrees in the a-axis direction and an off angle of +2 degrees in the c-axis direction relative to the m plane {1-100}, a nitride semiconductor laser chip was fabricated which was largely similar to that of Practical Example 13. Specifically, in Practical Example 16, the barrier layers were formed of AlInGaN. Whereas in Practical Example 13 the three barrier layers (first, second, and third barrier layers) had the same Al composition ratio and the same In composition ratio, in Practical Example 16, they had different Al composition ratios and different In composition ratios. Specifically, the first barrier layer had an Al composition ratio of 2% and a In composition ratio of 5%, and the second and third barrier layers had an Al composition ratio of 0.08% and an In composition ratio of 4%. Practical Example 16 offered similar effects as Practical Example 13 described above. A design in which the first barrier layer had a higher Al composition ratio than the other barrier layers as in Practical Example 16 offered similar effects.

### Embodiment 7

In a seventh embodiment (Embodiment 7) of the invention, a nitride semiconductor wafer and a nitride semiconductor laser chip are formed by use of a GaN substrate having the m plane as the principal growth plane. Moreover, a depressed portion (carved region) like that in Embodiment 6 described previously is formed in the principal growth plane of the GaN substrate. Furthermore, the barrier layers in the active layer are formed of AlInGaN, which is a nitride semiconductor containing Al and In. In other respects, the configuration of Embodiment 7 is similar to that of Embodiment 6 described previously.

In Embodiment 7, forming the barrier layers out of AlInGaN as described above makes it possible to suppress appearance of dark lines; doing so, as compared with forming the barrier layers out of GaN or InGaN, also helps enhance interface steepness, and thus helps make clear the satellite peak observed by X-ray diffraction measurement.

In Embodiment 7, by suppressing appearance of dark lines, it is possible to suppress a lowering in luminous efficacy, and thus it is possible to enhance device characteristics and reliability. By suppressing appearance of dark lines, it is possible to obtain an emission pattern of uniform light emission, and thus it is also possible to increase gain.

In Embodiment 7, as in Embodiment 6 described previously, by forming a depressed portion (carved region) in the GaN substrate, it is possible to obtain a very powerful effect of suppressing cracks, and thus it is possible to effectively suppress development of cracks in the nitride semiconductor layer.

Using a GaN substrate having the m plane as the principal growth plane, compared with using a GaN substrate having as the principal growth plane a plane having an off angle in the a-axis direction relative to the m plane, helps sufficiently enhance luminous efficacy, though with slightly lower flatness. Thus, it is possible to obtain sufficiently usable luminous efficacy. Moreover, using AlInGaN in the barrier layers helps greatly enhance the efficiency of In absorption into the well layers. Thus, even with a low gas flow rate of In, it is possible to maintain a high In composition ratio. This makes it possible to enhance In absorption efficiency, and thus to achieve lengthening of the emission wavelength effectively.

### Embodiment 8

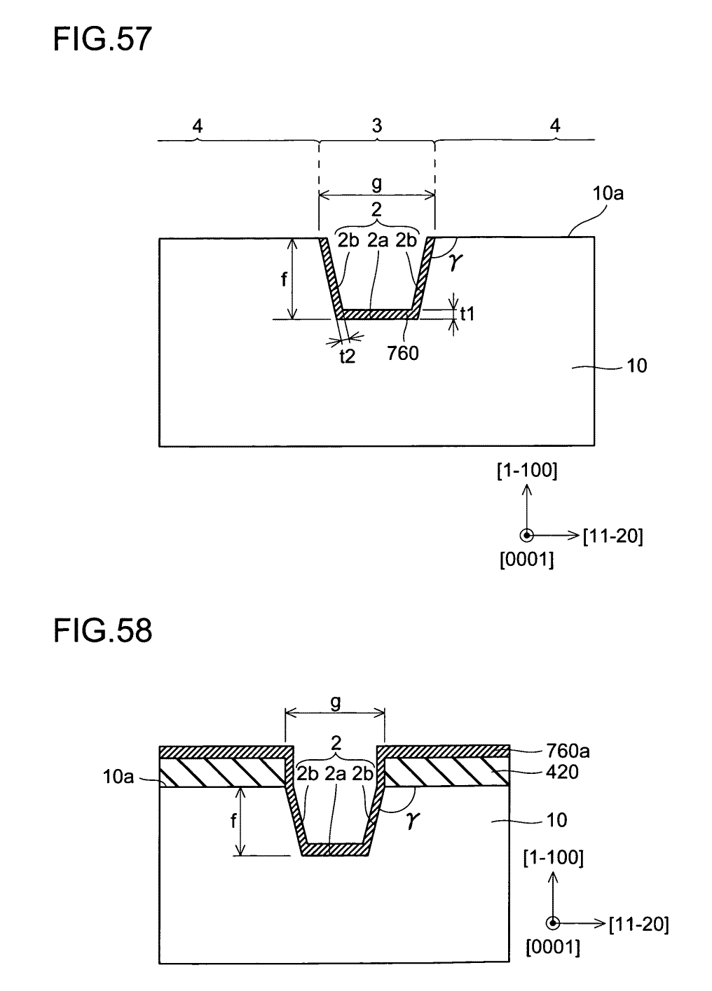

FIG. 57 is a sectional view illustrating a nitride semiconductor wafer and a nitride semiconductor laser chip according to an eighth embodiment (Embodiment 8) of the invention. FIG. 57 shows a section of part of a substrate used in a nitride semiconductor wafer and a nitride semiconductor laser chip according to Embodiment 8. Next, with reference to FIGS. 27, 31, and 57, a nitride semiconductor wafer and a nitride semiconductor laser chip according to Embodiment 8 of the invention will be described. Embodiment 8 will deal with an example in which a nitride semiconductor chip according to the invention is applied to a nitride semiconductor laser chip.

In a nitride semiconductor wafer and a nitride semiconductor laser chip according to Embodiment 8, in addition to the configuration of Embodiment 6 described previously, there is further provided a growth suppression film for suppressing growth of a nitride semiconductor crystal. Specifically, in Embodiment 8, as shown in FIG. 57, in the carved region 3 (in the region inside the depressed portion 2) on the n-type GaN substrate 10, there is further formed a growth suppression film 760 which is formed of an AlN film, which is a nitride film. The growth suppression film 760 is formed so as to cover the floor surface portion 2a and the side surface portions 2b of the depressed portion 2. Moreover, the growth suppression film 760 is formed with such a thickness as not to fill the inside of the depressed portion 2 (carved region 3).

Furthermore, the growth suppression film 760 is so formed that the thickness t2 of its part formed on the side surface portions 2b is smaller than the thickness t1 of its part formed on the floor surface portion 2a. Specifically, the growth suppression film 760 is formed so that the thickness t1 of its part formed on the floor surface portion 2a of the depressed portion 2 is about 100 nm and that the thickness t2 of its part formed on the side surface portions 2b of the depressed portion 2 is about 80 nm. With this configuration, it is possible to effectively suppress a defect such as exfoliation of the growth suppression film 760.

It is preferable that the thickness t1 of the growth suppression film 760 be equal to or less than a half of the depth f of the depressed portion 2. It is also preferable that the thickness t2 of the growth suppression film 760 be equal to or less than a half of the opening width g of the depressed portion 2. With this configuration, it is possible to suppress the filling of the inside of the depressed portion 2 with the growth suppression film.

Moreover, in Embodiment 8, the growth suppression film 760 is formed so as to extend along the depressed portion 2 (so as to extend in the c-axis [0001] direction).

In other respects, the configuration of Embodiment 8 is similar to that of Embodiment 6 described previously

In Embodiment 8, as described above, the growth suppression film 760 for suppressing growth of a nitride semiconductor crystal is formed in the carved region 3 (in the region inside the depressed portion 2) on the n-type GaN substrate 10; this makes it possible to surely suppress the filling of the inside of the depressed portion 2 (carved region 3) with the nitride semiconductor layer 620 (the individual semiconductor layers constituting the nitride semiconductor layer 620) during formation of the nitride semiconductor layer 620 (see FIGS. 27 and 31). As a result, it is possible to readily form a concavity in the surface of the nitride semiconductor layer 620 (the individual layers constituting the nitride semiconductor layer 20) over the depressed portion 2 (carved region 3). Thus, even in a case where a large difference in lattice constant, thermal expansion coefficient, etc. between the n-type GaN substrate 610 and the nitride semiconductor layer 620 produces strain in the nitride semiconductor layer 620, the strain in the nitride semiconductor layer 620 formed over the uncarved region 4 can be alleviated with the concavity formed in the nitride semiconductor layer 620 over the depressed portion 2 (carved region 3).

In particular, in a case where a particular nitride semiconductor layer (for example, the n-type clad layer) needs to be formed thicker, the depressed portion 2 (carved region 3) is more likely to be filled; in such a case, therefore, it is very effective to form a growth suppression film 760 as described above inside the depressed portion 2 (carved region 3). This is because, if the inside of the depressed portion 2 (carved region 3) is completely filled (if no concavity is formed), it is difficult to alleviate strain, leading to a diminished effect of suppressing cracks.

In Embodiment 8, forming the growth suppression film 760 with such a thickness as not to fill the inside of the depressed portion 2 (carved region 3) makes it possible to readily form a concavity on the surface of the nitride semiconductor layer 620 (the individual layers constituting the nitride semiconductor layer 620) over the depressed portion 2 (carved region 3).

In Embodiment 8, forming the growth suppression film 760 out of an AlN film, that is, a film of a nitride of aluminum, makes it possible to obtain a more powerful effect of suppressing cracks. Since AlN can have a crystal structure similar to that of a nitride semiconductor, a continuous crystal structure is obtained between the growth suppression film 760 and the region where the growth suppression film 760 is not formed. Thus, AlN may be said to be a suitable material for the growth suppression film.

In a case where the depressed portion 2 (carved region 3) is formed in an n-type GaN substrate 10 having as the principal growth plane 10a a plane having an off angle in the a-axis direction, and the growth suppression film 760 is formed in that depressed portion 2 (carved region 3), the gradient thickness region 5 (see FIG. 31) can be given a smaller width. This permits the emission portion formation region 6 (see FIG. 31) to be made wider, and is therefore preferable, for example, in cases where as many chips as possible need to be fabricated from a single nitride semiconductor wafer.

In other respects, the effects of Embodiment 8 are similar to those of Embodiment 6 described previously.

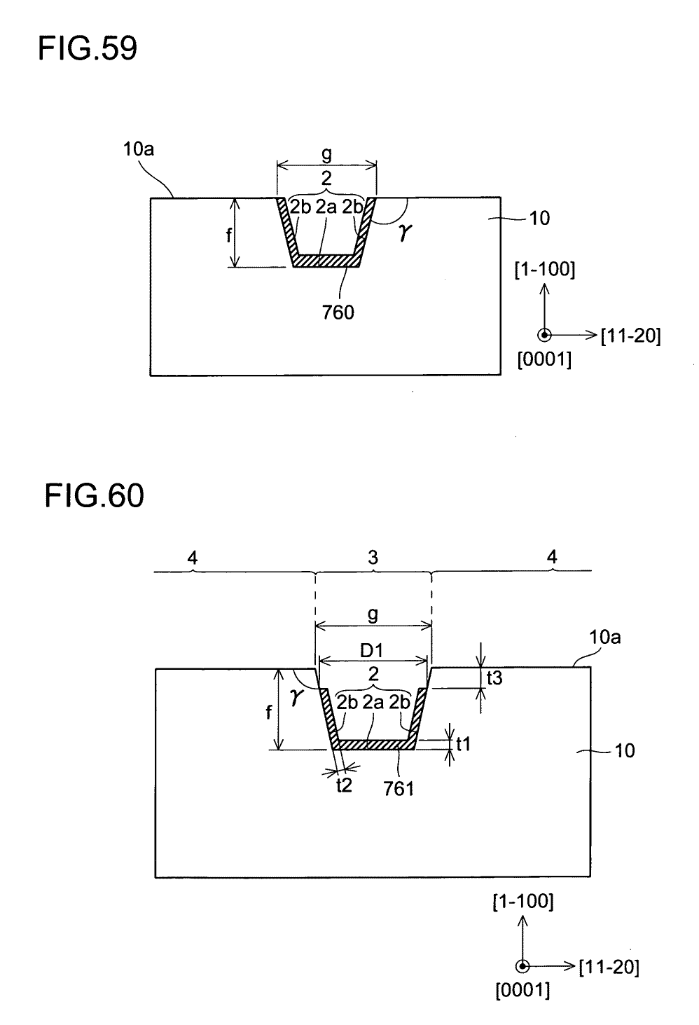

FIGS. 58 and 59 are sectional views illustrating a method of manufacture of a nitride semiconductor laser chip according to Embodiment 8 of the invention. Next, with reference to FIGS. 39 to 42, 58, and 59, a description will be given of a method of manufacture of a nitride semiconductor laser chip according to Embodiment 8 of the invention. The steps in Embodiment 8 other than that for forming the growth suppression film 760 are similar to those in Embodiment 6 described previously, and accordingly the following description only discusses the step for forming the growth suppression film 760.

First, an n-type GaN substrate having as a principal growth plane a plane having an off-angle in the a-axis direction relative to the m plane is prepared, and by a method similar to that used in Embodiment 6 shown in FIGS. 39 to 42, a depressed portion 2 is formed in the n-type GaN substrate.

Next, as shown in FIG. 58, by a sputtering process using an ECR (electron cyclotron resonance) machine, an AlN film 760a as a growth suppression film is formed with a thickness of about 100 nm over the entire surface. At this time, through adjustment of the sputtering conditions etc., the AlN film 760a is so formed that the thickness of the part of the AlN film 760a formed on the side surface portions 2b of the depressed portion 2 is about 80 nm.

Then, as shown in FIG. 59, by use of an etchant such as HF (hydrogen fluoride), the SiO₂ layer 420 (see FIG. 58) is removed. Thus, by lift-off, the above-described growth suppression film 760 formed of an AlN film is formed on the side surface portions 2b and the floor surface portion 2a of the depressed portion 2.

FIG. 60 is a sectional view illustrating a nitride semiconductor wafer and a nitride semiconductor laser chip according to a first modified example of Embodiment 8. Now, with reference to FIGS. 43 and 60, a description will be given of, as a first modified example of Embodiment 8, a case where the growth suppression film is given a different shape.

In the first modified example of Embodiment 8, as shown in FIG. 60, a growth suppression film 761 formed of an AlN film is formed in a region (position) lower than the principal growth plane 10a inside the depressed portion 2. The growth suppression film 761 here is formed on part of the side surface portions 2b and on the floor surface portion 2a of the depressed portion 2 so as to have a substantially square-cornered U-shaped (substantially depressed) sectional shape.

Moreover, the growth suppression film 761 has a predetermined width D1 smaller than the opening width g of the depressed portion 2, and is, as in Embodiment 8 described above, formed so as to extend along the depressed portion 2 (so as to extend in the c-axis [0001] direction).

Moreover, in the first modified example of Embodiment 8, the distance t3 from the principal growth plane 10a (the surface of the uncarved region 4) to the growth suppression film 761 is set at, for example, about 1.5 μm. Too small a distance t3 makes it difficult to form the growth suppression film 761; it is therefore preferable that the distance t3 be set at 0.5 μm or more.

In other respects, the configuration of the first modified example of Embodiment 8 is similar to that of Embodiment 8 described above. The effects of the first modified example of Embodiment 8 are similar to those of Embodiment 8 described above.

The above-described growth suppression film 761 can be formed, for example, in the following manner.

First, by a method similar to that used in Embodiment 6 described previously, a depressed portion (carved region) is formed in a substrate to prepare an n-type GaN substrate 10 having a depressed portion 2 (carved region) formed in it as shown in FIG. 43. Next, a resist is applied over the entire surface of the principal growth plane 10a of the n-type GaN substrate 10. Then, by use of a photolithography technology, part of the resist in an area narrower than the opening width g (see FIG. 60) of the depressed portion 2 is selectively removed. In this way, an opening as a resist pattern is formed such as to expose part of the side surface portions 2b of the depressed portion 2 and the floor surface portion 2a of the depressed portion 2.

Subsequently, by a sputtering process using an ECR sputtering machine, an AlN film as a growth suppression film is formed over the entire surface, and then by use of a resist removal liquid or organic solvent (for example, acetone, ethanol, etc.), the resist is removed. Thus, by lift-off, a growth suppression film 761 as shown in FIG. 60 is formed.

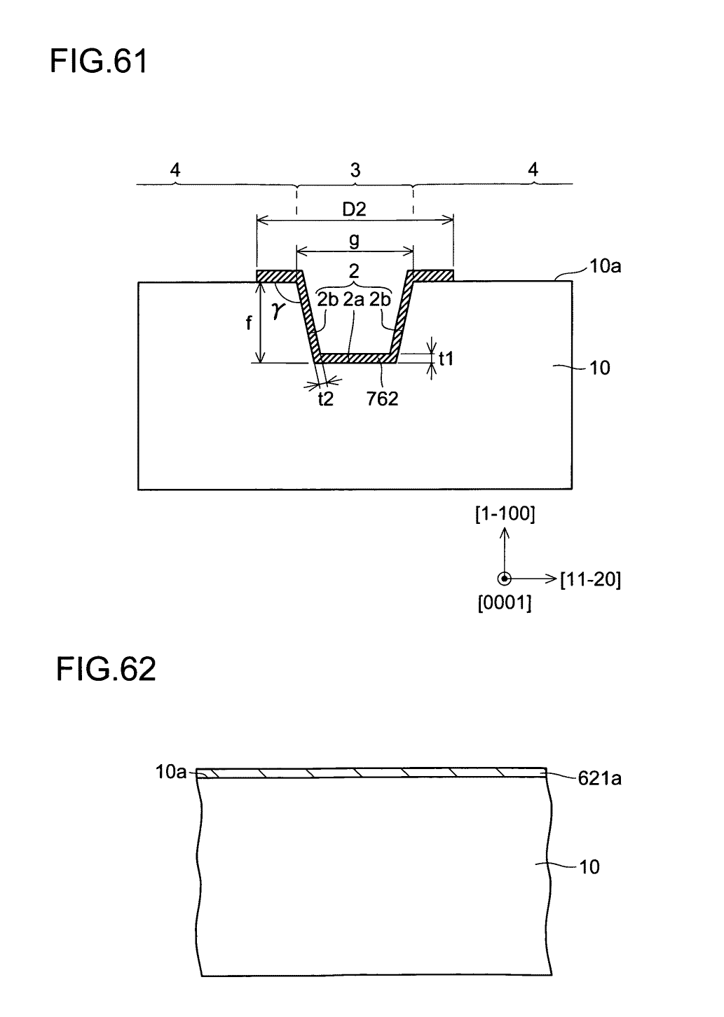

FIG. 61 is a sectional view illustrating a nitride semiconductor wafer and a nitride semiconductor laser chip according to a second modified example of Embodiment 8. Now, with reference to FIG. 61, a description will be given of, as a second modified example of Embodiment 8, another example where the growth suppression film is given a different shape.

In the second modified example of Embodiment 8, as shown in FIG. 61, a growth suppression film 762 formed of an AlN film is formed not only inside the depressed portion 2 (carved region 3) but also on part of the uncarved region 4.

Moreover, the growth suppression film 762 has a predetermined width D2 larger than the opening width g of the depressed portion 2, and is, as in Embodiment 8 described above, formed so as to extend along the depressed portion 2 (so as to extend in the c-axis [0001] direction).

In other respects, the configuration of the second modified example of Embodiment 8 is similar to that of Embodiment 8 described above. The effects of the second modified example of Embodiment 8 are similar to those of Embodiment 8 described above.

The above-described growth suppression film 762 can be formed, for example, by using a modified resist pattern in the method of manufacture of the first modified example described above. Specifically, by use of a photolithography technology, part of the resist in an area wider than the opening width g of the depressed portion 2 is selectively removed, so that an opening as a resist pattern is formed such as to expose the depressed portion 2 (carved region 3) and part of the uncarved region 4. Thereafter, by a method similar to that used in the first modified example described above, a growth suppression film 762 as shown in FIG. 61 is formed.

### Embodiment 9

In a nitride semiconductor wafer and a nitride semiconductor laser chip according to a ninth embodiment (Embodiment 9) of the invention, unlike in Embodiments 6 to 8 described previously, first, a layer of a nitride semiconductor is grown on a nitride semiconductor substrate, and thereafter a depressed portion (carved region) is formed. Then, on top of the nitride semiconductor substrate thus having the depressed portion (carved region) formed in it, further nitride semiconductor layers are formed (re-grown). Here, the substrate before having a depressed portion (carved region) formed in it (but having a nitride semiconductor layer formed on it) will be referred to as the “template substrate.”

In a specific configuration according to Embodiment 9, on an n-type GaN substrate similar to that in Embodiment 6 described previously, a first AlGaN layer of n-type Al_{0.02}Ga_{0.98}N with a thickness of about 0.5 μm is formed. This first AlGaN layer is formed before a depressed portion (carved region) is formed. In this way, as a result of the first AlGaN layer being formed on the n-type GaN substrate, the template substrate is formed.

In a predetermined region of the template substrate, a depressed portion (carved region) similar to that in Embodiment 6 described previously is formed. On top of the template substrate having the depressed portion (carved region) formed in it, individual nitride semiconductor layers are stacked. Formed on top of the template substrate is a device structure similar to those in Embodiments 1 and 7 described previously. A growth suppression film similar to that in Embodiment 7 may be formed on the template substrate.

Here, the width of the gradient thickness region depends on the off angle in the a-axis direction as described previously; it has also been found out that the width of the gradient thickness region varies with, in addition to the off angle in the a-axis direction, the thickness of the nitride semiconductor layer. Specifically, as the total thickness of the nitride semiconductor layer stacked on the substrate increases, the width of the gradient thickness region tends to increase. More specifically, as the thickness increases, the width of the gradient thickness region grows gradually starting at its part in contact with the depressed portion (carved region). This may be undesirable in a case where a thick nitride semiconductor layer is formed, because it makes the gradient thickness region wider and the emission portion formation region accordingly narrower.

On the other hand, in Embodiment 9, with the configuration described above, it is possible to suppress an increase in the width of the gradient thickness region. Specifically, since the gradient thickness region is formed by the nitride semiconductor layers formed after the depressed portion (carved region) is formed, by forming a nitride semiconductor layer before forming the depressed portion (carved region), it is possible to reduce the total thickness of the individual nitride semiconductor layers formed after formation of the depressed portion (carved region). This makes it possible to make the gradient thickness region narrow.

Moreover, in Embodiment 9, by first forming the first AlGaN layer and then forming the depressed portion (carved region), even in a case were a nitride semiconductor layer with a higher Al composition is formed, it is possible to suppress strain more effectively. Thus, it is possible to obtain a more powerful effect of suppressing cracks.

In other respects, the configuration and effects of Embodiment 9 are similar to those of Embodiment 6 described previously.

FIGS. 62 to 64 are sectional views illustrating a method of manufacture of a nitride semiconductor laser chip according to Embodiment 9 of the invention. FIG. 64 shows a section of a part where the depressed portion (carved region) is not formed. Next, with reference to FIGS. 62 to 64, a method of manufacture of a nitride semiconductor laser chip according to Embodiment 9 will be described.

First, as shown in FIG. 62, by an MOCVD process, by use of an n-type GaN substrate 10 similar to that in Embodiment 6, on its principal growth plane 10a, a first AlGaN layer 621a of n-type Al_{0.02}Ga_{0.98}N is grown with such a thickness as not to develop a crack (for example, about 0.5 μm). In this way, the template substrate is formed. At this stage, since no depressed portion (carved region) has yet been formed in the n-type GaN substrate 10, no gradient thickness region is formed in the first AlGaN layer 621a.

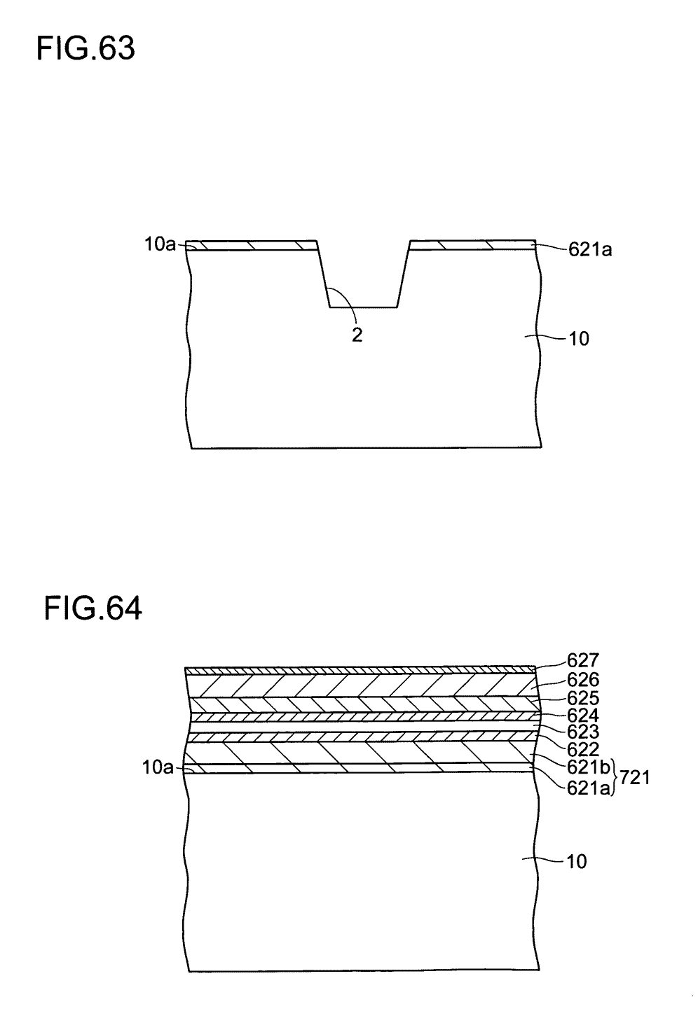

Next, the template substrate is taken out of the MOCVD machine for a while. Then, as shown in FIG. 63, by a method similar to that in Embodiment 6 described previously, a depressed portion (carved region) 2 is formed in the template substrate. At this time, strain in the first AlGaN layer 621a as results from lattice mismatch with the n-type GaN substrate 10 is alleviated by formation of the depressed portion 2. After formation of the depressed portion 2, a growth suppression film may be formed on the template substrate.

Thereafter, the n-type GaN substrate 10 having the depressed portion 2 formed in it (the template substrate) is introduced back into the MOCVD machine and, as shown in FIG. 64, on the first AlGaN layer 621a, a second AlGaN layer 621b of Al_{0.06}Ga_{0.94}N with a thickness of about 1.7 μm is grown. Now, the first AlGaN layer 621a and the second AlGaN layer 621b together form an n-type clad layer 721 with a thickness of about 2.2 μm (=0.5 μm+1.7 μm).

Here, in Embodiment 9, as a result of the thick second AlGaN layer 621b being grown on the first AlGaN layer 621a, as compared with in a case where it is formed directly on the n-type GaN substrate 10, development of strain as results from lattice mismatch is suppressed. This makes it possible to form a nitride semiconductor layer (for example, AlGaN layer) with a still higher Al composition thicker than ever.

Subsequently, on the n-type clad layer 721 (second AlGaN layer 621b), by an MOCVD process, individual nitride semiconductor layers 622 to 627 similar to those in Embodiment 6 described previously are grown. At this time, the nitride semiconductor layer grown after formation of the depressed portion 2 (the n-type clad layer 621) forms the gradient thickness region. Thus, by forming a nitride semiconductor layer (here, the first AlGaN layer 621a) before formation of the depressed portion 2, it is possible to reduce the total thickness of the individual nitride semiconductor layers grown after formation of the depressed portion 2. This makes it possible to form the gradient thickness region narrow.

Thereafter, through steps similar to those in Embodiment 6 described previously, the nitride semiconductor laser chip according to Embodiment 9 is manufactured.

In a case where the topmost layer of the template substrate is a nitride semiconductor layer containing Al (for example, an AlGaN, AlInGaN, AlInN, or like layer), after the second-time introduction into the MOCVD machine, if the temperature is raised to about 1100° C. for re-growth, atoms of other than Al, such as atoms of Ga and In, may evaporate, leaving an Al-rich, high-resistance layer at the surface. To avoid this, it is preferable that the nitride semiconductor layer so re-grown be formed at a growth temperature in a range of 700° C. to 950° C. Within this range of growth temperatures, it is possible to perform re-growth without forming an Al-rich, high-resistance layer.

Moreover, it has been found that, in a case where use is made of a nitride semiconductor substrate having as the principal growth plane a plane having an off angle in the a-axis direction relative to the m plane, even by growth at low temperature in a range of 700° C. to 950° C. as described above, it is possible to obtain a film with very good crystallinity and high surface flatness. Thus, also from this viewpoint, it is preferable to perform re-growth by use of a nitride semiconductor substrate having as the principal growth plane a plane having an off angle in the a-axis direction relative to the m plane. To suppress formation of an Al-rich, high-resistance layer, it is only necessary that the temperature at which re-growth is started be in a range of 700° C. to 950° C.; once re-growth has started, growth may be continued while the temperature is raised to an optimal level.

With respect to formation of an Al-rich, high-resistance layer as mentioned above, this phenomenon can be suppressed by forming a GaN layer at the surface of the nitride semiconductor layer before re-growth. Thus, from the viewpoint of suppressing formation of a high-resistance layer, it is preferable to form a GaN layer as the topmost layer of the template substrate.

A requirement for the nitride semiconductor layer formed before formation of the depressed portion (carved region) is that it be a semiconductor layer formed of AlₓGa_{y}In_{z}N (where 0≦x≦1, 0≦y≦1, 0≦z≦1, and x+y+z=1); it may also contain 10% or less of oxygen. For example, the just-mentioned nitride semiconductor layer may be a film of oxynitride such as AlON.

Before a depressed portion (carved region) is formed in the substrate, by use of an MOCVD machine, an n-type GaN layer and a first clad layer of n-type Al_{0.062}Ga_{0.938}N may be formed successively. In this way too, the template substrate may be formed. The template substrate thus formed is taken out of the MOCVD machine for a while, and is, after a depressed portion (carved region) is formed, introduced back into the MOCVD machine for re-growth of individual nitride semiconductor layers. Also in this case, as in the case described above, it is possible to suppress an increase in the width of the gradient thickness region.

### Embodiment 10

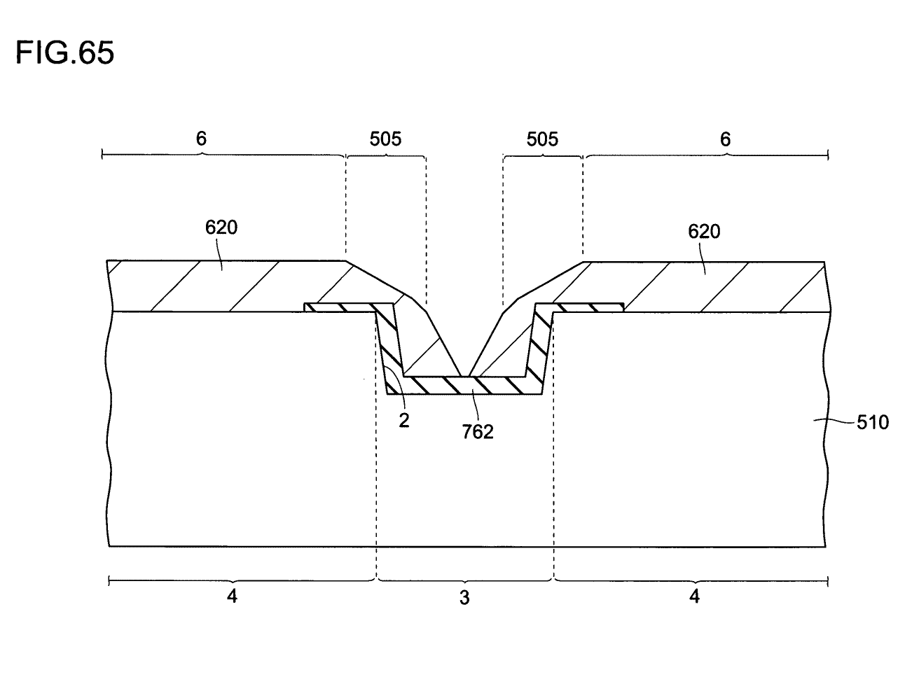

FIG. 65 is a sectional view illustrating a nitride semiconductor wafer and a nitride semiconductor laser chip according to a tenth embodiment (Embodiment 10) of the invention. Next, with reference to FIG. 65, a description will be given of, as Embodiment 10, a case where a gradient thickness region is formed by use of a substrate provided with substantially no off angle. Embodiment 10 will deal with an example in which a nitride semiconductor chip according to the invention is applied to a nitride semiconductor laser chip.

In a nitride semiconductor wafer and a nitride semiconductor laser chip according to Embodiment 10, as shown in FIG. 65, by use of an n-type GaN substrate 510 having the m plane as the principal growth plane, a nitride semiconductor wafer and a nitride semiconductor laser chip are formed. The n-type GaN substrate 510 here, however, unlike in Embodiments 1, 3, and 9 described previously, is provided with substantially no off angle. The n-type GaN substrate 510 is an example of a “nitride semiconductor substrate” according to the invention.

Moreover, in Embodiment 10, on the top surface of the n-type GaN substrate 510, a growth suppression film 762 for suppressing crystal growth of a nitride semiconductor is formed. Specifically, a growth suppression film 762 formed of an AlN film is formed inside the depressed portion 2 (carved region 3) and also on part of the uncarved region 4. That is, in Embodiment 10, a growth suppression film 762 similar to the one in the second modified example of Embodiment 7 described previously is formed on the n-type GaN substrate 510. This growth suppression film 762 forms, on the part of the nitride semiconductor layer 620 over the growth suppression film 762, a gradient thickness region 505.

In Embodiment 10, the growth suppression film 762 is so formed as to overlap the uncarved regions 4 on both sides of the depressed portion 2 (carved region 3). Thus, the gradient thickness region 505 is formed one on each side of the depressed portion 2 (carved region 3). The thickness of this gradient thickness region 505, as with the gradient thickness region in Embodiments 1 and 7 described previously, increases in a gradient fashion (gradually) toward the depressed portion 2 (carved region 3). Thus, also in this case, it is possible to obtain a powerful effect of suppressing cracks.

In other respects, the configuration of Embodiment 10 is similar to those of Embodiments 6 to 8 described previously. The configuration of Embodiment 9 described previously may be applied to Embodiment 10.

In Embodiment 10, by forming the growth suppression film 762 on the n-type GaN substrate 510 as described above, even in a case where use is made of an m-plane nitride semiconductor substrate having no off angle in the a-axis direction, it is possible to form a gradient thickness region 505 in part of the nitride semiconductor layer 620. This makes it possible to obtain a powerful effect of suppressing cracks as in Embodiment 6 described previously.

In a case where an oxide film is formed as the growth suppression film mentioned above, since almost no epitaxial growth occurs on an oxide film, it is difficult to form a satisfactory gradient thickness region. For this reason, preferable as the gradient thickness region in this case is a film of a nitride of aluminum or a film of an oxynitride of aluminum. By forming the growth suppression film out of such a material, it is possible to perform epitaxial growth even on the growth suppression film, and thus to form a satisfactory gradient thickness region easily.

In other respects, the effects of Embodiment 10 are similar to those of Embodiments 6 to 8 described previously.

### Embodiment 11

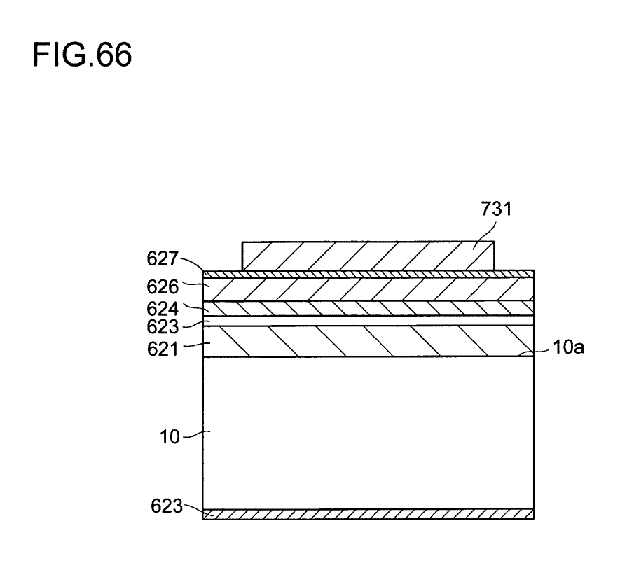

FIG. 66 is a sectional view of a light-emitting diode chip according to an eleventh embodiment (Embodiment 11) of the invention. Next, with reference to FIGS. 30 and 66, a light-emitting diode chip (LED, or light-emitting diode) according to Embodiment 11 of the invention will be described. Embodiment 11 will deal with an example in which a nitride semiconductor chip according to the invention is applied to a light-emitting diode chip.

In Embodiment 11, a light-emitting diode chip is formed by forming individual nitride semiconductor layers similar to those in Embodiments 1 and 7 described previously on an n-type GaN substrate 10 similar to that in Embodiments 1 and 7. In Embodiment 11, however, unlike in Embodiments 1 and 7 described previously, neither the n-type guide layer 622 (see FIG. 30) nor the p-type guide layer 625 (see FIG. 30) is formed.

Specifically, as shown in FIG. 66, on the principal growth plane 10a of the n-type GaN substrate 10, the following layers are formed successively: an n-type clad layer 621, an active layer 623, a carrier block layer 624, a p-type clad layer 626, and a p-type contact layer 627. On the p-type contact layer 627, a p-side electrode 731 is formed which is formed of an oxide-based transparent electrically conductive film such as ITO (indium tin oxide). On the back face of the GaN substrate 10, an n-side electrode 632 is formed.

Moreover, in Embodiment 11, as in Embodiments 6 to 9 described previously, the barrier layers in the active layer 623 are formed of AlInGaN, which is a nitride semiconductor containing Al and In.

In Embodiment 11, by forming the barrier layers out of a nitride semiconductor containing Al and In as described above, it is possible to suppress development of dark lines. This makes it possible to enhance luminous efficacy.

In the case of a light-emitting diode chip, since it does not require an AlGaN clad layer needed for light confinement, cracks are less likely to develop. Even then, forming the barrier layers out of a nitride semiconductor containing Al and In is preferable, because by doing so, it is possible to suppress appearance of dark lines. Moreover, forming a carved region in the substrate helps alleviate strain in the active layer resulting from use of a nitride semiconductor layer containing Al and In in the barrier layers, and this makes it possible to suppress appearance and expansion of dark lines effectively.

Moreover, in Embodiment 11, with the configuration described above, it is possible to enhance flatness on the layer surface and crystallinity. This too makes it possible to enhance luminous efficacy.

In Embodiment 11, by forming the barrier layers out of a nitride semiconductor containing Al and In, even in a case where an increased number of well layers are provided, it is possible to suppress a lowering in luminous efficacy. Thus, by increasing the number of well layers, it is possible to enhance luminous efficacy easily.

Moreover, as described previously, forming the barrier layers out of AlInGaN helps greatly enhance the efficiency of In absorption into the well layers. Thus, even with a reduced gas flow rate of In, it is possible to maintain a high In composition ratio, and thus to enhance absorption efficiency. This makes it possible to achieve a lengthening in emission wavelength more effectively. In that case, compared with in a case where the barrier layers are formed of AlGaN, it is possible to form the well layers in multiple layers more easily.

Furthermore, by forming the barrier layers out of AlInGaN, compared with forming them out of AlGaN, it is possible to reduce crystal strain. That is, by stacking well layers of InGaN and barrier layers of AlInGaN alternately, compared with stacking well layers of InGaN and barrier layers of AlGaN alternately, it is possible to reduce the crystal strain resulting from a difference in lattice constant. Generally, in light-emitting diode chips, the active layer is often given a quantum well structure with two or more, comparatively many, well layers. Thus, from the viewpoint of crystal strain, forming the barrier layers out of AlInGaN is more advantageous than forming them out of AlGaN.

In other respects, the effects of Embodiment 11 are similar to those obtained in cases where the configurations of Embodiments 1 and 7 described previously are applied to light-emitting diode chips.

### Practical Example 17

In Practical Example 17, an LED was fabricated by use of an n-type GaN substrate having an off angle of 3 degrees in the a-axis direction and an off angle of +0.5 degrees in the c-axis direction relative to the m plane {1-100}. In Practical Example 17, on the principal growth plane of the substrate, first, an n-type Al_{0.01}Ga_{0.99}N with a thickness of about 1 μm was formed, and then a 4QW active layer of Al_{0.01}In_{0.01}Ga_{0.98}N (with a thickness of about 15 nm) and In_{0.25}Ga_{0.75}N (with a thickness of about 3 nm) was formed. Next, on the 4QW active layer, a p-type Al_{0.2}Ga_{0.8}N carrier block layer with a thickness of about 20 nm was formed. Then, on the p-type Al_{0.2}Ga_{0.8}N carrier block layer, a p-type GaN contact layer with a thickness of about 0.2 μm was formed. Thereafter, on the p-type GaN contact layer, as an oxide-based transparent electrically conductive film, a film of ITO (indium tin oxide) with a thickness of about 50 nm was formed on an EB (electron beam) vapor deposition machine, thereby to form a p-side electrode of ITO. Configured in this way, Practical Example 17 too offered an effect of suppressing development of dark lines, an effect of improving luminous efficacy, and an effect of suppressing bright-spotted emission.

As the above-mentioned oxide-based transparent electrically conductive film, instead of an ITO transparent electrically conductive film, which is indium oxide-based, it is possible to use an In₂O₃—ZnO-based transparent electrically conductive film, a ZnO-based transparent electrically conductive film, of which the main component is zinc oxide, a SnO₂-based transparent electrically conductive film, which is tin oxide-based, or the like. By use of such a transparent electrically conductive film, it is possible to greatly enhance light extraction efficiency. Moreover, by use of a substrate having an off angle in the a-axis direction relative to the m plane, it is possible to form the electrode on a p-type layer whose surface morphology has been improved, and thus it is possible to obtain a low contact resistance; furthermore, it is possible to suppress bright-spotted emission to achieve uniform light emission and uniform injection and thereby enhance luminous efficacy; thus, using a transparent electrically conductive film as the contact electrode for the nitride semiconductor layers formed on the above-described substrate gives a great advantage, and is therefore preferable. Particularly preferable is an ITO electrode, because it allows annealing at low temperature and is thus less likely to inflict thermal damage to the active layer. In Practical Example 17, annealing was performed at 600° C.

Preferably, the oxide-based transparent electrically conductive film is formed, first, in an amorphous state on the p-type contact layer 627 on an EB vapor deposition machine, a sputtering machine, or the like, and is thereafter crystallized by thermal annealing at a temperature of about 400° C. to 700° C., because this lowers the resistance of the film and helps reduce the driving voltage. Here, more preferably, use is made of a nitride semiconductor substrate having an off angle in the a-axis direction, because this makes it possible to form a contact layer with very high flatness, and helps reduce the contact resistance between the oxide-based transparent electrically conductive film and the p-type contact layer 627.

### Practical Example 18

In Practical Example 18, an LED having substantially the same structure as that of Practical Example 17 was fabricated by use of a substrate similar to that in Practical Example 17. In Practical Example 18, however, the barrier layers were formed of AlₛInₜGaᵤN (s=0.01, t=0.03, u=0.96). This too offered effects similar to those mentioned above. Moreover, the content of In in addition to that of Al in the barrier layers permits growth at low temperature, and is therefore preferable.

### Practical Example 19

In Practical Example 19, by use of a substrate similar to that in Practical Example 17, an LED similar to that in Practical Example 11 described above was fabricated. In Practical Example 19, however, the barrier layers were formed of AlₛInₜGaᵤN (s=0.02, t=0.01, u=0.97). The LED of Practical Example 19 emitted light at an emission wavelength of 520 nm, and no dark lines were observed in its emission pattern.

In cases where the barrier layers were formed of AlₛInₜGaᵤN, largely similar effects were obtained when the Al composition ratio s was in a range of 0<s≦0.08 and the In composition ratio t was in a range of 0<t≦0.10.

Furthermore, a plurality of chips with different numbers, increasing from two to eight in increments of one, of well layers were fabricated, and their luminous efficacy was measured. With chips having the barrier layers formed of GaN or InGaN, as the number of well layers increased, luminous efficacy greatly lowered. By contrast, with chips having the barrier layers formed of a nitride semiconductor containing Al (for example, AlInGaN), no lowering in luminous efficacy was observed. With three or more well layers, forming the barrier layers out of AlInGaN, as compared with forming them out of AlGaN, resulted in about 1.2 time enhanced luminous efficacy.

### Embodiment 12

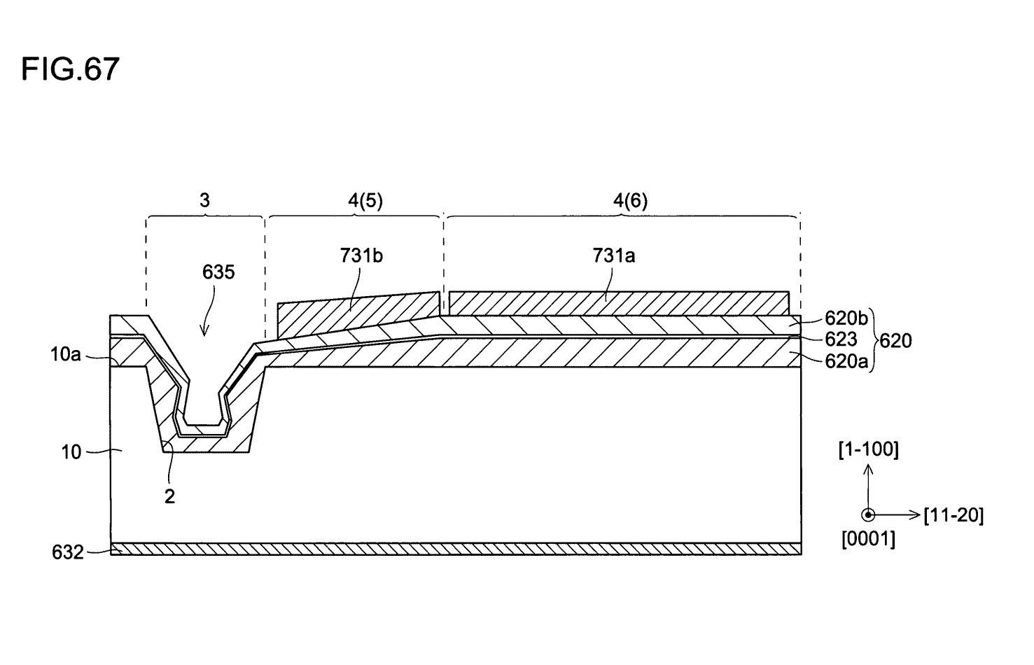

FIG. 67 is a sectional view schematically showing a light-emitting diode chip according to a twelfth embodiment (Embodiment 12) of the invention. Next, with reference to FIG. 67, a description will be given of, as Embodiment 12, an example in which a nitride semiconductor chip according to the invention is applied to a light-emitting diode chip. Embodiment 12 will deal with an example in which a nitride semiconductor chip according to the invention is applied to a light-emitting diode chip.

The light-emitting diode chip according to Embodiment 12 is formed by stacking a nitride semiconductor layer 620 similar to that in Embodiment 6 described previously on an n-type GaN substrate 10 similar to that in Embodiment 6 described previously. Specifically, the light-emitting diode chip has a structure in which, as shown in FIG. 67, a nitride semiconductor layer 620 including an n-type nitride semiconductor layer 620a, an active layer 623, and a p-type nitride semiconductor layer 620b is formed on the principal growth plane 10a of the n-type GaN substrate 10. The n-type nitride semiconductor layer 620a includes an n-type clad layer; the p-type nitride semiconductor layer 620b includes a carrier block layer, a p-type clad layer, and a p-type contact layer. Here, there is no need for light confinement as in a laser chip, and accordingly the n-type and p-type clad layers do not need to have so high Al compositions as in a laser chip; they are formed to have Al compositions of about 0% to 2%.

Moreover, in the light-emitting diode chip according to Embodiment 12, in a predetermined region of the n-type GaN substrate 10, a depressed portion 2 (carved region 3) similar to that in Embodiment 6 is formed. Furthermore, in Embodiment 12, as a result of the nitride semiconductor layer 620 being formed on the principal growth plane 10a of the n-type GaN substrate 10, a gradient thickness region 5 and an emission portion formation region 6 are formed in the nitride semiconductor layer 620 over the uncarved region 4.

Here, compared with the emission portion formation region 6, the gradient thickness region 5 has a weaker effect of suppressing bright-spotted emission but does permit EL emission to occur. Moreover, the gradient thickness region 5 emits light at a shorter wavelength than the emission portion formation region 6. Accordingly, in the light-emitting diode chip according to Embodiment 12, p-side electrodes 731a and 731b which are transparent electrodes are formed on both the emission portion formation region 6 and the gradient thickness region 5 respectively. The p-side electrodes 731a and 731b are formed separate from each other so that light emission in the emission portion formation region 6 and in the gradient thickness region 5 can be controlled separately.

On the back face of the n-type GaN substrate 10, an n-side electrode 632 as a common electrode is formed.

A nitride semiconductor wafer according to Embodiment 12 is formed so as to include a plurality of the light-emitting diode chip according to Embodiment 12 described above.

In Embodiment 12, as described above, light-emitting regions are formed in both the gradient thickness region 5 and the emission portion formation region 6, and this makes it possible to obtain a novel light-emitting chip (light-emitting diode chip) that, in a single chip, has two or more emission peaks.

In Embodiment 12, a configuration that permits light emission in the emission portion formation region 6 and in the gradient thickness region 5 to be controlled separately is adopted, and this makes it possible to obtain a novel light-emitting chip (light-emitting diode chip) that emits light in a very wide range of emission wavelength.

In other respects, the effects of Embodiment 12 are similar to those obtained in a case where the configuration of Embodiment 6 described previously is applied to a light-emitting diode chip.

It should be understood that the embodiments disclosed herein are in every respect illustrative and not restrictive. The scope of the present invention is set out not in the description of the embodiments presented above but in the appended claims, and encompasses any variations and modifications within the sense and scope equivalent to those of the claims.

For example, although Embodiments 1 to 12 described above deal with examples in which the invention is applied to light-emitting chips such as nitride semiconductor laser chips and light-emitting diode chips as examples of nitride semiconductor chips, this is not meant to limit the invention; the invention may be applied to semiconductor chips other than nitride semiconductor light-emitting chips. For example, the invention may be applied to devices employing a nitride semiconductor in general such as electronic devices (for example, power transistors, ICs (integrated circuits), LSIs (large-scale integrated circuits), etc.). In such cases, in Embodiments 6 to 12 described above, the device can be formed in a region over the uncarved region other than the gradient thickness region (that is, in a region corresponding to the emission portion formation region). With that configuration, it is possible to obtain an electronic device with superb characteristics.

Although Embodiments 1 to 3, 5, 6, 8, 9, 11, and 12 described above deal with examples in which the off-angle in the a-axis direction is set to be larger than 0.1 degrees, this is not meant to limit the invention; the off-angle in the a-axis direction may be 0.1 degrees or smaller. With consideration given to the effect of suppressing bright-spotted emission, and to surface morphology, however, it is preferable that the off-angle in the a-axis direction be larger than ±0.1 degrees.

Although Embodiments 1 to 12 described above deal with examples in which a GaN substrate is used as a nitride semiconductor substrate, this is not meant to limit the invention; any nitride semiconductor substrate other than a GaN substrate may be used. As a nitride semiconductor substrate, it is possible to use a substrate of a nitride semiconductor such as GaN, AlN, InN, BN, TIN, or a mixed crystal of any of these. It is also possible to use a substrate in which a layer of a nitride semiconductor having carved and uncarved regions is formed on top of a substrate of a nitride semiconductor or on top of a substrate of other than a nitride semiconductor. For example, it is possible to use a substrate obtained by first forming a primer layer of a nitride semiconductor on top of a base substrate such as a GaN substrate, a sapphire substrate, or SiC substrate and then forming a depressed portion in the primer layer. A “nitride semiconductor substrate” in the present invention conceptually includes such substrates (including template substrates).

In Embodiments 1 to 12 described above, with regard to the individual nitride semiconductor layers grown as a crystal on top of the substrate, their respective thicknesses, compositions, etc. may be differently combined or changed as necessary to suit the desired characteristics. For example, a semiconductor layer may be added or eliminated, or the order of semiconductor layers may be partly changed. For another example, a layer such as a buffer layer of GaN may be formed between the GaN substrate and the n-type clad layer. The conductivity types of semiconductor layers may be partly changed. That is, any variations and modifications are possible so long as the basic characteristics of a nitride semiconductor chip are obtained.

Although Embodiments 1 to 12 described above deal with examples in which the In composition ratio in the well layers is 0.2 to 0.28, this is not meant to limit the invention; the In composition ratio in the well layers may be changed as necessary within a range of 0.15 or more but 0.45 or less. The In composition ratio in the well layers may even be less than 0.15. The well layers may contain Al so long as its content is 5% or less. The carrier block layer may contain In so long as its content is 7% or less. The In content there is preferable because it makes it easy to form a film with good crystallinity at low temperature; it is preferable also because it helps reduce strain in the active layer that is formed to include a barrier layer formed of a nitride semiconductor layer containing Al, or Al and In.

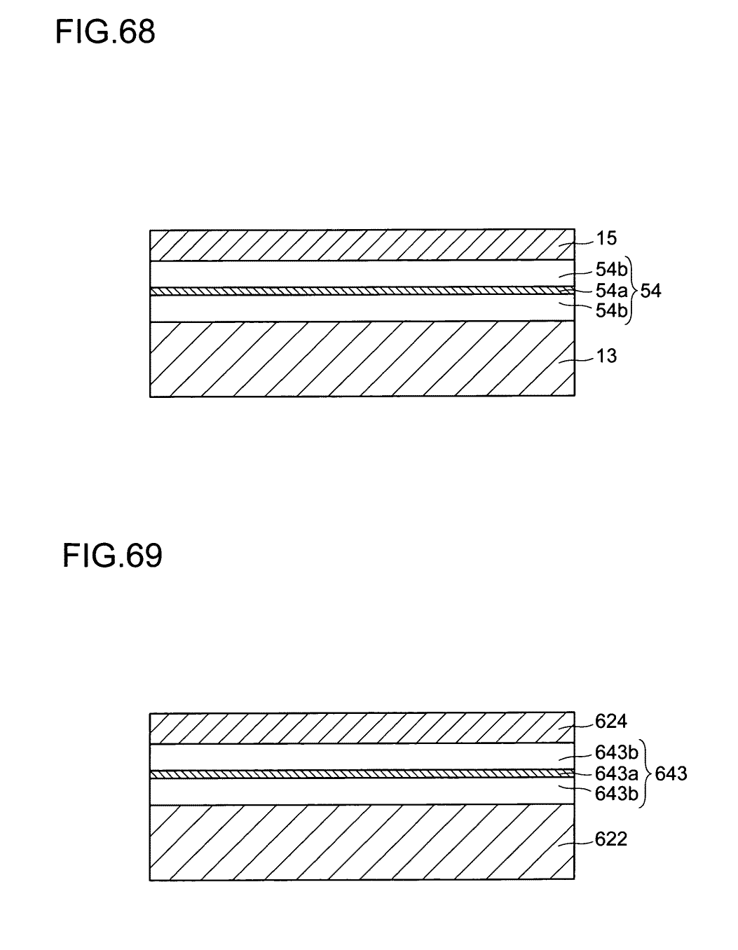

Although Embodiments 1 to 5 described above deal with examples in which the quantum well structure of the active layer is a DQW structure, this is not meant to limit the invention; the active layer may be formed to have a quantum well structure other than a DQW structure. For example, the quantum well structure of the active layer may be an SQW (single quantum well) structure. Specifically, for example, as shown in FIG. 68, on the lower guide layer 13 (in Embodiment 5, the lower clad layer), it is possible to form an active layer 54 having an SQW structure in which one well layer 54a of InGaN and two barrier layers 54b of Al_{0.005}Ga_{0.995}N are alternately stacked. The well layer 54a is given a thickness of about 3 nm to 4 nm, and the barrier layers 54b are given a thickness of about 70 nm. In Embodiments 1 to 5 described above, giving the active layer an SQW structure helps reduce the driving voltage compared with giving it a DQW structure. Specifically, with an active layer having an SQW structure, the driving voltage as observed when a current of 50 mA is injected is about 0.1 V to 0.25 V lower than with an active layer having a DQW structure. This is considered to result possibly from the fact that, in a DQW structure, depletion of carriers in the barrier layer sandwiched between two well layers produces a strong electric field in the barrier layer.

Although Embodiments 6 to 12 described above deal with examples in which the quantum well structure of the active layer is a DQW structure, this is not meant to limit the invention; the active layer may be formed to have a quantum well structure other than a DQW structure. For example, the quantum well structure of the active layer may be an SQW (single quantum well) structure. Specifically, for example, as shown in FIG. 69, on the n-type guide layer 22 (in Embodiments 6 and 12, the n-type clad layer), it is possible to form an active layer 643 having an SQW structure in which one well layer 643a of InGaN and two barrier layers 643b of Al_{0.005}In_{0.02}Ga_{0.975}N are alternately stacked. The well layer 643a is given a thickness of about 3 nm to 4 nm, and the barrier layers 643b are given a thickness of about 70 nm.

The active layer may be given, other than an SQW structure, an MQW structure. Also in cases where the active layer is given an SQW or MQW structure, it is possible to obtain an effect of suppressing appearance of dark lines and an effect of suppressing bright-spotted emission. Moreover, with a multiple quantum well structure including three or more well layers, it is possible to achieve effective light confinement and thereby increase gain. Furthermore, in an MQW structure including comparatively many well layers as used in LEDs etc., forming the barrier layers out of a nitride semiconductor containing Al and In helps reduce lattice strain from the well layers, and is thus preferable. The composition, thickness, etc. of the active layer (well layers, barrier layers) may be changed as desired.

In Embodiments 1 to 12, in a case where the active layer is given a multiple quantum well structure, the first quantum well, the second quantum well, and so forth do not need to have quite the same thickness and composition, but may each have a different thickness and composition. In that case, while each quantum well exhibits a different emission wavelength, it is preferable that the relationship between the first and second quantum wells be such that the emission wavelength of the first quantum wall, which is closest to the substrate, is the shortest and the emission wavelength of the second quantum wall is longer than that of the first quantum well.

Although Embodiments 1 to 12 described above deal with examples in which the distance between the carrier block layer and the well layers is made equal to the thickness of the third barrier layer, it is also possible to form a plurality of nitride semiconductor layers of different compositions between the carrier block layer and the well layers (the most carrier block layer-side one of the well layers). Also preferable is to dope, to p-type, part of the interface between the carrier block layer and the well layers (the most carrier block layer-side one of the well layers) with a p-type impurity such as Mg. In Embodiments 1 to 12 described above, no such doping is done.

Although Embodiments 1 to 12 described above deal with examples in which a carrier block layer is formed as a layer for preventing the carriers (electrons) injected into the active layer from flowing into the p-type semiconductor layer, this is not meant to limit the invention; in a nitride semiconductor laser chip, a clad layer containing Al can be used as a layer for blocking such carriers. In that case, it is preferable that the Al composition ratio in the clad layer be 0.08 or more.

In Embodiments 1 to 5 described above, the Al composition ratio x2 in the barrier layers may be changed as necessary within a range of 0<x2≦0.08. By forming the barrier layers out of AlGaN, it is possible to suppress dislocations that develop in the direction parallel to the c-axis direction (and appear as dark lines in the EL emission pattern) when the In composition ratio in the well layers is increased. In Embodiments 1 to 4 described above, in a case where the barrier layers are formed of AlGaN, for effective light confinement, for example, the In composition ratio in a nitride semiconductor layer such as the guide layers is increased.

In Embodiments 6 to 12 described above, the Al composition ratio s in the barrier layers formed of AlₛInₜGaᵤN may be changed as necessary within a range of 0<s≦0.08. The In composition ratio t in the barrier layers may be changed as necessary within a range lower than the In composition ratio in the well layers.

Although Embodiments 1 to 5 described above deal with examples in which the barrier layers in the active layer are formed of AlGaN, this is not meant to limit the invention; the barrier layers may be formed of, instead of AlGaN, for example an AlInGaN, AlInN, or like layer. Also with this configuration, it is possible to enhance luminous efficacy and reliability.

Although Embodiments 6 to 12 described above deal with examples in which the barrier layers are formed of AlInGaN, this is not meant to limit the invention; the barrier layers may be formed of, instead of AlInGaN, for example AlInN or the like. Forming the barrier layers in the active layer out of a nitride semiconductor containing Al (for example, AlGaN) also gives effects similar to those described above.

Although Embodiments 1 to 12 described above deal with examples in which a carrier block layer is formed on the active layer, this is not meant to limit the invention; no carrier block layer may be formed. However, just as a barrier layer formed of a nitride semiconductor layer containing Al (for example, an AlGaN, AlInGaN, or like layer) has a function of protecting the active layer, a carrier block layer, when formed, gives an effect of protecting the active layer after its growth from degradation. Thus, in a region where the In composition ratio in the well layers is high (x1≧0.15), it is preferable to form a carrier block layer. Here, in a nitride semiconductor light-emitting chip employing a nitride semiconductor substrate having the m plane as the principal growth and thus having no off angle (an m-plane just substrate), as described earlier, its EL emission pattern exhibits bright-spotted emission. This might be an adverse effect of the carrier block layer having a comparatively high Al composition ratio. On the other hand, in a case where use is made of a nitride semiconductor substrate having an off angle in the a-axis direction relative to the m plane, as described earlier, the emission pattern can be made uniform. Thus, a nitride semiconductor substrate having an off angle in the a-axis direction relative to the m plane may be said to be a non-polar substrate very suitable to form a nitride semiconductor containing Al (for example, an AlGaN or like layer) with good crystallinity. Thus, by use of a nitride semiconductor substrate having an off angle in the a-axis direction relative to the m plane, it is possible to make the carrier block layer function in a better state.

Although Embodiments 1 to 5 described above deal with examples in which the barrier layers are formed of a single nitride semiconductor layer containing Al, this is not meant to limit the invention; the barrier layers may be given a multiple-layer structure including at least one nitride semiconductor layer containing Al (for example, a super-lattice structure of InGaN and AlGaN). In that case, it is preferable that the layer contiguous with the well layer be formed of a nitride semiconductor containing Al. In a case where a multiple-layer structure is adopted, the layer contiguous with the well layer and formed of a nitride semiconductor containing Al be formed with a thickness of 1.0 nm or more, and more preferably with a thickness of 3.0 nm or more. This configuration is effective in obtaining more notable effects in terms of an effect of suppressing appearance of dark lines, an effect of enhancing heat resistance of the active layer, an effect of enhancing flatness, etc. Moreover, in a nitride semiconductor laser chip, even when a nitride semiconductor layer containing Al such as AlGaN is used in the barrier layers, by a technique of using InGaN in a guide layer, or by a technique of increasing the Al composition ratio in a clad layer, it is possible to achieve light confinement satisfactorily. In a case where the Al composition ratio is increased, a crack resulting from tensile strain may develop; however, as described in connection with Embodiment 3 above, by forming a groove (depressed portion) in the GaN substrate, it is possible to suppress development of a crack.

Although Embodiments 6 to 12 describe above deal with examples in which the barrier layers are formed of a single nitride semiconductor layer containing Al and In, this is not meant to limit the invention; the barrier layers may be given a multiple-layer structure including at least one nitride semiconductor layer containing Al and In (for example, a super-lattice structure of InGaN and AlInGaN). In that case, it is preferable that the layer contiguous with the well layer be formed of a nitride semiconductor containing Al and In. In a case where a multiple-layer structure is adopted, the layer contiguous with the well layer and formed of a nitride semiconductor containing Al and In be formed with a thickness of 1.0 nm or more, and more preferably with a thickness of 3.0 nm or more. This configuration is effective in obtaining more notable effects in terms of an effect of suppressing appearance of dark lines, an effect of enhancing heat resistance of the active layer, an effect of enhancing flatness, etc.

Although Embodiments 1 to 5 described above deal with examples in which the three barrier layers are all AlGaN layers, this is not meant to limit the invention; an AlGaN layer may be used as part of the three barrier layers. Forming at least one, in contact with a well layer, of a plurality of barrier layers out of a nitride semiconductor layer containing Al (for example, an AlGaN, AlInGaN, AlInN, or like layer) offers an effect of enhancing luminous efficacy. As the number of well layers in the active layer varies, the number of barrier layers varies accordingly. In any case, by forming at least one barrier layer out of a nitride semiconductor layer containing Al, it is possible to obtain the just-mentioned effect. For example, in Embodiment 1 described above, to enhance the flatness of the underlayer before the formation of a well layer, it is preferable to form the first and second barrier layers, which each serve as an underlayer before the formation of a well layer, out of a nitride semiconductor layer containing Al. An AlGaN layer also serves as an evaporation prevention layer for (serves to protect) an InGaN layer, and accordingly, from the viewpoint of preventing evaporation (from the viewpoint of protecting the active layer), the second and third barrier layers, each formed on a well layer, may be nitride semiconductor layers containing Al. The second barrier layer may be given a two-layer structure composed of a side in contact with the first well layer and a side in contact with the second well layer, the side of the second barrier layer in contact with the first well layer being called the lower second barrier layer and the side of the second barrier layer in contact with the second well layer being called the upper second barrier layer. To enhance the flatness of the underlayer, it is preferable to form a nitride semiconductor layer containing Al as the upper second barrier layer. On the other hand, from the viewpoint of preventing evaporation, it is preferable to form a nitride semiconductor layer containing Al as the lower second barrier layer. All the barrier layers may be nitride semiconductor layers containing Al.

Although Embodiments 6 to 12 described above deal with examples in which the three barrier layers are all AlInGaN layers, this is not meant to limit the invention; an AlInGaN layer may be used as part of the three barrier layers. Forming at least one, in contact with a well layer, of a plurality of barrier layers out of a nitride semiconductor layer containing Al (for example, an AlGaN, AlInGaN, AlInN, or like layer) offers an effect of enhancing luminous efficacy. As the number of well layers in the active layer varies, the number of barrier layers varies accordingly. In any case, by forming at least one barrier layer out of a nitride semiconductor layer containing Al and In, it is possible to obtain the just-mentioned effect. For example, in Embodiment 6 described above, to enhance the flatness of the underlayer before the formation of a well layer, it is preferable to form the first and second barrier layers, which each serve as an underlayer before the formation of a well layer, out of a nitride semiconductor layer containing Al and In. An AlInGaN layer also serves as an evaporation prevention layer for (serves to protect) an InGaN layer, and accordingly, from the viewpoint of preventing evaporation (from the viewpoint of protecting the active layer), the second and third barrier layers, each formed on a well layer, may be nitride semiconductor layers containing Al and In. The second barrier layer may be given a two-layer structure composed of a side in contact with the first well layer and a side in contact with the second well layer, the side of the second barrier layer in contact with the first well layer being called the lower second barrier layer and the side of the second barrier layer in contact with the second well layer being called the upper second barrier layer. To enhance the flatness of the underlayer, it is preferable to form a nitride semiconductor layer containing Al and In as the upper second barrier layer. On the other hand, from the viewpoint of preventing evaporation, it is preferable to form a nitride semiconductor layer containing Al and In as the lower second barrier layer. All the barrier layers may be nitride semiconductor layers containing Al and In.

In Embodiments 1 to 12 described above, the semiconductor layer formed in contact with the nitride semiconductor substrate (GaN substrate) may be of n-type conductivity or may be of p-type conductivity; it may even be non-doped.

In Embodiments 1 to 12 described above, in cases where the layer formed under the active layer, between the active layer and the substrate, is an n-side semiconductor layer and the layer formed over the active layer is a p-side semiconductor layer, it is preferable that the n-side semiconductor layer, the active layer, and the p-side semiconductor layer be formed at growth temperatures as noted below.

In a case where the n-side semiconductor layer is formed of a nitride semiconductor containing Al, it is preferable that the n-side semiconductor layer be formed at a growth temperature of 900° C. or higher but 1300° C. or lower (for example, 1075° C.), and more preferably 1000° C. or higher but 1300° C. or lower. In this way, in a case where the n-side semiconductor layer is formed of a nitride semiconductor containing Al, by forming it at a high temperature of 900° C. or higher, it is possible to give the n-side semiconductor layer a flat surface. Thus, by forming on the n-type nitride semiconductor with a flat surface the active layer and the p-side semiconductor layer, it is possible to suppress degradation of crystallinity in the active layer and the p-side semiconductor layer. This too makes it possible to form a high-quality crystal. On the other hand, by forming the n-side semiconductor layer at a growth temperature lower than 1300° C., it is possible to suppress the inconvenience of the surface of the GaN substrate re-evaporating and becoming rough during the raising of temperature due to the n-side semiconductor layers being formed at a growth temperature of 1300° C. or higher. Thus, with this configuration, it is possible to easily manufacture a nitride semiconductor light-emitting chip with superb device characteristics and high reliability.

In a case where the n-side semiconductor layer is formed of a nitride semiconductor containing In, it is preferable that the n-side semiconductor layer be formed at a growth temperature of 600° C. or higher but lower than 1100° C. (for example, 1000° C.), and more preferably 700° C. or higher but lower than 950° C. In this way, in a case where the n-side semiconductor layer is formed of a nitride semiconductor layer containing In, by forming it at a temperature of 600° C. or higher, it is possible to give the n-side semiconductor layer a flat surface. Thus, by forming on the n-type nitride semiconductor with a flat surface the active layer and the p-side semiconductor layer, it is possible to suppress degradation of crystallinity in the active layer and the p-side semiconductor layer. This too makes it possible to form a high-quality crystal. On the other hand, by forming the n-side semiconductor layer at a growth temperature lower than 1100° C., it is possible to suppress the inconvenience of poor In absorption and hence low source material efficiency. Moreover, in a case where the In composition ratio is high, it is also possible to suppress inconvenience such as degraded flatness. Thus, with this configuration, it is possible to easily manufacture a nitride semiconductor light-emitting chip with superb device characteristics and high reliability.

In a case where the n-side semiconductor layer is formed of a nitride semiconductor containing Al and In, it is preferable that the n-side semiconductor layer be formed at a growth temperature of 700° C. or higher but lower than 1000° C., more preferably 800° C. or higher but 900° C. or lower.

It is preferable that the growth temperature of the well layers in the active layer be 600° C. or higher but 830° C. or lower and, in a case where the In composition ratio in the well layers is 0.15 or more, 600° C. or higher but 770° C. or lower; more preferably, 630° C. or higher but 740° C. or lower. It is preferable that the growth temperature of the barrier layers in the active layer be the same as or higher than that of the well layers.

It is preferable that the growth temperature of the p-side semiconductor layer be, in a case where it is formed of a nitride semiconductor containing Al, 700° C. or higher but lower than 900° C., and more preferably 700° C. or higher but 880° C. or lower, and, in a case where it is formed of a nitride semiconductor containing In, 600° C. or higher but lower than 850° C., and more preferably 700° C. or higher but 800° C. or lower. In a case where the p-side semiconductor layer is formed of a nitride semiconductor containing Al and In, its preferred growth temperature is 600° C. or higher but lower than 1000° C., and more preferably 700° C. or higher but 850° C. or lower.

Although Embodiments 1 to 12 described above deal with examples in which the plurality of barrier layers are formed with different thicknesses, this is not meant to limit the invention; the plurality of barrier layers may be formed with the same thickness.

Although Embodiments 1 to 12 described above deal with examples in which the carrier block layer is given a thickness of 40 nm or less, this is not meant to limit the invention; the carrier block layer may be given a thickness more than 40 nm. Even when the carrier block layer contains about 3% of In, the effects of the present invention can be obtained. For the purpose of reducing the driving voltage, it is preferable that the Al composition ratio in the carrier block layer be higher than the Al composition ratio in the upper clad layer.

Although Embodiments 1 to 12 described above deal with examples in which Si is used as an n-type impurity, this is not meant to limit the invention; as an n-type impurity other than Si, it is possible to use, for example, O, Cl, S, C, Ge, Zn, Cd, Mg, or Be. Particularly preferable n-type impurities are Si, O, and Cl.

Although Embodiments 1 to 4 and 6 to 10 described above deal with examples in which the insulating layer is formed of SiO₂, this is not meant to limit the invention; the insulating layer may be formed of an insulating material other than SiO₂. For example, the insulating layer may be formed of SiN, Al₂O₃, ZrO₂, or the like.

In Embodiments 1 to 12 described above, any crystal axis direction (the [1-100], [11-20], and [0001] directions) may instead be any direction crystallographically equivalent to it.

In Embodiments 1 to 12 described above, as an epitaxial growth process other than an MOCVD process, it is possible to use, for example, an HVPE (hydride vapor phase epitaxy) process, an MBE (molecular beam epitaxy) process, or the like.

In Embodiments 1 to 12 described above, the method for etching used in the manufacturing procedure of the nitride semiconductor chip (nitride semiconductor laser chip, light-emitting diode chip) may be vapor-phase etching or liquid-phase etching.

Embodiments 1 to 4 described above deal with examples in which the upper guide layer is formed of p-type Al_{0.01}Ga_{0.99}N, this is not meant to limit the invention; the upper guide layer may be formed of GaN, AlGaN, or AlInGaN, or may be formed to have a super-lattice structure of a combination of any of those. Unless there is a problem from the viewpoint of light confinement or far-field pattern, it is also possible to form the p-type clad layer directly on the carrier block layer without forming the p-type guide layer (upper guide layer).

In a case where the upper guide layer is formed, and in addition the upper guide layer is a non-doped GaN layer not doped with any impurity, and thus there is further formed a p-type GaN layer doped with a p-type impurity, it is preferable that, of all the thickness of the layers constituting the light-emitting chip, the thickness (total thickness) L_{pgan} of the p-type GaN layer and the thickness (total thickness) L_{gan} of the GaN layer not doped with a p-type impurity (the n-type GaN layer intentionally doped with an n-type impurity and the non-doped n-type GaN layer intentionally left undoped with any impurity) fulfill the relationship L_{gan}<L_{pgan}. Furthermore, it is preferable that the thickness of the p-type GaN layer be 0.3 μm or less. A thickness more than 0.3 μm there may result in a wider light distribution and hence lower light confinement efficiency; it may also lead to degraded flatness.

On the other hand, in a case where the upper guide layer is a p-type GaN layer doped with a p-type impurity, no degradation of flatness occurs; thus the design can be done from the viewpoint of light confinement, and accordingly the thickness is set at, for example, about 0.3 μm or less.

In a case where InGaN, AlGaN, or AlInGaN is used in the upper guide layer, it may be intentionally left undoped with any impurity, so as to be non-doped, or may be doped with, for example, Mg as a p-type impurity. In a case where the upper guide layer is formed of AlGaN, and in addition it is a non-doped AlGaN layer, it is preferable that the Al composition ratio there be set in a range of higher than 0.0 but 0.03 or lower. In a case where it is a p-type AlGaN layer doped with a p-type impurity, it is preferable that the Al composition ratio there be set in a range of higher than 0.0 but 0.03 or lower. Forming the upper guide layer out of AlGaN gives an effect of enhancing flatness. With a non-doped AlGaN layer, if the Al composition ratio equals 0, that is, with a GaN layer, it is difficult to obtain a sufficient effect of enhancing flatness. On the other hand, if the Al composition ratio is higher than 0.03, light confinement is insufficient. In a case where the upper guide layer is formed of AlGaN, it is preferable that it be formed with a thickness of 0.05 μm or more but 0.4 μm or less, more preferably 0.08 μm or more but 0.25 μm or less. With an upper guide layer formed of AlGaN, a thickness less than 0.05 μm tends to result in an insufficient effect of enhancing flatness. On the other hand, a thickness more than 0.4 μm causes the distribution of optical electric field intensity to widen across the layer, and thus diminishes the light confinement coefficient. In a case where the upper guide layer is formed of AlGaN, by increasing the Al composition ratio in the clad layer, it is possible to enhance light confinement. Moreover, from the viewpoint of light confinement, it is more preferable that the upper guide layer be formed of a nitride semiconductor containing In.

In a case where the upper guide layer is formed of InGaN, the In composition ratio there is set in a range lower than the In composition ratio in the well layers. In a case where the upper guide layer is a non-doped InGaN layer, it is preferable that the In composition ratio there be set to be higher than 0 but 0.05 or lower. In a case where the upper guide layer is a p-type layer doped with a p-type impurity, doping with Mg helps secure flatness even with GaN, and thus it is possible to set the In composition ratio in the InGaN layer in a range of 0.0 or higher but 0.05 or lower. In a case where the upper guide layer is a non-doped InGaN layer, with a GaN layer with an In composition ratio of 0, it is difficult to obtain a sufficient effect of enhancing flatness. On the other hand, with an In composition ratio higher than 0.05, high strain may degrade crystal quality. It is preferable that an upper guide layer formed of InGaN be given a thickness of 0.05 μm or more but 0.5 μm or less, and more preferably 0.08 μm or more but 0.3 μm or less. Giving an upper guide layer formed of InGaN a thickness less than 0.05 μm results in insufficient light confinement. On the other hand, a thickness more than 0.5 μm causes the distribution of optical electric field intensity to widen across the layer, and thus diminishes the light confinement coefficient.

In a case where the upper guide layer is formed of AlInGaN, when it is a non-doped AlInGaN layer, it is preferable that the In composition ratio there be set in a range of higher than 0.002 but 0.05 or lower. It is preferable that the Al composition ratio there be set in a range of higher than 0.005 but 0.05 or less. In a case of a p-type AlInGaN layer doped with a p-type impurity, it is preferable that the In composition ratio there be set in a range of higher than 0.0 but 0.05 or lower. It is preferable that the Al composition ratio there be set in a range of higher than 0.0 but 0.05 or lower. It is preferable that an upper guide layer formed of AlInGaN be formed with a thickness of 0.05 μm or more but 0.5 μm or less, and more preferably 0.07 μm or more but 0.3 μm or less. A value outside the just mentioned ranges (over the upper limit of at least one of the ranges for composition and thickness) may result in degraded crystal quality. On the other hand, at least a value equal to or under the just mentioned ranges for composition or a value under the lower limit of the just mentioned range for thickness results in an insufficient effect of light confinement or of flatness enhancement.

The configurations described as Embodiments 1 to 4 above may be combined as necessary.

Although Embodiment 1 described above deals with an example in which two GaN layers, namely an n-type GaN layer and a lower guide layer, are formed between the substrate and the active layer, this is not meant to limit the invention; any GaN layer other than those just mentioned may also be formed so long as the total thickness is 0.7 μm or less. It is possible even to adopt a configuration in which no GaN layer is formed between the substrate and the active layer. In this case, it is preferable that the layered structure stacked on the substrate not include a GaN layer but be composed of semiconductor layers of compositions different from GaN, such as InGaN, AlGaN, InAlGaN, InAlN, etc.

Although Embodiment 1 described above deals with an example in which the semiconductor layer in contact with the principal growth plane of the GaN substrate is a GaN layer, this is not meant to limit the invention; the semiconductor layer in contact with the principal growth plane of the GaN substrate may be an AlGaN, AlInGaN, AlInN, InGaN, InN, or like layer.

Although Embodiment 1 described above deals with an example in which the individual nitride semiconductor layers stacked on the GaN substrate do not include a GaN layer among the nitride semiconductor layers formed over the active layer, this is not meant to limit the invention; the nitride semiconductor layers formed over the active layer may include a GaN layer. For example, a contact layer may be formed of a GaN layer. In a case where a p-type GaN layer doped with a p-type impurity is formed, it is preferable to adopt a configuration in which the thickness (total thickness) L_{pgan} of the p-type GaN layer and the thickness (total thickness) L_{gan} of the GaN layer not doped with a p-type impurity (the n-type GaN layer intentionally doped with an n-type impurity and the n-type GaN layer intentionally left undoped with any impurity) fulfill the relationship L_{gan}<L_{pgan}.

Although Embodiment 1 described above deals with an example in which, with the GaN layer formed on the GaN substrate, between the substrate and the active layer, given a total thickness of 0.7 μm or less, a barrier layer in the active layer is formed out of AlGaN, this is not meant to limit the invention; even when the total thickness of the GaN layer is greater than 0.7 μm, by forming a barrier layer out of AlGaN, it is possible to obtain an effect of enhancing luminous efficacy.

Although Embodiment 4 described above deals with a case in which use is made of a GaN substrate having an off angle in the c-axis direction relative to the m plane, this is not meant to limit the invention; an m-plane GaN substrate having no off angle may instead be used. Even a GaN substrate having off angles in both the a- and c-axis directions may be used. That is, by use of any substrate so long as it is a nitride semiconductor substrate having a non-polar plane as a principal growth plane, it is possible to obtain effects similar to those of Embodiment 4.

Although Embodiment 5 described above deals with a case in which the layer in contact with the principal growth plane of the substrate is an AlGaN layer (lower clad layer), this is not meant to limit the invention; the layer in contact with the principal growth plane of the substrate may be any other layer than an AlGaN layer. For example, as in Embodiment 1 described above, between the substrate and the lower clad layer, an n-type GaN layer may be formed so that the layer in contact with the principal growth plane is an n-type GaN layer. For another example, as in Embodiment 2 described above, between the substrate and the lower clad layer, an InGaN, AlInGaN, AlInN, or like layer may be formed in contact with the principal growth plane.

In Embodiment 5 described above, a carved region (depressed portion) similar to that in Embodiment 3 described above may be formed in the GaN substrate. It is also possible to use a substrate similar to that in Embodiment 4 described above (a nitride semiconductor substrate having no off angle in the c-axis direction relative to the m plane) or a non-polar substrate.

Embodiments 6 to 12 described above deal with examples in which the semiconductor layer in contact with the principal growth plane of the n-type GaN substrate is a nitride semiconductor layer containing Al (AlGaN layer), this is not meant to limit the invention; the semiconductor layer in contact with the principal growth plane of the n-type GaN substrate may be, for example, a GaN layer. In a case where the principal growth plane of the substrate has an off angle in the a-axis direction relative to the m plane, it is preferable that the GaN layer in contact with the principal growth plane be formed thin. In a case where, as just mentioned, on a nitride semiconductor substrate having as the principal growth plane a plane having an off angle in the a-axis direction relative to the m plane, a GaN layer is formed in contact with the principal growth plane, by giving the GaN layer a comparatively small thickness, it is possible to suppress degradation of surface morphology. In that case, it is preferable that the GaN layer have a thickness of 0.7 μm or less, and more preferably 0.5 μm or less. It is further preferable that the GaN layer have a thickness of 0.3 μm or less.

In a case where a GaN layer is formed on a nitride semiconductor substrate having as the principal growth plane a plane having an off angle in the a-axis direction relative to the m plane, it is preferable that the GaN layer formed between the substrate surface and the well layer (when a plurality of well layers are formed, preferably, the most substrate-side one), which is a nitride semiconductor layer containing In, have a total thickness of 0.7 μm or less, and more preferably 0.5 μm or less. It is further preferable that the GaN layer have a total thickness of 0.3 μm or less. Also in this case, it is preferable that a nitride semiconductor layer containing Al (for example, an AlGaN layer) be formed in contact with the principal growth plane of the substrate. This is because, with poor surface morphology at the time of active layer formation, under the influence of the poor surface morphology, the In contained in the well layers comes to have a large composition distribution across the plane. A composition distribution across the plane causes metallization, and notable degradation of crystallinity, in a part where In absorption is high, leading to diminished emission intensity. Also for these reasons, it is preferable to fulfill the above conditions.

Even when the layered structure stacked on the substrate is formed not to include a GaN layer but out of semiconductor layers of compositions different from GaN, such as InGaN, AlGaN, InAlGaN, InAlN, etc., it is possible to form a light-emitting chip or electronic device with superb characteristics.

In Embodiments 3 and 6 to 12 described above, the opening width and depth of the depressed portion formed in the substrate may be changed as necessary. It is, however, preferable that the opening width of the depressed portion be 1 μm or more but 50 μm or less. With the opening width of the depressed portion less than 1 μm, it is difficult to obtain, among others, the effect of suppressing cracks. On the other hand, with the opening width of the depressed portion more than 50 μm, the depressed portion (carved region) occupies too large a proportion of the area of the wafer surface. This, since it is undesirable to form the ridge portion over the depressed portion (carved region), reduces the number of chips obtained from a single wafer. It is preferable that the depth of the depressed portion be 0.1 μm or more but 15 μm or less. With the depth of the depressed portion less than 0.1 μm, the depressed portion is filled too readily. On the other hand, with the depth of the depressed portion more than 15 μm, it takes too long to form the depressed portion.

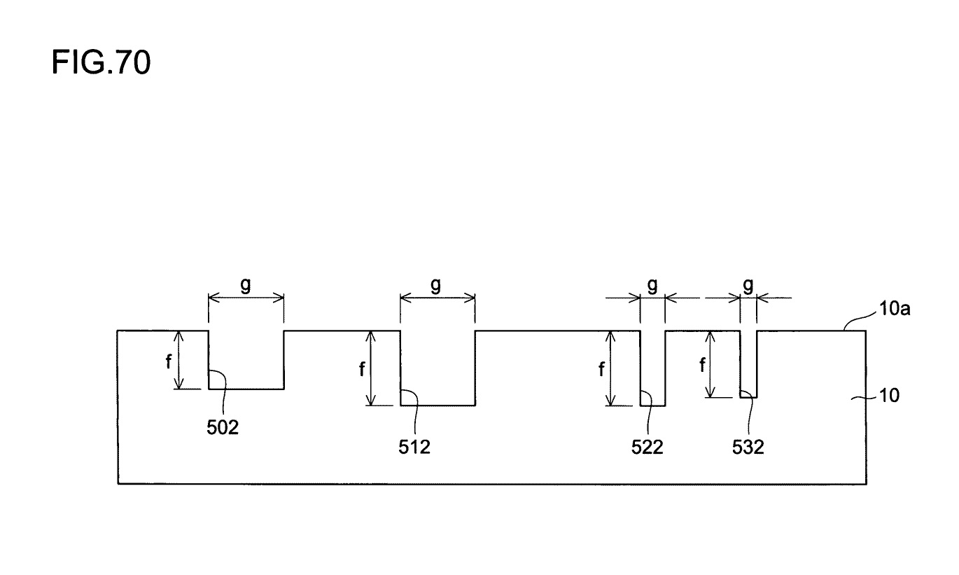

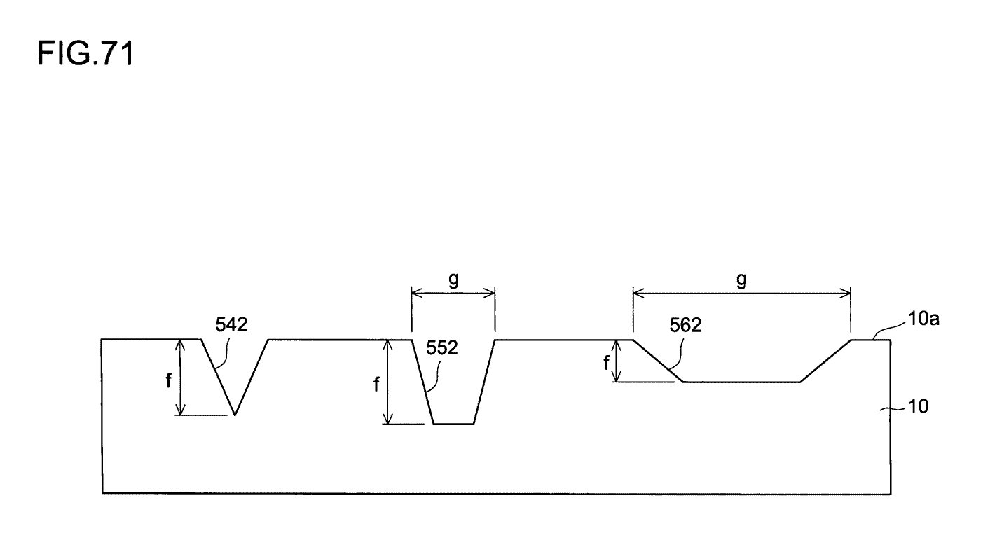

In Embodiments 3 and 6 to 12 described above, the sectional shape of the depressed portion may be changed as necessary. For example, the depressed portion may be formed to have a rectangular sectional shape as shown in FIG. 70. In this case, the depressed portion may be formed, like the depressed portion 502, such that the opening width g is larger than the depth f, or may be formed, like the depressed portion 512, such that the opening width g and the depth f are approximately equal; it may even be formed, like the depressed portions 522 and 532, such that the depth f is larger than the opening width g. The depressed portion may be formed such that its side surface portions are inclined surfaces as shown in FIG. 71. In this case, the depressed portion may be formed, like the depressed portion 542, to have a V-shaped (inverted triangular) sectional shape, or may be formed to have a O-shaped sectional shape, or may be formed, like the depressed portions 552 and 562, to have a trapezoidal sectional shape. In this case, the depressed portion may be formed, like the depressed portion 552, such that the opening width g and the depth f are approximately equal, or may be formed, like the depressed portion 562, such that the opening width g is larger than the depth f. That is, the depressed portion (carved region) formed in the substrate has simply to produce a level difference between depressed and elevated parts. With regard to the relationship between the opening width and depth of the depressed portion, it is preferable that the opening width be larger than the depth. With the opening width equal to or smaller than the depth, when the growth suppression film is formed, its part on the floor surface portion of the depressed portion may be formed thinner. By contrast, with the opening width larger than the depth, the growth suppression film can be formed with a stable thickness.

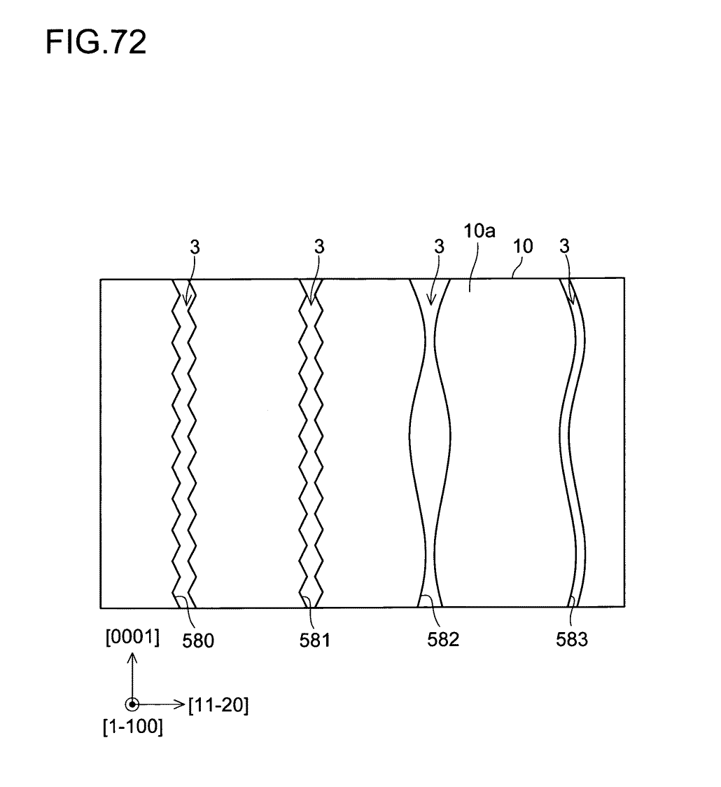

Although Embodiments 3 and 6 to 12 described above deal with examples in which the carved region is formed in the substrate by forming a depressed portion with a constant opening width in a rectilinear shape, this is not meant to limit the invention; the carved region may be formed in the substrate by forming a depressed portion in any other shape. For example, as shown in FIG. 72, the carved region 3 may be formed in the substrate by forming a depressed portion 580 in a zigzag shape, or a depressed portion 583 in a wavy shape; the carved region may be formed in the substrate by forming a depressed portion 581 or 582 with a varying opening width. With any of the carved regions formed in these ways, it is possible to obtain the effects of the invention.

Although Embodiments 3 and 6 to 12 described above deal with examples in which a plurality of depressed portions are formed at equal intervals, this is not meant to limit the invention; a plurality of depressed portions may be formed with varying intervals between adjacent depressed portions. It is possible to form depressed portions of different sectional shapes on a single substrate.

Although Embodiments 3 and 6 to 12 described above deal with examples in which the period of the depressed portions is set at about 400 μm, the period of the depressed portions can be determined according to the chip width of the nitride semiconductor laser chip: in a case where the chip width is set at, for example, about 200 μm, the period of the depressed portions can be set at about 200 μm. It is preferable that the period of (interval between) the depressed portions (carved regions) be 1 mm or less, and more preferably 400 gm or less. With this configuration, even if the wafer (substrate) has a defective part and this produces a variation in thickness, the concavity in the surface of the nitride semiconductor layer over the depressed portion severs lateral growth and thereby suppresses the spread of the defect-induced variation in thickness. On the other hand, with the period of (interval between) the depressed portions (carved regions) equal to or less than 5 μm, it is difficult to form the ridge portion, and therefore it is preferable that the period of (interval between) the depressed portions (carved regions) be more than 5 μm.

Although Embodiments 3 and 6 to 12 described above deal with examples in which the depressed portion (carved region) is formed so as to extend, as seen in a plan view, in a direction parallel to the c-axis direction, this is not meant to limit the invention; the depressed portion (carved region) may be formed so as to extend in a direction crossing the c-axis direction at a predetermined angle as observed on the principal growth plane. That is, the depressed portion (carved region) in the substrate may be formed so as to extend in a direction crossing the a-axis direction. Specifically, for example, the depressed portion (carved region) may be formed to extend in a direction crossing the c-axis direction at an angle of ±15 degrees or smaller. The depressed portions (carved regions) may be formed, other than in the shape of stripes, for example, in the shape of a lattice. Also with the depressed portion (carved region) formed in this way, so long as the principal growth plane of the substrate has an off angle in the a-axis direction, it is possible to easily form the gradient thickness region in the nitride semiconductor layer. The depressed portions (carved regions) may also be formed in the shape of stripes extending in a direction parallel to the a-axis direction. In that case, no gradient thickness region is formed in the nitride semiconductor layer, but even without a gradient thickness region, it is possible to sufficiently alleviate strain. Forming a carved region alone helps alleviate strain in the nitride semiconductor layer; thus, although it is preferable to form a gradient thickness region as well, even without it, it is possible to obtain a sufficient effect of suppressing development of cracks and a sufficient effect of alleviating strain in the active layer.

Although Embodiments 6 to 12 described above deal with examples in which the nitride semiconductor wafer is split so that each nitride semiconductor chip (nitride semiconductor laser chip, light-emitting diode chip) includes one depressed portion (concavity), this is not meant to limit the invention; the nitride semiconductor wafer may be split so that each nitride semiconductor chip (nitride semiconductor laser chip, light-emitting diode chip) includes no depressed portion (concavity). The nitride semiconductor wafer may also be split so that each nitride semiconductor chip (nitride semiconductor laser chip, light-emitting diode chip) includes a plurality of depressed portions (concavities), or so that each nitride semiconductor laser chip includes part of a depressed portion (concavity). More preferably, the wafer is so split that each chip includes a depressed portion (concavity) with a result that either the entire depressed portion (concavity) or part of it remains in the chip. Also with this configuration, it is possible to obtain nitride semiconductor chips (nitride semiconductor laser chips, light-emitting diode chips) with high yields.

Although Embodiments 6 to 12 described above deal with examples in which the nitride semiconductor wafer is split so that each chip includes at least part of the gradient thickness region, this is not meant to limit the invention; the nitride semiconductor wafer may be split so that each chip includes no gradient thickness region

In Embodiments 6, 8, 9, 11, and 12 described above, the principal growth plane of the substrate does not need to have an off angle in the c-axis direction so long as it has an off angle in the a-axis direction.

In Embodiments 3, 6 to 8, and 10 to 12 described above, the depressed portion (carved region) may be formed, as in Embodiment 9 described above, after first growing a nitride semiconductor layer of GaN, InGaN, AlGaN, InAlGaN, InAlN, or the like on the substrate. That is, the contents of the present specification apply even in cases where, first, growth is performed for a while and then the depressed portion (carved region) is formed.

Although Embodiments 7 and 10 described above deal with examples in which use is made of a GaN substrate having the m plane as the principal growth plane (a just substrate), this is not meant to limit the invention; it is also possible to use, for example, a nitride semiconductor substrate having an off angle in the c-axis direction relative to the m plane. It is also possible to use a nitride semiconductor substrate having off angles in both the a- and c-directions relative to the m plane. That is, any substrate may be used so long as it is a nitride semiconductor substrate having a non-polar plane as a principal growth plane.

Although Embodiment 8 described above deals with an example in which a growth suppression film of AlN is formed in the carved region, this is not meant to limit the invention; so long as crystal growth of a nitride semiconductor can be suppressed, any material other than AlN can be used to form a growth suppression film in the carved region. As the growth suppression film, it is preferable to use a film of a nitride of aluminum (Al), a film of an oxynitride of aluminum (Al), or a film of a nitride of aluminum (Al) and gallium (Ga). These materials offer powerful effects in all of the following aspects: suppression of cracks; improvement of surface morphology; and suppression of variation in the composition of the nitride semiconductor layer. Moreover, those materials can have a crystal structure similar to that of a nitride semiconductor, and thus a continuous crystal structure is obtained between the growth suppression film and the region where the growth suppression film is not formed. This makes those materials suitable for the growth suppression film. Materials of second choice for the growth suppression film include an oxide, a nitride, and an oxynitride of silicon (Si), an oxide of aluminum (Al), an oxide of titanium (Ti), an oxide of zirconium (Zr), an oxide of yttrium (Y), an oxide of niobium (Nb), an oxide of hafnium (Hf), an oxide of tantalum (Ta), and an oxynitride and a nitride of any of these materials. Materials of third choice include high-melting-point metals such as molybdenum (Mo), tungsten (W), and tantalum (Ta). In the effect of suppressing growth of a nitride semiconductor, a film of an oxide is the most powerful, followed by a film of an oxynitride and a film of nitride in order of decreasing effect. Accordingly, it is more preferable to form a film of an oxide as the growth suppression film inside the depressed portion.

Although Embodiments 8 and 10 described above deal with examples in which the growth suppression film is formed by a sputtering process using an ECR sputtering machine, this is not meant to limit the invention; the growth suppression film may be formed by any method other than specifically mentioned above. For example, the growth suppression film can be formed by a sputtering process using a magnetron sputtering machine, an EB (electron beam) vapor deposition process, a plasma CVD process, or the like.

The growth suppression film may be formed in any shape other than that specifically mentioned with regard to Embodiment 8 above so long as it is so shaped as to allow a concavity to be formed in the surface of the nitride semiconductor layer over the depressed portion (carved region).

Although Embodiment 10 described above deals with an example in which the growth suppression film is so formed as to overlap the uncarved regions on both sides of the depressed portion (carved region), this is not meant to limit the invention; the growth suppression film may be so formed as to overlap only the uncarved region on one side of the depressed portion (carved region). Even with this configuration, as with the configuration described above, it is possible to obtain a powerful effect of suppressing cracks.

Although Embodiment 12 described above deals with a light-emitting diode chip that has light-emitting regions in both the gradient thickness region and the emission portion formation region, this is not meant to limit the invention; a light-emitting diode chip may have a light-emitting region only in one of the gradient thickness region and the emission portion formation region. In a case where a light-emitting diode chip has a light-emitting region only in the emission portion formation region, the nitride semiconductor wafer may be split such that the light-emitting diode chip does not include the gradient thickness region.

What is claimed is:

1. A nitride semiconductor chip comprising:
a nitride semiconductor substrate having a principal growth plane; and
an active layer formed to a principal growth plane side of the nitride semiconductor substrate and having a quantum well structure including a well layer and a barrier layer, wherein
the principal growth plane is a plane having an off angle in an a-axis direction relative to an m plane, and
the barrier layer is formed of a nitride semiconductor containing Al.

2. The nitride semiconductor chip according to claim 1, wherein
the barrier layer is formed of a nitride semiconductor containing Al, Ga, and N.

3. The nitride semiconductor chip according to claim 1, wherein
the barrier layer is formed of AlInGaN.

4. The nitride semiconductor chip according to claim 1, wherein
the barrier layer is formed of AlGaN.

5. The nitride semiconductor chip according to claim 1, wherein
the active layer includes a plurality of barrier layers as the barrier layer, and
at least part of the plurality of barrier layers is formed of AlInGaN.

6. The nitride semiconductor chip according to claim 1, wherein
an absolute value of the off angle in the a-axis direction is greater than 0.1 degrees.

7. The nitride semiconductor chip according to claim 1, wherein
the well layer is formed of a nitride semiconductor containing In and has an In composition ratio of 0.15 or more but 0.45 or less.

8. The nitride semiconductor chip according to claim 1, wherein
the well layer is formed of InGaN.

9. The nitride semiconductor chip according to claim 1, wherein
the nitride semiconductor substrate is formed of GaN.

10. The nitride semiconductor chip according to claim 1, wherein
on the principal growth plane of the nitride semiconductor substrate, a nitride semiconductor layer containing Al is formed in contact with the principal growth plane.

11. The nitride semiconductor chip according to claim 1, wherein
to the principal growth plane side of the nitride semiconductor substrate, a pair of guide layers are formed between which the active layer is formed, and
the guide layers are formed of a nitride semiconductor containing In.

12. The nitride semiconductor chip according to claim 1, wherein
the principal growth plane of the nitride semiconductor substrate has an off angle, in addition to in the a-axis direction, also in a c-axis direction, and
the off angle in the a-axis direction is larger than the off angle in the c-axis direction.

13. A nitride semiconductor chip comprising:
a nitride semiconductor substrate having an m plane as a principal growth plane; and
a nitride semiconductor layer formed on the principal growth plane of the nitride semiconductor substrate and including an active layer, wherein
the nitride semiconductor substrate includes a carved region, which is a region carved in a thickness direction from the principal growth plane, and an uncarved region, which is a region not carved, and
the active layer has a barrier layer formed of a nitride semiconductor containing Al and In.

14. The nitride semiconductor chip according to claim 13, wherein
the barrier layer is formed of AlInGaN.

15. A nitride semiconductor chip comprising:
a nitride semiconductor substrate having as a principal growth plane a plane having an off angle in an a-axis direction relative to an m plane; and
a nitride semiconductor layer formed on the principal growth plane of the nitride semiconductor substrate and including an active layer, wherein
the nitride semiconductor substrate includes a carved region, which is a region carved in a thickness direction from the principal growth plane, and an uncarved region, which is a region not carved, and
the active layer has a barrier layer formed of a nitride semiconductor containing Al and In.

16. The nitride semiconductor chip according to claim 15, wherein
an absolute value of the off angle in the a-axis direction is greater than 0.1 degrees.

17. The nitride semiconductor chip according to claim 15, wherein
the principal growth plane of the nitride semiconductor substrate has an off angle, in addition to in the a-axis direction, also in a c-axis direction, and
the off angle in the a-axis direction is larger than the off angle in the c-axis direction.

18. The nitride semiconductor chip according to claim 15, wherein
the nitride semiconductor layer includes a gradient thickness region which is formed over the uncarved region and whose thickness decreases in gradient fashion toward the carved region.

19. The nitride semiconductor chip according to claim 15, wherein
the carved region is formed to extend in a c-axis direction as seen in a plan view.

20. The nitride semiconductor chip according to claim 15, wherein
the nitride semiconductor layer includes an optical waveguide region, and
the optical waveguide region is located over the uncarved region.

21. A nitride semiconductor wafer comprising:
a nitride semiconductor substrate having an m plane as a principal growth plane; and
a nitride semiconductor layer formed on the principal growth plane of the nitride semiconductor substrate and including an active layer, wherein
the nitride semiconductor substrate includes a carved region, which is a region carved in a thickness direction from the principal growth plane, and an uncarved region, which is a region not carved, and
the active layer has a barrier layer formed of a nitride semiconductor containing Al and In.

22. A nitride semiconductor wafer comprising:
a nitride semiconductor substrate having as a principal growth plane a plane having an off angle in an a-axis direction relative to an m plane; and
a nitride semiconductor layer formed on the principal growth plane of the nitride semiconductor substrate and including an active layer, wherein
the nitride semiconductor substrate includes a carved region, which is a region carved in a thickness direction from the principal growth plane, and an uncarved region, which is a region not carved, and
the active layer has a barrier layer formed of a nitride semiconductor containing Al and In.

23. The nitride semiconductor wafer according to claim 22, wherein
the principal growth plane of the nitride semiconductor substrate has an off angle, in addition to in the a-axis direction, also in a c-axis direction, and
the off angle in the a-axis direction is larger than the off angle in the c-axis direction.

24. The nitride semiconductor wafer according to claim 22, wherein
the nitride semiconductor layer includes a gradient thickness region which is formed over the uncarved region and whose thickness decreases in gradient fashion toward the carved region.

25. The nitride semiconductor wafer according to claim 22, wherein
the carved region is formed to extend in a c-axis direction as seen in a plan view.

26. A nitride semiconductor chip formed by use of the nitride semiconductor wafer according to claim 22.

27. A method of manufacturing a nitride semiconductor chip, comprising:
a step of preparing a nitride semiconductor substrate including as a principal growth plane a plane having an off angle in an a-axis direction relative to an m plane; and
a step of forming, to a principal growth plane side of the nitride semiconductor substrate, by an epitaxial growth process, an active layer having a quantum well structure including a well layer and a barrier layer, wherein
the step of forming the active layer includes a step of forming the barrier layer out of a nitride semiconductor containing Al.

28. A method of manufacturing a nitride semiconductor chip, comprising:
a step of preparing a nitride semiconductor substrate having an m plane as a principal growth plane;
a step of forming a carved region, which is a region carved in a depressed shape, in the principal growth plane of the nitride semiconductor substrate; and
a step of forming a nitride semiconductor layer on the principal growth plane of the nitride semiconductor substrate, wherein
the step of forming the nitride semiconductor layer includes a step of forming a quantum well structure including a well layer and a barrier layer, and
the step of forming the active layer includes a step of forming the barrier layer out of a nitride semiconductor containing Al and In.

29. A method of manufacturing a nitride semiconductor chip, comprising:
a step of preparing a nitride semiconductor substrate having as a principal growth plane a plane having an off angle in an a-axis direction relative to an m plane;
a step of forming a carved region, which is a region carved in a depressed shape, in the principal growth plane of the nitride semiconductor substrate; and
a step of forming a nitride semiconductor layer on the principal growth plane of the nitride semiconductor substrate, wherein
the step of forming the nitride semiconductor layer includes a step of forming a quantum well structure including a well layer and a barrier layer, and
the step of forming the active layer includes a step of forming the barrier layer out of a nitride semiconductor containing Al and In.

30. The method according to claim 29, wherein
the principal growth plane of the nitride semiconductor substrate has an off angle, in addition to in the a-axis direction, also in a c-axis direction, and
the off angle in the a-axis direction is larger than the off angle in the c-axis direction.

31. The method according to claim 29, wherein
the step of forming the carved region includes a step of forming, in a region of the principal growth plane other than the carved region, an uncarved region, which is a region not carved, and
the step of forming the nitride semiconductor layer includes a step of forming, in a region over the uncarved region, a gradient thickness region whose thickness decreases in a gradient fashion toward the carved region.

32. A semiconductor device comprising the nitride semiconductor chip according to claim 1.

33. A semiconductor device comprising the nitride semiconductor chip according to claim 15.
